(19) United States
(12) Patent Application Publication
(10) Pub. No.: US 2024/0260291 A1
(43) Pub. Date: Aug. 1, 2024

(54) LIGHT EMITTING DEVICE AND FUSED POLYCYCLIC COMPOUND FOR THE LIGHT EMITTING DEVICE

(71) Applicant: Samsung Display Co., Ltd., Yongin-si (KR)

(72) Inventors: Kyoung SUNWOO, Yongin-si (KR); SUN YOUNG PAK, Yongin-si (KR); TAEIL KIM, Yongin-si (KR); JUNHA PARK, Yongin-si (KR); JANG YEOL BAEK, Yongin-si (KR); MinJae SUNG, Yongin-si (KR); MINJUNG JUNG, Yongin-si (KR)

(73) Assignee: Samsung Display Co., Ltd., Yongin-si (KR)

(21) Appl. No.: 18/463,115

(22) Filed: Sep. 7, 2023

(30) Foreign Application Priority Data
Dec. 1, 2022 (KR) 10-2022-0165954

(51) Int. Cl. H10K 50/11; H10K 85/30; H10K 85/60

(52) U.S. Cl. CPC H10K 50/11; H10K 85/346; H10K 85/658

(57) ABSTRACT

Embodiments provide a light emitting device that includes a first electrode, a second electrode facing the first electrode, and an emission layer disposed between the first electrode and the second electrode, wherein the emission layer includes a first compound represented by Formula 1, which is explained in the specification:

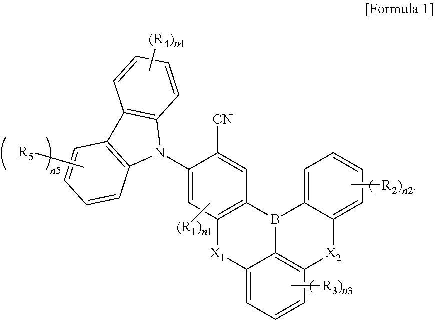

### CROSS-REFERENCE TO RELATED APPLICATION(S)

This application claims priority to and benefits of Korean Patent Application No. 10-2022-0165954 under 35 U.S.C. § 119, filed on Dec. 1, 2022 in the Korean Intellectual Property Office, the entire contents of which are incorporated herein by reference.

### BACKGROUND

### 1. Technical Field

The disclosure relates to a light emitting device and a fused polycyclic compound used in the light emitting device.

### 2. Description of the Related Art

Active development continues for an organic electroluminescence display as an image display. The organic electroluminescence display is different from a liquid crystal display in that it is a so-called self-luminescent display in which holes and electrons respectively injected from a first electrode and a second electrode recombine in an emission layer, so that a light emitting material including an organic compound in the emission layer emits light to achieve display.

In the application of an organic electroluminescence device to a display, there is a demand for an organic electroluminescence device having a low driving voltage, high emission efficiency, and a long service life, and continuous development is required on materials for an organic electroluminescence device that are capable of stably achieving such characteristics.

In order to implement an organic electroluminescence device with high efficiency, technologies on phosphorescence emission which uses energy in a triplet state, or on fluorescence emission which uses the generating phenomenon of singlet excitons by the collision of triplet excitons (triplet-triplet annihilation, TTA) are being developed. Development is currently directed to a thermally activated delayed fluorescence (TADF) material using delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device having improved emission efficiency and device lifetime.

The disclosure further provides a fused polycyclic compound which is capable of improving emission efficiency and device lifetime of a light emitting device.

An embodiment provides a light emitting device which may include a first electrode, a second electrode facing the first electrode, and an emission layer disposed between the first electrode and the second electrode, wherein the emission layer may include a first compound represented by Formula 1:

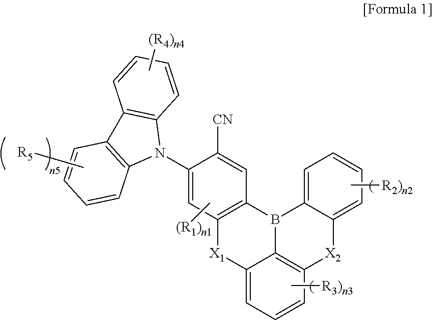

In Formula 1, X₁ and X₂ may each independently be N(Rₐ); and Rₐ may be a substituted or unsubstituted aryl group of 6 to 30 ring-forming carbon atoms or a substituted or unsubstituted heteroaryl group of 2 to 30 ring-forming carbon atoms.

In Formula 1, R₁ to R₅ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring; n1 may be an integer from 0 to 2; n2, n4, and n5 may each independently be an integer from 0 to 4; and n3 may be an integer from 0 to 3.

In an embodiment, a substituent represented by R₂ may be a hydrogen atom, a deuterium atom, a cyano group, a substituted or unsubstituted alkyl group of 1 to 10 carbon atoms, or a group represented by Formula A-1 or Formula A-2:

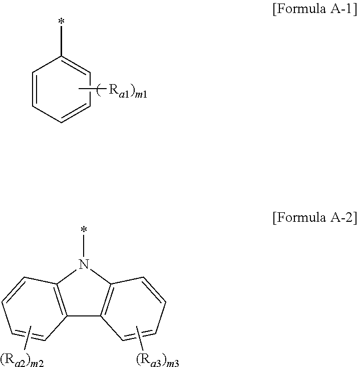

In Formula A-1 and Formula A-2, Rₐ₁ to Rₐ₃ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; m1 may be an integer from 0 to 5; and m2 and m3 may each independently be an integer from 0 to 4.

In an embodiment, the first compound represented may be represented by Formula 2-1 or Formula 2-2:

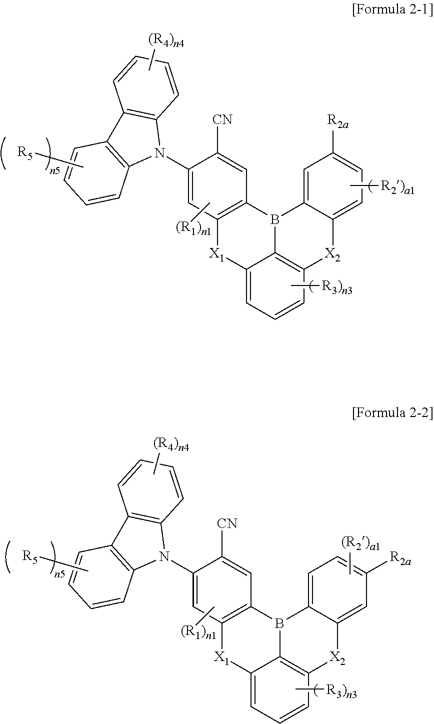

In Formula 2-1 and Formula 2-2, R₂′ may be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring; R₂ₐ may be a cyano group, a substituted or unsubstituted t-butyl group, a substituted or unsubstituted phenyl group, or a substituted or unsubstituted carbazole group; and a1 may be an integer from 0 to 3.

In Formula 2-1 and Formula 2-2, X₁, X₂, R₁, R₃ to R₅, n1, and n3 to n5 are the same as defined in Formula 1.

In an embodiment, the first compound may be represented by any one of Formula 3-1 to Formula 3-5:

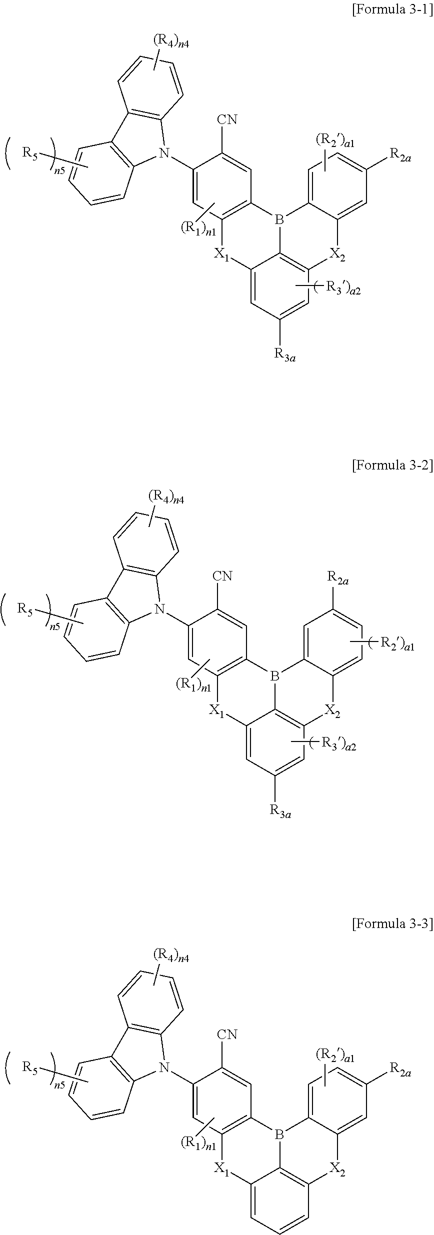

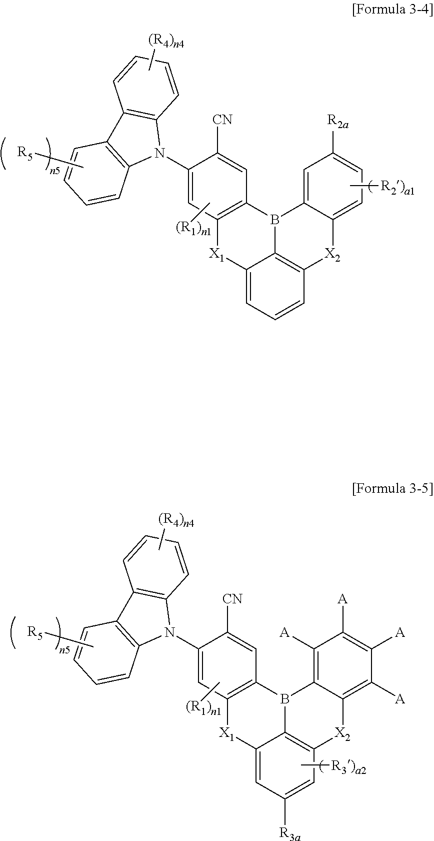

In Formula 3-1 to Formula 3-5, A may each independently be a hydrogen atom or a deuterium atom; R₂ₐ may be a cyano group, a substituted or unsubstituted t-butyl group, a substituted or unsubstituted phenyl group, or a substituted or unsubstituted carbazole group; R₂′ and R₃′ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring; a1 may be an integer from 0 to 3; a2 may be an integer from 0 to 2; and R₃ₐ may be a substituted or unsubstituted t-butyl group, or a group represented by Formula B-1 or Formula B-2:

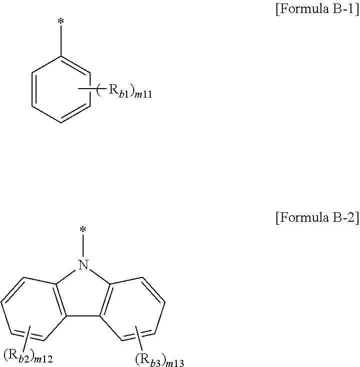

In Formula B-1 and Formula B-2, R_{b1} to R_{b3} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; m11 may be an integer from 0 to 5; and m12 and m13 may each independently be an integer from 0 to 4.

In Formula 3-1 to Formula 3-5, X₁, X₂, R₁, R₄, R₅, n1, n4, and n5 are the same as defined in Formula 1.

In an embodiment, the first compound may be represented by Formula 4-1 or Formula 4-2:

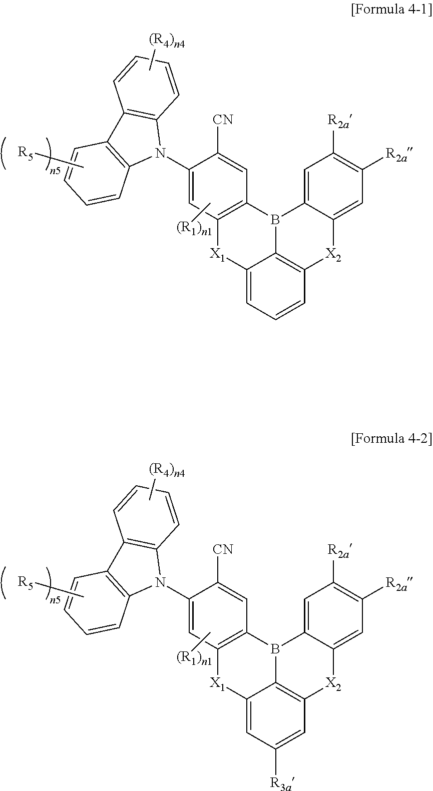

In Formula 4-1 and Formula 4-2, R₂ₐ′ and R₂ₐ″ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; at least one of R₂ₐ′ and R₂ₐ″ may each independently be a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; and R₃ₐ′ may be a substituted or unsubstituted t-butyl group, a substituted or unsubstituted phenyl group, or a substituted or unsubstituted carbazole group.

In Formula 4-1 and Formula 4-2, X₁, X₂, R₁, R₄, R₅, n1, n4, and n5 are the same as defined in Formula 1.

In an embodiment, the first compound may be represented by Formula 5:

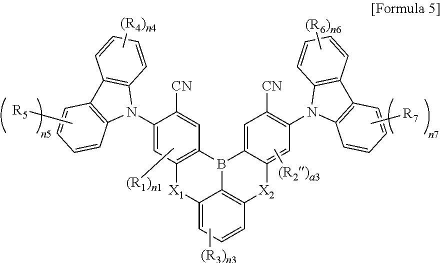

In Formula 5, R₂″, R₆, and R₇ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring; n6 and n7 may each independently be an integer from 0 to 4; and a3 may be an integer from 0 to 2.

In Formula 5, X₁, X₂, R₁, R₃, R₄, R₅, n1, n3, n4, and n5 are the same as defined in Formula 1.

In an embodiment, the first compound may be represented by Formula 6-1 or Formula 6-2:

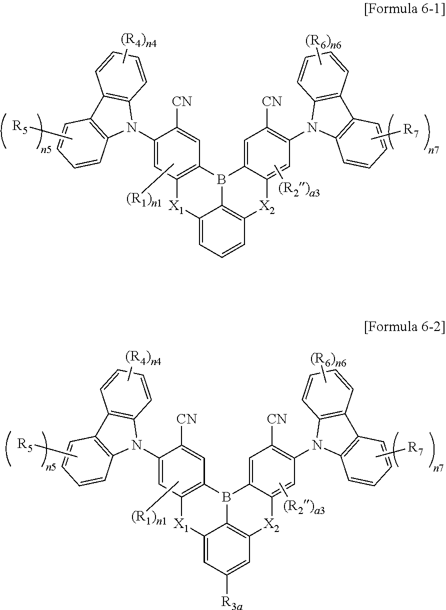

In Formula 6-1 and Formula 6-2, R₃ₐ may be a substituted or unsubstituted t-butyl group, or a group represented by Formula B-1 or Formula B-2:

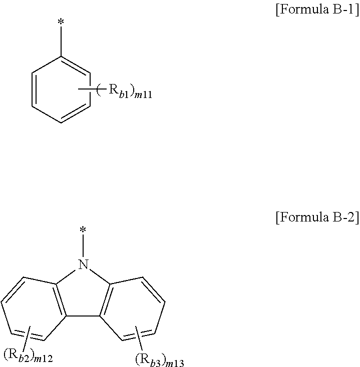

In Formula B-1 and Formula B-2, R_{b1} to R_{b3} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; m11 may be an integer from 0 to 5; and m12 and m13 may each independently be an integer from 0 to 4.

In Formula 6-1 and Formula 6-2, X₁, X₂, R₁, R₄, R₅, n1, n4, and n5 are the same as defined in Formula 1; and R₂″, R₆, R₇, n6, n7, and a3 are the same as defined in Formula 5.

In an embodiment, X₁ and X₂ may each independently be represented by Formula X-1 or Formula X-2:

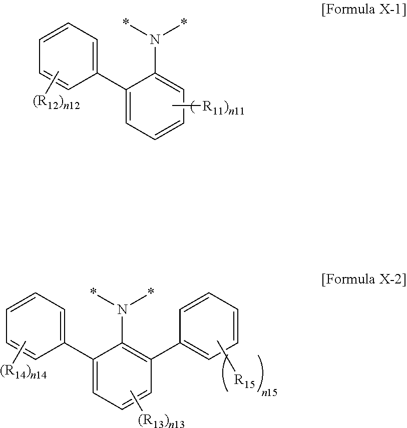

In Formula X-1 and Formula X-2, R₁₁ to R₁₅ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; n11 may be an integer from 0 to 4; n12, n14, and m15 may each independently be an integer from 0 to 5; n13 may be an integer from 0 to 3; and -*is a position connected with Formula 1.

In an embodiment, the first compound may be represented by any one of Formula 7-1 to Formula 7-4:

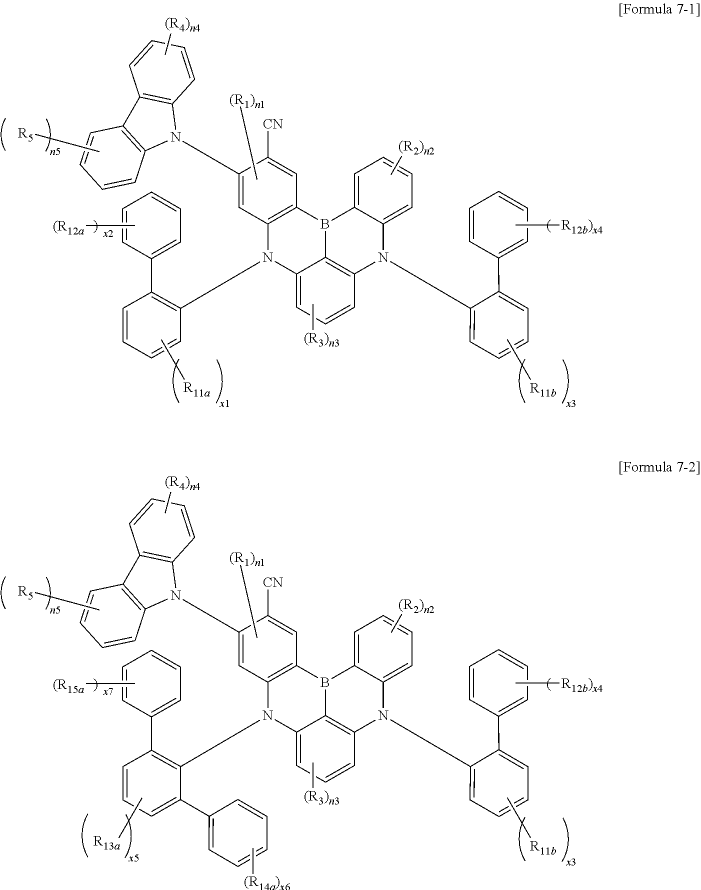

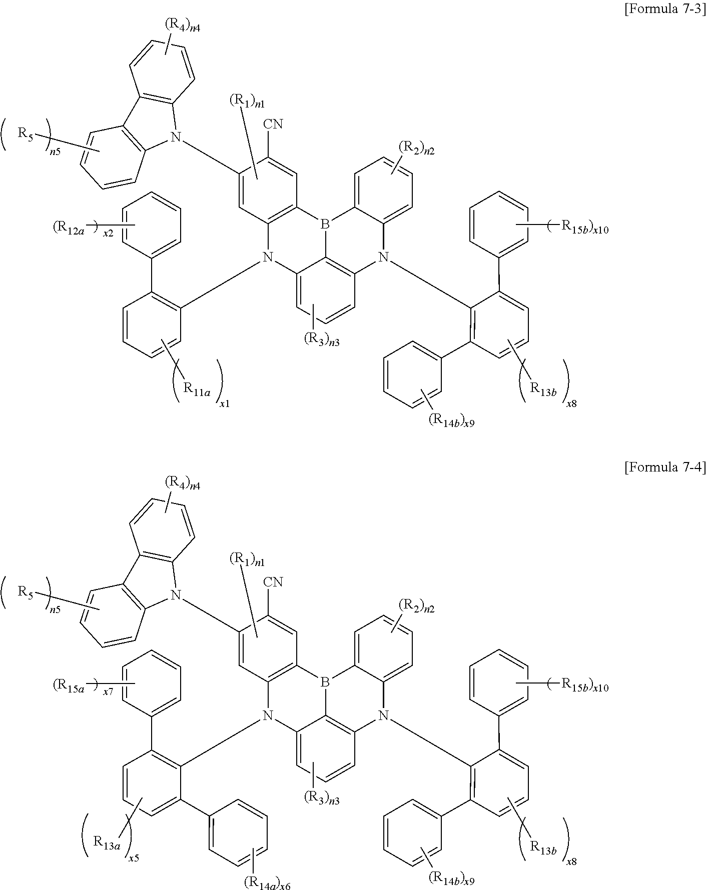

In Formula 7-1 to Formula 7-4, R₁₁ₐ to R₁₅ₐ and R_{11b} to R_{15b} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; x1 and x3 may each independently be an integer from 0 to 4; x2, x4, x6, x7, x9, and x10 may each independently be an integer from 0 to 5; and x5 and x8 may each independently be an integer from 0 to 3.

In Formula 7-1 to Formula 7-4, R₁ to R₅ and n1 to n5 are the same as defined in Formula 1.

In an embodiment, the first compound may include at least one compound selected from Compound Group 1, which is explained below.

In an embodiment, the emission layer may further include at least one of a second compound represented by Formula HT-1, and a third compound represented by Formula ET-1:

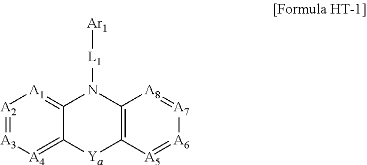

In Formula HT-1, A₁ to A₈ may each independently be N or C(R₅₁); L₁ may be a direct linkage, a substituted or unsubstituted arylene group of 6 to 30 ring-forming carbon atoms, or a substituted or unsubstituted heteroarylene group of 2 to 30 ring-forming carbon atoms; Yₐ may be a direct linkage, C(R₅₂)(R₅₃), or Si(R₅₄)(R₅₅); Ar₁ may be a substituted or unsubstituted aryl group of 6 to 30 ring-forming carbon atoms or a substituted or unsubstituted heteroaryl group of 2 to 30 ring-forming carbon atoms; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

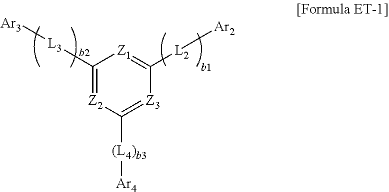

In Formula ET-1, at least one of Z₁ to Z₃ may each be N; the remainder of Z₁ to Z₃ may each independently be C(R₅₆); R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms; b1 to b3 may each independently be an integer from 0 to 10; and Ar₂ to Ar₄ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In an embodiment, the emission layer may further include a fourth compound represented by Formula D-1:

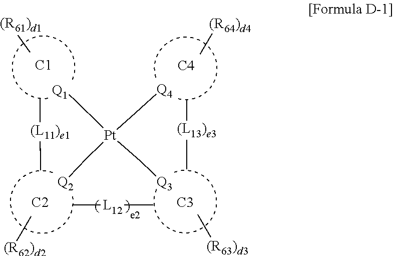

In Formula D-1, Q₁ to Q₄ may each independently be C or N; C1 to C4 may each independently be a substituted or unsubstituted hydrocarbon ring of 5 to 30 ring-forming carbon atoms or a substituted or unsubstituted heterocycle of 2 to 30 ring-forming carbon atoms; L₁₁ to L₁₃ may each independently be a direct linkage, * —O—*, *—S—*

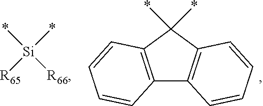

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms; e1 to e3 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or may be combined with an adjacent group to form a ring; and d1 to d4 may each independently be an integer from 0 to 4.

Embodiments provide a fused polycyclic compound which may be represented by Formula 1, which is explained herein.

In an embodiment, a substituent represented by R₂ may be a hydrogen atom, a deuterium atom, a cyano group, a substituted or unsubstituted alkyl group of 1 to 10 carbon atoms, or a group represented by Formula A-1 or Formula A-2, which are explained herein.

In an embodiment, the fused polycyclic compound represented by Formula 1 may be represented by Formula 2-1 or Formula 2-2, which are explained herein.

In an embodiment, the fused polycyclic compound represented by Formula 1 may be represented by any one of Formula 3-1 to Formula 3-5, which are explained herein.

In an embodiment, the fused polycyclic compound represented by Formula 1 may be represented by Formula 5, which is explained herein.

In an embodiment, X₁ and X₂ may each independently be represented by Formula X-1 or Formula X-2, which are explained herein.

In an embodiment, the fused polycyclic compound represented by Formula 1 may be represented by any one of Formula 7-1 to Formula 7-4, which are explained herein.

In an embodiment, the fused polycyclic compound represented by Formula 1 may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic cross-sectional view of a light emitting device according to an embodiment;

FIG. 4 is a schematic cross-sectional view of a light emitting device according to an embodiment;

FIG. 5 is a schematic cross-sectional view of a light emitting device according to an embodiment;

FIG. 6 is a schematic cross-sectional view of a light emitting device according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment;

FIG. 10 is a schematic cross-sectional view of a display apparatus according to an embodiment; and

FIG. 11 is a schematic perspective view of a vehicle including a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “combined with an adjacent group to form a ring” may be interpreted as a group that is combined with an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being combined with each other may itself be combined with another ring to form a spiro structure.

In the specification, the term “adjacent group” may be interpreted as a substituent that is substituted for an atom which is directly combined with an atom substituted with a corresponding substituent, as another substituent that is substituted for an atom which is substituted with a corresponding substituent, or as a substituent that is sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. For example, in 4,5-dimethylphenanthrene, two methyl groups may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., without limitation.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group etc., without limitation.

In the specification, an alkenyl group may be a hydrocarbon group including one or more carbon-carbon double bonds in the middle or at a terminus of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styrylvinyl group, etc., without limitation.

In the specification, an alkynyl group may be a hydrocarbon group including one or more carbon-carbon triple bonds in the middle or at a terminus of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, etc., without limitation.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., without limitation.

In the specification, a fluorenyl group may be substituted, and two substituents may be combined with each other to form a spiro structure. Examples of a substituted fluorenyl group may include the compounds presented below, but embodiments are not limited thereto.

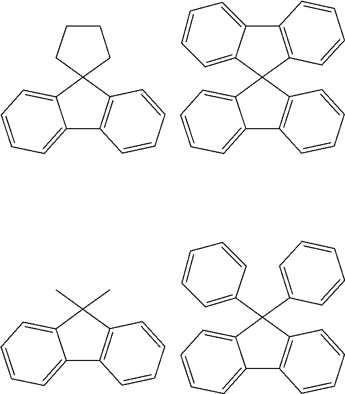

In the specification, a heterocyclic group may be any functional group or substituent derived from a ring including one or more of B, O, N, P, Si, and S as a heteroatom. The heterocyclic group may be an aliphatic heterocyclic group or an aromatic heterocyclic group. An aromatic heterocyclic group may be a heteroaryl group. An aliphatic heterocyclic group and an aromatic heterocyclic group may each independently be monocyclic or polycyclic.

In the specification, a heterocyclic group may include one or more of B, O, N, P, Si, and S as a heteroatom. If a heterocyclic group includes two or more heteroatoms, the two or more heteroatoms may be the same as or different from each other. A heterocyclic group may be monocyclic or polycyclic, and a heterocyclic group may be a heteroaryl group. The number of ring-forming carbon atoms in a heterocyclic group may be 2 to 30, 2 to 20, or 2 to 10.

In the specification, an aliphatic heterocyclic group may include one or more of B, O, N, P, Si, and S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the specification, a heteroaryl group may include one or more of B, O, N, P, Si, and S as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyridine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isooxazole group, an oxazole group, an oxadiazole group, a thiadiazole group, a phenothiazine group, a dibenzosilole group, a dibenzofuran group, etc., without limitation.

In the specification, the above explanation of an aryl group may be applied to an arylene group, except that the arylene group is a divalent group. In the specification, the above explanation of a heteroaryl group may be applied to a heteroarylene group, except that the heteroarylene group is a divalent group.

In the specification, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the specification, the number of carbon atoms in a carbonyl group is not particularly limited, but may be 1 to 40, 1 to 30, or 1 to 20. For example, a carbonyl group may have one of the structures below, but embodiments are not limited thereto.

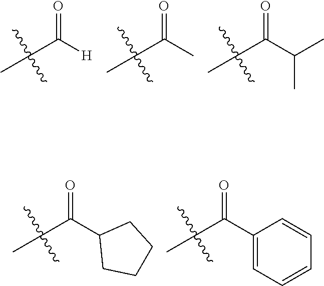

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkyl thio group or an aryl thio group. A thio group may be a sulfur atom that is bonded to an alkyl group or an aryl group as defined herein. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the specification, an oxy group may be an oxygen atom that is bonded to an alkyl group or an aryl group as defined herein. An oxy group may be an alkoxy group or an aryl oxy group. An alkoxy group may be linear, branched, or cyclic. The number of carbon atoms in an alkoxy group is not particularly limited but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a phenoxy group, a benzyloxy group, etc. However, embodiments are not limited thereto.

In the specification, a boron group may be a boron atom that is bonded to an alkyl group or an aryl group as defined herein. A boron group may be an alkyl boron group or an aryl boron group. Examples of a boron group may include a dimethylboron group, a diethylboron group, a t-butylmethylboron group, a diphenylboron group, a phenylboron group, etc., without limitation.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., without limitation.

In the specification, alkyl groups in an alkylthio group, an alkylsulfoxy group, an alkylaryl group, an alkylamino group, an alkyl boron group, an alkyl silyl group, or an alkyl amine group may be the same as an example of the alkyl group as described herein.

In the specification, aryl groups in an aryloxy group, an arylthio group, an arylsulfoxy group, an arylamino group, an aryl boron group, an aryl silyl group, and an aryl amine group may be the same as an example of the aryl group as described herein.

In the specification, a direct linkage may be a single bond.

In the specification, the symbols

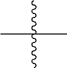

or -* each represent a bond to a neighboring atom in a corresponding formula.

Hereinafter, embodiments will be explained with reference to the drawings.

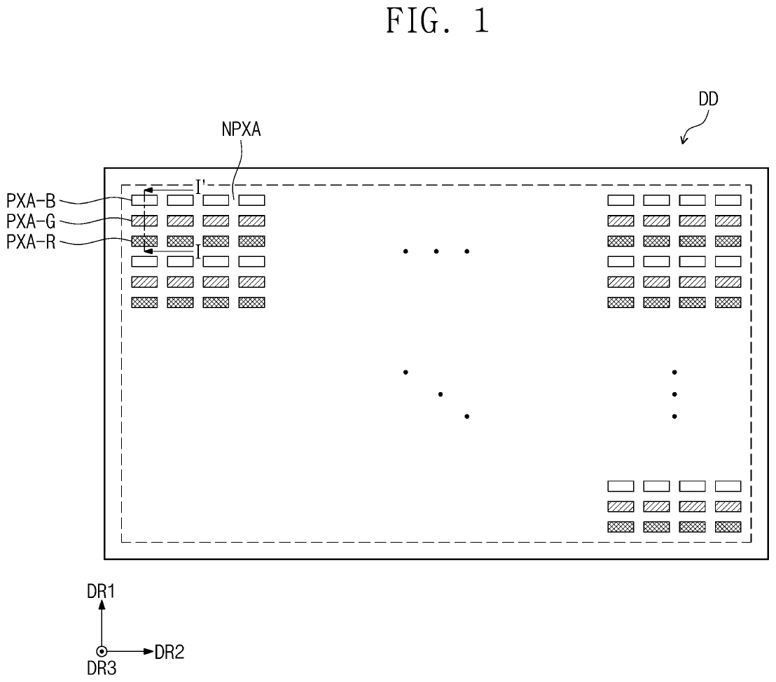

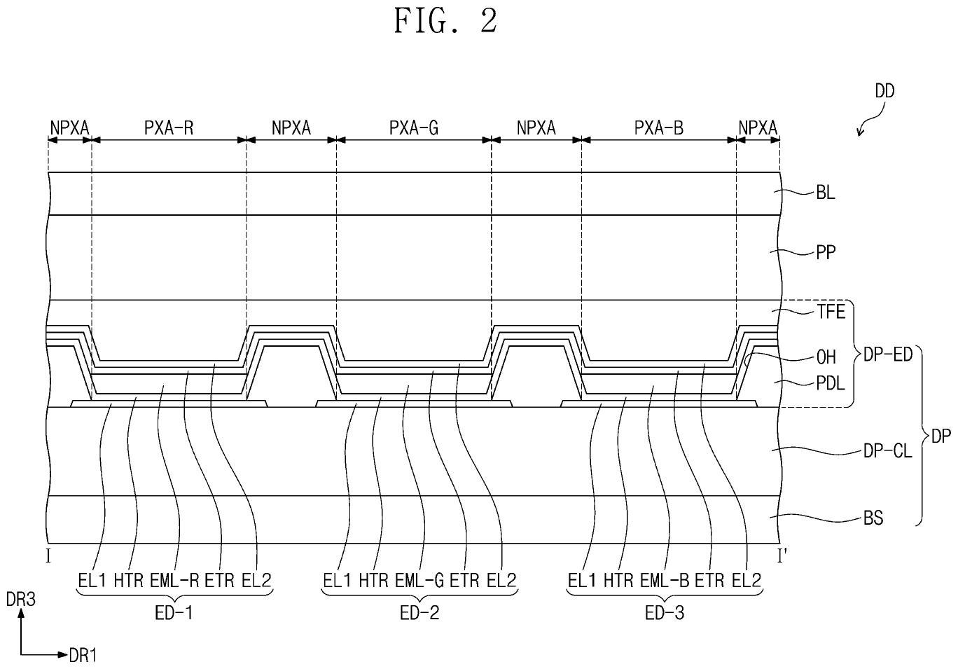

FIG. 1 is a schematic plan view of an embodiment of a display apparatus DD. FIG. 2 is a schematic cross-sectional view of a display apparatus DD according to an embodiment. FIG. 2 is a schematic cross-sectional view showing a part corresponding to line I-I′ in FIG. 1.

The display apparatus DD may include a display panel DP and an optical layer PP disposed on the display panel DP. The display panel DP includes light emitting devices ED-1, ED-2, and ED-3. The display apparatus DD may include multiples of each of the light emitting devices ED-1, ED-2, and ED-3. The optical layer PP may be disposed on the display panel DP and may control light that is reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a plugging layer (not shown). The plugging layer (not shown) may be disposed between a display device layer DP-ED and a base substrate BL. The plugging layer (not shown) may be an organic material layer. The plugging layer (not shown) may include at least one of an acrylic resin, a silicon-based resin, or an epoxy-based resin.

The display panel DP may include a base layer BS, a circuit layer DP-CL provided on the base layer BS, and a display device layer DP-ED. The display device layer DP-ED may include a pixel definition layer PDL, light emitting devices ED-1, ED-2, and ED-3 disposed in the pixel definition layer PDL, and an encapsulating layer TFE disposed on the light emitting devices ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include multiple transistors (not shown). Each of the transistors (not shown) may include a control electrode, an input electrode, and an output electrode. For example, the circuit layer DP-CL may include switching transistors and driving transistors for driving the light emitting devices ED-1, ED-2, and ED-3 of the display device layer DP-ED.

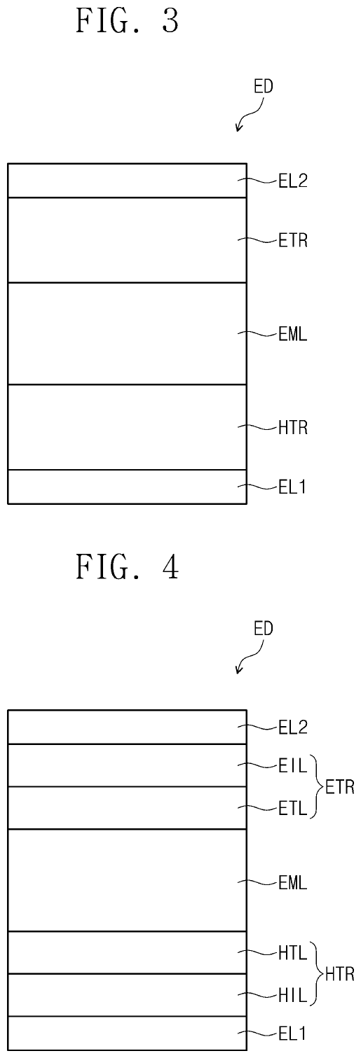

The light emitting devices ED-1, ED-2, and ED-3 may each have a structure of a light emitting device ED of an embodiment according to any of FIG. 3 to FIG. 6, which will be explained later. The light emitting devices ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment where the emission layers EML-R, EML-G, and EML-B of the light emitting devices ED-1, ED-2, and ED-3 are disposed in openings OH defined in a pixel definition layer PDL, and a hole transport region HTR, an electron transport region ETR, and a second electrode EL2 are each provided as a common layer for the light emitting devices ED-1, ED-2, and ED-3. However, embodiments are not limited thereto. Although not shown in FIG. 2, in an embodiment, the hole transport region HTR and the electron transport region ETR may each be patterned and provided in the openings OH defined in the pixel definition layer PDL. For example, in an embodiment, the hole transport region HTR, the emission layers EML-R, EML-G, and EML-B, and the electron transport region ETR of the light emitting devices ED-1, ED-2, and ED-3 may each be patterned by an ink jet printing method and provided.

An encapsulating layer TFE may cover the light emitting devices ED-1, ED-2, and ED-3. The encapsulating layer TFE may encapsulate a display device layer DP-ED. The encapsulating layer TFE may be a thin film encapsulating layer. The encapsulating layer TFE may be a single layer or a stack of multiple layers. The encapsulating layer TFE includes at least one insulating layer. In an embodiment, the encapsulating layer TFE may include at least one inorganic layer (hereinafter, an encapsulating inorganic layer). In an embodiment, the encapsulating layer TFE may include at least one organic layer (hereinafter, an encapsulating organic layer) and at least one encapsulating inorganic layer.

The encapsulating inorganic layer protects the display device layer DP-ED from moisture and/or oxygen, and the encapsulating organic layer protects the display device layer DP-ED from foreign materials such as dust particles. The encapsulating inorganic layer may include silicon nitride, silicon oxy nitride, silicon oxide, titanium oxide, or aluminum oxide, without limitation. The encapsulating organic layer may include an acrylic compound, an epoxy-based compound, etc. The encapsulating organic layer may include a photopolymerizable organic material, without limitation.

The encapsulating layer TFE may be disposed on the second electrode EL2 and may be disposed to fill the openings OH.

Referring to FIG. 1 and FIG. 2, the display apparatus DD may include non-luminous areas NPXA and luminous areas PXA-R, PXA-G, and PXA-B. The luminous areas PXA-R, PXA-G and PXA-B may each be an area which emits light respectively produced from the light emitting devices ED-1, ED-2, and ED-3. The luminous areas PXA-R, PXA-G, and PXA-B may be separated from each other in a plan view.

The luminous areas PXA-R, PXA-G, and PXA-B may each be an area separated by the pixel definition layer PDL. The non-luminous areas NPXA may be areas between neighboring luminous areas PXA-R, PXA-G, and PXA-B, and which may correspond to the pixel definition layer PDL. In an embodiment, the luminous areas PXA-R, PXA-G, and PXA-B may each correspond to a pixel. The pixel definition layer PDL may separate the light emitting devices ED-1, ED-2, and ED-3. The emission layers EML-R, EML-G, and EML-B of the light emitting devices ED-1, ED-2, and ED-3 may be disposed in the openings OH defined in the pixel definition layer PDL and separated from each other.

The luminous areas PXA-R, PXA-G, and PXA-B may be arranged into groups according to the color of light produced from the light emitting devices ED-1, ED-2, and ED-3. In the display apparatus DD according to an embodiment shown in FIG. 1 and FIG. 2, three luminous areas PXA-R, PXA-G, and PXA-B, which respectively emit red light, green light, and blue light, are illustrated. For example, the display apparatus DD may include a red luminous area PXA-R, a green luminous area PXA-G, and a blue luminous area PXA-B, which are separated from each other.

In the display apparatus DD according to an embodiment, the light emitting devices ED-1, ED-2, and ED-3 may emit light having different wavelength regions. For example, in an embodiment, the display apparatus DD may include a first light emitting device ED-1 emitting red light, a second light emitting device ED-2 emitting green light, and a third light emitting device ED-3 emitting blue light. For example, the red luminous area PXA-R, the green luminous area PXA-G, and the blue luminous area PXA-B of the display apparatus DD may respectively correspond to the first light emitting device ED-1, the second light emitting device ED-2, and the third light emitting device ED-3.

However, embodiments are not limited thereto, and the first to third light emitting devices ED-1, ED-2, and ED-3 may each emit light in a same wavelength region, or at least one light emitting device may emit light in a different wavelength region. For example, the first to third light emitting devices ED-1, ED-2, and ED-3 may each emit blue light.

The luminous areas PXA-R, PXA-G, and PXA-B in the display apparatus DD according to an embodiment may be arranged in a stripe configuration. Referring to FIG. 1, the red luminous areas PXA-R, the green luminous areas PXA-G, and the blue luminous areas PXA-B may be respectively arranged along a second direction axis DR2. In another embodiment, the red luminous area PXA-R, the green luminous area PXA-G, and the blue luminous area PXA-B may be alternately arranged in this order along a first direction axis DR1.

FIG. 1 and FIG. 2 show that the luminous areas PXA-R, PXA-G, and PXA-B each have a similar area, but embodiments are not limited thereto. In an embodiment, the luminous areas PXA-R, PXA-G, and PXA-B may have areas that are different from each other, according to a wavelength region of emitted light. For example, the areas of the luminous areas PXA-R, PXA-G, and PXA-B may be areas in a plan view that are defined by the first direction axis DR1 and the second direction axis DR2.

An arrangement of the luminous areas PXA-R, PXA-G, and PXA-B is not limited to the configuration shown in FIG. 1, and the order in which the red luminous areas PXA-R, the green luminous areas PXA-G, and the blue luminous areas PXA-B are arranged may be provided in various combinations according to the display quality properties that are required for the display apparatus DD. For example, the luminous areas PXA-R, PXA-G, and PXA-B may be provided in a pentile configuration (such as PENTILE™ configuration) or in a diamond configuration (such as a Diamond Pixel™ configuration).

The areas of the luminous areas PXA-R, PXA-G, and PXA-B may be different in size from each other. For example, in an embodiment, an area of the green luminous area PXA-G may be smaller than an area of the blue luminous area PXA-B, but embodiments are not limited thereto.

Hereinafter, FIG. 3 to FIG. 6 are each a schematic cross-sectional view of a light emitting device according to an embodiment. The light emitting devices ED according to embodiments may each include a first electrode EL1, a hole transport region HTR, an emission layer EML, an electron transport region ETR, and a second electrode EL2, which are stacked in that order.

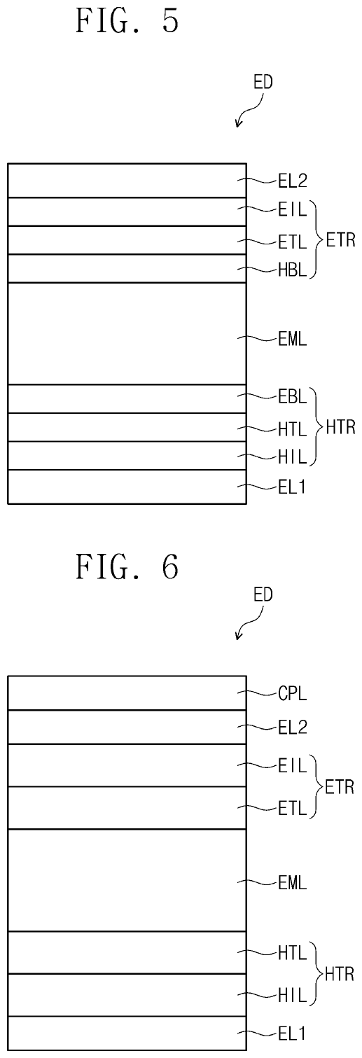

In comparison to FIG. 3, FIG. 4 shows a schematic cross-sectional view of a light emitting device ED according to an embodiment, wherein a hole transport region HTR includes a hole injection layer HIL and a hole transport layer HTL, and an electron transport region ETR includes an electron injection layer EIL and an electron transport layer ETL. In comparison to FIG. 3, FIG. 5 shows a schematic cross-sectional view of a light emitting device ED according to an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 shows a schematic cross-sectional view of a light emitting device ED according to an embodiment that includes a capping layer CPL disposed on the second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, a compound thereof, or a mixture thereof (for example, a mixture of Ag and Mg). In another embodiment, the first electrode EL1 may have a multilayered structure including a reflective layer or a transflective layer formed of the above materials, and a transmissive conductive layer formed of ITO, IZO, ZnO, or ITZO. For example, the first electrode EL1 may include a three-layer structure of ITO/Ag/ITO. However, embodiments are not limited thereto. The first electrode EL1 may include the above-described metal materials, combinations of two or more metal materials selected from the above-described metal materials, or oxides of the above-described metal materials. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission auxiliary layer (not shown), or an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting device ED according to an embodiment, the hole transport region HTR may include a compound represented by Formula H-2.

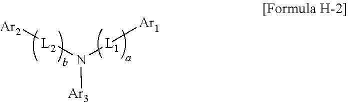

In Formula H-2, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. In Formula H-2, a and b may each independently be an integer from 0 to 10. If a or b is 2 or more, multiple L₁ groups or multiple L₂ groups may each independently be a substituted or unsubstituted arylene group of 6 to 30 ring-forming carbon atoms or a substituted or unsubstituted heteroarylene group of 2 to 30 ring-forming carbon atoms.

In Formula H-2, Ar and Ar₂ may each independently be a substituted or unsubstituted aryl group of 6 to 30 ring-forming carbon atoms or a substituted or unsubstituted heteroaryl group of 2 to 30 ring-forming carbon atoms. In Formula H-2, Ar₃ may be a substituted or unsubstituted aryl group of 6 to 30 ring-forming carbon atoms or a substituted or unsubstituted heteroaryl group of 2 to 30 ring-forming carbon atoms.

In an embodiment, the compound represented by Formula H-2 may be a monoamine compound. In another embodiment, the compound represented by Formula H-2 may be a diamine compound in which at least one of Ar₁ to Ar₃ includes an amine group as a substituent. In yet another embodiment, the compound represented by Formula H-2 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-2 may be any compound selected from Compound Group H. However, the compounds shown in Compound Group H are only examples, and the compound represented by Formula H-2 is not limited to Compound Group H.

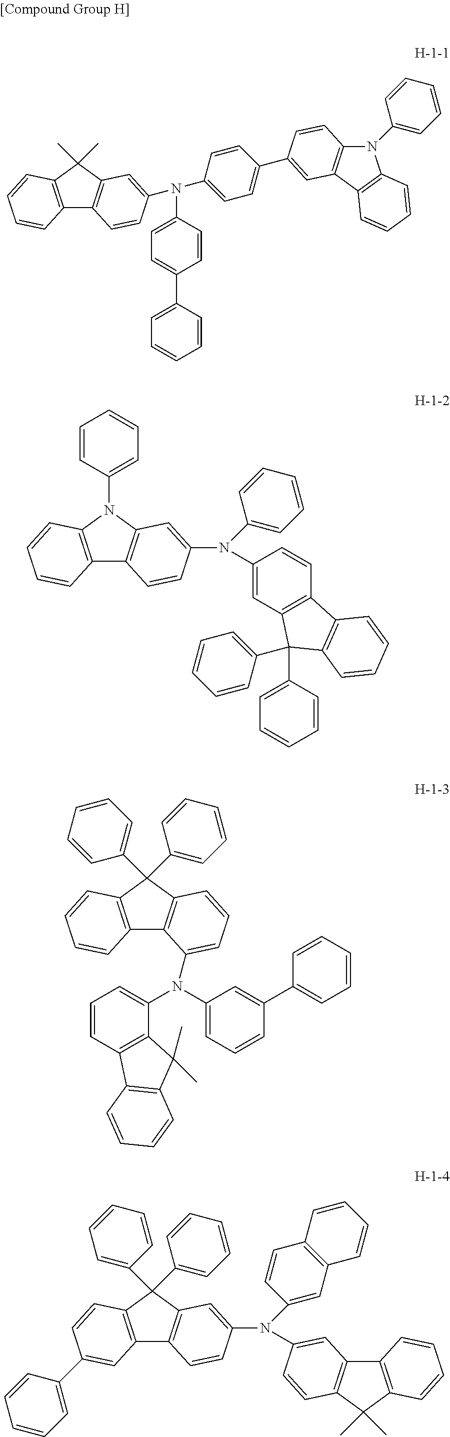 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

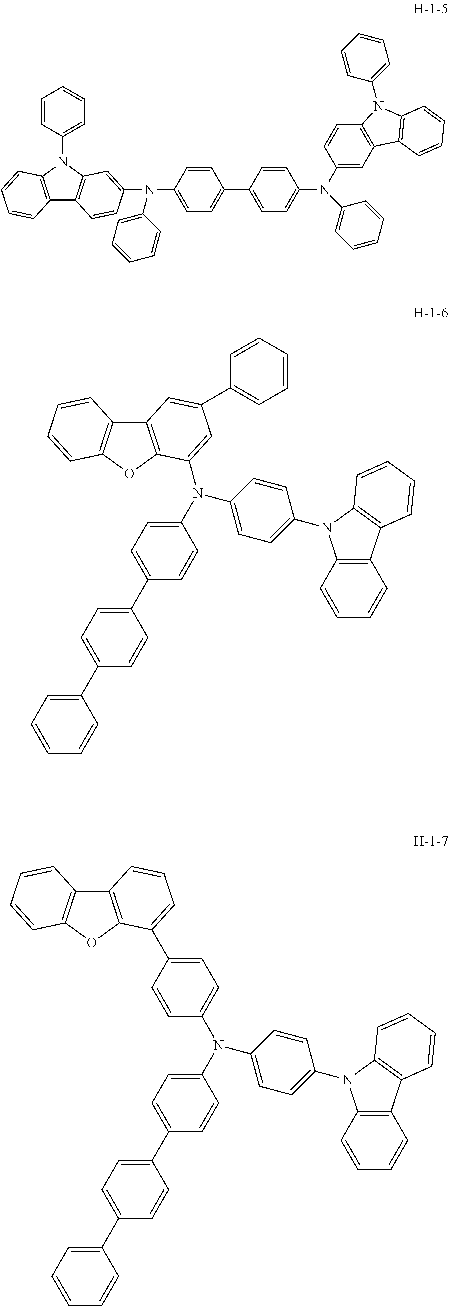 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

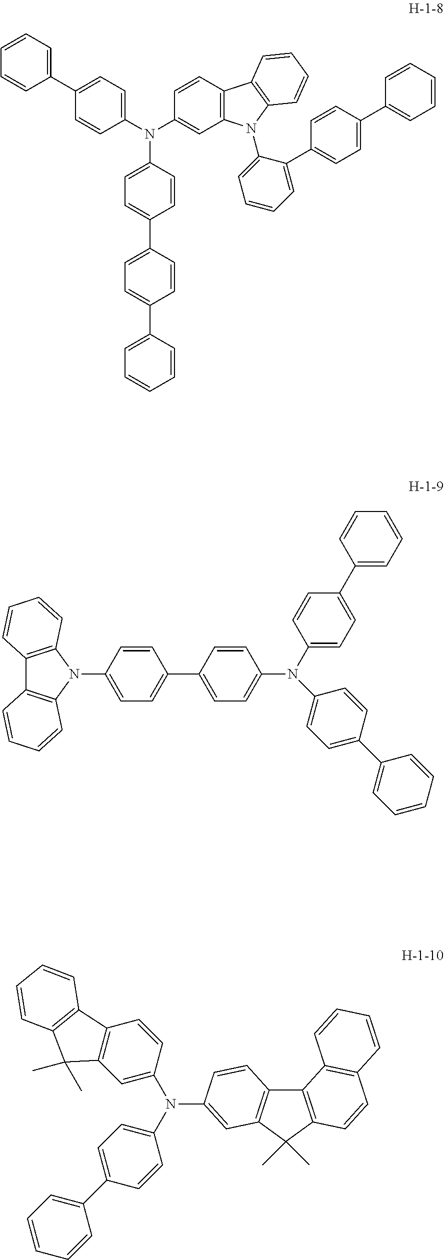 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

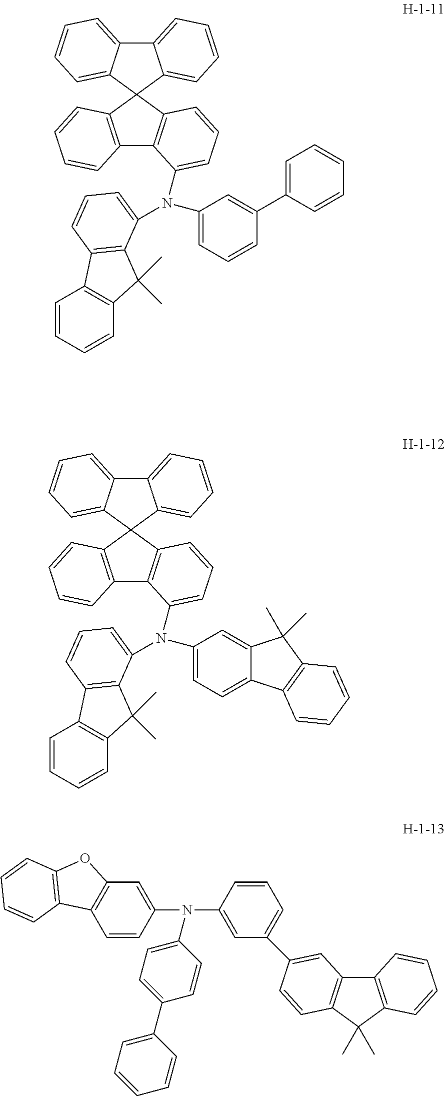 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

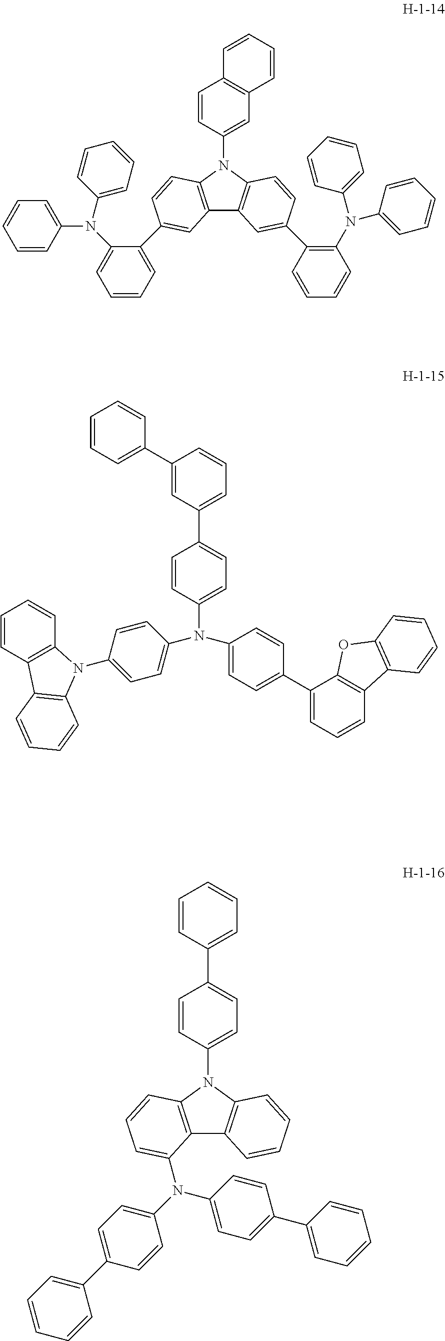 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

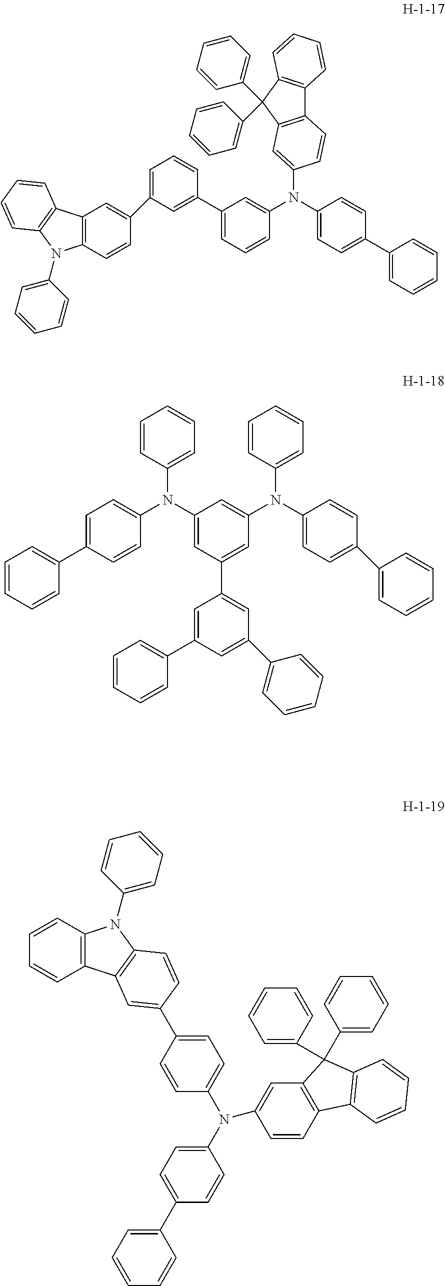 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], or dipyrazino[2,3-f:2′,3′-h] quinoxaline-2,3,6,7,10,11-hexacarbonitrile (HAT-CN).

The hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. If the hole transport region HTR includes a hole injection layer HIL, a thickness of the hole injection layer HIL may be in a range of about 30 Å to about 1,000 Å. If the hole transport region HTR includes a hole transport layer HTL, a thickness of the hole transport layer HTL may be in a range of about 30 Å to about 1,000 Å. If the hole transport region HTR includes an electron blocking layer, a thickness of the electron blocking layer EBL may be in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of metal halide compounds, quinone derivatives, metal oxides, and cyano group-containing compounds, without limitation.

For example, the p-dopant may include metal halide compounds such as CuI and RbI, quinone derivatives such as tetracyanoquinodimethane (TCNQ) and 2,3,5,6-tetrafluoro-7,7′,8,8-tetracyanoquinodimethane (F4-TCNQ), metal oxides such as tungsten oxide and molybdenum oxide, cyano group-containing compounds such as dipyrazino[2,3-f: 2′,3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from an emission layer EML and may increase emission efficiency. A material which may be included in the hole transport region HTR may be used as a material included in the buffer layer (not shown). The electron blocking layer EBL may block the injection of electrons from an electron transport region ETR to a hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

In the light emitting device ED according to an embodiment, the emission layer EML may include a fused polycyclic compound according to an embodiment. In an embodiment, the emission layer EML may include the fused polycyclic compound as a dopant. The fused polycyclic compound may be a dopant material of the emission layer EML. In the specification, the fused polycyclic compound, which will be explained later, may be referred to as a first compound.

The fused polycyclic compound may include a fused structure in which aromatic rings are fused via a boron atom and two nitrogen atoms. The fused polycyclic compound may include a fused structure of first to third aromatic rings that are fused via a boron atom, a first nitrogen atom, and a second nitrogen atom. The first to third aromatic rings may each be connected to the boron atom, the first aromatic ring and the third aromatic ring may be connected via the first nitrogen atom, and the second aromatic ring and the third aromatic ring may be connected via the second nitrogen atom. In an embodiment, the first to third aromatic rings may be six-member aromatic hydrocarbon rings. For example, the first to third aromatic rings may each be a benzene ring. In the specification, the boron atom, the first nitrogen atom, and the second nitrogen atom, and the fused structure formed by the first to third aromatic rings being fused via the boron atom, the first nitrogen atom, and the second nitrogen atom may be referred to as a “fused ring core”.

The fused polycyclic compound may include a first substituent and a second substituent connected with the fused ring core. The first substituent and the second substituent may each be connected with the first aromatic ring of the fused ring core. The first substituent may include a third nitrogen atom and a structure in which a fourth aromatic ring and a fifth aromatic ring are fused via the third nitrogen atom. For example, the first substituent may be a substituted or unsubstituted carbazole group. The first substituent may be connected with the fused ring core at a para position to the boron atom. The third nitrogen atom of the first substituent may be connected with the first aromatic ring at a para position to the boron atom. The first substituent may be connected with the first aromatic ring at a carbon atom that is at a para position to a carbon atom connected with the boron atom, from among carbon atoms which constitute the first aromatic ring. The first substituent may be directly bonded to the first aromatic ring. In an embodiment, the second substituent may be a cyano group. The second substituent may be connected at an ortho position to the first substituent. The second substituent may be connected at an ortho position to the first substituent and at a para position to the first nitrogen atom of the fused ring core. The second substituent may be connected with the first aromatic ring at a carbon atom that is at a para position to a carbon atom connected with the first nitrogen atom, from among carbon atoms which constitute the first aromatic ring.

In an embodiment, the fused polycyclic compound may be represented by Formula 1:

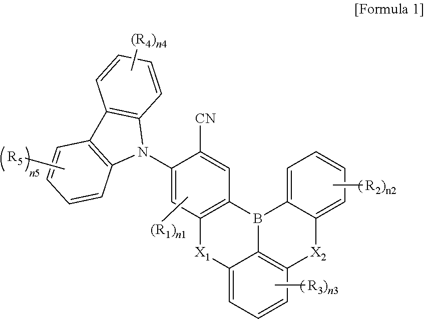

The fused polycyclic compound represented by Formula 1 may include a fused structure of three aromatic rings that are fused via a boron atom, a first nitrogen atom, and a second nitrogen atom. In the specification, a benzene ring that includes R₁ may correspond to a first aromatic ring, a benzene ring that includes R₂ may correspond to a second aromatic ring, and a benzene ring that includes R₃ may correspond to a third aromatic ring. In Formula 1, a carbazole group that includes R₄ and R₅ may correspond to the above-described first substituent, and in Formula 1, the CN group that is bonded at a para position to X₁ may correspond to the above-described second substituent.

In Formula 1, X₁ and X₂ may each independently be N(Rₐ).

In Formula 1, Rₐ may be a substituted or unsubstituted aryl group of 6 to 30 ring-forming carbon atoms or a substituted or unsubstituted heteroaryl group of 2 to 30 ring-forming carbon atoms. In an embodiment, Rₐ may be a substituted or unsubstituted biphenyl group, or a substituted or unsubstituted terphenyl group.

In Formula 1, R₁ to R₅ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In an embodiment, R₁ to R₅ may be each independently a hydrogen atom, a deuterium atom, a cyano group, a substituted or unsubstituted t-butyl group, a substituted or unsubstituted phenyl group, or a substituted or unsubstituted carbazole group. For example, R₁ may be a hydrogen atom. For example, R₂ may be a hydrogen atom, a cyano group, a substituted or unsubstituted t-butyl group, a substituted or unsubstituted phenyl group, or a substituted or unsubstituted carbazole group. For example, R₃ may be a hydrogen atom, a substituted or unsubstituted t-butyl group, a substituted or unsubstituted phenyl group, or a substituted or unsubstituted carbazole group. For example, R₄ and R₅ may each independently be a hydrogen atom, a deuterium atom, a substituted or unsubstituted t-butyl group, or a substituted or unsubstituted phenyl group.

In Formula 1, n1 may be an integer from 0 to 2. In Formula 1, if n1 is 0, the fused polycyclic compound may not be substituted with R₁. In Formula 1, a case where n1 is 2 and all R₁ groups are hydrogen atoms may be the same as a case where n1 is 0. If n1 is 2, multiple R₁ groups may be all the same, or at least one group thereof may be different from the remainder.

In Formula 1, n2, n4, and n5 may each independently be an integer from 0 to 4. In Formula 1, if n2, n4, and n5 are each 0, the fused polycyclic compound may not be substituted with R₂, R₄, and R₅, respectively. In Formula 1, cases where n2, n4, and n5 are 4, and R₂ groups, R₄ groups, and R₅ groups are all hydrogen atoms may be the same as cases where n2, n4, and n5 are 0, respectively. If n2, n4, and n5 are 2 or more, multiple R₂ groups, multiple R₄ groups, and multiple R₅ groups may be all the same, or at least one group thereof may be different from the remainder.

In Formula 1, n3 may be an integer from 0 to 3. In Formula 1, if n3 is 0, the fused polycyclic compound may not be substituted with R₃. In Formula 1, a case where n1 is 3 and all R₃ groups are hydrogen atoms may be the same as a case where n3 is 0. If n3 is 2 or more, multiple R₃ groups may be all the same, or at least one group thereof may be different from the remainder.

In an embodiment a substituent represented by R₂ may be a hydrogen atom, a deuterium atom, a cyano group, a substituted or unsubstituted alkyl group of 1 to 10 carbon atoms, or a group represented by Formula A-1 or Formula A-2:

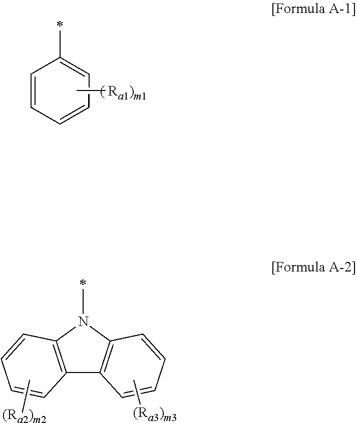

In Formula A-1 and Formula A-2, Rₐ₁ to Rₐ₃ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Rₐ₁ may be a hydrogen atom, a deuterium atom, or a substituted or unsubstituted t-butyl group. For example, Rₐ₂ and Rₐ₃ may each independently be a hydrogen atom, a deuterium atom, a substituted or unsubstituted t-butyl group, or a substituted or unsubstituted phenyl group.

In Formula A-1, m1 may be an integer from 0 to 5. In Formula A-1, if m1 is 0, the fused polycyclic compound may not be substituted with Rₐ₁. In Formula A-1, a case where m1 is 5 and all Rₐ₁ groups are hydrogen atoms may be the same as a case where m1 is 0. If m1 is 2 or more, multiple Rₐ₁ groups may be all the same, or at least one group thereof may be different from the remainder.

In Formula A-2, m2 and m3 may each independently be an integer from 0 to 4. In Formula A-2, if m2 and m3 are 0, the fused polycyclic compound may not be substituted with Rₐ₂ and Rₐ₃, respectively. In Formula A-2, a case where m2 and m3 are 4 and all Rₐ₂ groups and Rₐ₃ groups are hydrogen atoms may be the same as a case where m2 and m3 are 0, respectively. If m2 and m3 are 2 or more, multiple Rₐ₂ groups and multiple Rₐ₃ groups may be all the same, or at least one group thereof may be different from the remainder.

In an embodiment, at least one of R₂ and R₃ may each independently be a group represented by any one of Formula R-1 to Formula R-12:

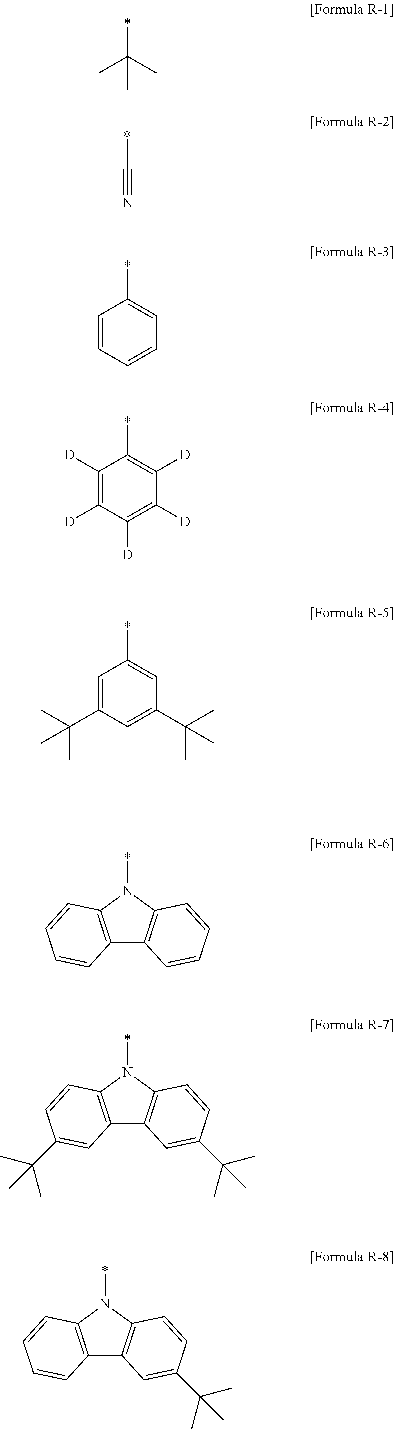

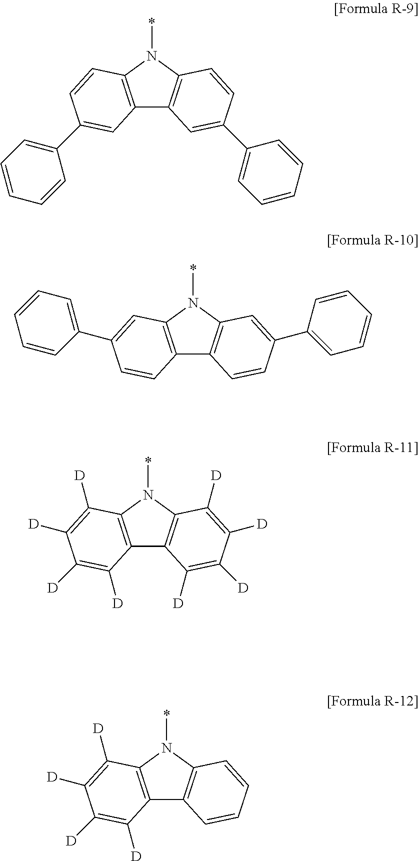 [SMILES: *n1c2ccc(-c3ccccc3)cc2c2cc(-c3ccccc3)ccc21 ; *n1c2cc(-c3ccccc3)ccc2c2ccc(-c3ccccc3)cc21 ; *n1c2c([2H])c([2H])c([2H])c([2H])c2c2c([2H])c([2H])c([2H])c([2H])c21 ; *n1c2ccccc2c2c([2H])c([2H])c([2H])c([2H])c21]

In Formula R-1 to Formula R-12, -* represents a position connected to Formula 1. In Formula R-4, Formula R-11, and Formula R-12, D represents a deuterium atom.

In an embodiment, the first compound represented by Formula 1 may be represented by Formula 2-1 or Formula 2-2:

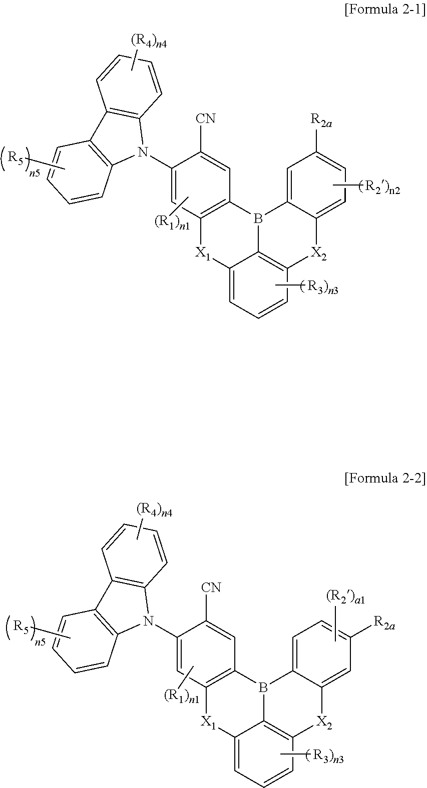

Formula 2-1 and Formula 2-2 each represent an embodiment of Formula 1 where the type and bonding position of R₂ are further defined.

In Formula 2-1 and Formula 2-2, R₂ may be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, R₂′ may be a hydrogen atom, a deuterium atom, a cyano group, or a substituted or unsubstituted carbazole group.

In Formula 2-1 and Formula 2-2, R₂ₐ may be a cyano group, a substituted or unsubstituted t-butyl group, a substituted or unsubstituted phenyl group, or a substituted or unsubstituted carbazole group.

In Formula 2-1 and Formula 2-2, a1 may be an integer from 0 to 3. In Formula 2-1 and Formula 2-2, if a1 is 0, the fused polycyclic compound may not be substituted with R₂′. In Formula 2-1 and Formula 2-2, a case where a1 is 3 and all R₂′ groups are hydrogen atoms may be the same as a case where a1 is 0. In Formula 2-1 and Formula 2-2, if a1 is 2 or more, multiple R₂′ groups may be all the same, or at least one group thereof may be different from the remainder.

In Formula 2-1 and Formula 2-2, X₁, X₂, R₁, R₃ to R₅, n1, and n3 to n5 are the same as defined in Formula 1.

In an embodiment, the first compound represented by Formula 1 may be represented by Formula 2-3 or Formula 2-4:

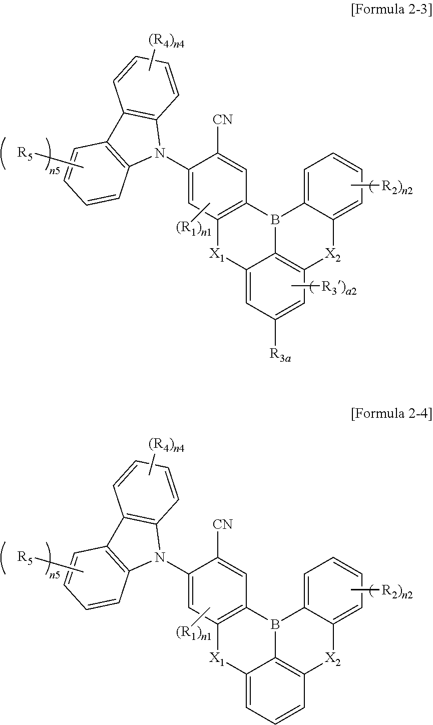

Formula 2-3 and Formula 2-4 each represent an embodiment Formula 1 where the type and bonding position of R₃ are further defined.

In Formula 2-3, R₃′ may be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, R₃′ may be a hydrogen atom or a deuterium atom.

In Formula 2-3, a2 may be an integer from 0 to 2. In Formula 2-3, if a2 is 0, the fused polycyclic compound may not be substituted with R₃′. In Formula 2-3, a case where a2 is 2 and all R₃′ groups are hydrogen atoms may be the same as a case where a2 is 0.3. In Formula 2-3, if a2 is 2, multiple R₃′ groups may be all the same, or at least one group thereof may be different from the remainder.

In Formula 2-3, R₃ₐ may be a substituted or unsubstituted t-butyl group or a group represented by Formula B-1 or Formula B-2:

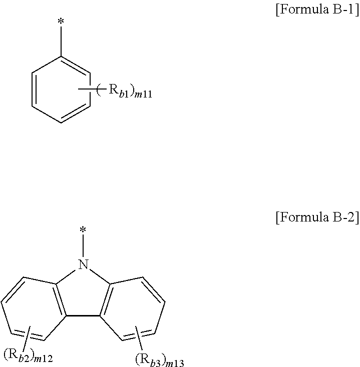

In Formula B-1 and Formula B-2, R_{b1} to R_{b3} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R_{b1} to R_{b3} may each independently be a hydrogen atom, a deuterium atom, a substituted or unsubstituted t-butyl group, or a substituted or unsubstituted phenyl group.

In Formula B-1, m11 may be an integer from 0 to 5. In Formula B-1, if m11 is 0, the fused polycyclic compound may not be substituted with R_{b1}. In Formula B-1, a case where m11 is 5 and all R_{b1} groups are hydrogen atoms may be the same as a case where m11 is 0. If m11 is 2 or more, multiple R_{b1} groups may be all the same, or at least one group thereof may be different from the remainder.

In Formula B-2, m12 and m13 may each independently be an integer from 0 to 4. In Formula B-2, if m12 and m13 are 0, the fused polycyclic compound may not be substituted with R_{b2} and R_{b3}, respectively. In Formula B-2, a case where m12 and m13 are 4 and all R_{b2} groups and R_{b3} groups are hydrogen atoms may be the same as a case where m12 and m13 are 0, respectively. If m12 and m13 are 2 or more, multiple R_{b2} groups and multiple R_{b3} groups may be all the same, or at least one group thereof may be different from the remainder.

In Formula 2-3 and Formula 2-4, X₁, X₂, R₁, R₂, R₄, R₅, n1, n2, n4, and n5 are the same as defined in Formula 1.

In an embodiment, the first compound represented by Formula 1 may be represented by any one of Formula 3-1 to Formula 3-5:

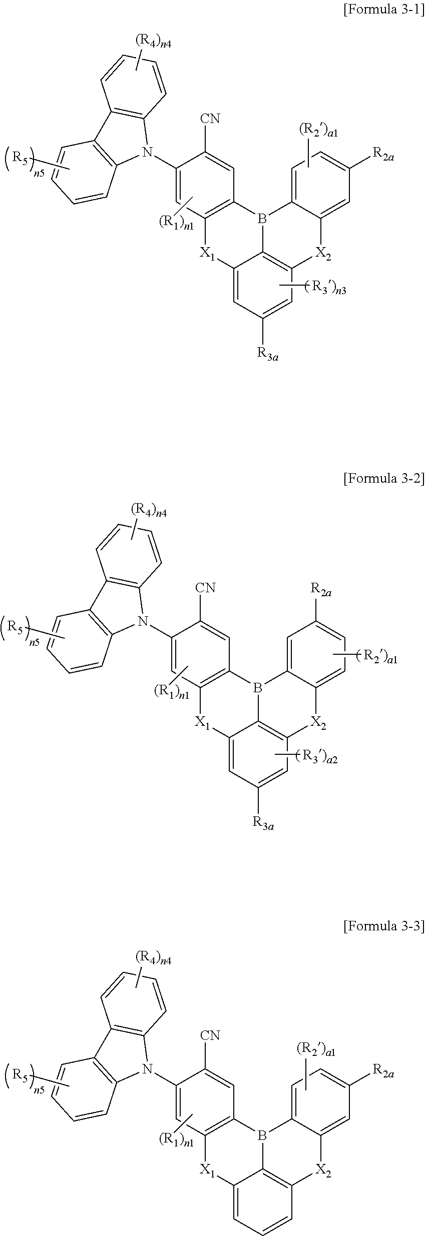

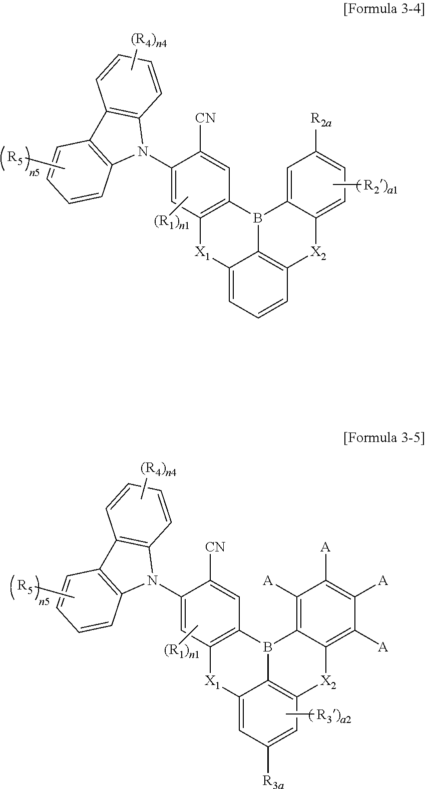

Formula 3-1 to Formula 3-5 each represent an embodiment of Formula 1 where at least one of the type, number, and bonding position of R₂ and R₃ are further defined.

In Formula 3-5, A may each independently be a hydrogen atom or a deuterium atom.

In Formula 3-1 to Formula 3-4, R₂ₐ may be a cyano group, a substituted or unsubstituted t-butyl group, a substituted or unsubstituted phenyl group, or a substituted or unsubstituted carbazole group.

In Formula 3-1 to Formula 3-5, R₂′ and R₃′ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, R₂′ may be a hydrogen atom, a deuterium atom, a cyano group, or a substituted or unsubstituted carbazole group. For example, R₃′ may be a hydrogen atom or a deuterium atom.

In Formula 3-1 to Formula 3-4, a1 may be an integer from 0 to 3. In Formula 3-1 to Formula 3-4, if a1 is 0, the fused polycyclic compound may not be substituted with R₂′. In Formula 3-1 to Formula 3-4, a case where a1 is 3 and all R₂′ groups are hydrogen atoms may be the same as a case where a1 is 0. In Formula 3-1 to Formula 3-4, if a1 is 2 or more, multiple R₂′ groups may be all the same, or at least one group thereof may be different from the remainder.

In Formula 3-1, Formula 3-2, and Formula 3-5, a2 may be an integer from 0 to 2. In Formula 3-1, Formula 3-2, and Formula 3-5, if a2 is 0, the fused polycyclic compound may not be substituted with R₃′. In Formula 3-1, Formula 3-2, and Formula 3-5, a case where a2 is 2 and all R₃′ groups are hydrogen atoms may be the same as a case where a2 is 0. In Formula 3-1, Formula 3-2, and Formula 3-5, if a2 is 2, multiple R₃′ groups may be all the same, or at least one group thereof may be different from the remainder.

In Formula 3-1, Formula 3-2, and Formula 3-5, R₃ₐ is the same as defined in Formula 2-3. Thus, in Formula 3-1, Formula 3-2, and Formula 3-5, R₃ₐ may be a substituted or unsubstituted t-butyl group or a group represented by Formula B-1 or Formula B-2 as described above.

In Formula 3-1 to Formula 3-5, X₁, X₂, R₁, R₄, R₅, n1, n4, and n5 are the same as defined in Formula 1.

In an embodiment, the first compound represented by Formula 1 may be represented by Formula 4-1 or Formula 4-2:

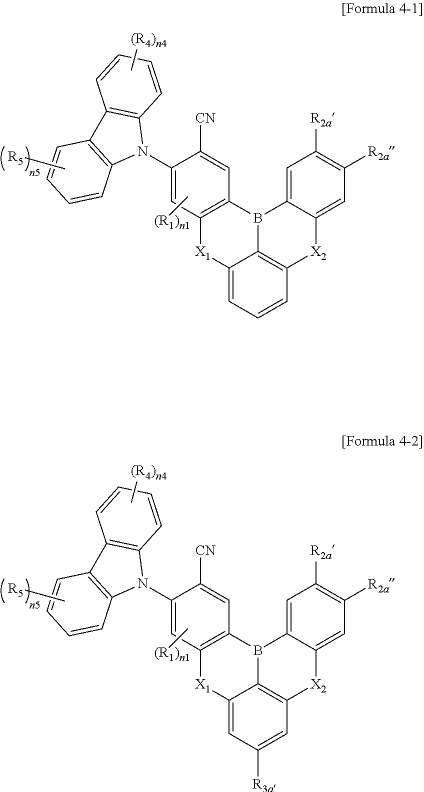

Formula 4-1 and Formula 4-2 each represent an embodiment of Formula 1 where the type and number of R₂ and R₃ are further defined.

In Formula 4-1 and Formula 4-2, R₂ₐ′ and R₂ₐ″ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₂ₐ′ and R₂ₐ″ may each independently be a hydrogen atom, a cyano group, a substituted or unsubstituted t-butyl group, a substituted or unsubstituted phenyl group, or a substituted or unsubstituted carbazole group.

In Formula 4-1 and Formula 4-2, at least one of R₂ₐ′ and R₂ₐ″ may each independently be a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, at least one of R₂ₐ′ and R₂ₐ″ may each independently be a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and the remainder thereof may be a hydrogen atom. For example, R₂ₐ′ and R₂ₐ″ may each independently be a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In an embodiment, at least one of R₂ₐ′ and R₂ₐ″ may each independently be a cyano group, a substituted or unsubstituted t-butyl group, a substituted or unsubstituted phenyl group, or a substituted or unsubstituted carbazole group.

In Formula 4-2, R₃ₐ′ may be a substituted or unsubstituted t-butyl group, a substituted or unsubstituted phenyl group, or a substituted or unsubstituted carbazole group.

In Formula 4-1 and Formula 4-2, X₁, X₂, R₁, R₄, R₅, n1, n4, and n5 are the same as defined in Formula 1.

In an embodiment, the fused polycyclic compound may further include a third substituent and a fourth substituent connected with the fused ring core. The third substituent and the fourth substituent may each be connected with the second aromatic ring of the fused ring core. In an embodiment, the third substituent may be a substituted or unsubstituted carbazole group. In an embodiment, the fourth substituent may be a cyano group. The third substituent may be connected with the fused ring core at a para position to the boron atom. The third substituent may be connected with the second aromatic ring at a carbon atom that is at a para position to a carbon atom connected with the boron atom, from among carbon atoms which constitute the second aromatic ring. The third substituent may be directly bonded to the second aromatic ring. The fourth substituent may be connected at an ortho position to the third substituent. The fourth substituent may be connected at an ortho position to the third substituent and at a para position to the second nitrogen atom of the fused ring core. The fourth substituent may be connected with the second aromatic ring at a carbon atom that is at a para position to a carbon atom connected with the second nitrogen atom, from among carbon atoms which constitute the second aromatic ring. The fourth substituent may be directly bonded to the second aromatic ring.

In an embodiment, the first compound represented by Formula 1 may be represented by Formula 5:

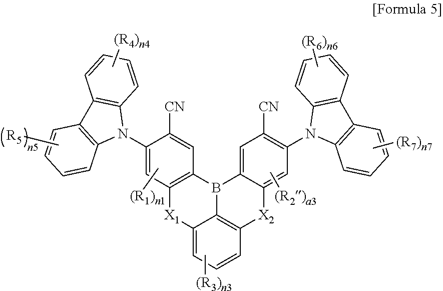

In Formula 5, a carbazole group that includes R₆ and R₇ may correspond to the third substituent, and the CN group that is bonded at a para position to X₂ may correspond to the fourth substituent.

In Formula 5, R₂″, R₆, and R₇ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, R₂″ may be a hydrogen atom. For example, R₆ and R₇ may each independently be a hydrogen atom, a deuterium atom, a substituted or unsubstituted t-butyl group, or a substituted or unsubstituted phenyl group.

In Formula 5, n6 and n7 may each independently be an integer from 0 to 4. In Formula 5, if n6 and m7 are 0, the fused polycyclic compound may not be substituted with R₆ and R₇, respectively. In Formula 5, a case where n6 and n7 are 4 and all R₆ groups and R₇ groups are hydrogen atoms may be the same as a case where n6 and n7 are 0. In Formula 5, if n6 and n7 are 2 or more, multiple R₆ groups and multiple R₇ groups may be all the same, or at least one group thereof may be different from the remainder.

In Formula 5, a3 may be an integer from 0 to 2. In Formula 5, if a3 is 0, the fused polycyclic compound may not be substituted with R₂″. In Formula 5, a case where a3 is 2 and all R₂″ groups are hydrogen atoms may be the same as a case where a3 is 0. In Formula 5, if a3 is 2, multiple R₂″ groups may be all the same, or at least one group thereof may be different from the remainder.

In Formula 5, X₁, X₂, R₁, R₃, R₄, R₅, n1, n3, n4, and n5 are the same as defined in Formula 1.

In an embodiment, the first compound represented by Formula 5 may be represented by Formula 6-1 or Formula 6-2:

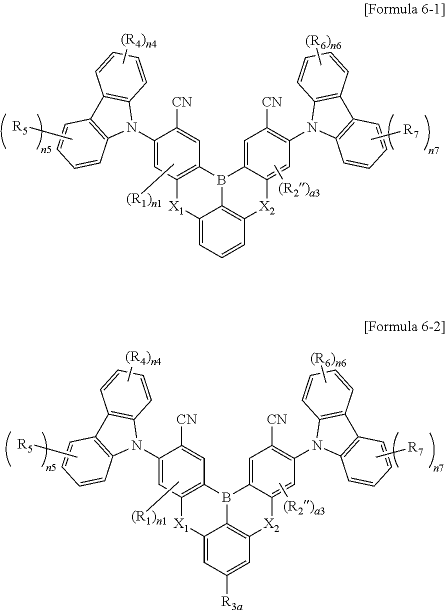

In Formula 6-2, R₃ₐ is the same as defined in Formula 2-3. Thus, in Formula 6-2, R₃ₐ may be a substituted or unsubstituted t-butyl group or a group represented by Formula B-1 or Formula B-2 as described above.

In Formula 6-1 and Formula 6-2, X₁, X₂, R₁, R₄, R₅, n1, n4, n5 are the same as defined in Formula 1, and R₂″, R₆, R₇, n6, n7, and a3 are the same as defined in Formula 5.

In an embodiment, the fused polycyclic compound may include a first sub-substituent and a second sub-substituent, which are substituents that provide steric hindrance in a molecular structure. The first sub-substituent and the second sub-substituent may be respectively connected with the first nitrogen atom and the second nitrogen atom of the fused ring core. The first sub-substituent includes a first benzene moiety and a substituted or unsubstituted phenyl group that is bonded to a carbon atom at a defined position of the first benzene moiety. The first sub-substituent may include a first benzene moiety connected with the first nitrogen atom, and at least one substituted or unsubstituted phenyl group that is connected with a carbon atom of the first benzene moiety that is at an ortho to the first nitrogen atom. The second sub-substituent may include a second benzene moiety and a substituted or unsubstituted phenyl group that is bonded to a carbon atom at a defined position of the second benzene moiety. The second sub-substituent may include a second benzene moiety connected with the second nitrogen atom, and at least one substituted or unsubstituted phenyl group that is connected with a carbon atom of the second benzene moiety that is at an ortho position to the second nitrogen atom.

The fused polycyclic compound having such a structure may effectively maintain the trigonal planar structure of a boron atom through steric hindrance effects due to the first sub-substituent and the second sub-substituent. With respect to the boron atom of the fused ring core, electron-deficient properties may be shown by a vacant p-orbital, and a bond may be formed with another nucleophile to change into a tetrahedral structure, which may contribute to the deterioration of a device. According to embodiments, the fused polycyclic compound includes the first sub-substituent and the second sub-substituent to the fused ring core, and the vacant p-orbital of the boron atom may be effectively protected, so that deterioration of a device by structural deformation of the polycyclic compound may be prevented.

In the fused polycyclic compound, intermolecular interaction may be suppressed by the first sub-substituent and the second sub-substituent, so that aggregation and the formation of an excimer or an exciplex may be suppressed, and thus, emission efficiency and device lifespan may be improved. The fused polycyclic compound includes the first sub-substituent and the second sub-substituent, thereby introducing additional substituents at defined positions, so that intermolecular distance may increase, and effects of reducing exciton quenching such as Dexter energy transfer may be achieved. Dexter energy transfer is an intermolecular movement phenomenon of triplet excitons, which increases with the reduction of the intermolecular distance, and therefore may be a factor in increasing quenching phenomenon due to an increase of triplet concentration. According to embodiments, the fused polycyclic compound has a bulky structure having large steric hindrance, thereby increasing intermolecular distance, so that Dexter energy transfer may be suppressed. Accordingly, the deterioration of device lifespan due to increased triplet concentration may be suppressed. Accordingly, if the fused polycyclic compound is applied to the emission layer EML of the light emitting device ED, emission efficiency may be improved, and the device lifetime may also be increased.

In an embodiment, X₁ and X₂ may each independently be represented by Formula X-1 or Formula X-2:

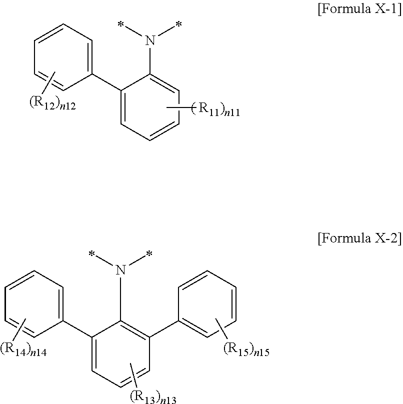

In Formula X-1 and Formula X-2, R₁₁ to R₁₅ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₁₁ to R₁₅ may each independently be a hydrogen atom, a deuterium atom, or a substituted or unsubstituted t-butyl group.

In Formula X-1, n11 may be an integer from 0 to 4. In Formula X-1, if n11 is 0, the fused polycyclic compound may not be substituted with R₁₁. In Formula X-1, a case where n1l is 4 and all R₁₁ groups are hydrogen atoms may be the same as a case where n11 is 0. If n11 is 2 or more, multiple R₁₁ groups may be all the same, or at least one group thereof may be different from the remainder.

In Formula X-1 and Formula X-2, n12, n14, and n15 may each independently be an integer from 0 to 5. In Formula X-1 and Formula X-2, if n12, n14, and n15 are 0, the fused polycyclic compound may not be substituted with R₁₂, R₁₄, and R₁₅, respectively. In Formula X-1 and Formula X-2, a case where n12, n14, and n15 are 5, and all R₁₂ groups, R₁₄ groups, and R₁₅ groups are hydrogen atoms may be the same as a case where n12, n14, and n15 are 0, respectively. If n12, n14, and n15 are 2 or more, multiple R₁₂ groups, multiple R₁₄ groups, and multiple R₁₅ groups may be all the same, or at least one group thereof may be different from the remainder.

In Formula X-2, n13 may be an integer from 0 to 3. In Formula X-2, if n13 is 0, the fused polycyclic compound may not be substituted with R₁₃. In Formula X-2, a case where n13 is 3 and all R₁₃ groups are hydrogen atoms may be the same as a case where n13 is 0. If n13 is 2 or more, multiple R₁₃ groups may be all the same, or at least one group thereof may be different from the remainder.

In Formula X-1 and Formula X-2, -* is a position connected with Formula 1.

In an embodiment, the first compound represented by Formula 1 may be represented by any one of Formula 7-1 to Formula 7-4:

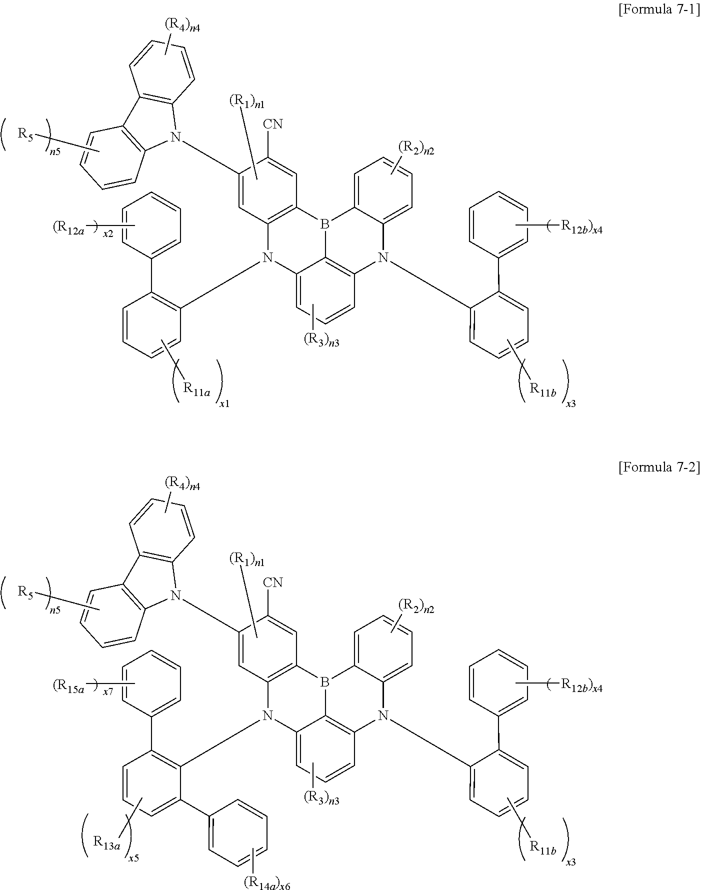

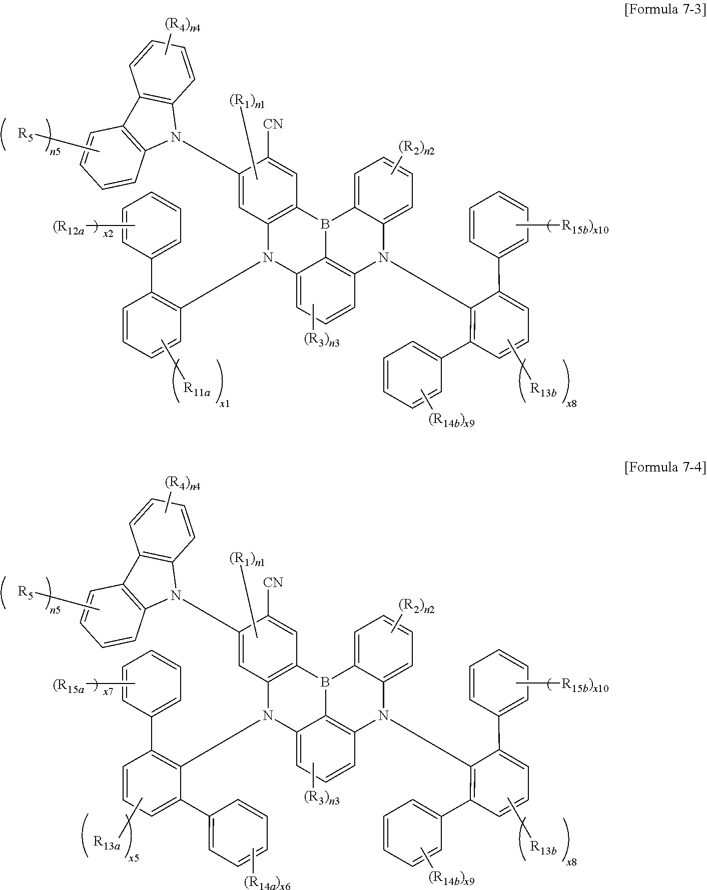

In Formula 7-1 to Formula 7-4, R₁₁ₐ to R₁₅ₐ and R_{11b} to R_{15b} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₁₁ₐ to R₁₅ₐ and R_{11b} to R_{15b} may each independently be a hydrogen atom, a deuterium atom, or a substituted or unsubstituted t-butyl group.

In Formula 7-1 to Formula 7-3, x1 and x3 may each independently be an integer from 0 to 4. In Formula 7-1 to Formula 7-3, if x1 and x3 are 0, the fused polycyclic compound may not be substituted with R₁₁ₐ and R_{11b}, respectively. In Formula 7-1 to Formula 7-3, a case where x1 and x3 are 4 and all R₁₁ₐ groups and R_{11b} groups are hydrogen atoms may be the same as a case where x1 and x3 are 0, respectively. If x1 and x3 are 2 or more, multiple R₁₁ₐ groups and multiple R_{11b} groups may be all the same, or at least one group thereof may be different from the remainder.

In Formula 7-1 to Formula 7-4, x2, x4, x6, x7, x9, and x10 may each independently be an integer from 0 to 5. In Formula 7-1 to Formula 7-4, if x2, x4, x6, x7, x9, and x10 are 0, the fused polycyclic compound may not be substituted with R₁₂ₐ, R_{12b}, R₁₄ₐ, R₁₅ₐ, R_{14b}, and R_{15b}, respectively. In Formula 7-1 to Formula 7-4, a case where x2, x4, x6, x7, x9, and x10 are 5 and all R₁₂ₐ groups, R_{12b} groups, R₁₄ₐ groups, R₁₅ₐ groups, R_{14b} groups, and R_{15b} groups are hydrogen atoms may be the same as a case where x2, x4, x6, x7, x9, and x10 are 0, respectively. If x2, x4, x6, x7, x9, and x10 are 2 or more, multiple groups of each of R₁₂ₐ, R_{12b}, R₁₄ₐ, R₁₅ₐ, R_{14b}, and R_{15b} may be all the same, or at least one group thereof may be different from the remainder.

In Formula 7-2 to Formula 7-4, x5 and x8 may each independently be an integer from 0 to 3. In Formula 7-2 to Formula 7-4, if x5 and x8 are 0, the fused polycyclic compound may not be substituted with R₁₃ₐ and R_{13b}, respectively. In Formula 7-2 to Formula 7-4, a case where x5 and x8 are 3 and all R₁₃ₐ groups and R_{13b} groups are hydrogen atoms may be the same as a case where x5 and x8 are 0, respectively. If x5 and x8 are 2 or more, multiple R₁₃ₐ groups and multiple R_{13b} groups may be all the same, or at least one group thereof may be different from the remainder.

In Formula 7-1 to Formula 7-4, R₁ to R₅ and n1 to n5 are the same as defined in Formula 1.

In an embodiment, the compound represented by Formula 1 may be represented by any one of Formula 8-1 to Formula 8-3:

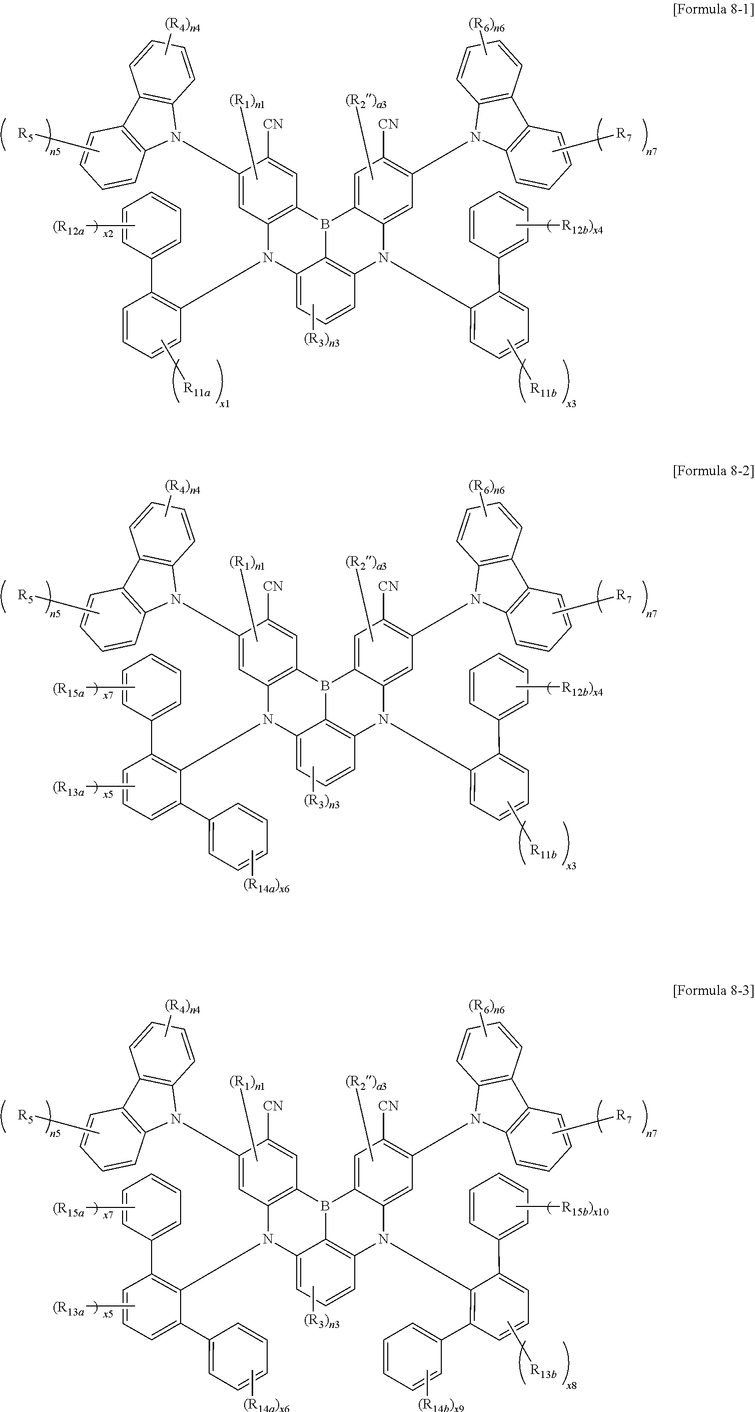

In Formula 8-1 to Formula 8-3, R₁₁ₐ to R₁₅ₐ, R_{11b} to R_{15b}, and x1 to x10 are the same as defined in Formula 7-1 to Formula 7-4.

In Formula 8-1 to Formula 8-3, R₁, R₃ to R₅, n1, and n3 to n5 are the same as defined in Formula 1.

In Formula 8-1 to Formula 8-3, R₂″, R₆, R₇, n6, n7, and a3 are the same as defined in Formula 5.

In an embodiment, the fused polycyclic compound may be any compound selected from Compound Group 1. In an embodiment, the light emitting device ED may include at least one fused polycyclic compound selected from Compound Group 1 in an emission layer EML.

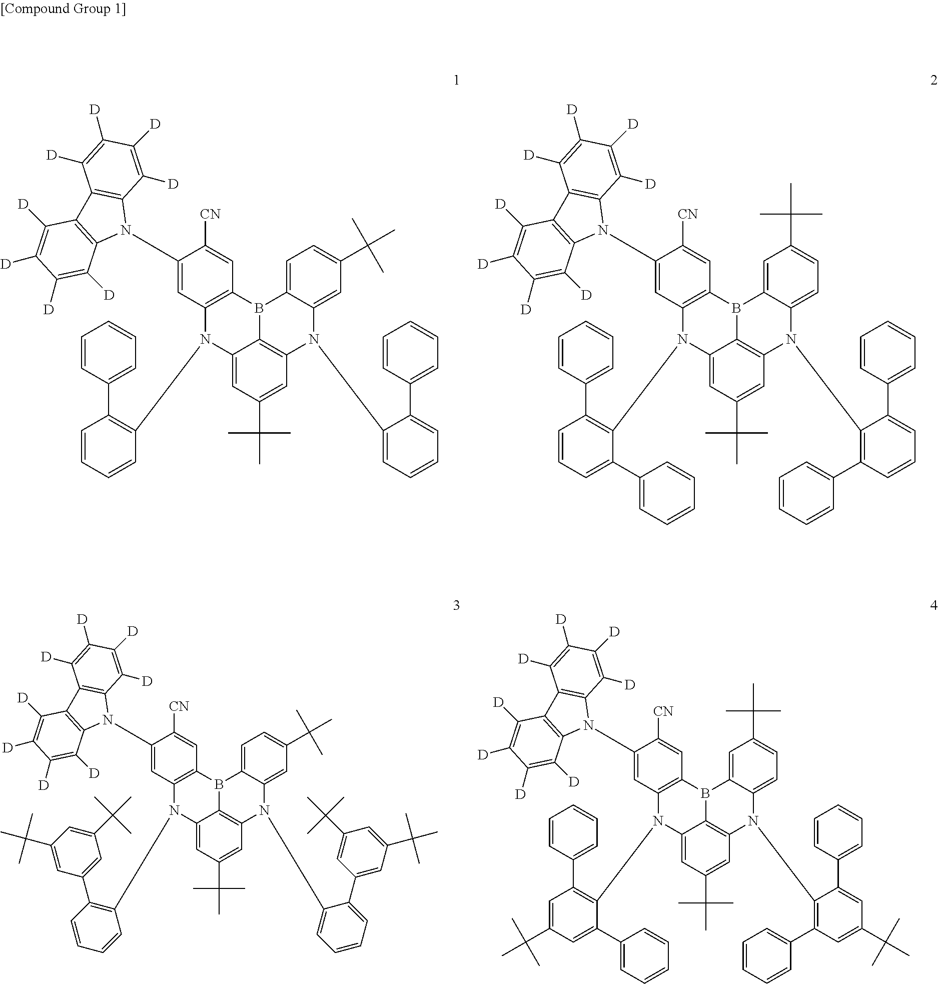

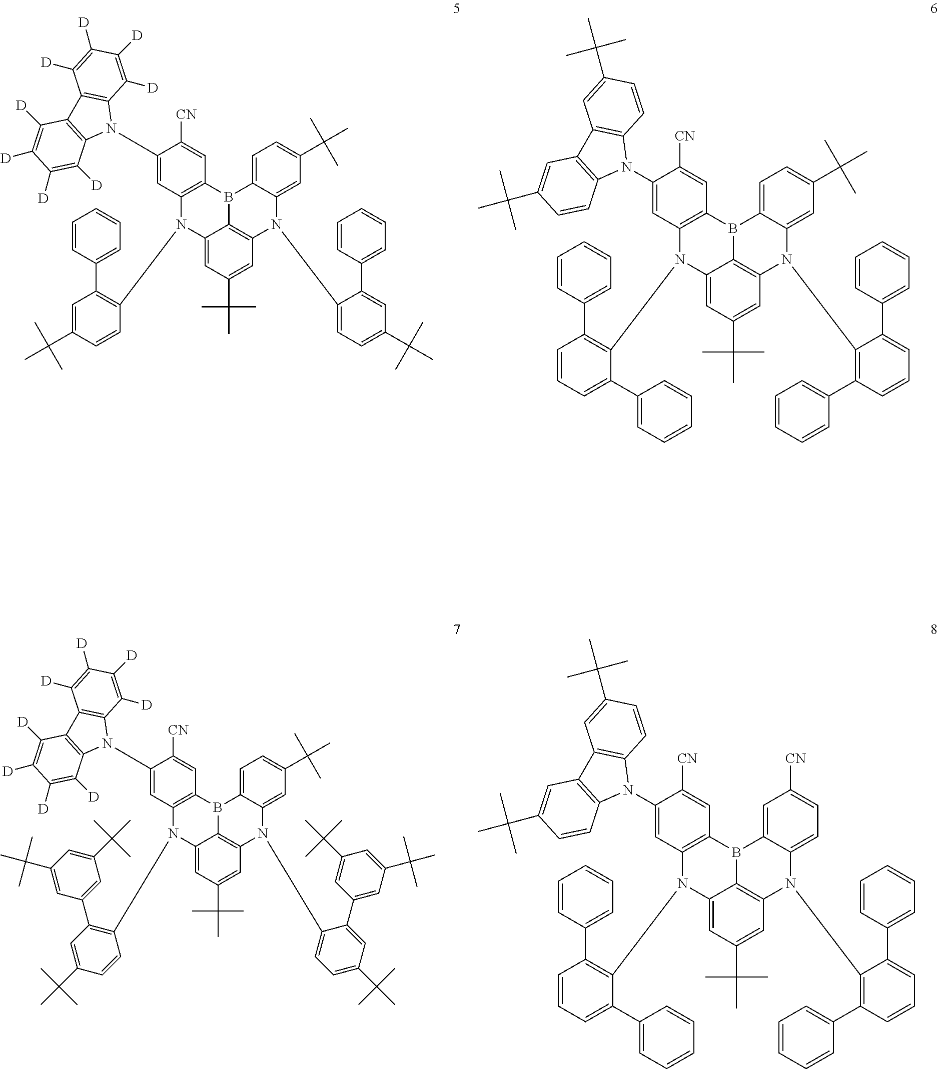

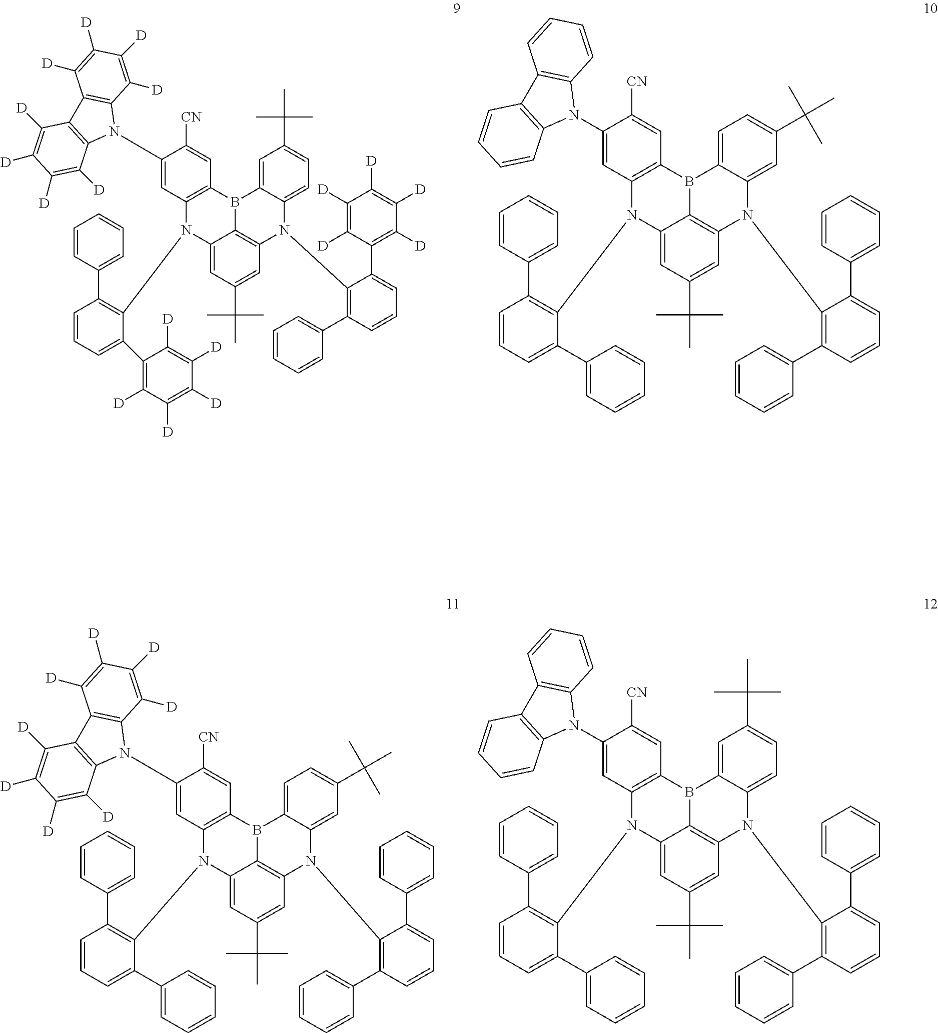

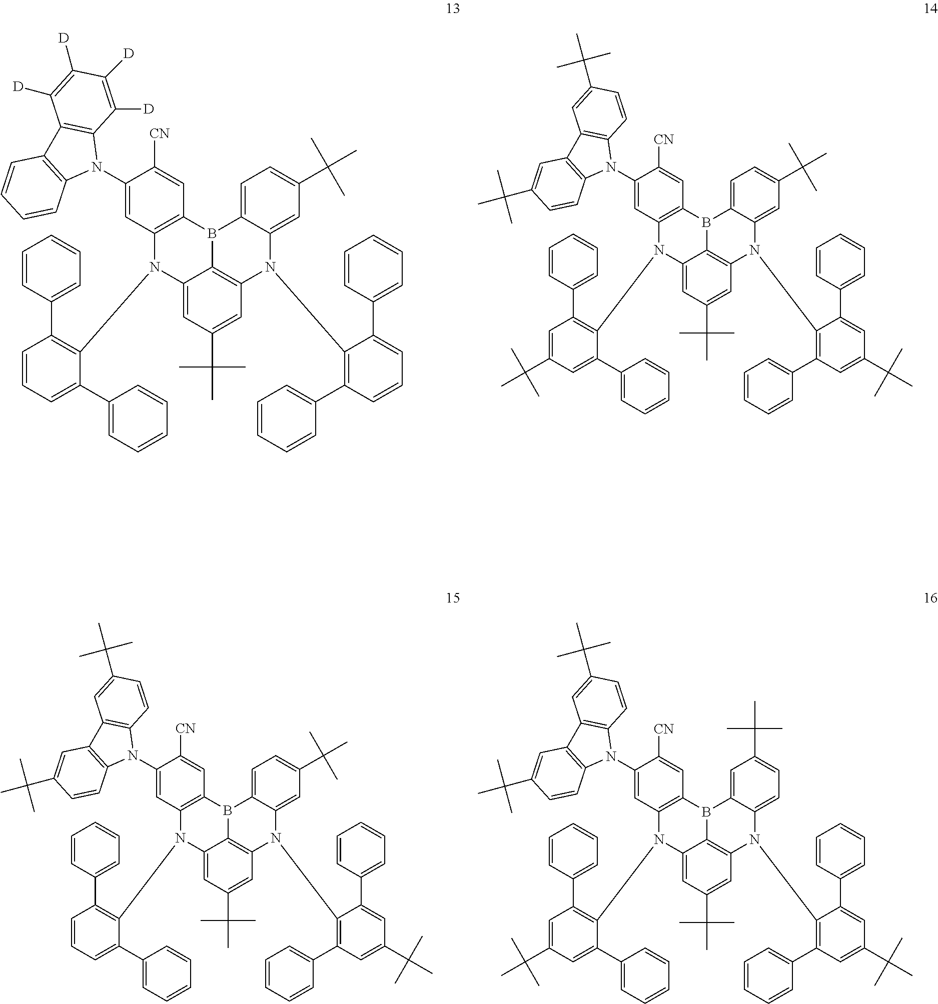

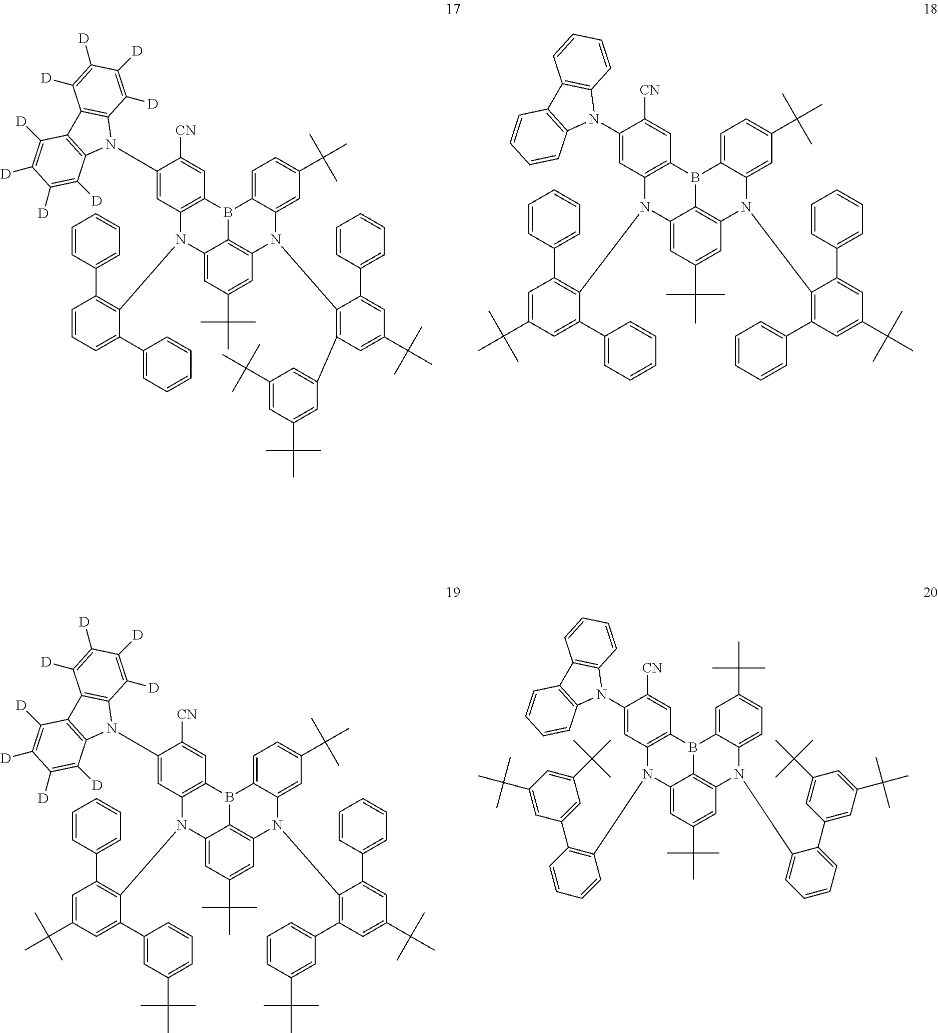

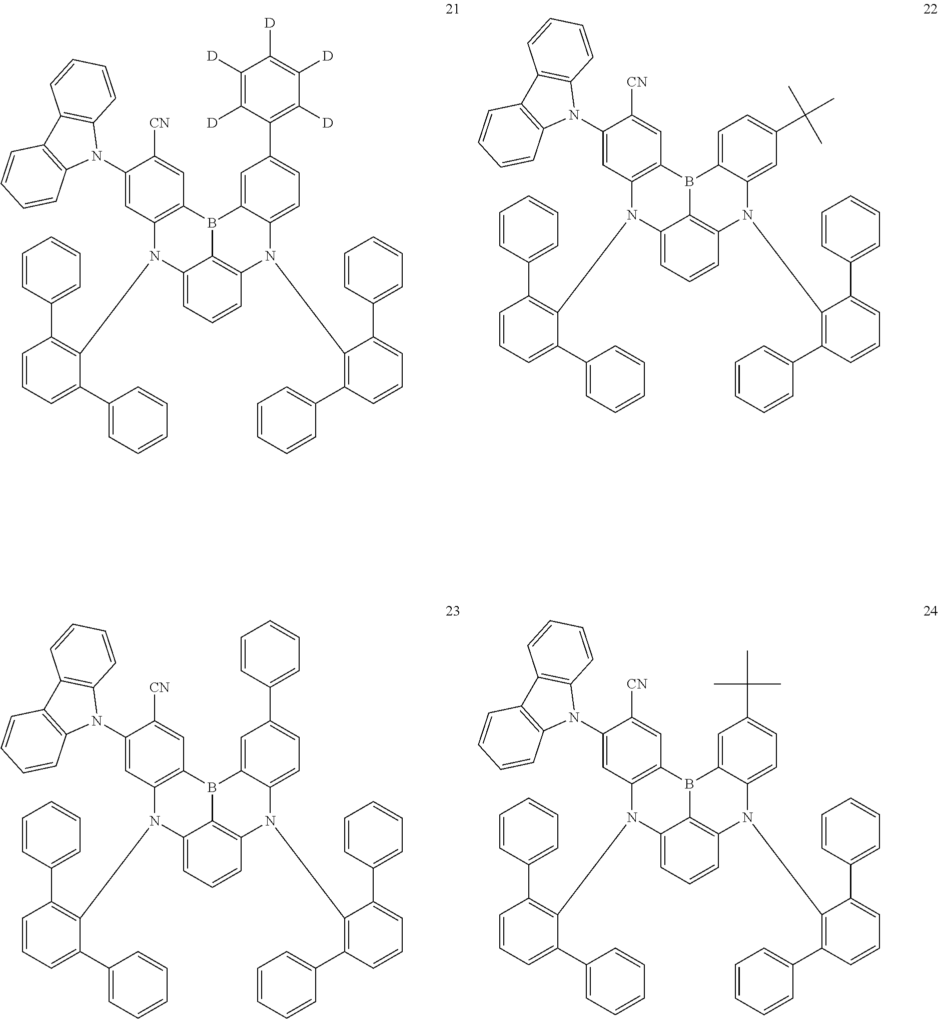

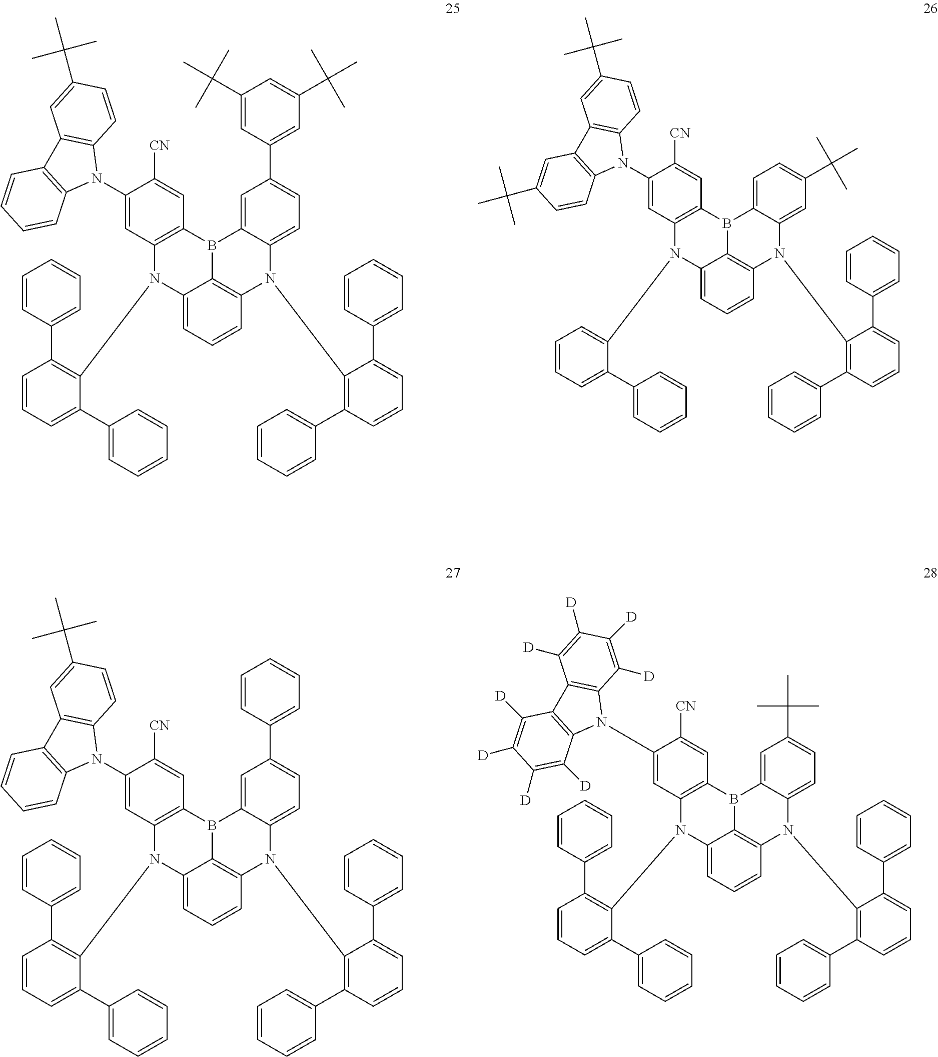

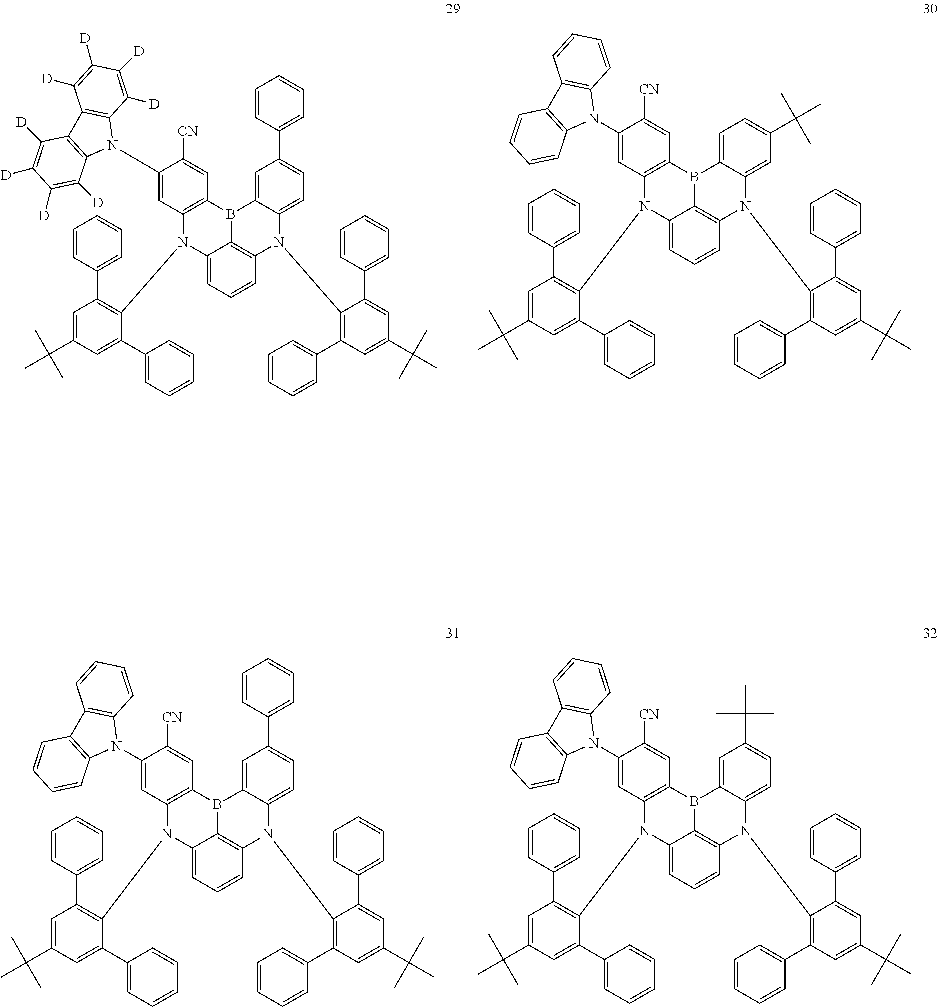

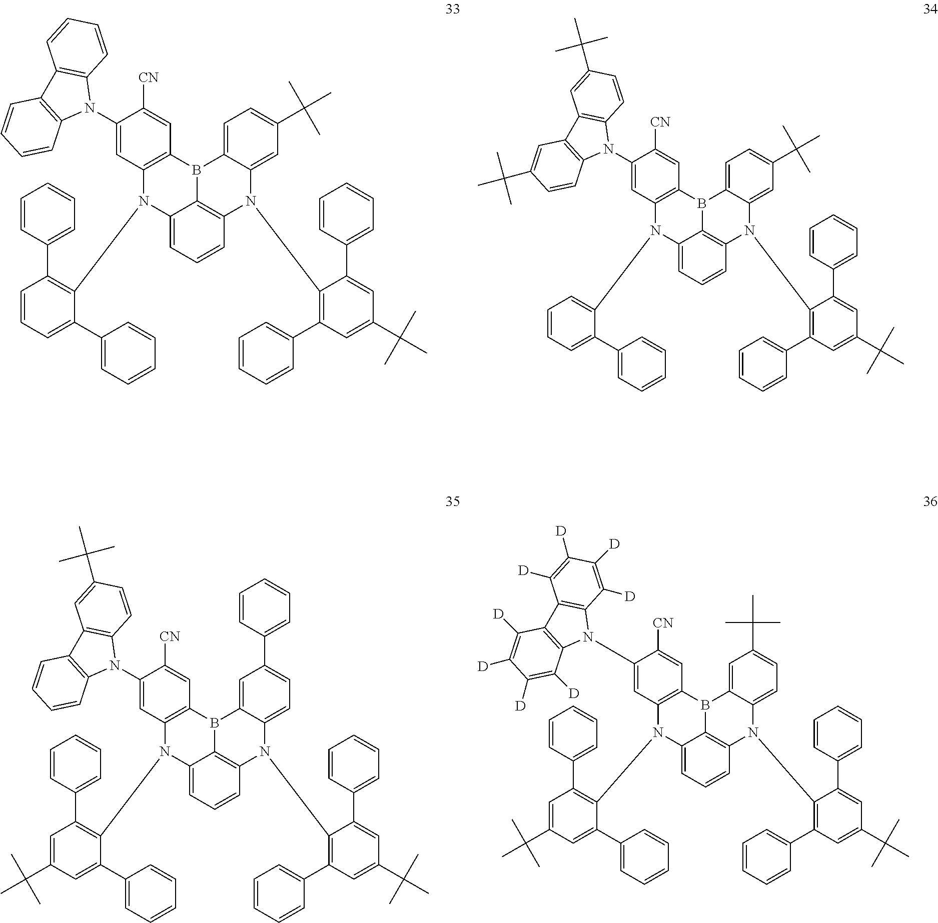

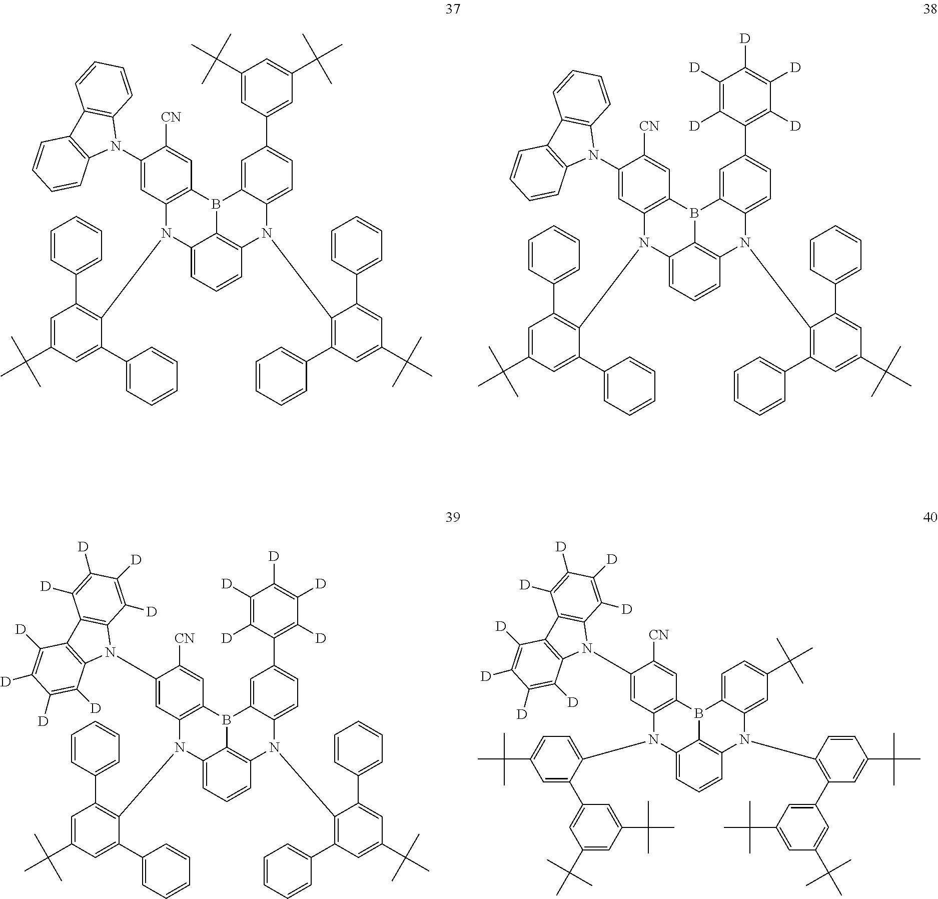

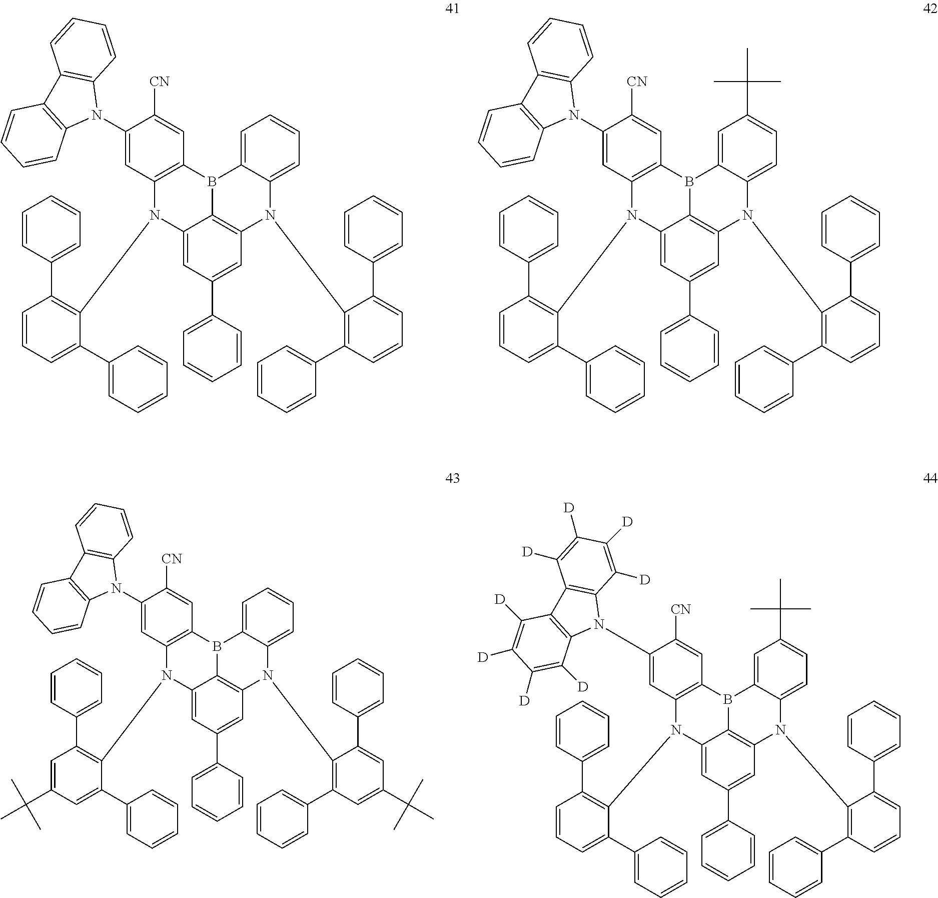

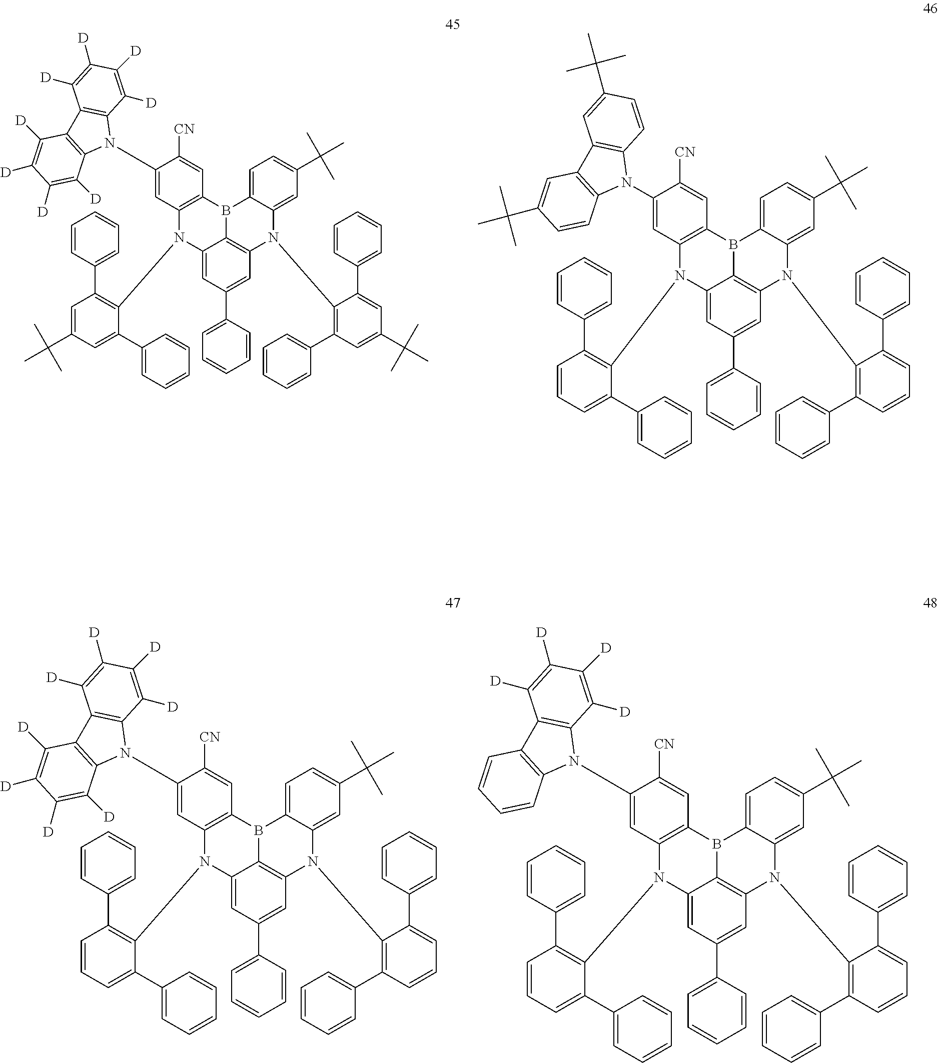

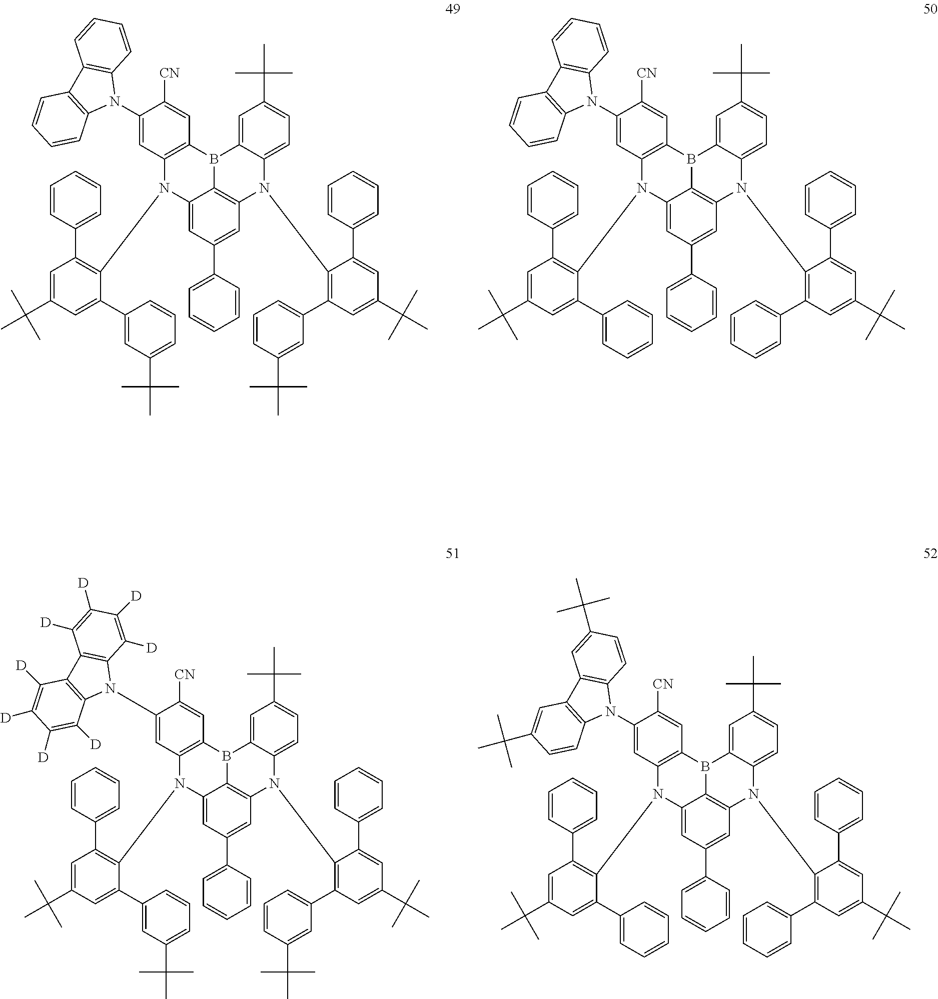

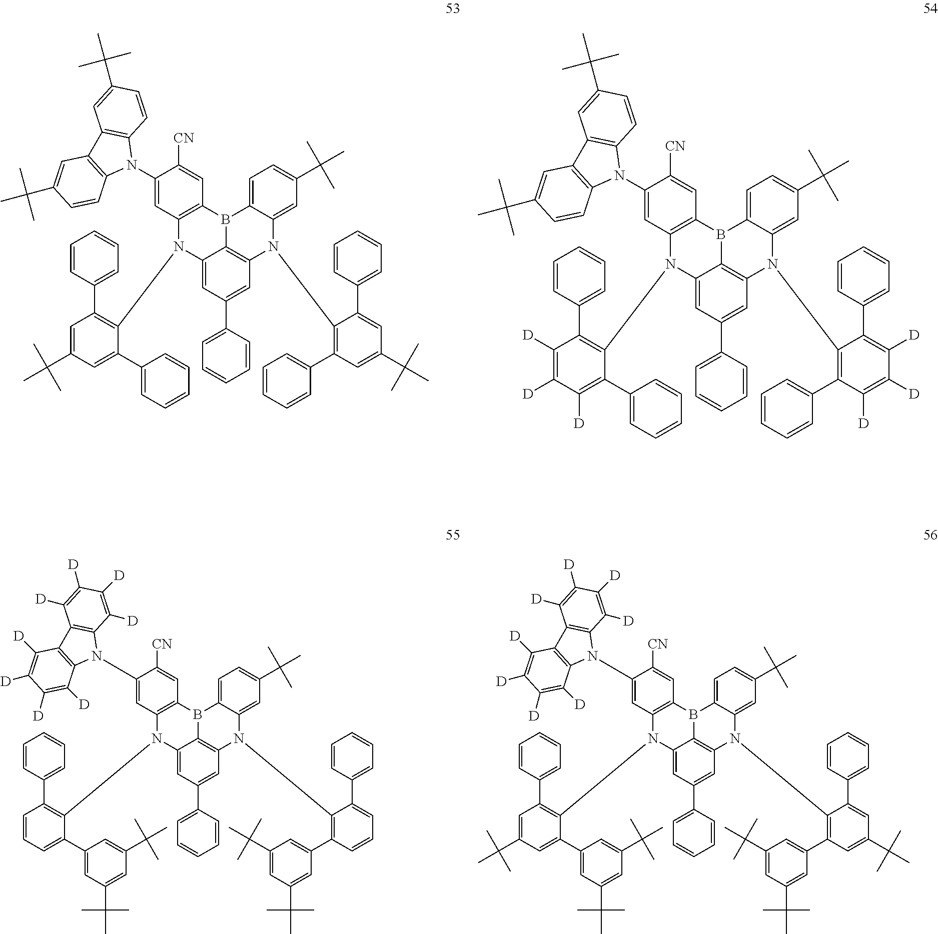

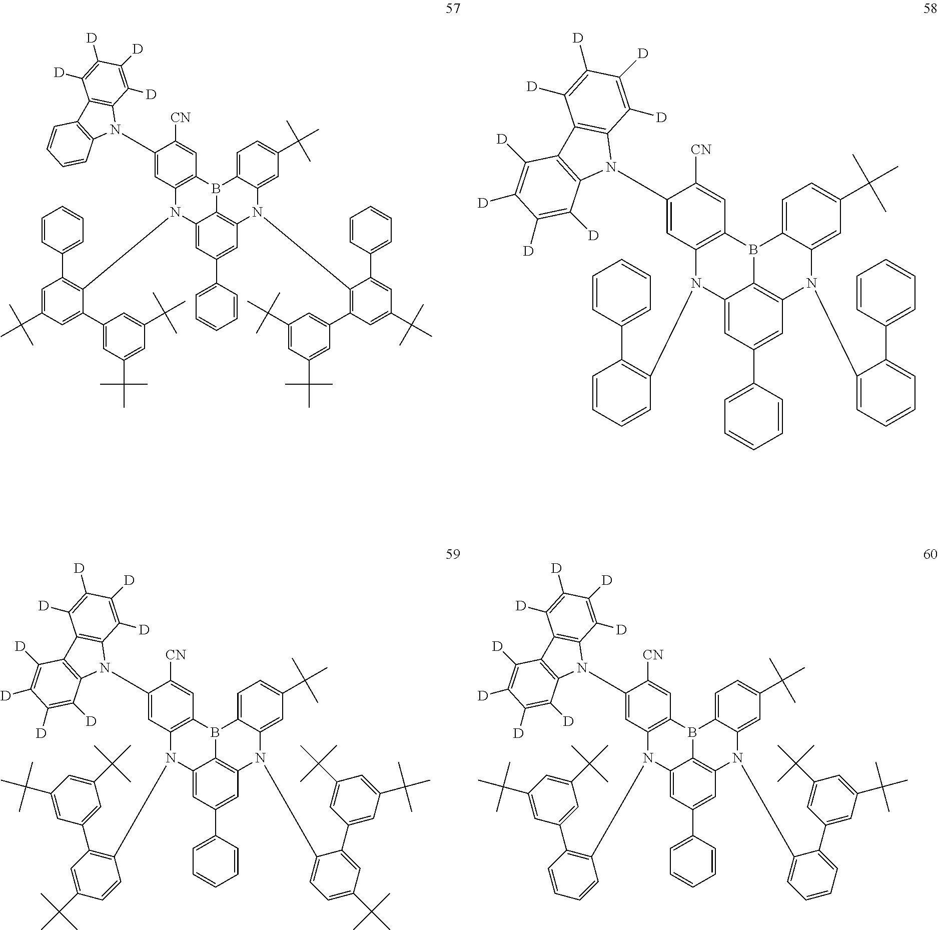

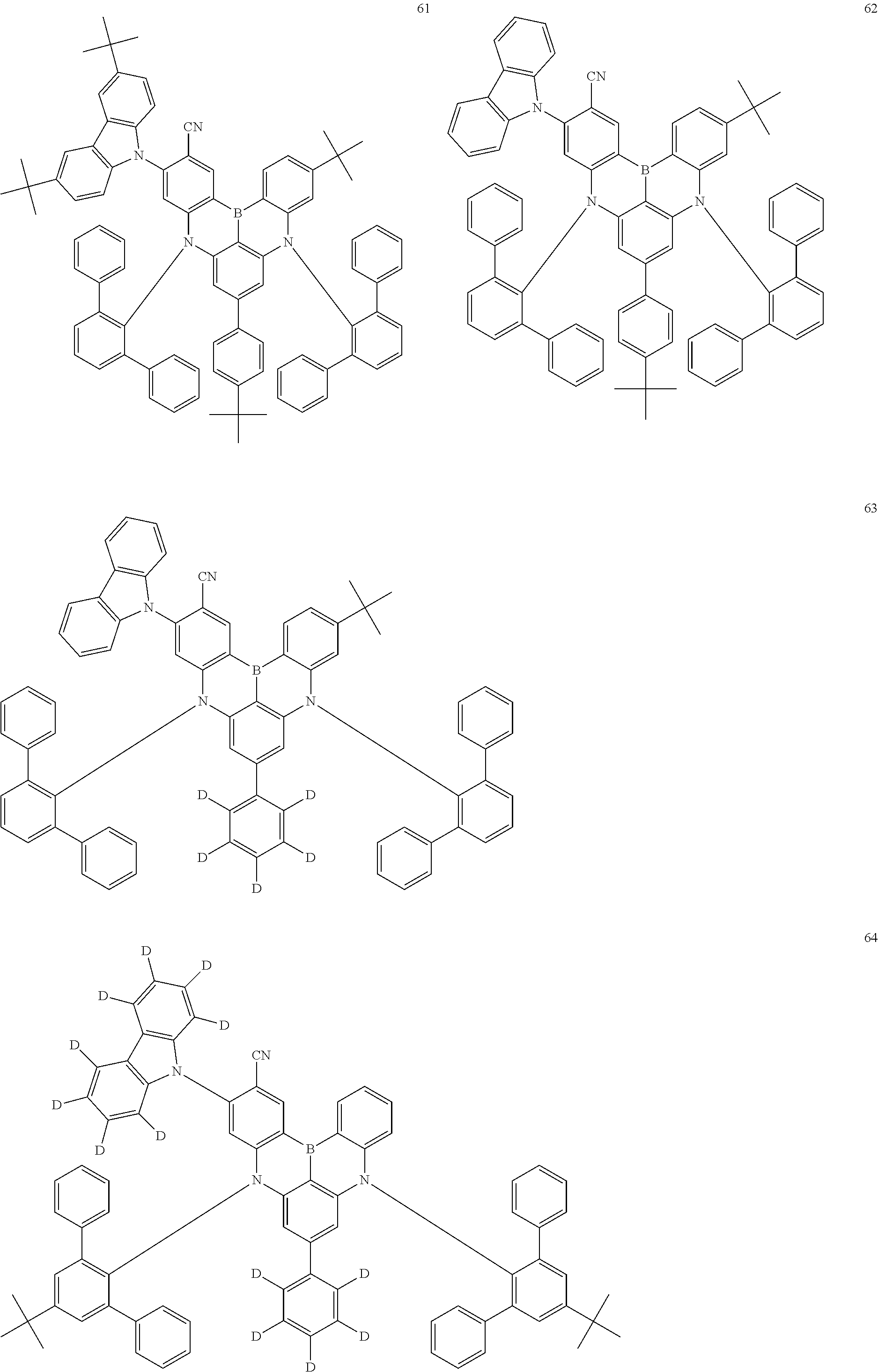

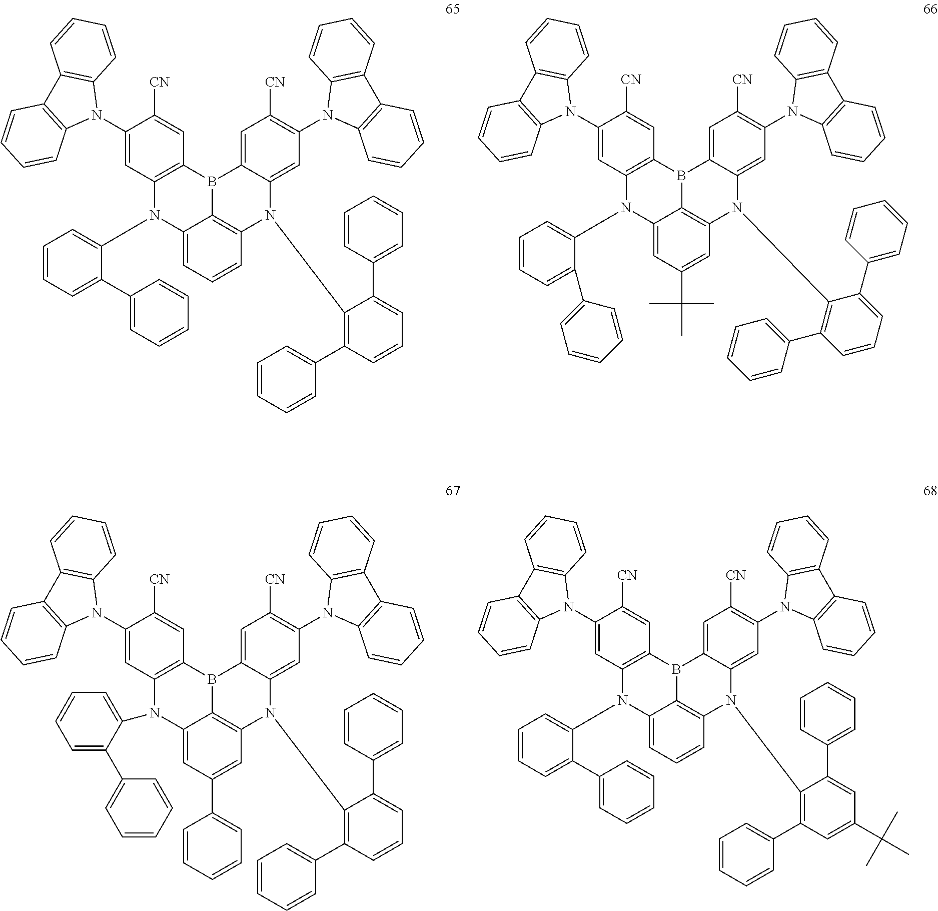

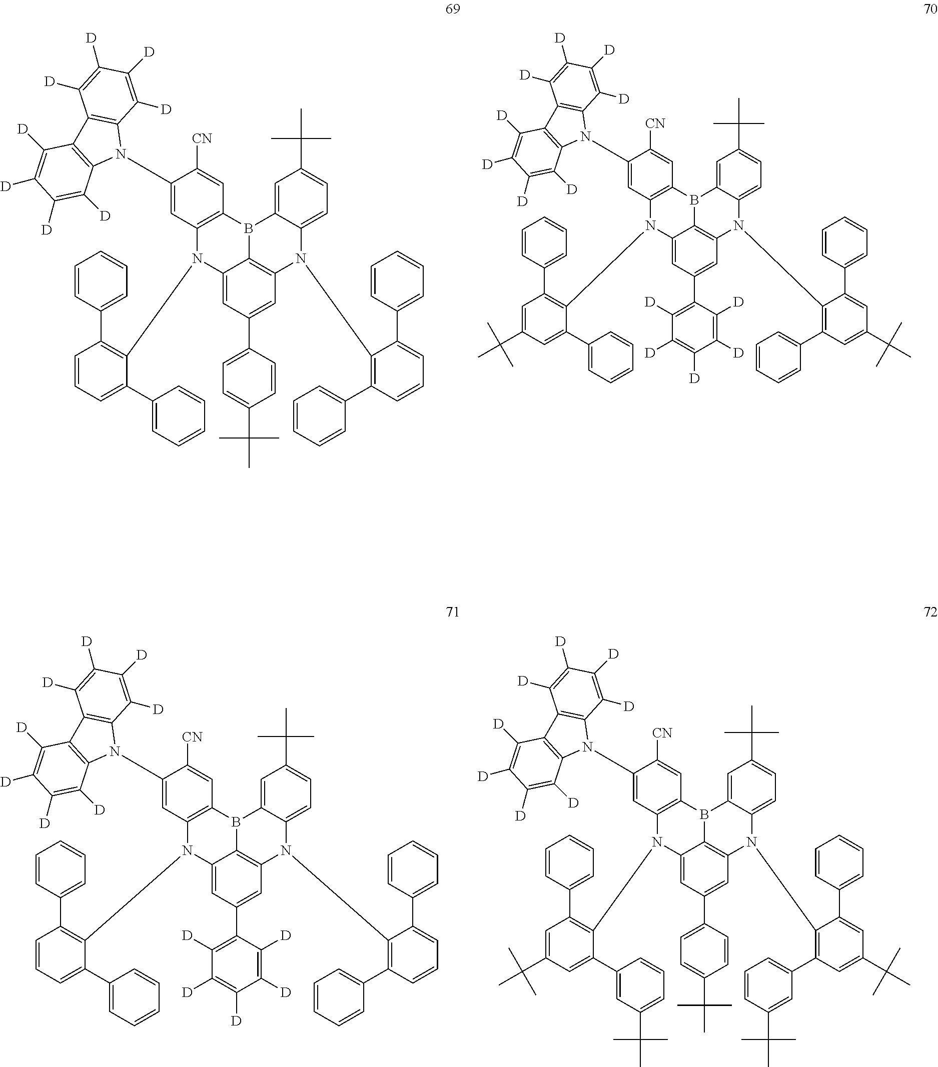

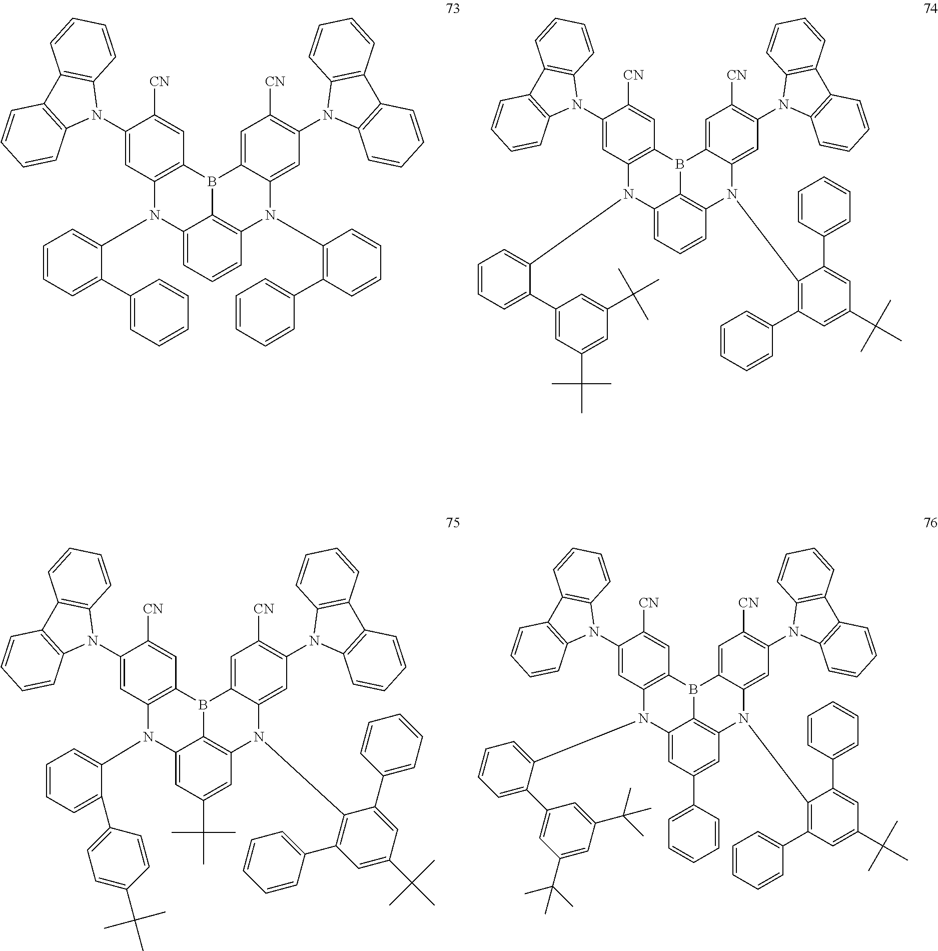

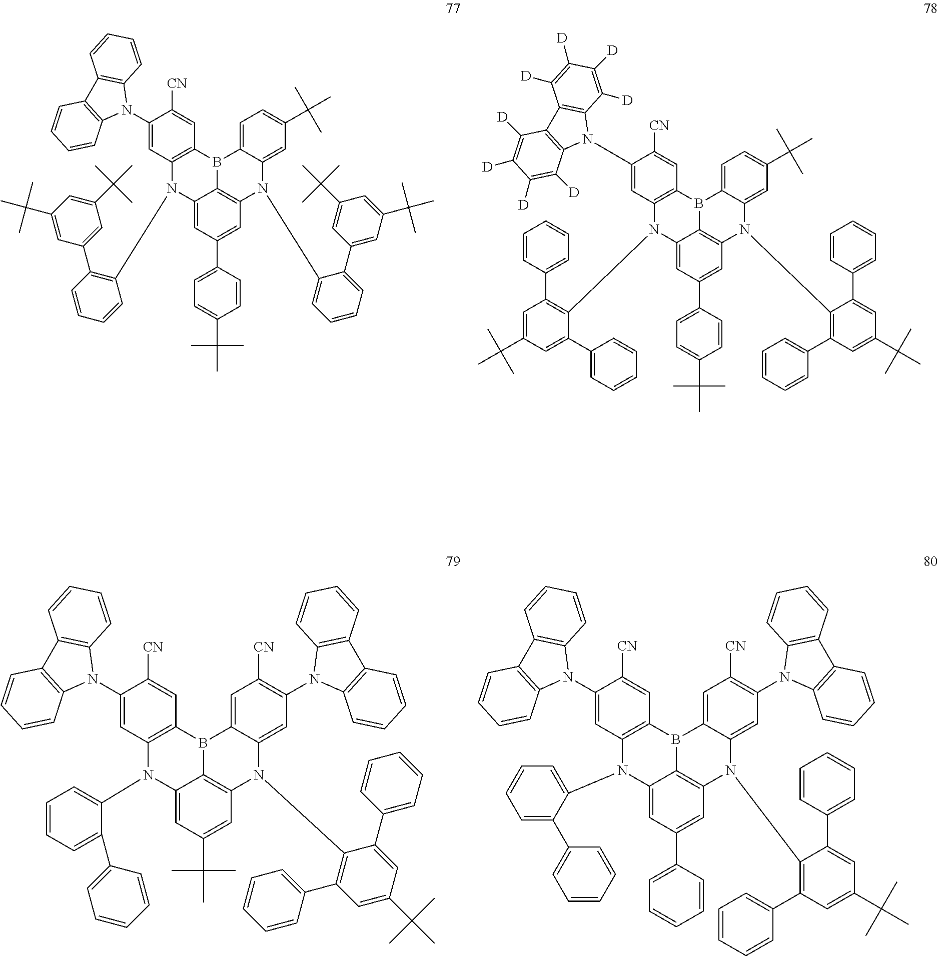

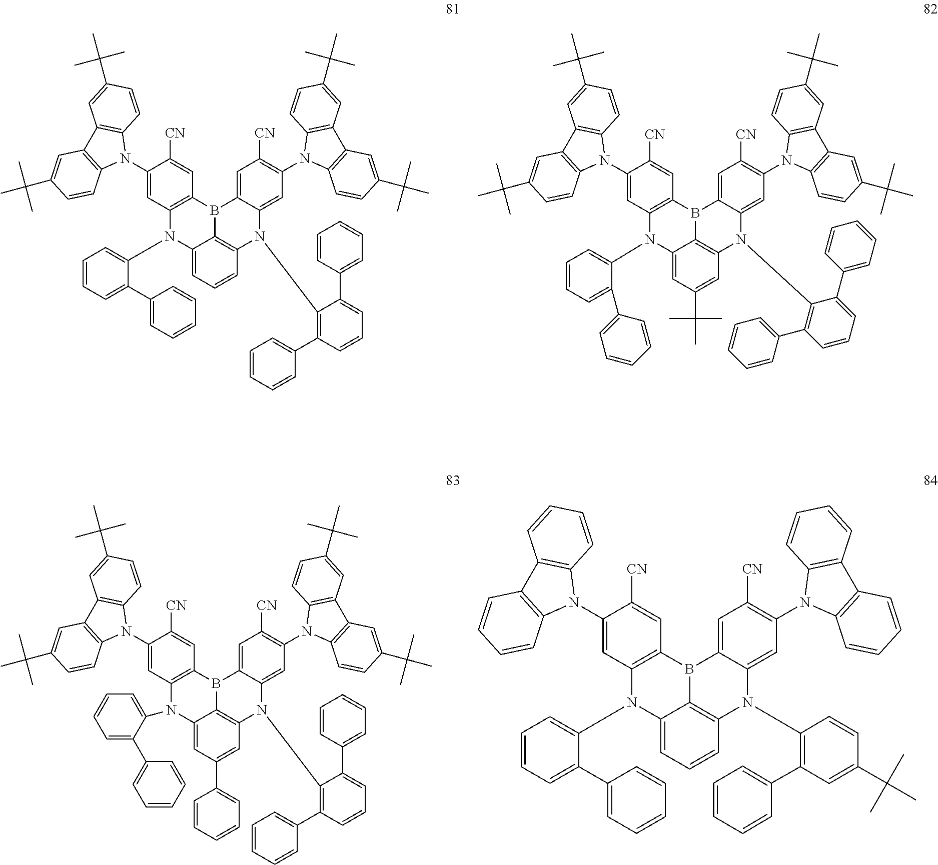

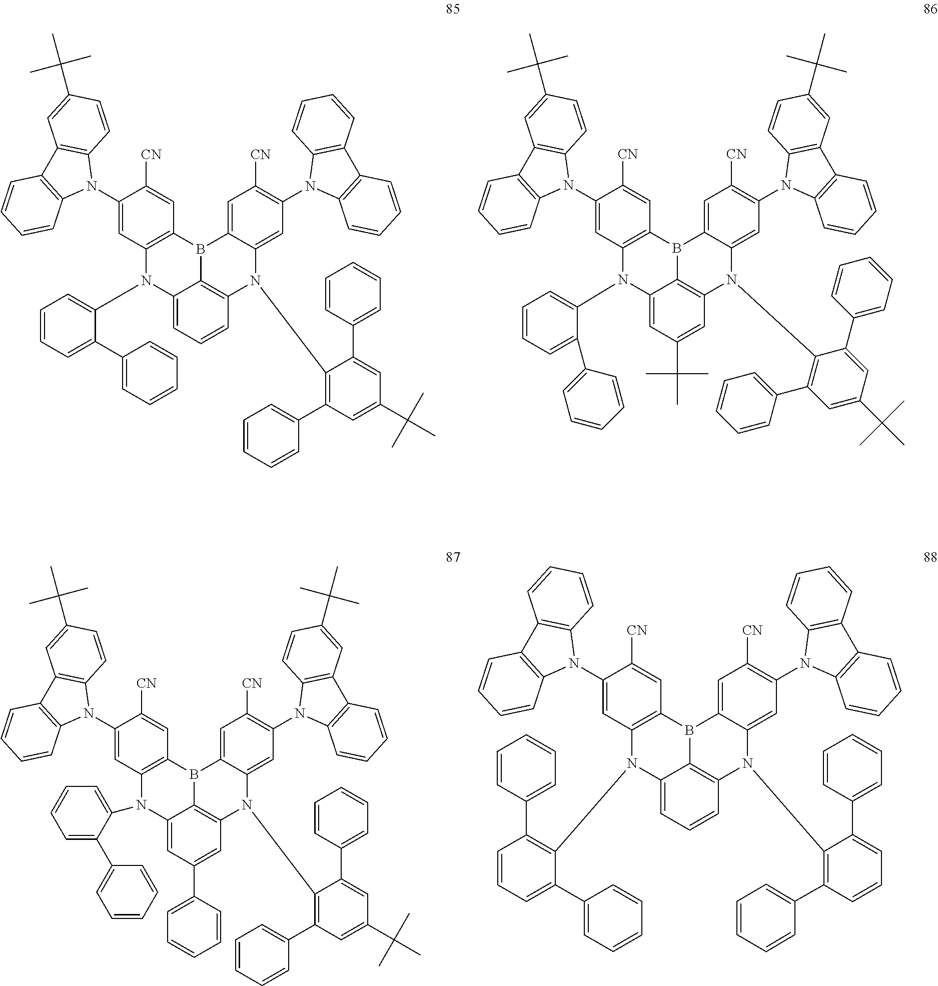

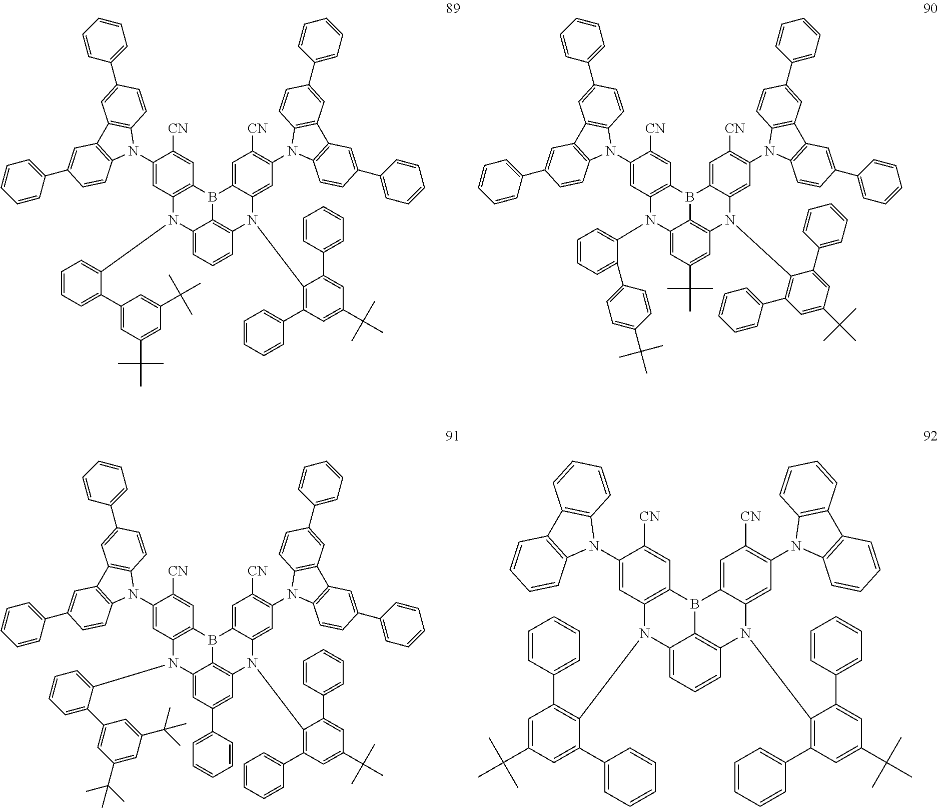

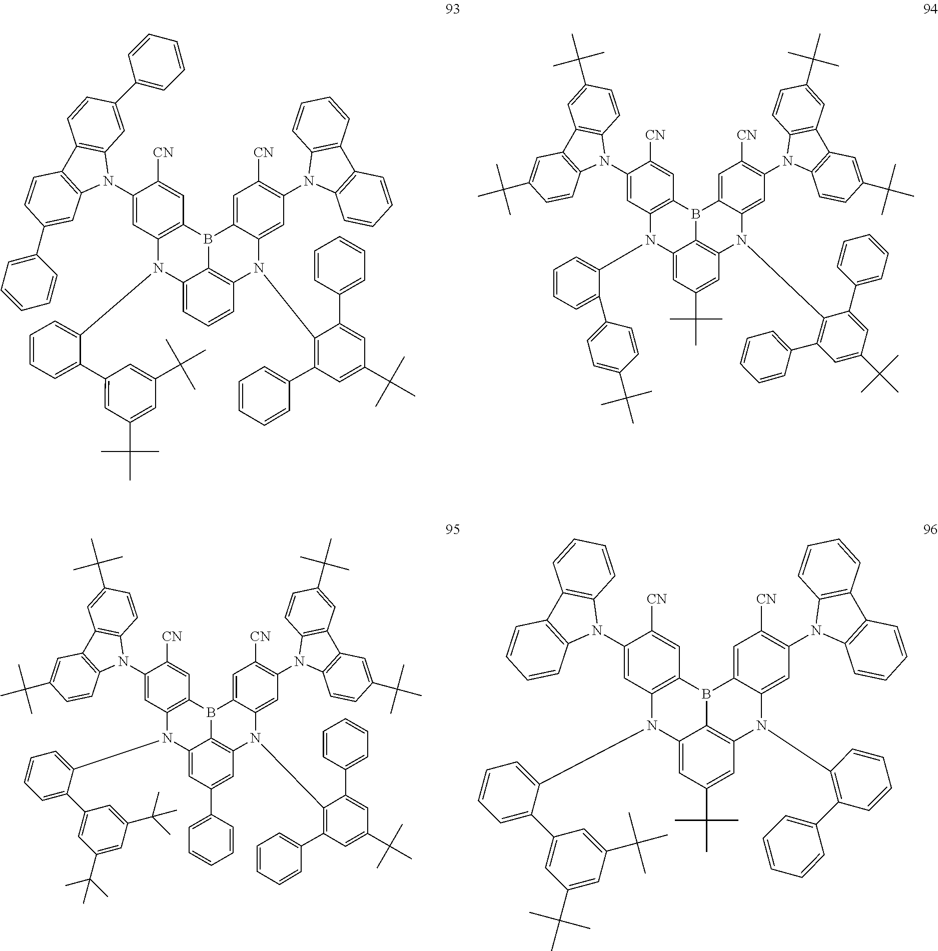

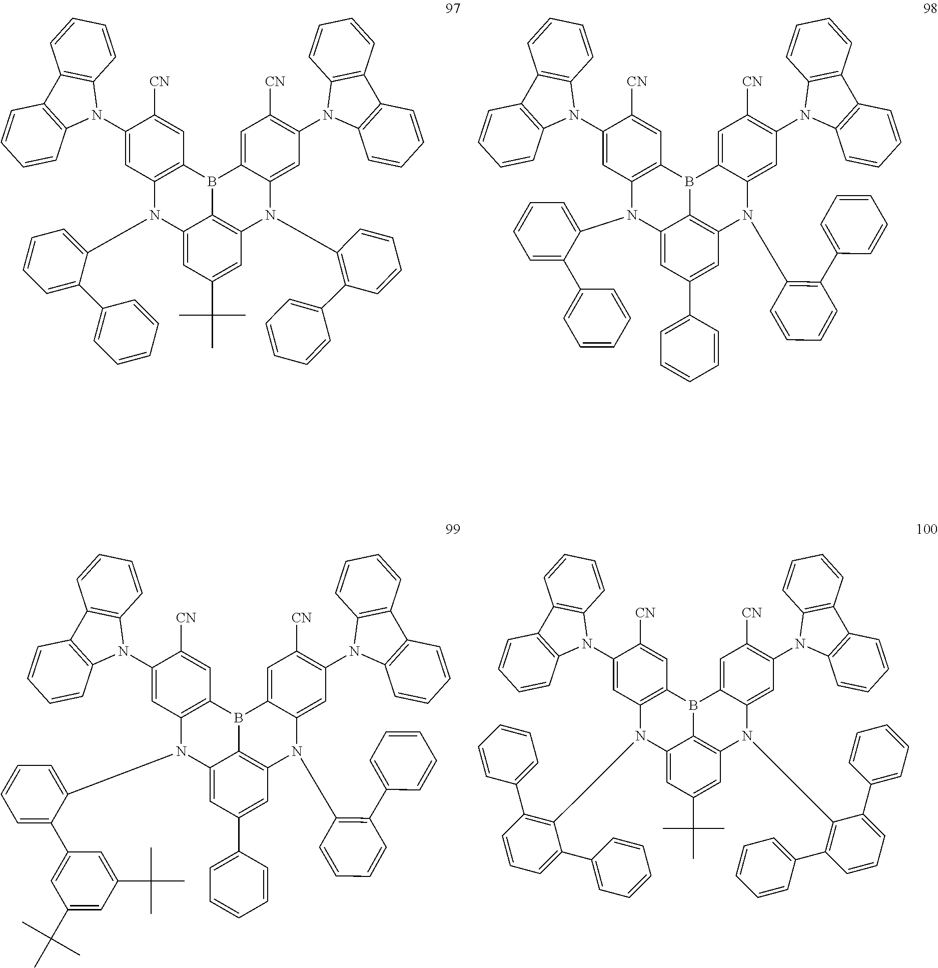

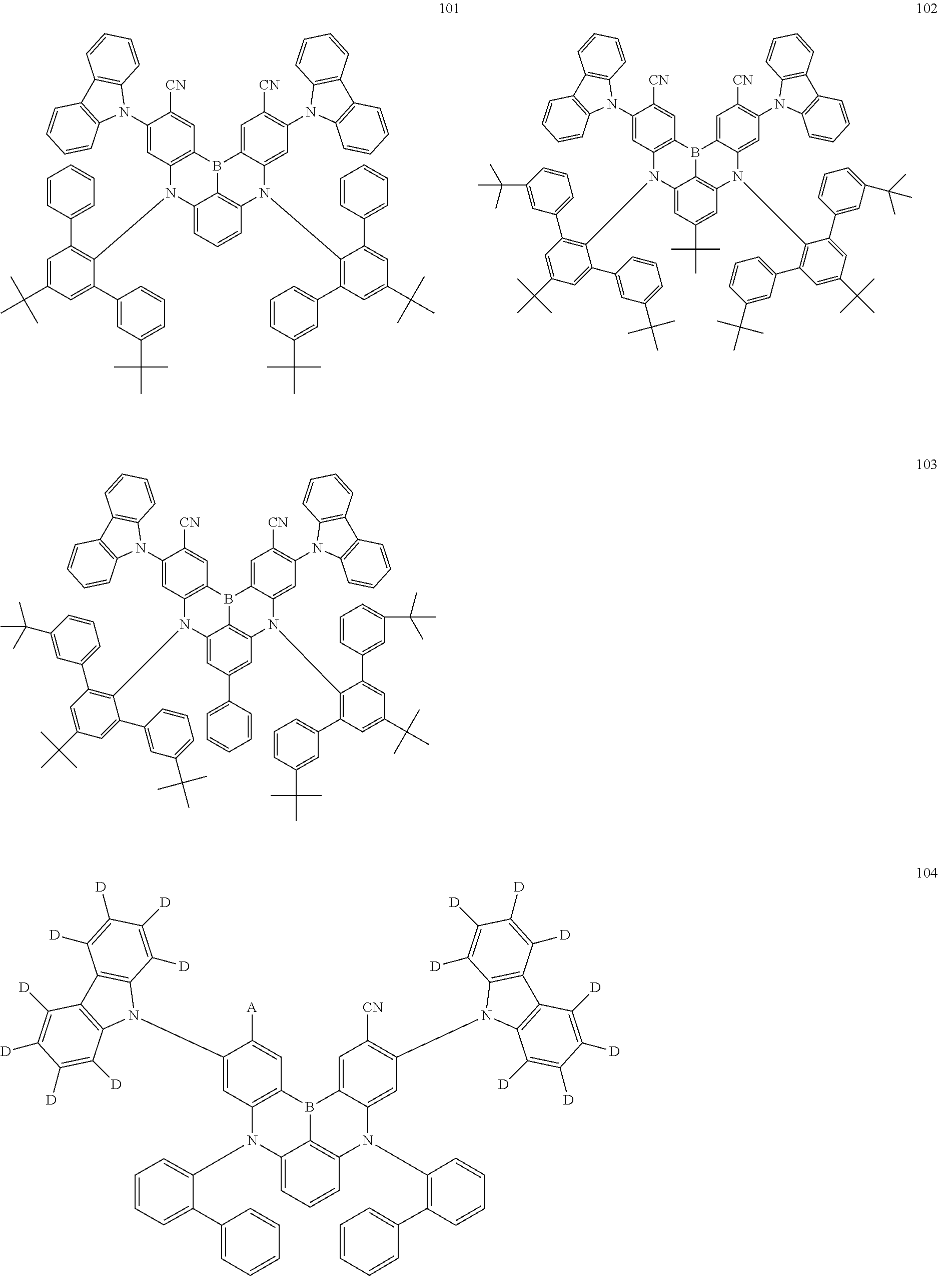

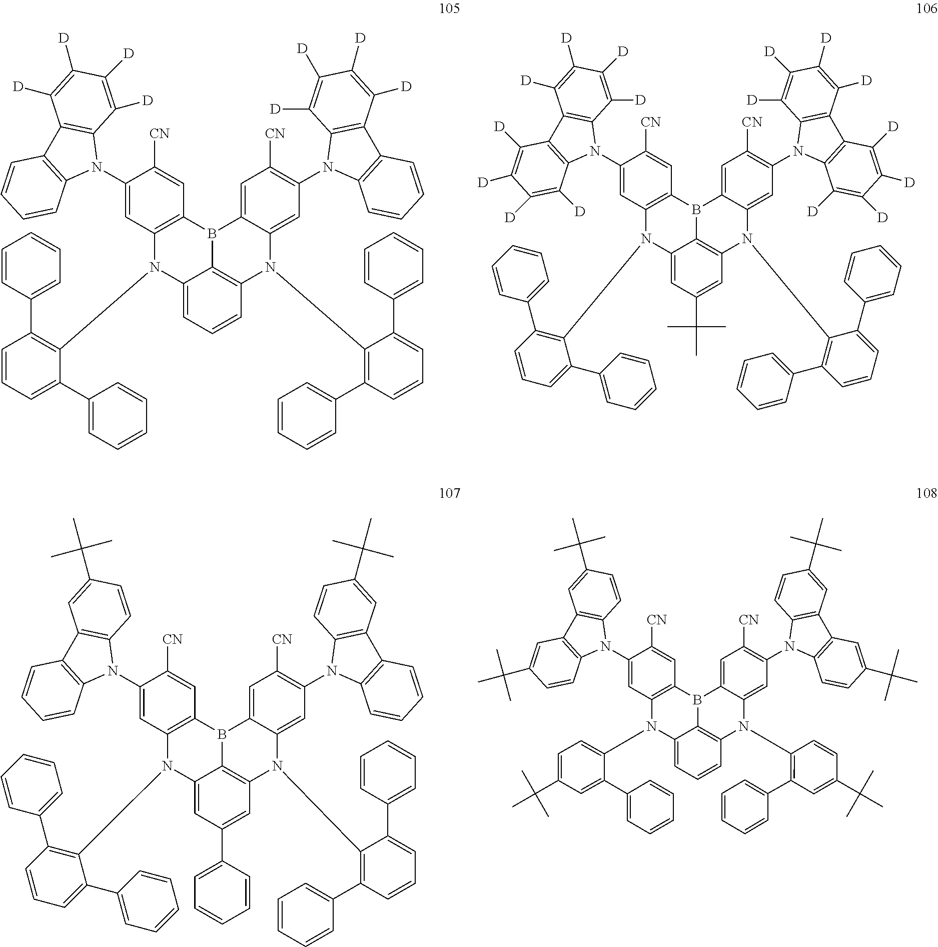

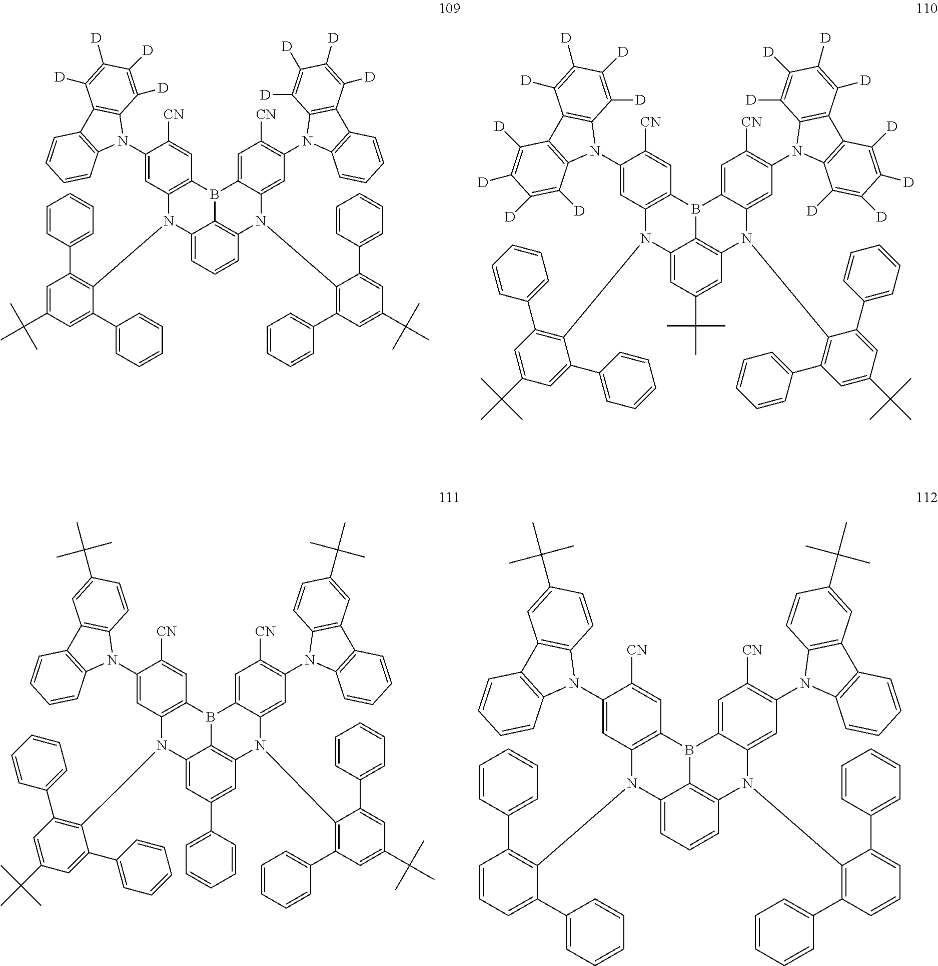

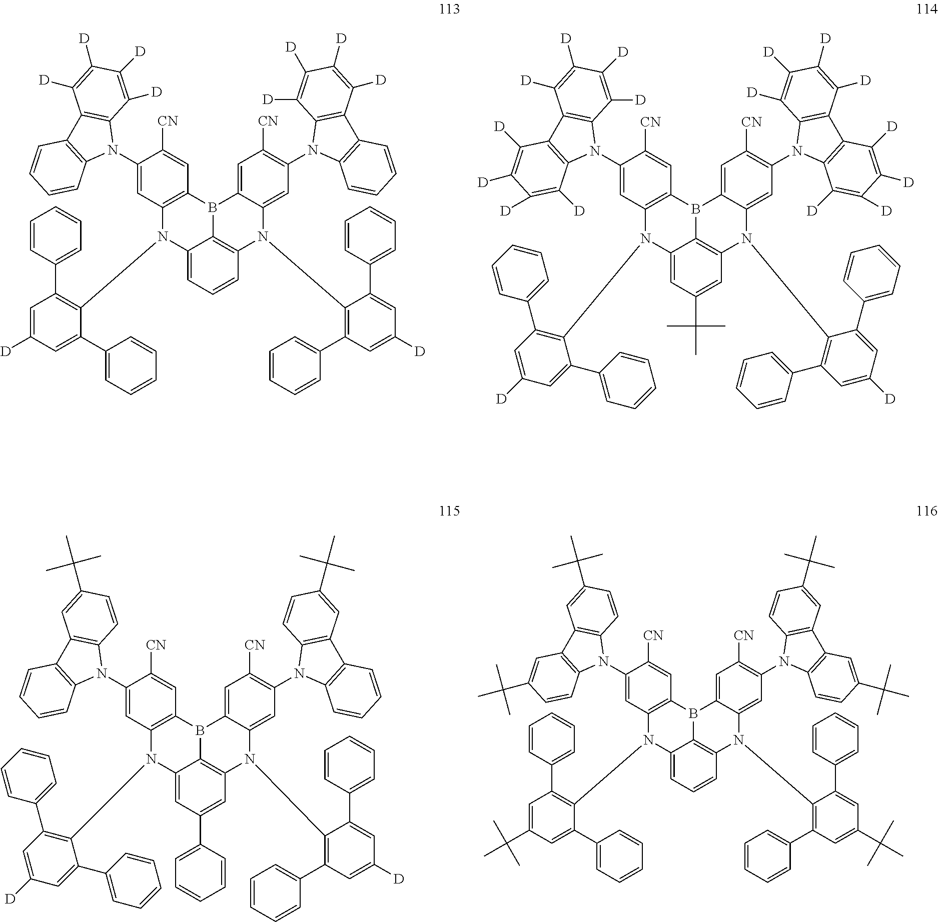

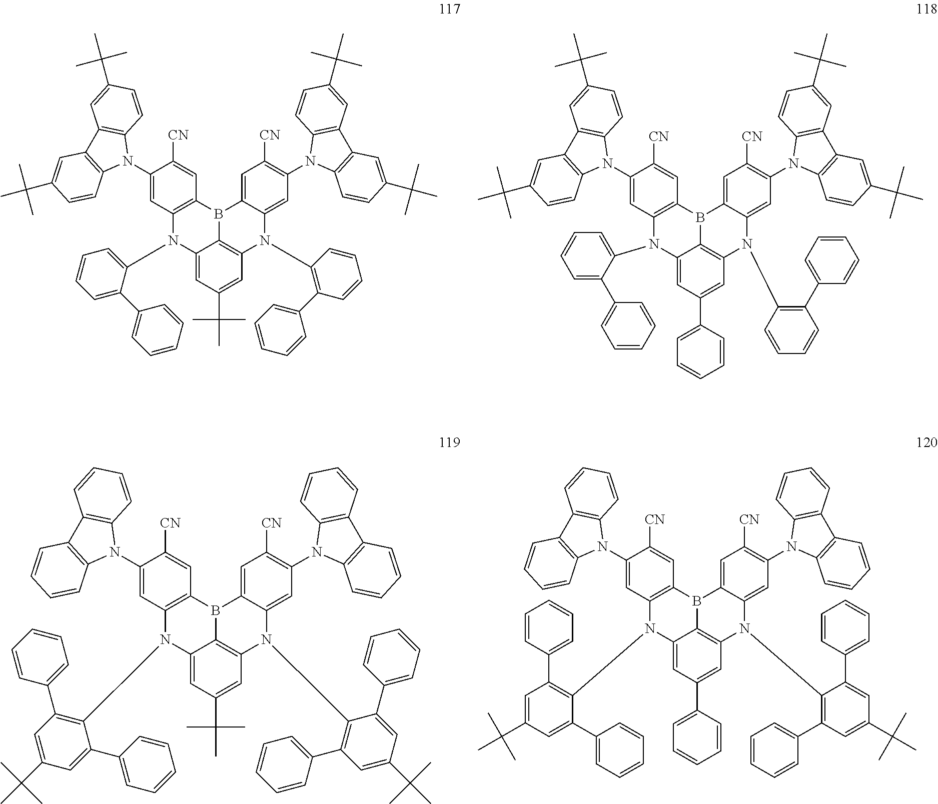

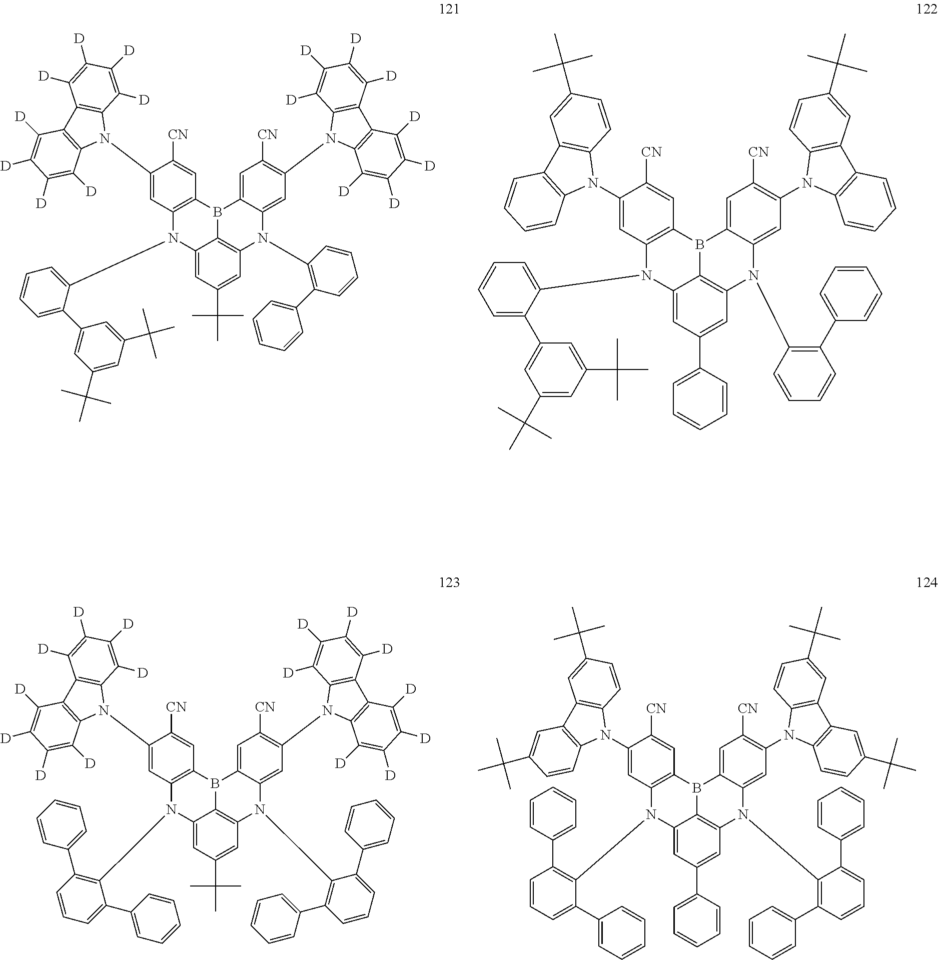

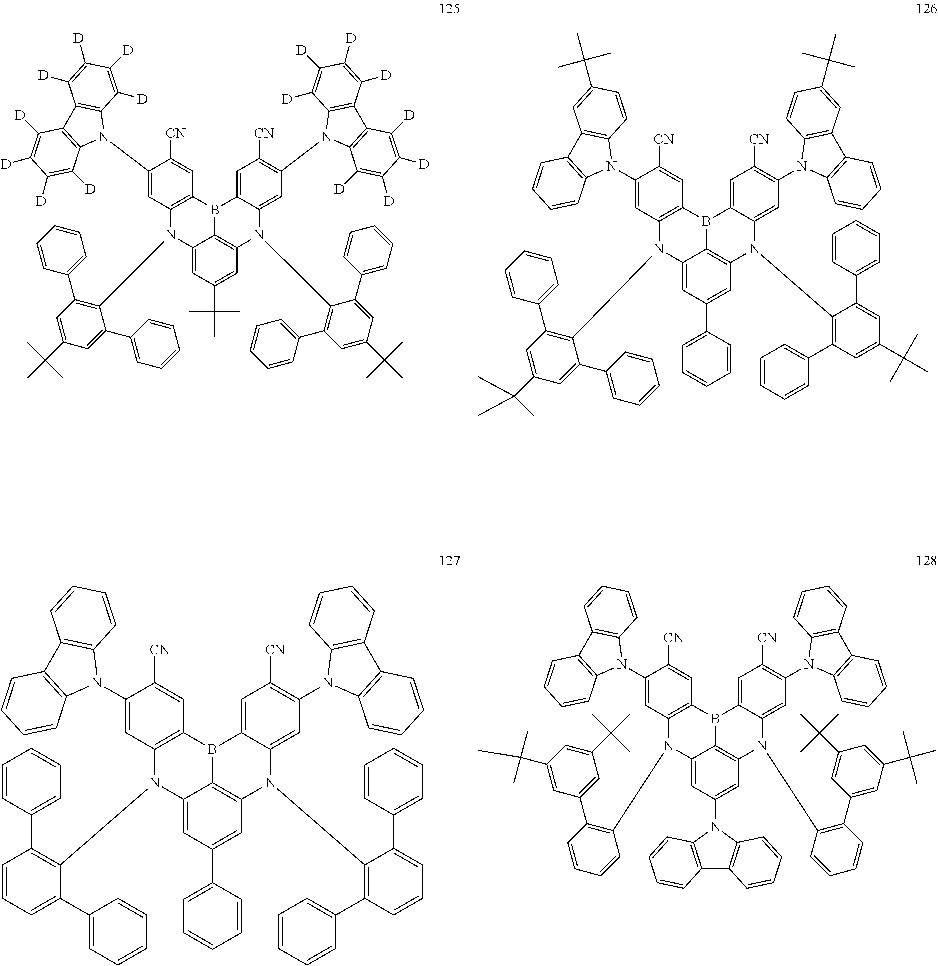

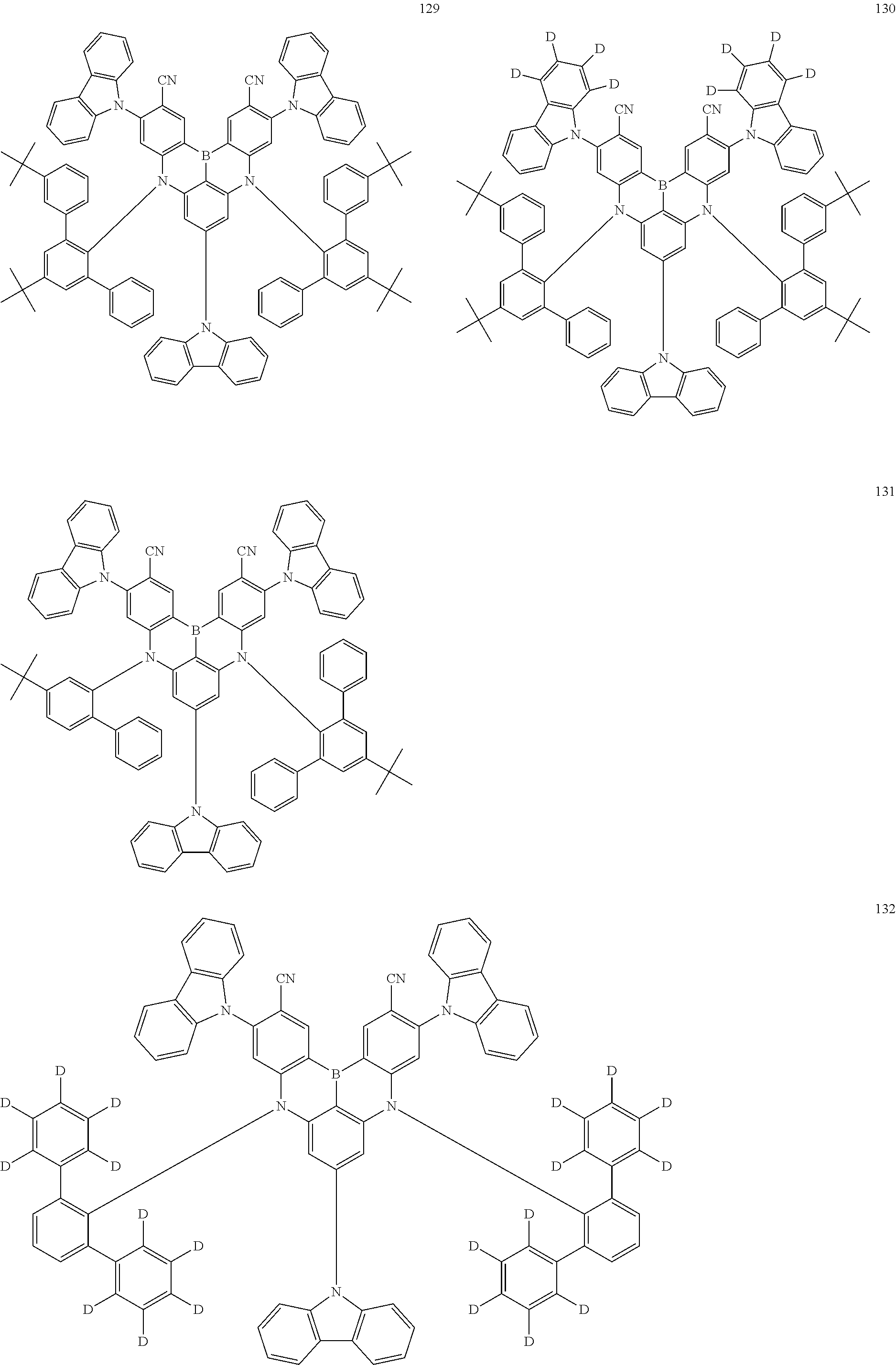

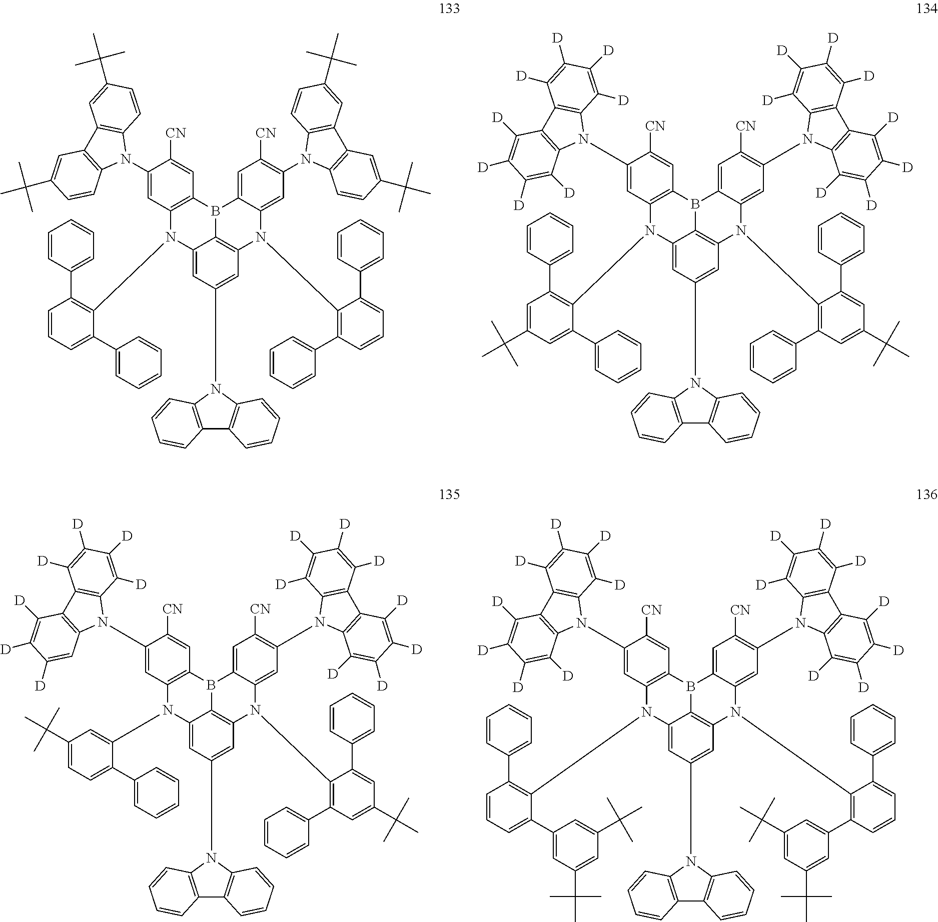

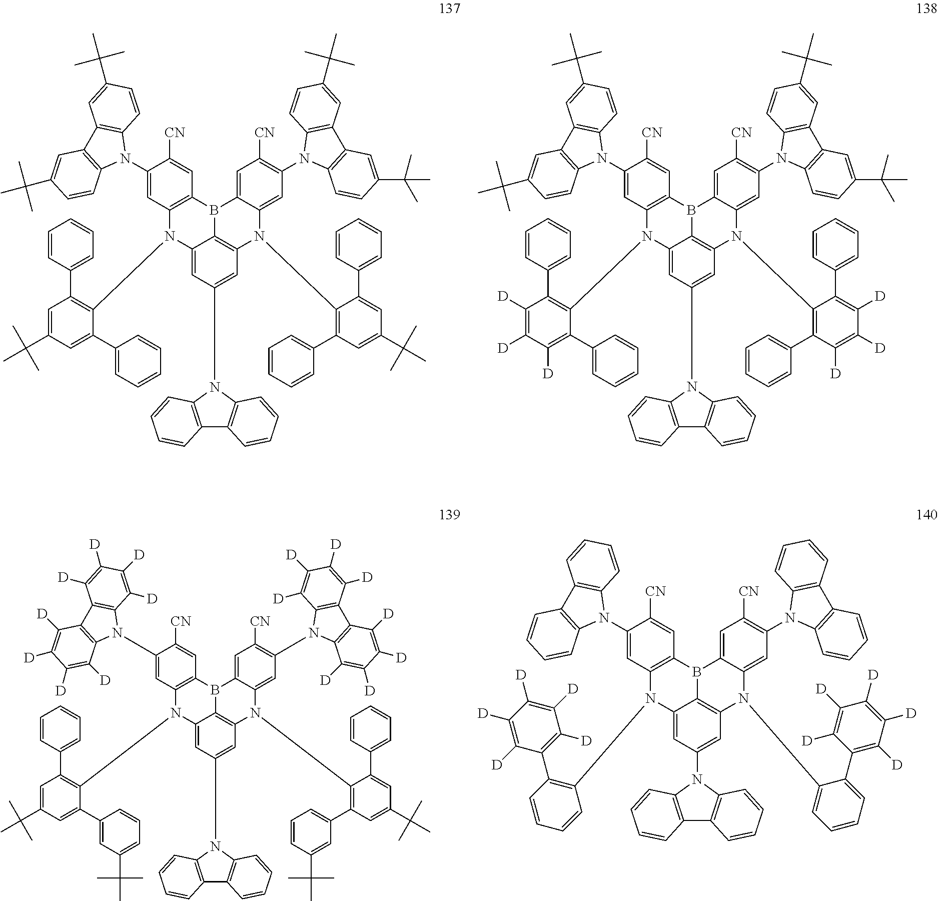

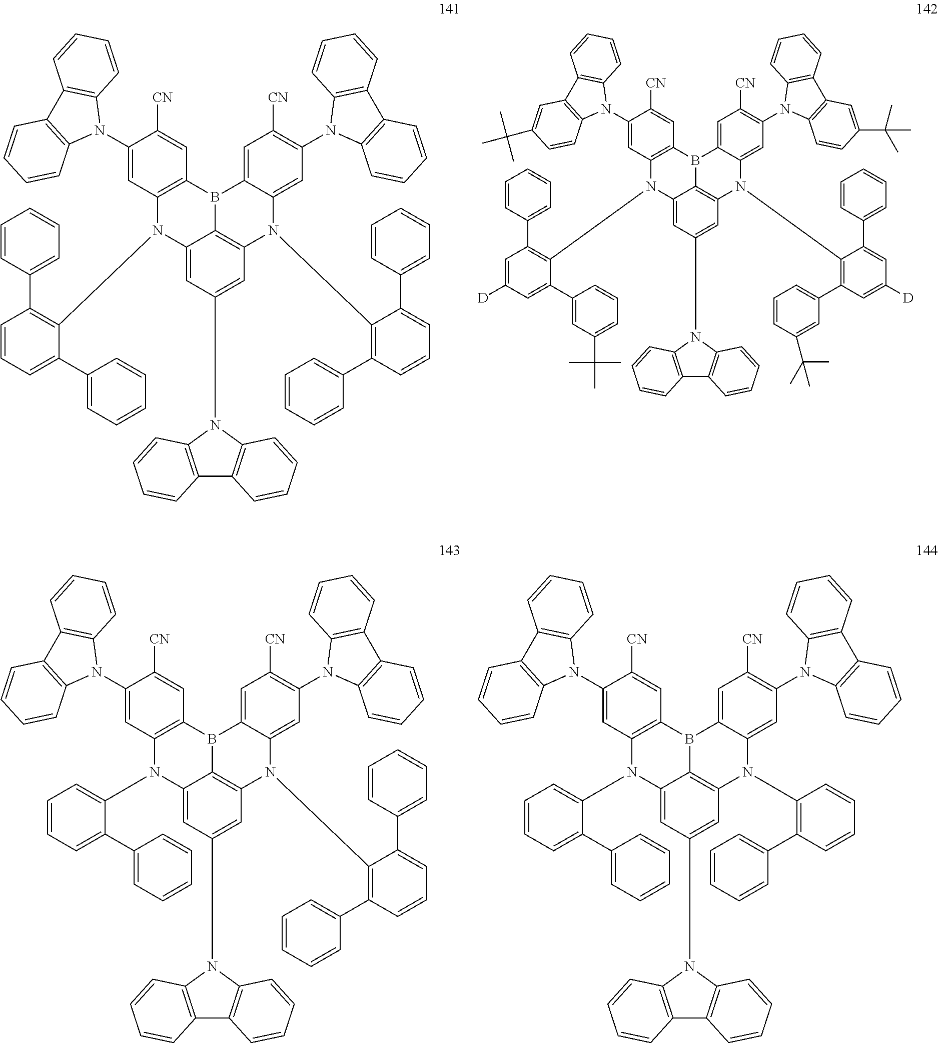

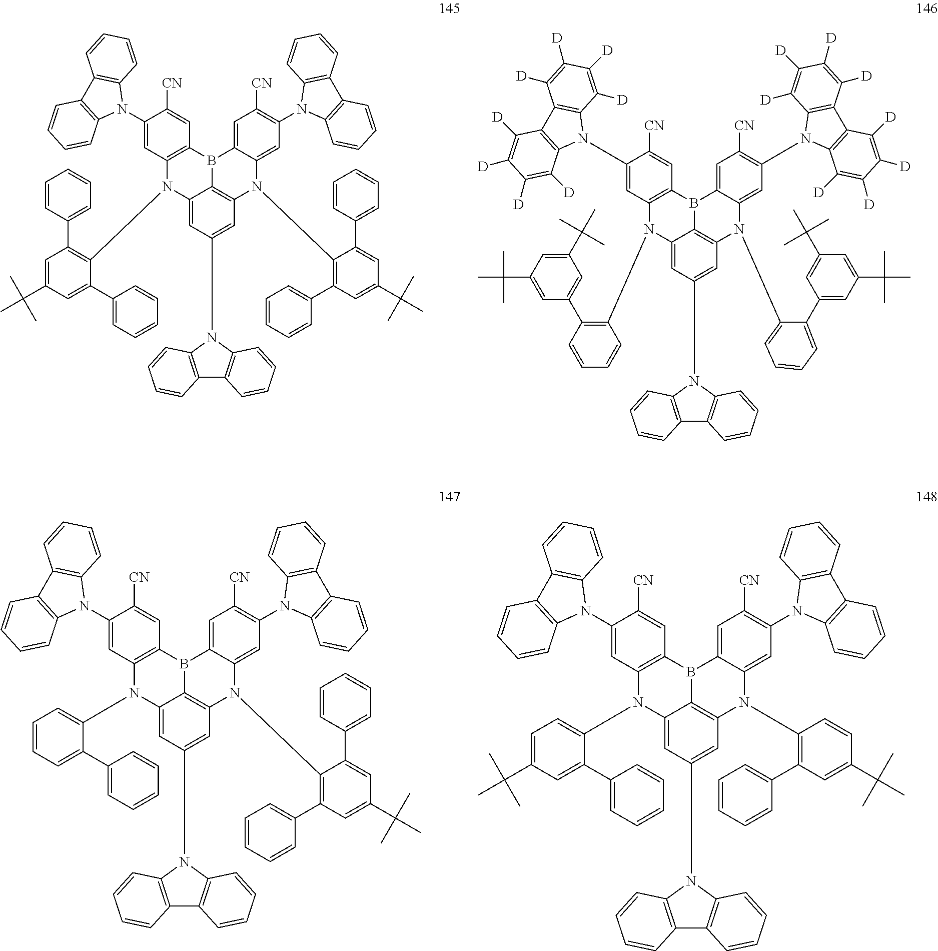

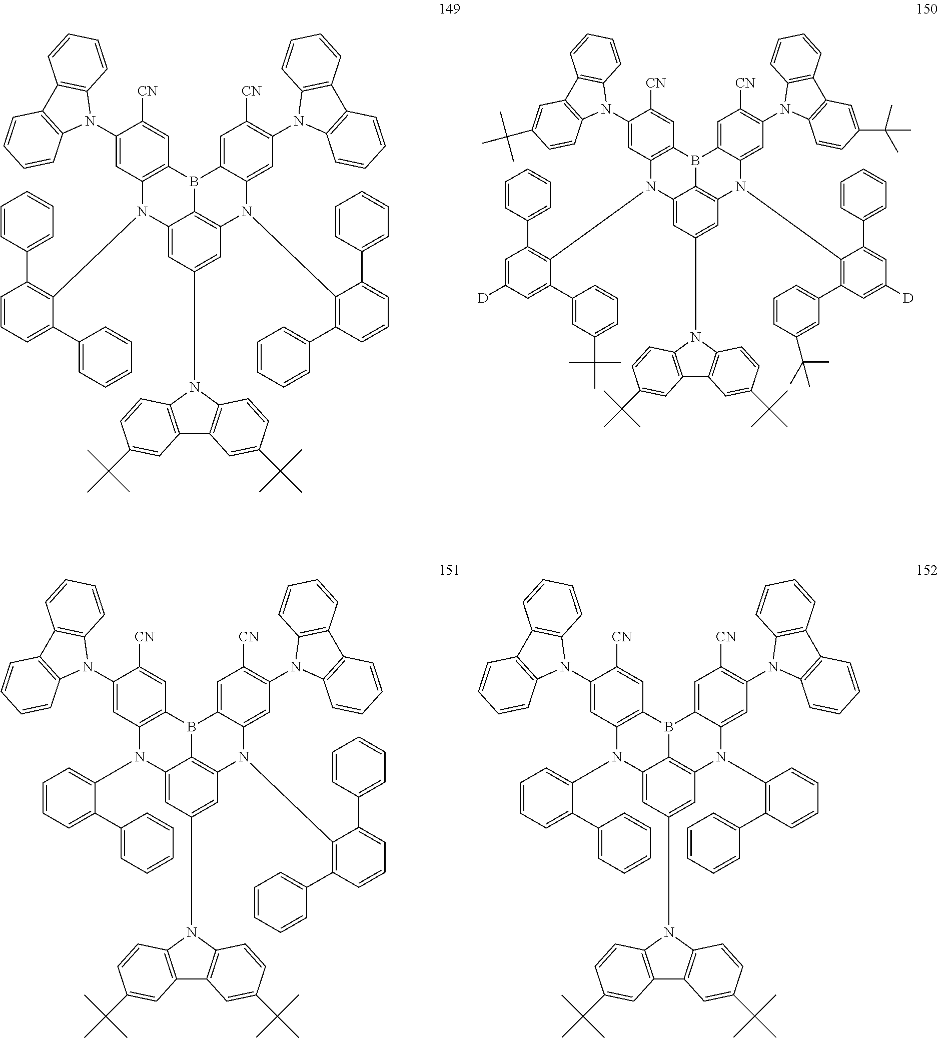

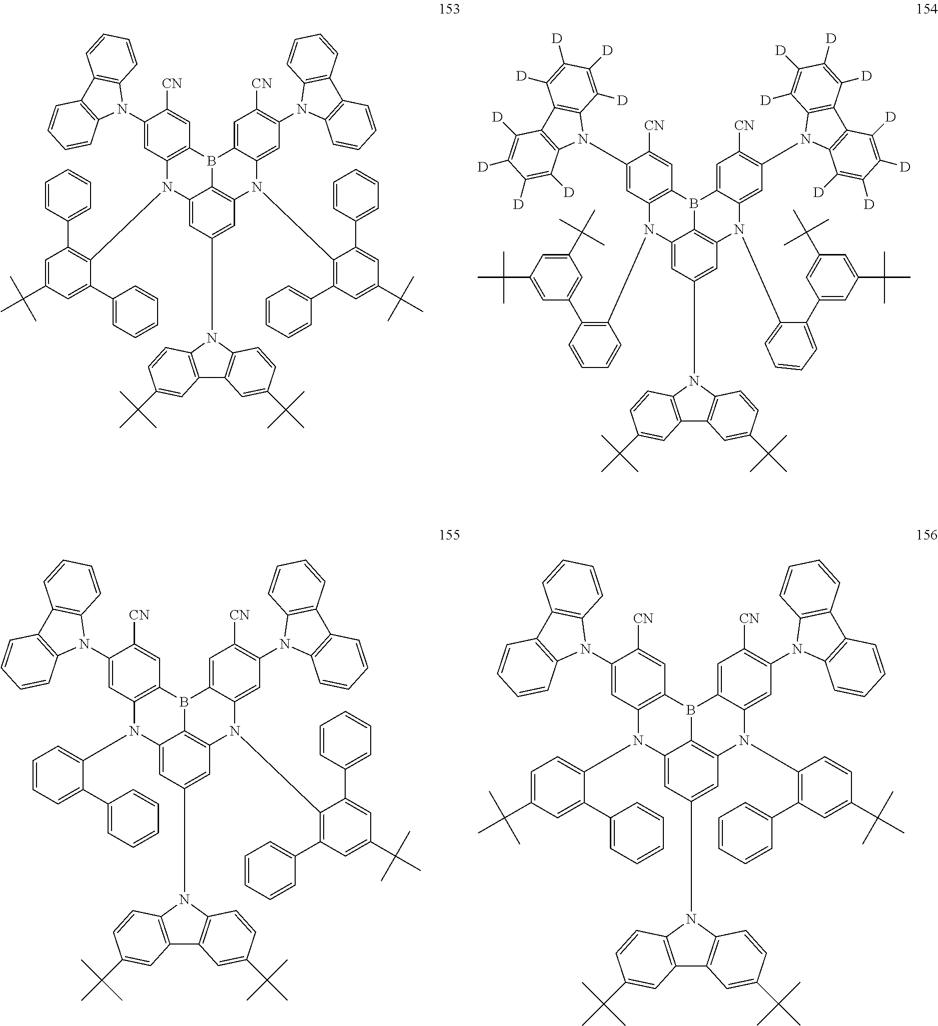

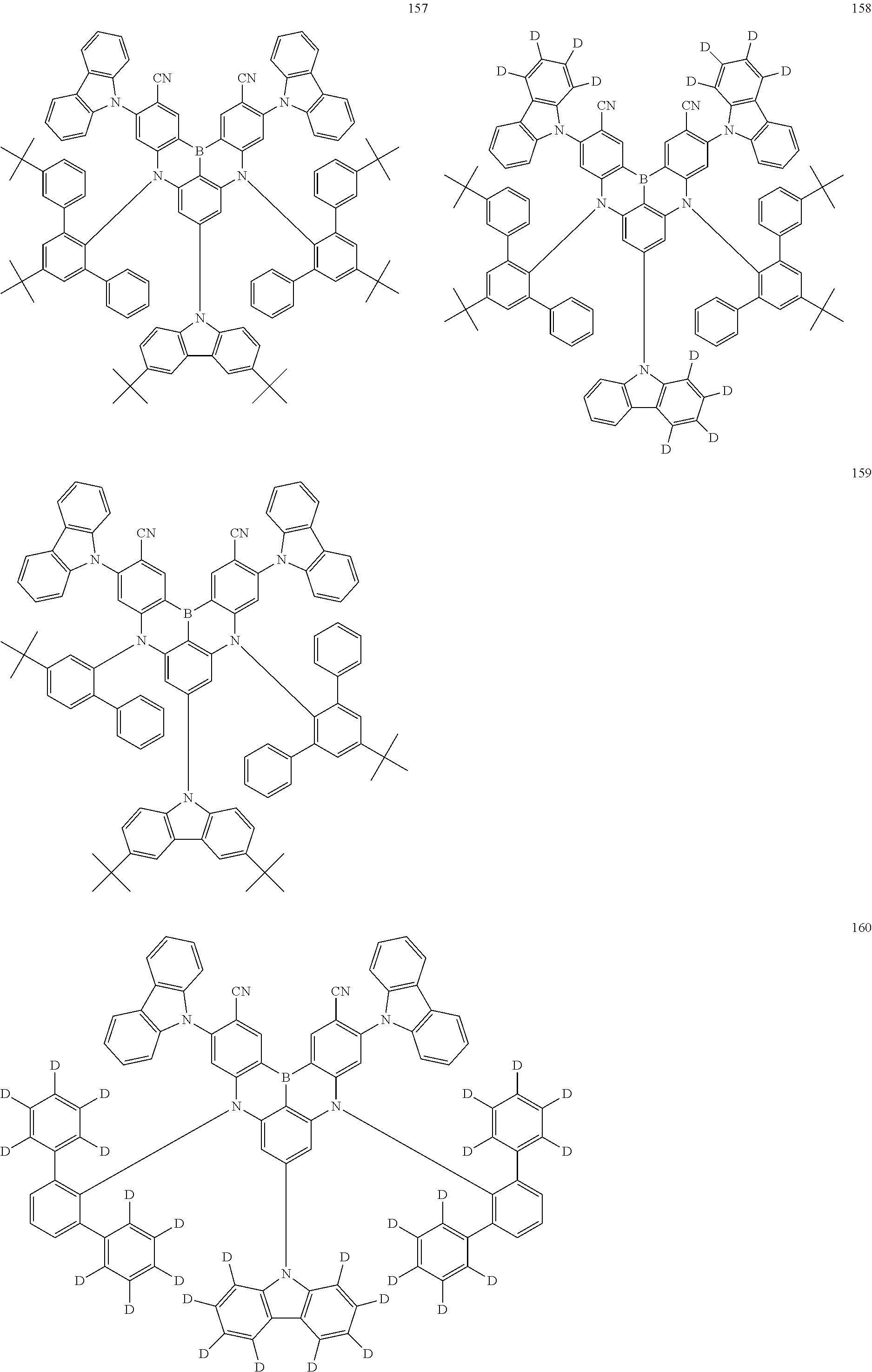

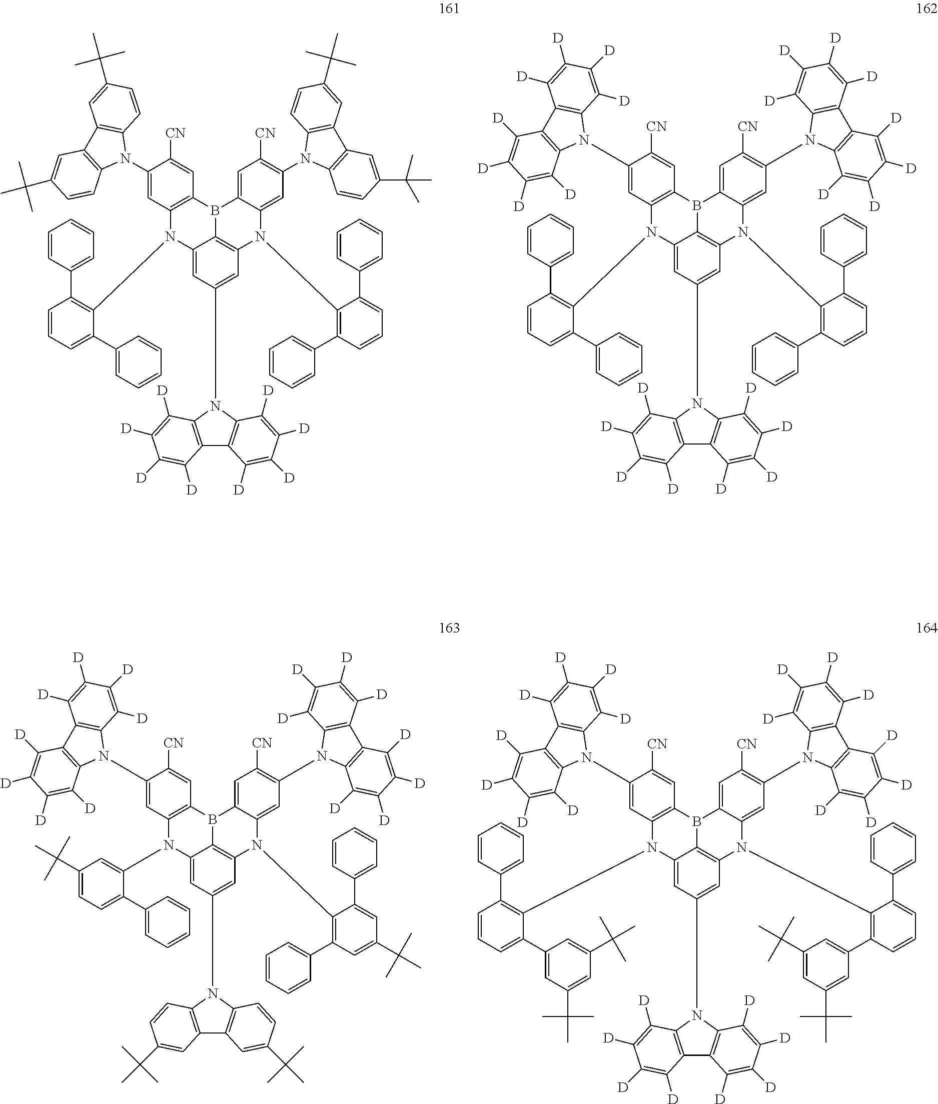

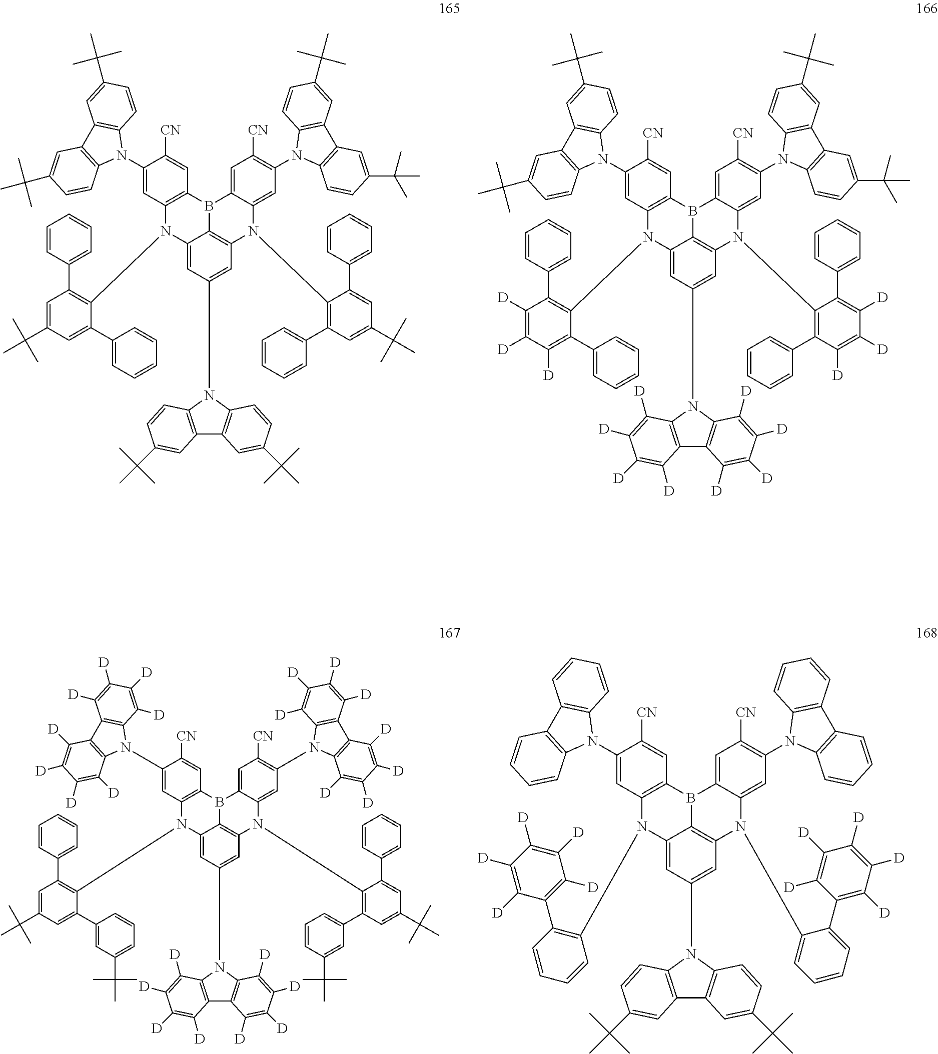

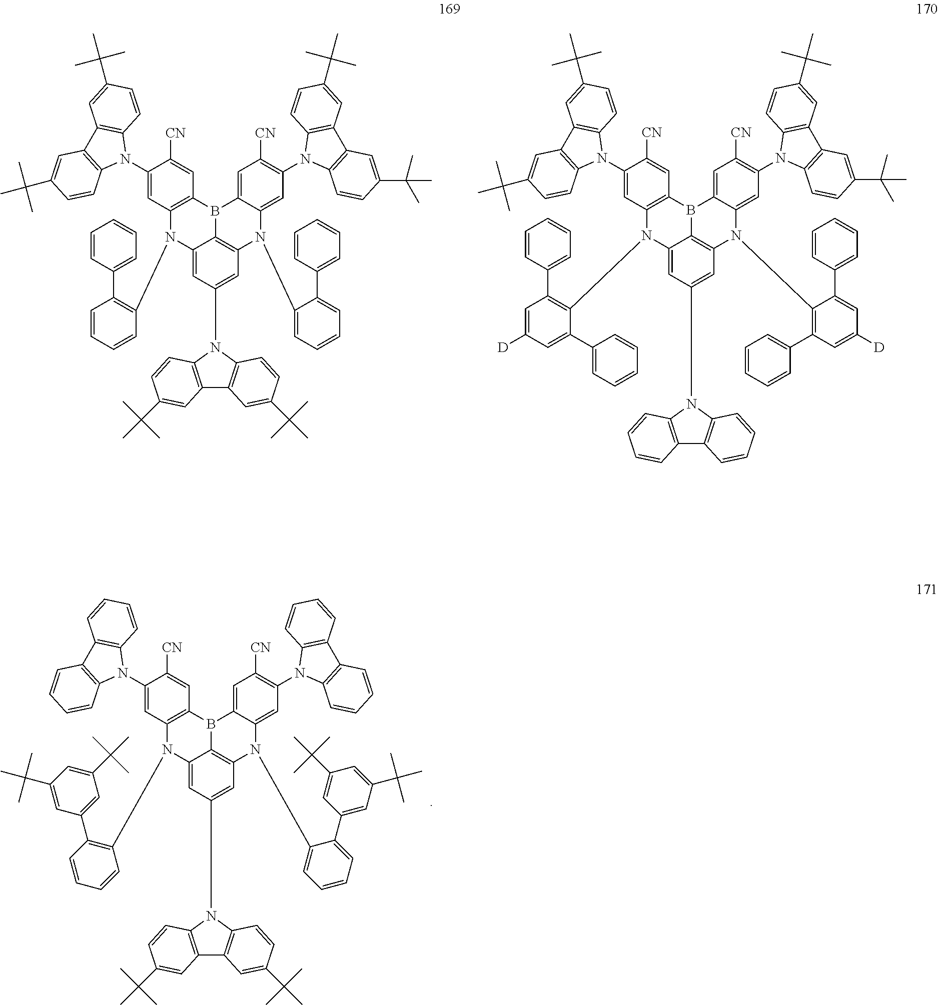

In Compound Group 1, D represents a deuterium atom.

The fused polycyclic compound represented by Formula 1 has a structure which includes a first substituent and a second substituent that are each bonded to a defined position and thus may achieve high emission efficiency and long lifetime.

The fused polycyclic compound represented by Formula 1 includes a fused ring core wherein first to third aromatic rings as fused via a boron atom, a first nitrogen atom, and a second nitrogen atom, and wherein a first substituent and a second substituent are each connected to the first aromatic ring. The first substituent may be connected with the first aromatic ring at a carbon atom that is at a para position to a carbon atom connected with the boron atom, from among carbon atoms which constitute the first aromatic ring. The first substituent may include a third nitrogen atom and a structure in which a fourth aromatic ring and a fifth aromatic ring are fused via the third nitrogen atom. For example, the first substituent may be a substituted or unsubstituted carbazole group. The third nitrogen atom of the first substituent may be connected with the first aromatic ring. The second substituent may be a cyano group. The second substituent may be connected with the first aromatic ring at an ortho position to the first substituent. The second substituent may be connected with the first aromatic ring at the ortho position to the first substituent and at a para position to the first nitrogen atom.

The fused polycyclic compound has a structure that includes the first substituent and the second substituent connected at defined positions of the fused ring core and may show increased emission efficiency and improved device lifetime. Excitons in an emission layer may be formed by a Langevin recombination (LR) pathway by which holes and electrons are recombined in a host molecule, or a trap-assisted recombination pathway by which holes and electrons are directly recombined in a dopant. If a highest occupied molecular orbital (HOMO) energy level of a dopant is shallow, hole trap phenomenon in an emission layer may be induced that would deteriorate the efficiency of a device, and the formation of excitons may be induced in the dopant through the trap-assisted recombination mechanism. The accumulation of high-energy excitons formed by the trap-assisted recombination may contribute to the reduction of device lifetime. According to embodiments, the fused polycyclic compound includes a cyano group that is an electron withdrawing group at a defined position to deepen the HOMO energy level and suppress the trap-assisted recombination. Thus, if the fused polycyclic compound is used as a dopant material of an emission layer, the device lifetime of a light emitting device may be improved. Due to low HOMO energy level properties, energy transfer from the host in the light emitting device may be facilitated even further, and effects of improving efficiency may be expected. In the specification, a “shallow” energy level may be interpreted as a reduction of an absolute value of an energy level. In the specification, a “deep” energy level may be interpreted as an increase of an absolute value of an energy level.

The fused polycyclic compound according to embodiments has a structure that includes the second substituent, which is an electron withdrawing group, at a position that is adjacent to the first substituent, and may have a strong bonding structure between the first substituent and the fused ring core, thereby improving the chemical stability of a material itself. Since a nitrogen-carbon bond formed by the connection of the first substituent that is an electron donating group with the first aromatic ring, has bonding energy that is lower than that of a carbon-carbon bond, the chemical stability of the material itself may be degraded. According to embodiments, by introducing the second substituent, which is an electron withdrawing group, at an ortho position to the first substituent, the lone electron pair of the third nitrogen atom included in the first substituent may be attracted. Accordingly, the bond dissociation energy (BDE) of the nitrogen-carbon bond between the first substituent and the first aromatic ring may be reinforced to increase the chemical stability of the material itself. The fused polycyclic compound according to an embodiment may increase electron density in the fused ring core by introducing the second substituent at a defined position, and if used as a light emitting material, may improve the emission efficiency of a light emitting device even further. Accordingly, if the fused polycyclic compound is applied in the emission layer of the light emitting device, emission efficiency may be increased, and the device lifetime may be improved.

An emission spectrum of the fused polycyclic compound represented by Formula 1 may have a full width at half maximum (FWHM) in a range of about 10 nm to about 50 nm. For example, an emission spectrum of the fused polycyclic compound may have a FWHM in a range of about 20 nm to about 40 nm. Since the emission spectrum of the first compound represented by Formula 1 has the above-described range of a full width at half maximum, emission efficiency may be improved when it is applied to a device. If the first compound represented by Formula 1 is used as a material for a blue light emitting device, the device lifetime may be improved.

The fused polycyclic compound represented by Formula 1 may be a material for emitting thermally activated delayed fluorescence. The fused polycyclic compound represented by Formula 1 may be a thermally activated delayed fluorescence dopant having a difference (ΔE_{ST}) between a lowest triplet excitation energy level (T1 level) and a lowest singlet excitation energy level (S1 level) equal to or less than about 0.6 eV. For example, the fused polycyclic compound represented by Formula 1 may be a thermally activated delayed fluorescence dopant having a difference (ΔE_{ST}) between a lowest triplet excitation energy level (T1 level) and a lowest singlet excitation energy level (S1 level) equal to or less than about 0.2 eV.

The fused polycyclic compound represented by Formula 1 may be a light-emitting material that emits light having a central wavelength in a range of about 430 nm to about 490 nm. For example, the fused polycyclic compound represented by Formula 1 may be a blue thermally activated delayed fluorescence (TADF) dopant. However, embodiments are not limited thereto, and if the fused polycyclic compound of an embodiment is used as a light-emitting material, the first dopant may be used as a dopant material that emits light in various wavelength regions, such as a red emitting dopant, or a green emitting dopant.

In the light emitting device ED according to an embodiment, the emission layer EML may emit delayed fluorescence. For example, the emission layer EML may emit thermally activated delayed fluorescence (TADF).

In an embodiment, the emission layer EML of the light emitting device ED may emit blue light. For example, the emission layer EML of an organic electroluminescence light emitting device ED may emit blue light having a wavelength of about 490 nm or less. However, embodiments are not limited thereto, and the emission layer EML may emit green light or red light.

The fused polycyclic compound according to an embodiment may be included in an emission layer EML. The fused polycyclic compound may be included in an emission layer EML as a dopant material. The fused polycyclic compound may be a thermally activated delayed fluorescence emitting material. The fused polycyclic compound may be used as a thermally activated delayed fluorescence dopant. For example, in the light emitting device ED, the emission layer EML may include at least one fused polycyclic compound selected from Compound Group 1 as a thermally delayed fluorescence dopant. However, the use of the fused polycyclic compound is not limited thereto.

In an embodiment, the emission layer EML may include multiple compounds. The emission layer EML may include the fused polycyclic compound represented by Formula 1 (the first compound); and at least one of a second compound represented by Formula HT-1, a third compound represented by Formula ET-1, and a fourth compound represented by Formula D-1.

In an embodiment, the emission layer EML may include the first compound represented by Formula 1 and may further include at least one of a second compound represented by Formula HT-1, and a third compound represented by Formula ET-1.

In an embodiment, the emission layer EML may further include a second compound represented by Formula HT-1. In an embodiment, the second compound may be used as a hole transport host material in an emission layer EML.

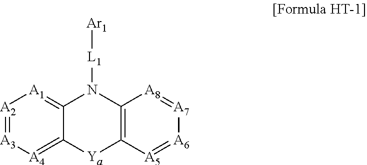

In Formula HT-1, A₁ to A₈ may each independently be N or C(R₅₁). For example, A₁ to A₈ may each independently be C(R₅₁). For example, any one of A₁ to A₈ may be N, and the remainder of A₁ to A₈ may each independently be C(R₅₁).

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, two benzo rings that are connected to the nitrogen atom of Formula HT-1 may be connected to each other via a direct linkage,

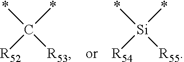

In Formula HT-1, if Yₐ is a direct linkage, the compound represented by Formula HT-1 may include a carbazole moiety.

In Formula HT-1, Ar may be a substituted or unsubstituted aryl group of 6 to 30 ring-forming carbon atoms or a substituted or unsubstituted heteroaryl group of 2 to 30 ring-forming carbon atoms. For example, Ar may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 60 ring-forming carbon atoms, or may be combined with an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting device ED, the second compound may include at least one compound selected from Compound Group 2.

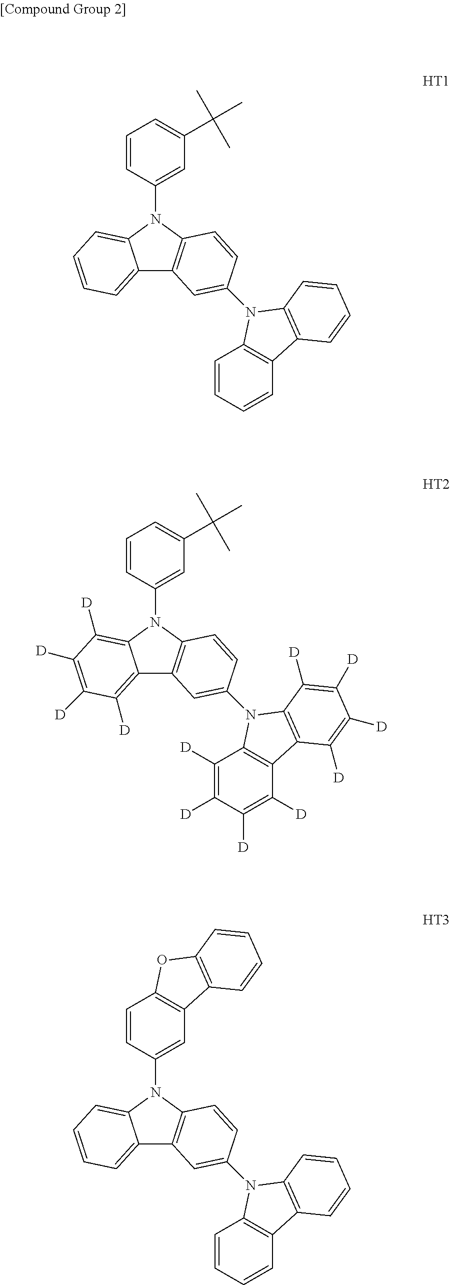 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

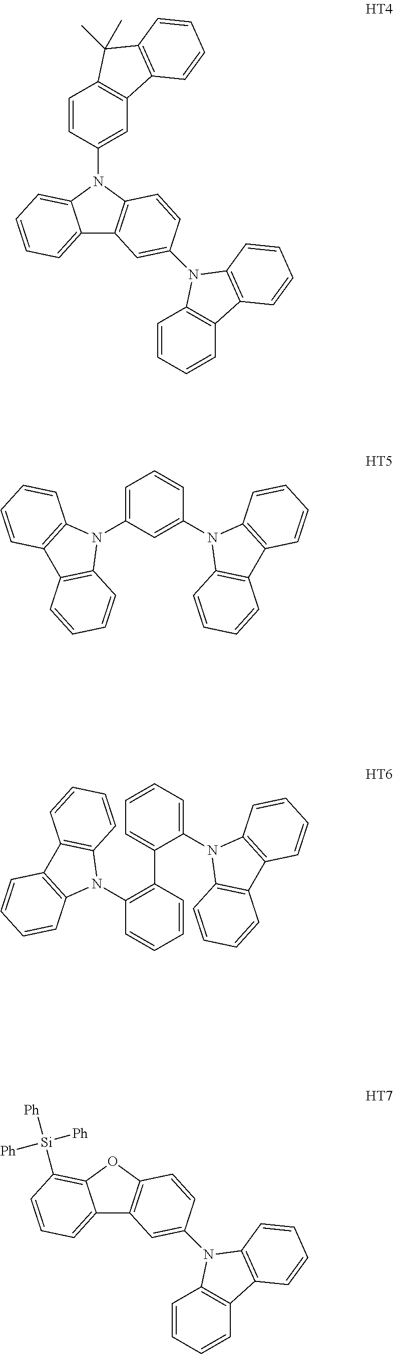 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

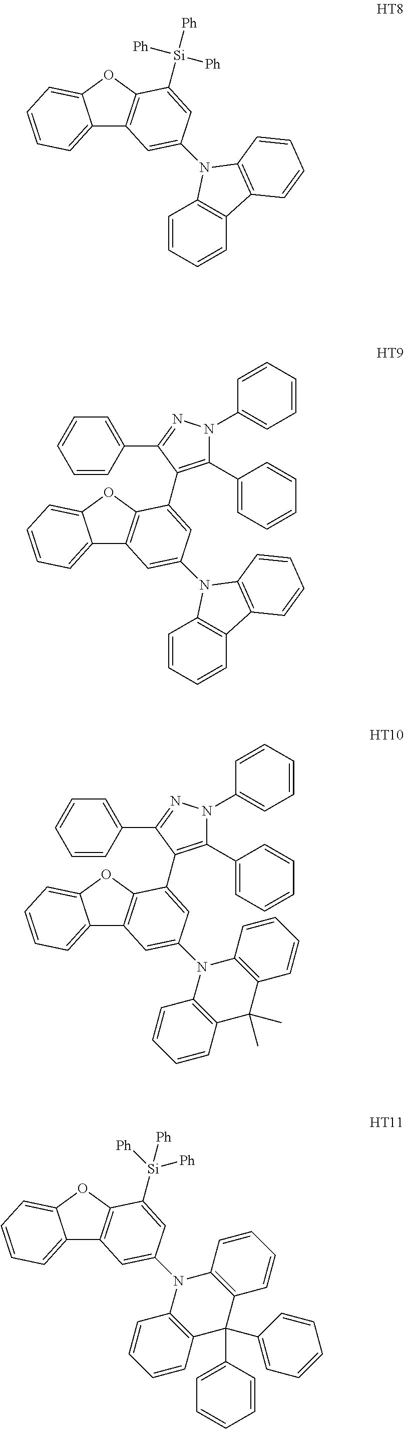 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

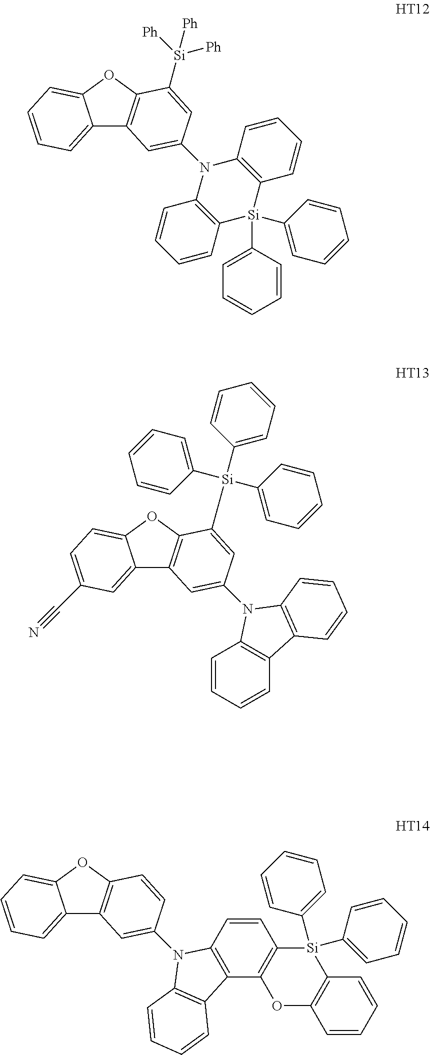 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

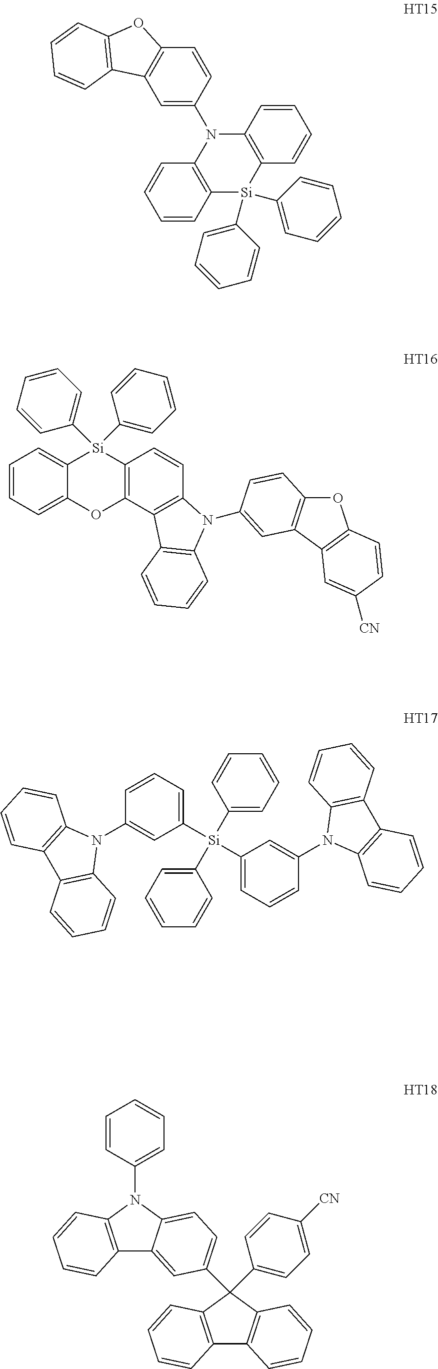 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

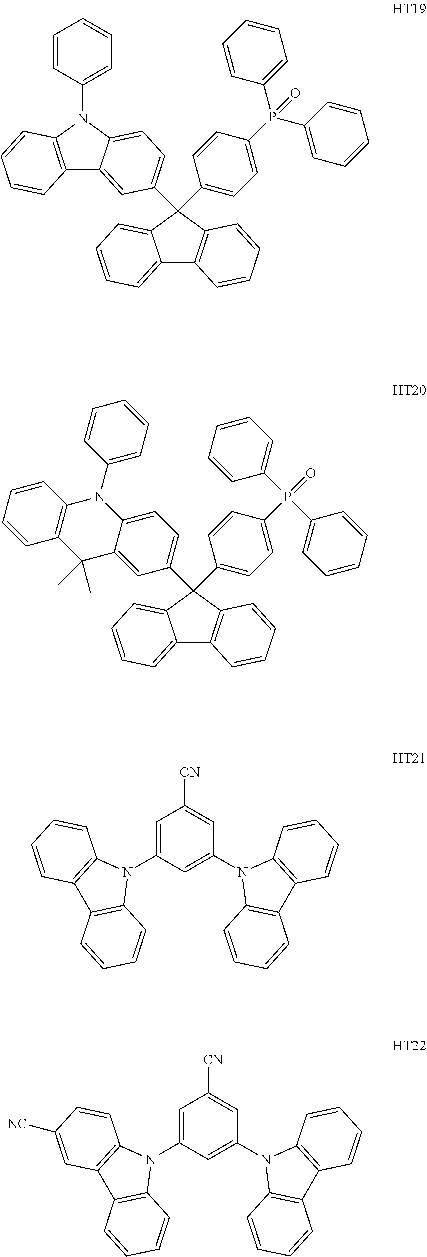 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

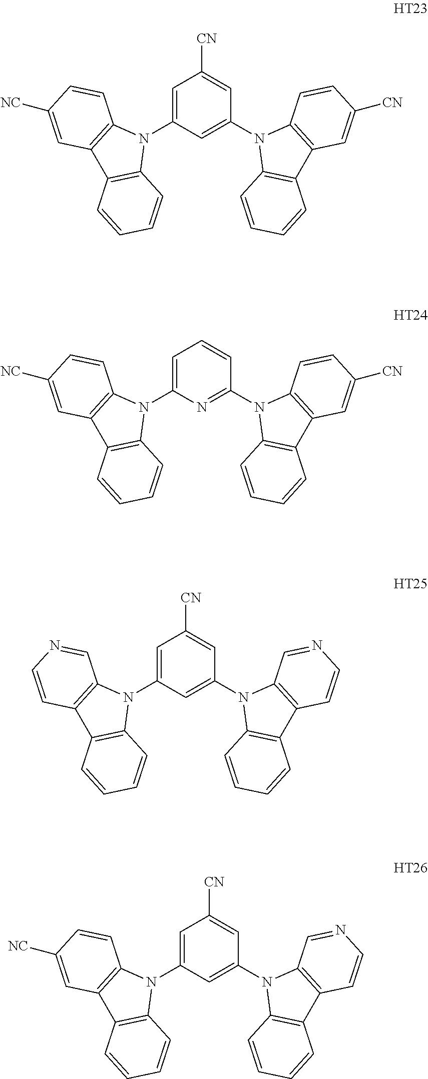 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

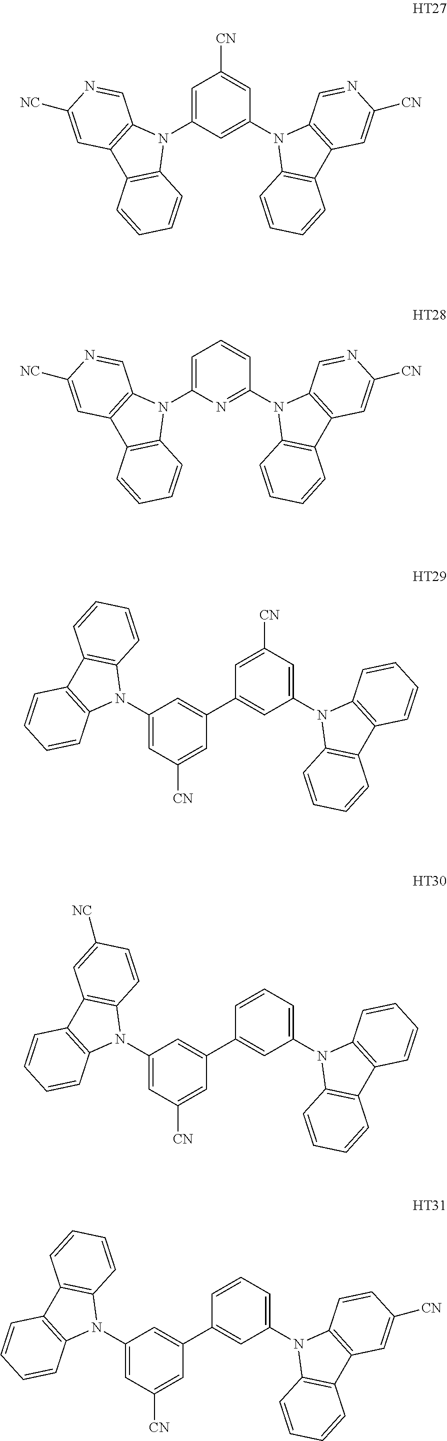 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

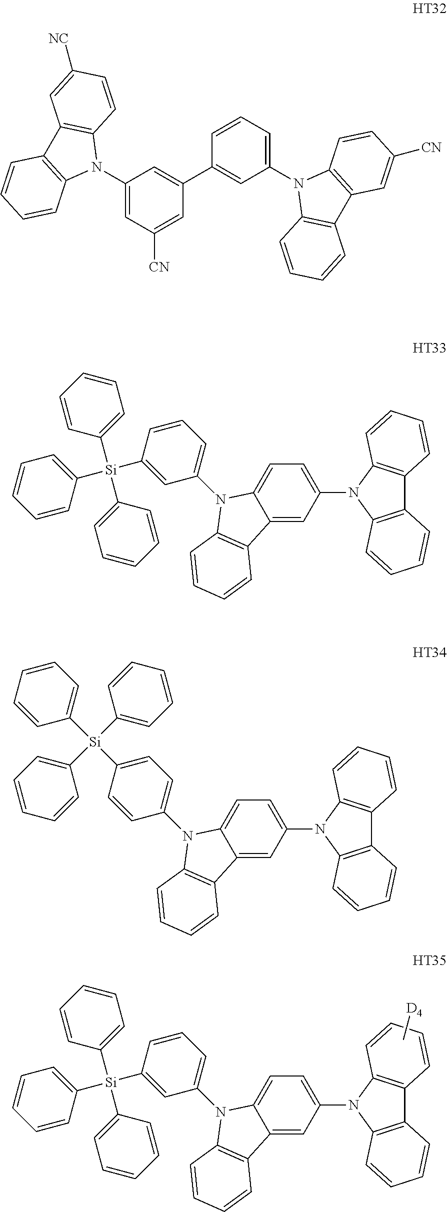

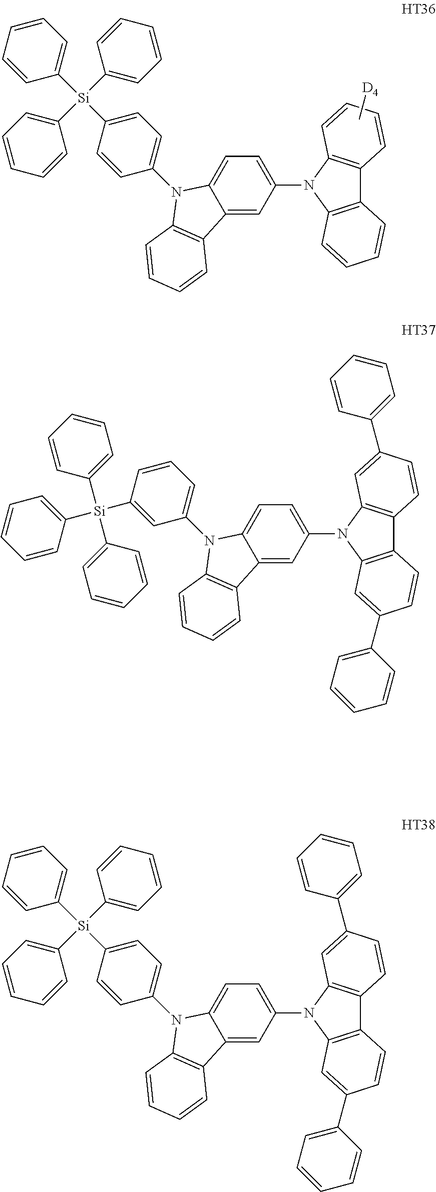

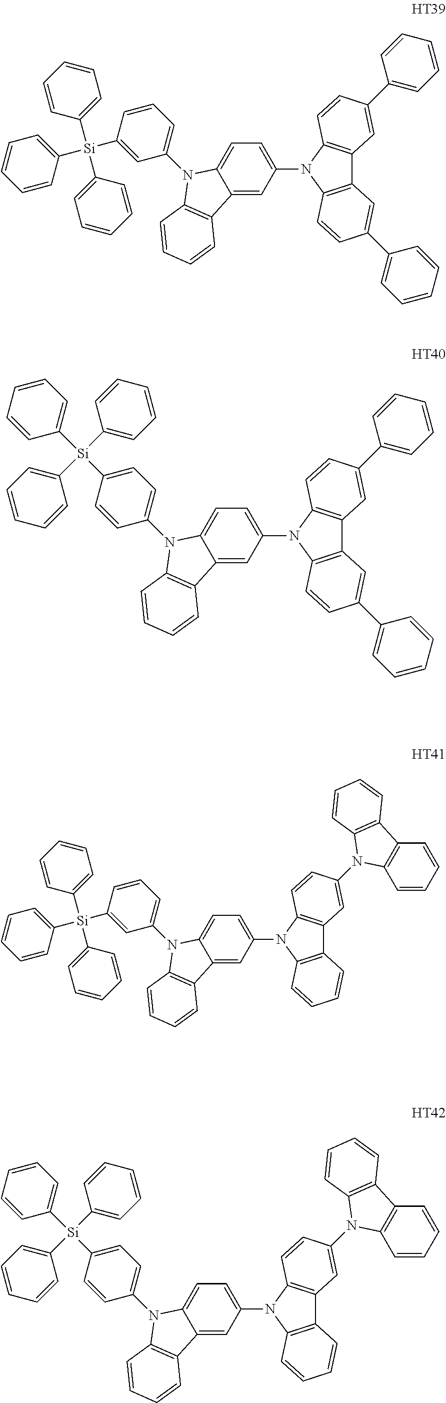 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

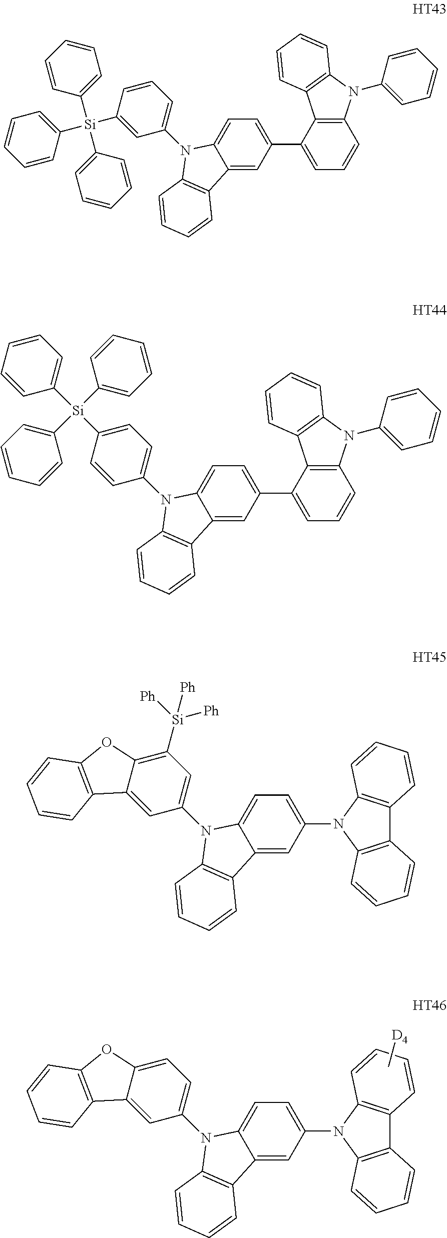

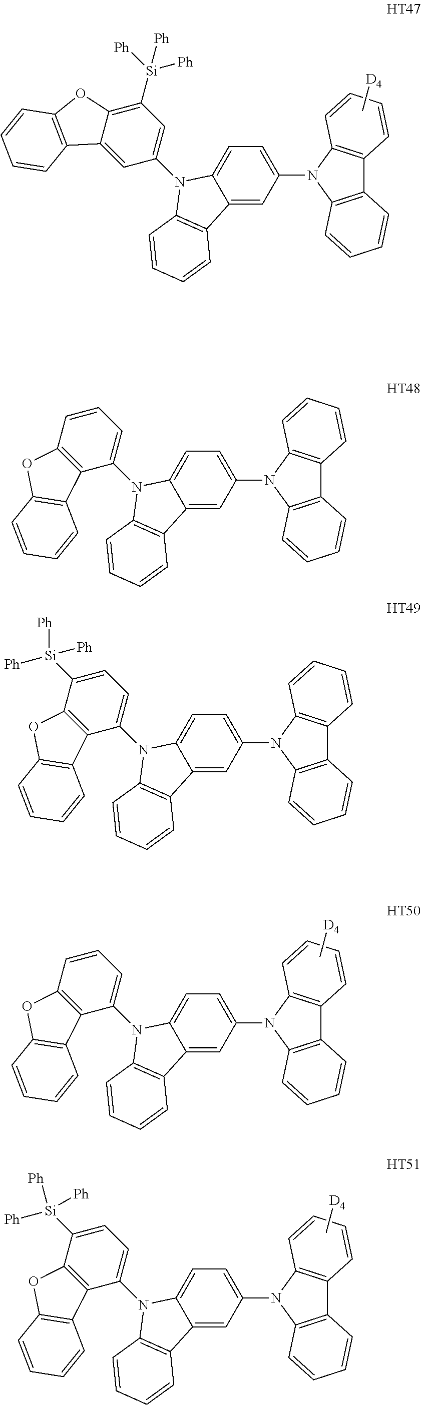

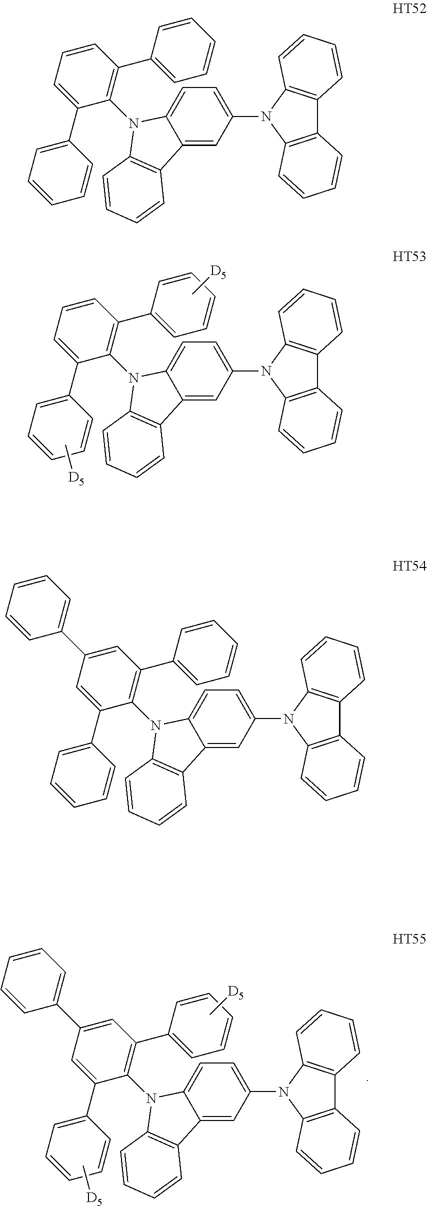

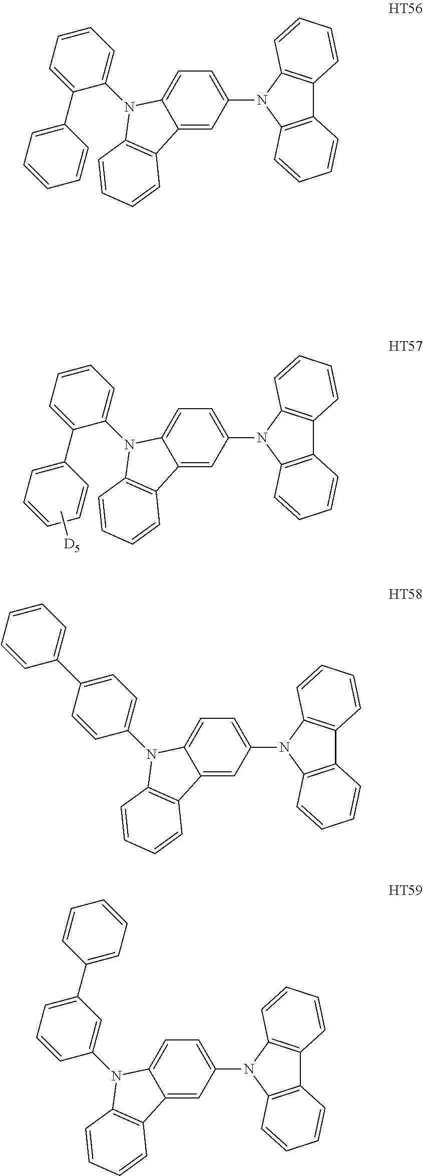

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound represented by Formula ET-1 may be used as an electron transport host material in an emission layer EML.

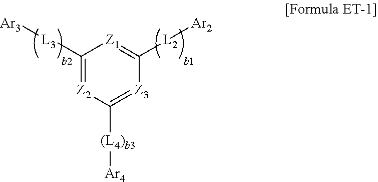

In Formula ET-1, at least one of Z₁ to Z₃ may each be N, and the remainder of Z₁ to Z₃ may each independently be C(R₅₆). In an embodiment, at least one of Z₁ to Z₃ may each be N, and the remainder of Z₁ to Z₃ may each independently be C(R₅₆). For example, the third compound represented by Formula ET-1 may include a pyridine moiety. In an embodiment, at least two of Z₁ to Z₃ may each be N, and the remainder of Z₁ to Z₃ may be C(R₅₆). For example, the third compound represented by Formula ET-1 may include a pyrimidine moiety. In an embodiment, Z₁ to Z₃ may each be N. For example, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. If b1 to b3 are each 2 or more, then L₂ to L₄ may each independently be a substituted or unsubstituted arylene group of 6 to 30 ring-forming carbon atoms or a substituted or unsubstituted heteroarylene group of 2 to 30 ring-forming carbon atoms.

In an embodiment, the third compound represented by Formula ET-1 may be selected from Compound Group 3. In an embodiment, in the light emitting device ED, the third compound may include at least one compound selected from Compound Group 3.

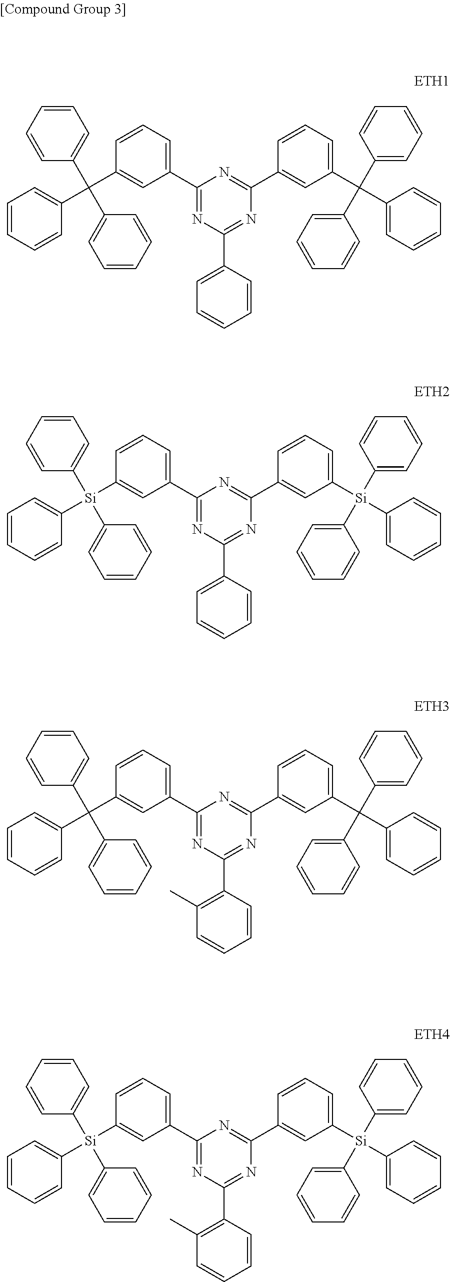 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

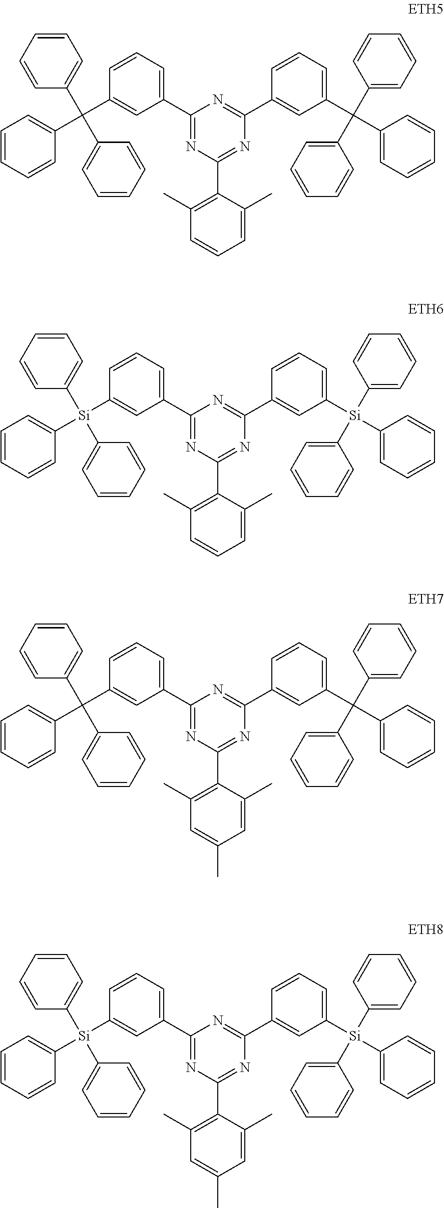 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

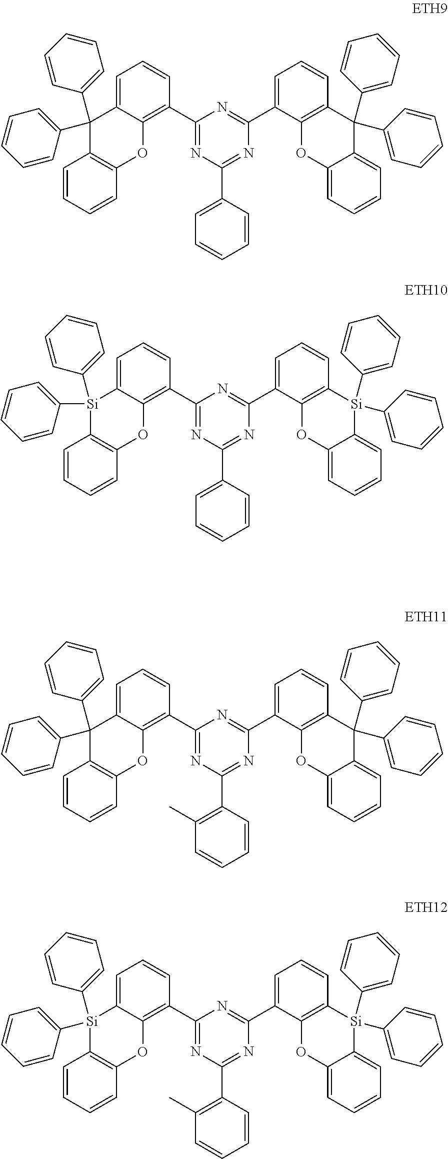 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

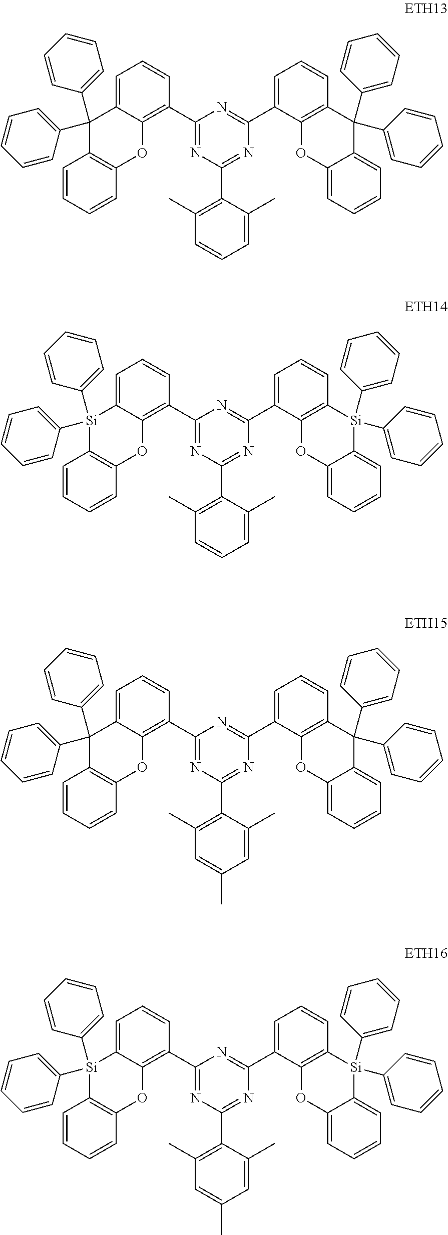 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

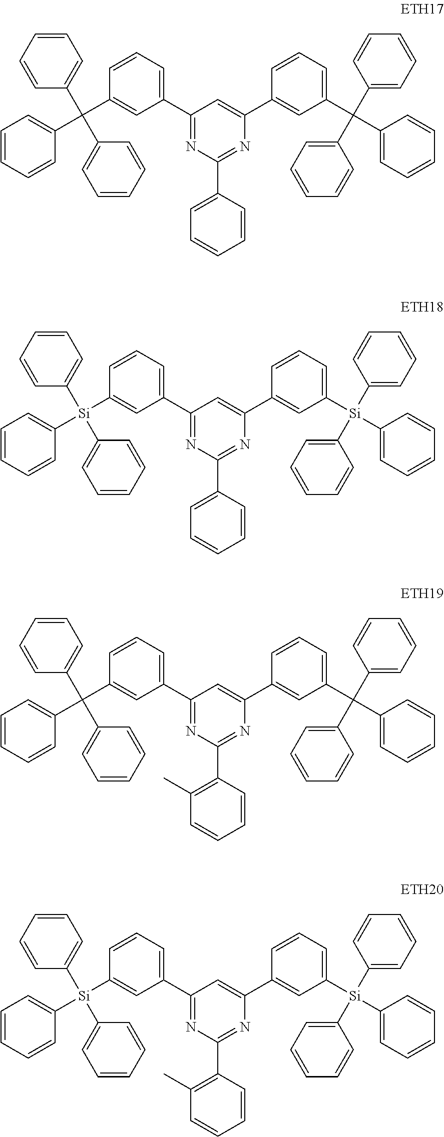 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

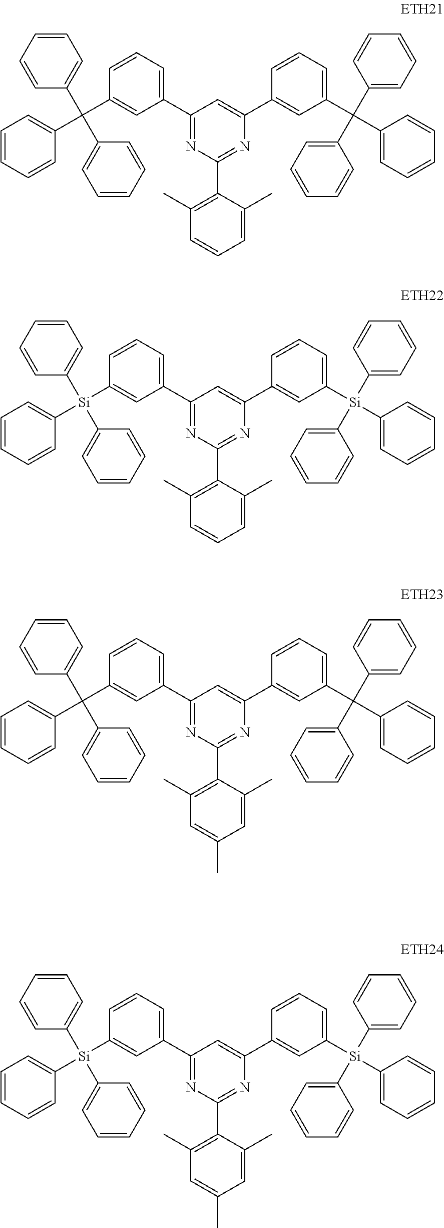 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

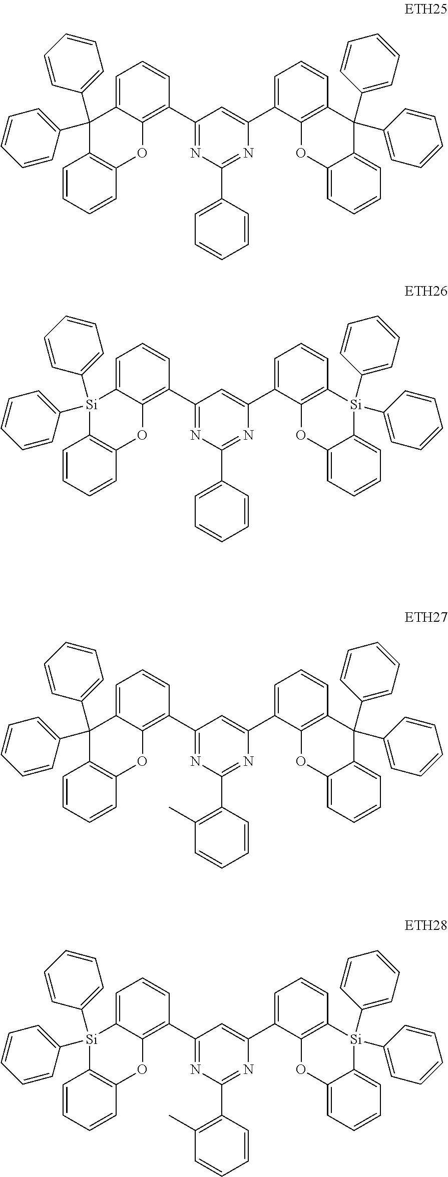 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

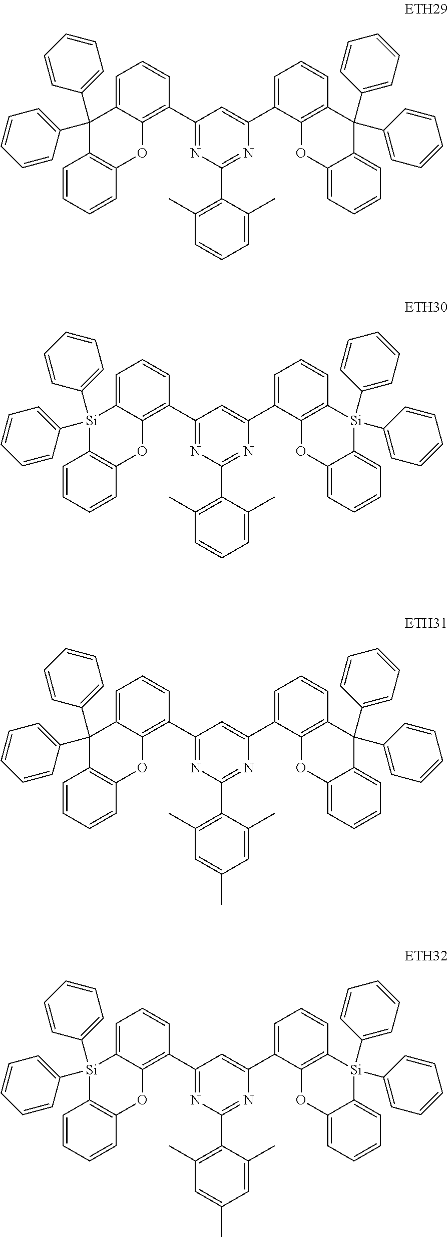 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

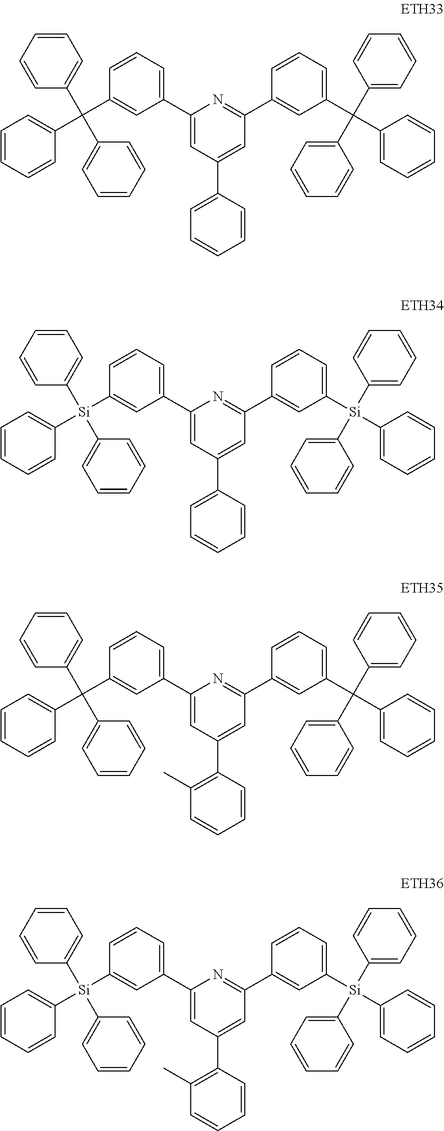 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

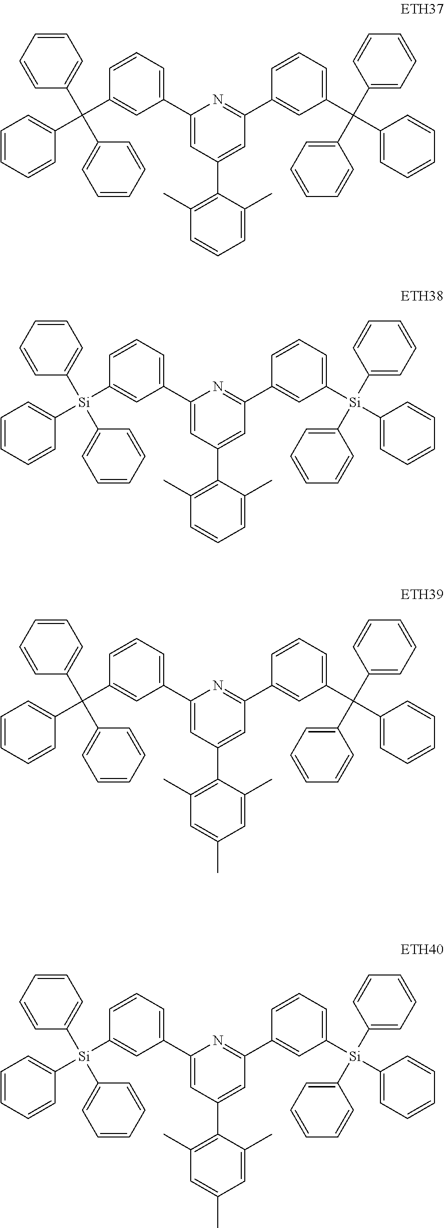 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

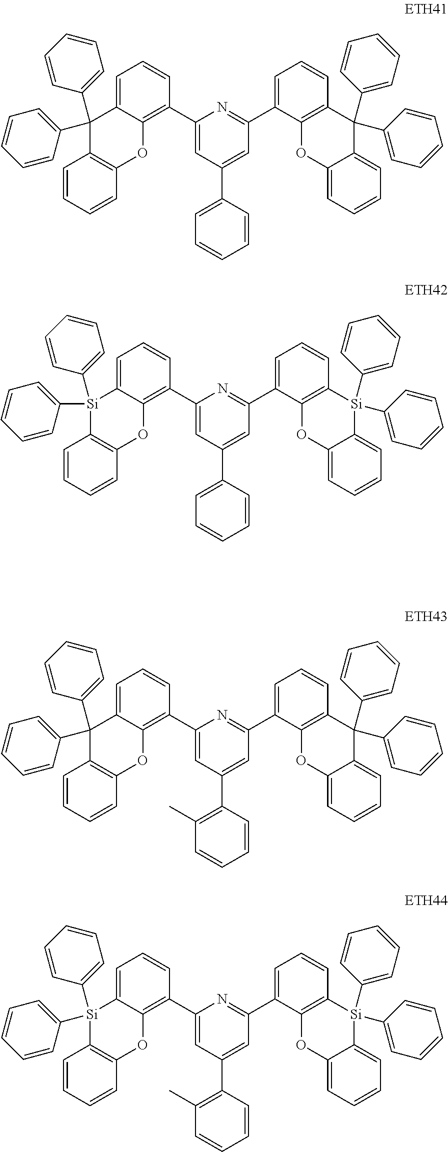 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

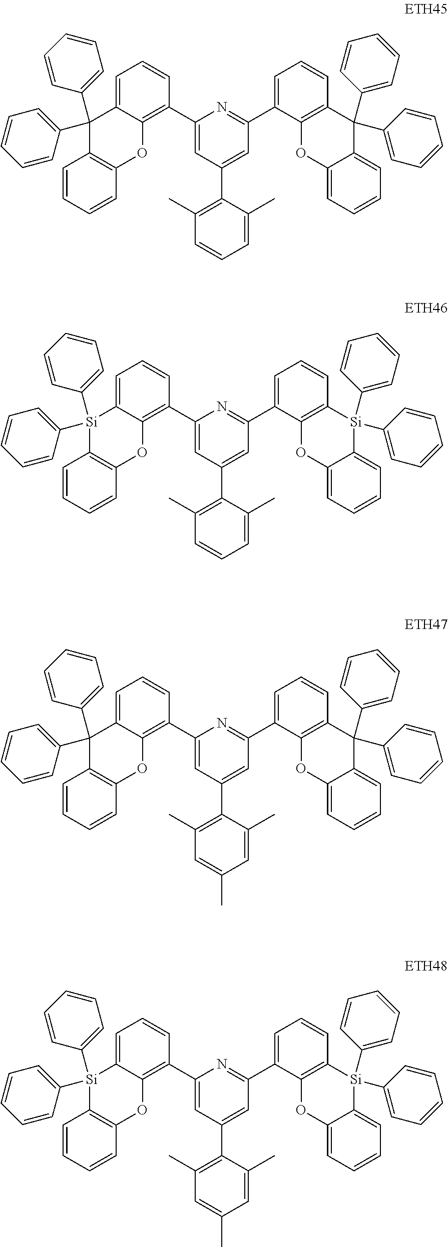 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

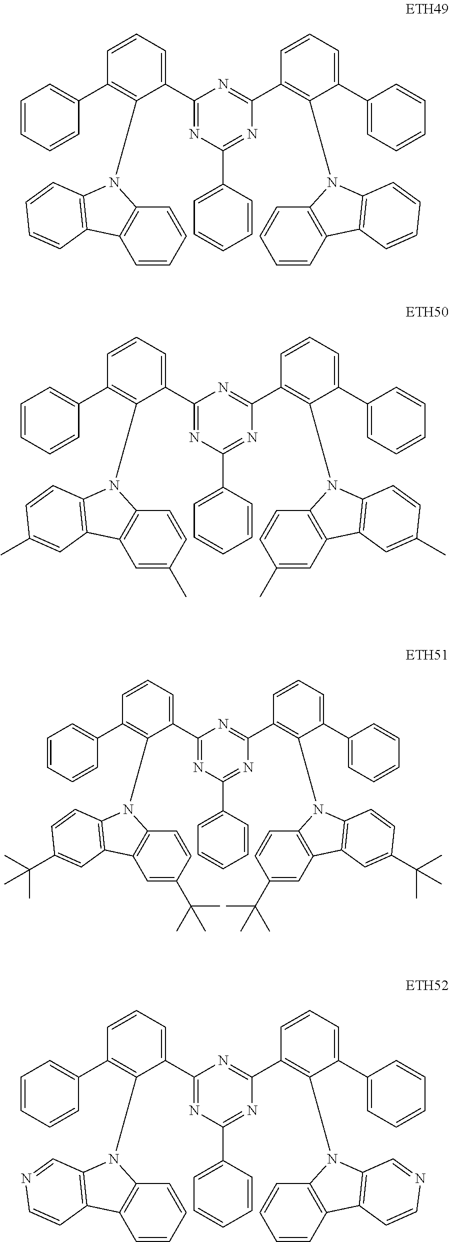

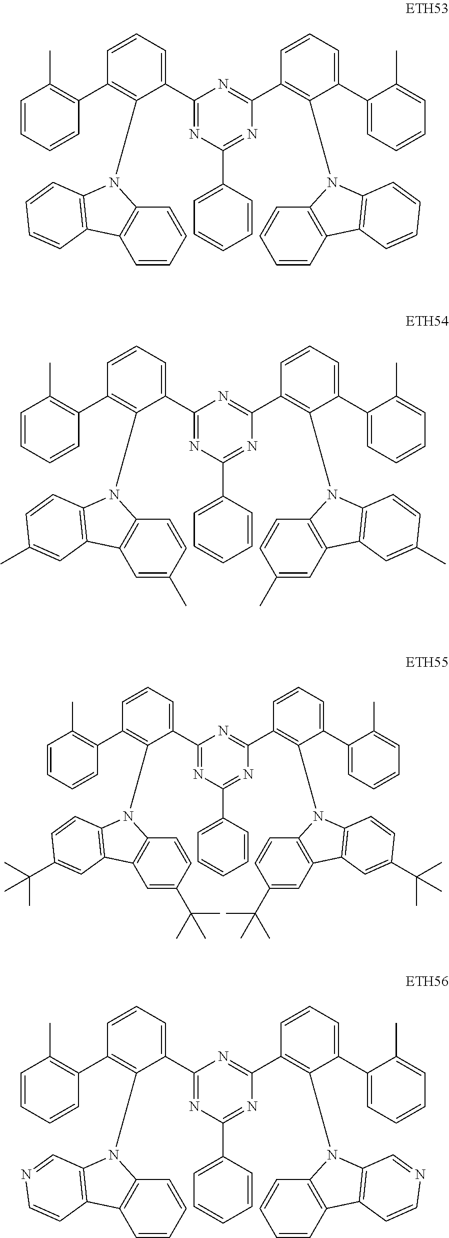

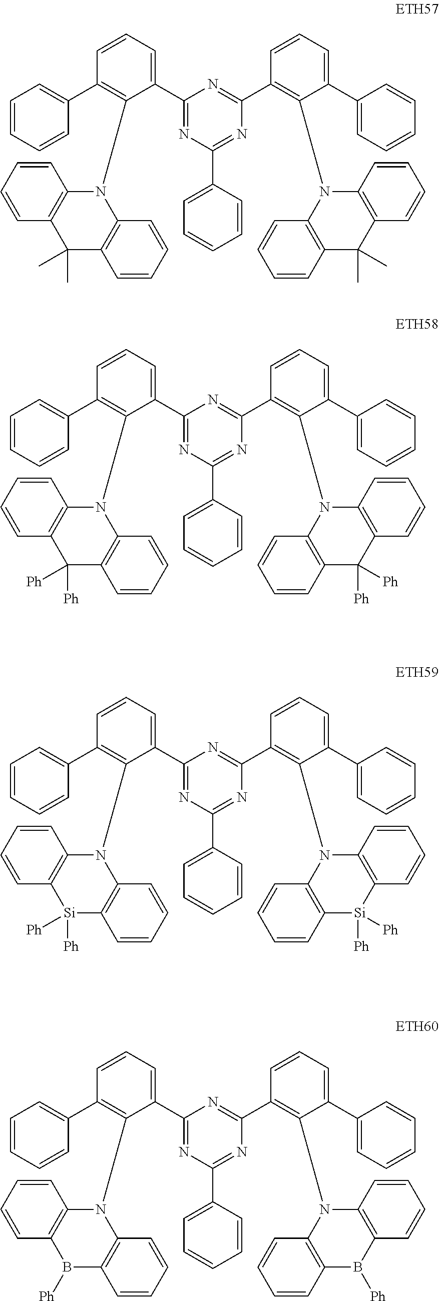

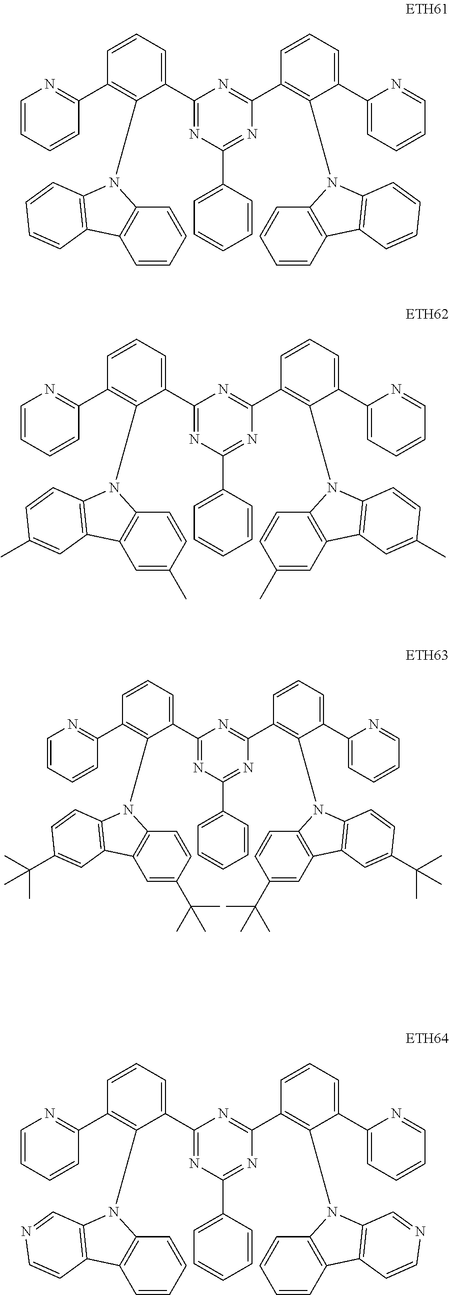

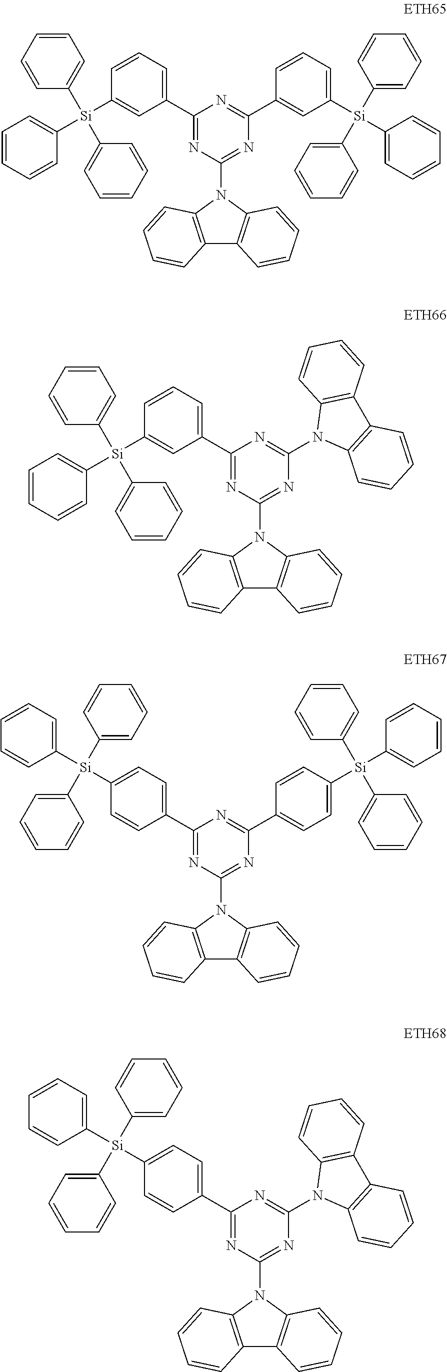 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

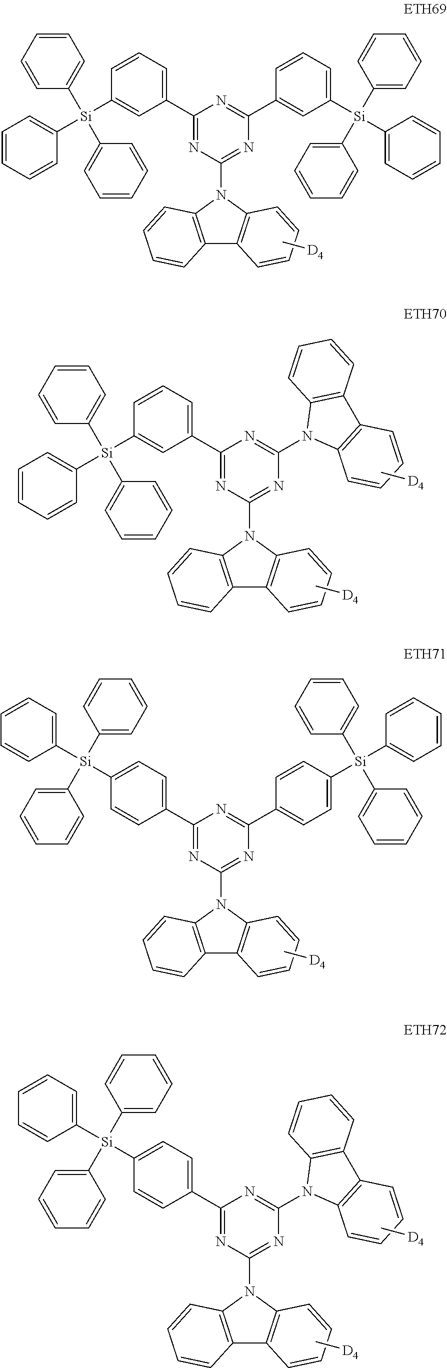

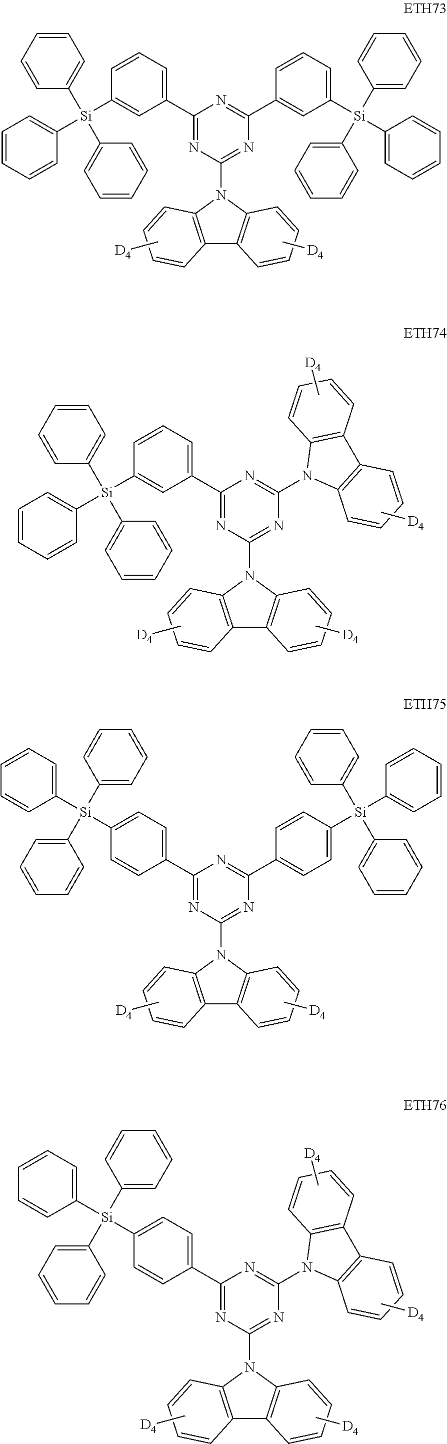

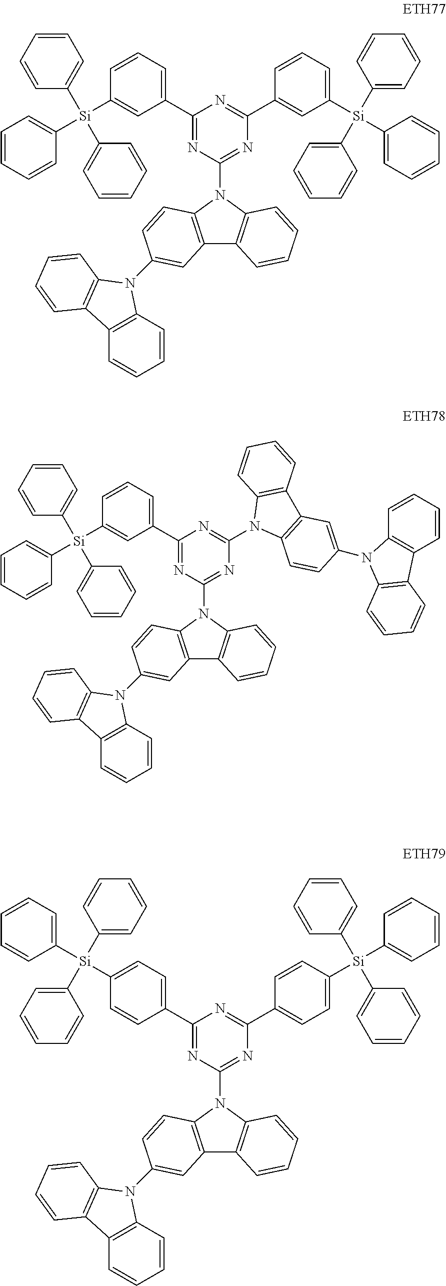 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

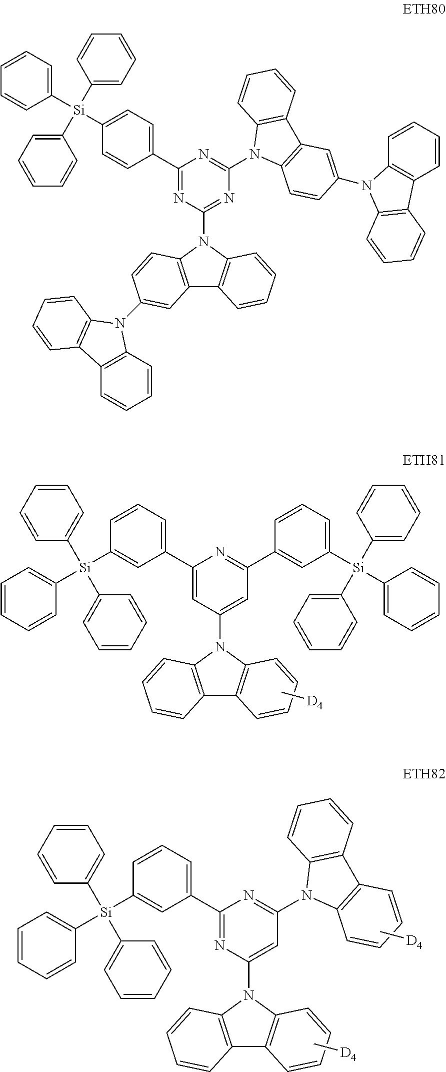

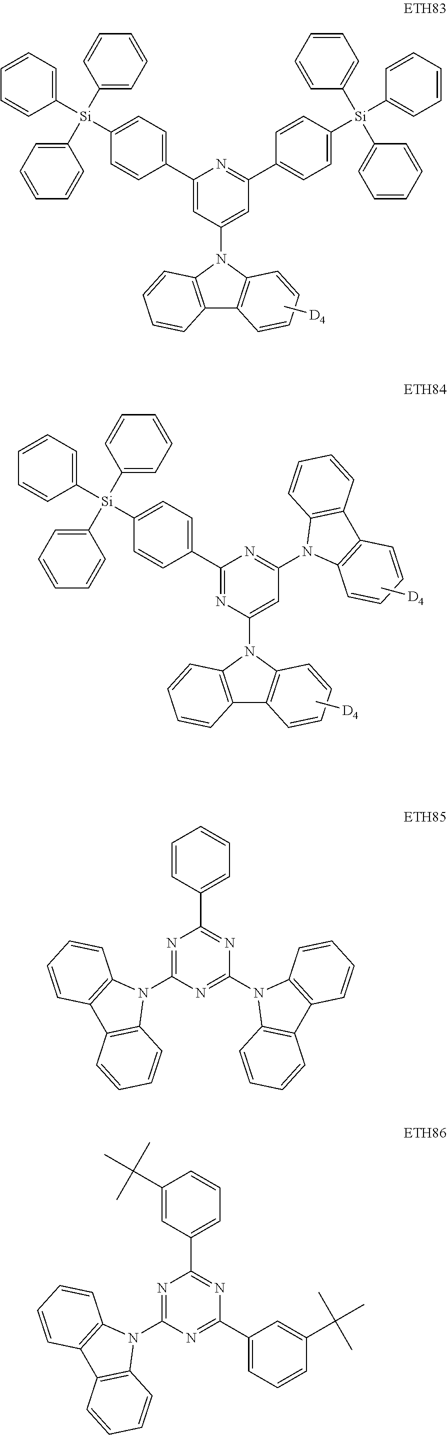

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by a hole transport host and an electron transport host may be in a range of about 2.4 eV to about 3.0 eV. A triplet energy level of the exciplex may be a value that is smaller than an energy gap of each host material. The exciplex may have a triplet energy level that is less than or equal to about 3.0 eV, which is an energy gap between the hole transport host and the electron transport host.

In an embodiment, the emission layer EML may further include a fourth compound, in addition to the first compound, the second compound, and the third compound. The fourth compound may be used as a phosphorescence sensitizer in an emission layer EML. Energy may be transferred from the fourth compound to the first compound, thereby emitting light.

An emission layer EML may include a fourth compound that is an organometallic complex including platinum (Pt) as a central metal atom and ligands bonded to the central metal atom. In an embodiment, an emission layer EML may include a fourth compound represented by Formula D-1.

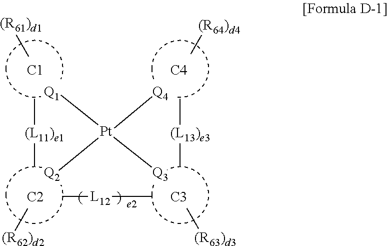

In Formula D-1, Q₁ to Q₄ may each independently be C or N.

In Formula D-1, C1 to C4 may each independently be a substituted or unsubstituted hydrocarbon ring of 5 to 30 ring-forming carbon atoms or a substituted or unsubstituted heterocycle of 2 to 30 ring-forming carbon atoms.

In Formula D-1, L₁₁ to L₁₃ may each independently be a direct linkage, *—O—*, *—S—*,

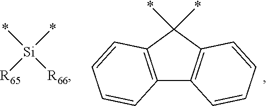

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, -* represents a bonding site to one of C1 to C4.

In Formula D-1, e1 to e3 may each independently be 0 or 1. If e1 is 0, C1 and C2 may not be directly bonded to each other. If e2 is 0, C2 and C3 may not be directly bonded to each other. If e3 is 0, C3 and C4 may not be directly bonded to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or may be combined with an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be unsubstituted with R₆₁ to R₆₄, respectively. A case where d1 to d4 are each 4 and R₆₁ groups, R₆₂ groups, R₆₃ groups, and R₆₄ groups are all hydrogen atoms may be the same as a case where d1 to d4 are each 0. If d1 to d4 are each 2 or more, multiple groups of each of R₆₁ to R₆₄ may all be the same, or at least one group thereof may be different from the remainder.

In an embodiment, in Formula D-1, C1 to C4 may each independently be a substituted or unsubstituted hydrocarbon ring or a substituted or unsubstituted heterocycle that is represented by any one of Formula C-1 to Formula C-4.

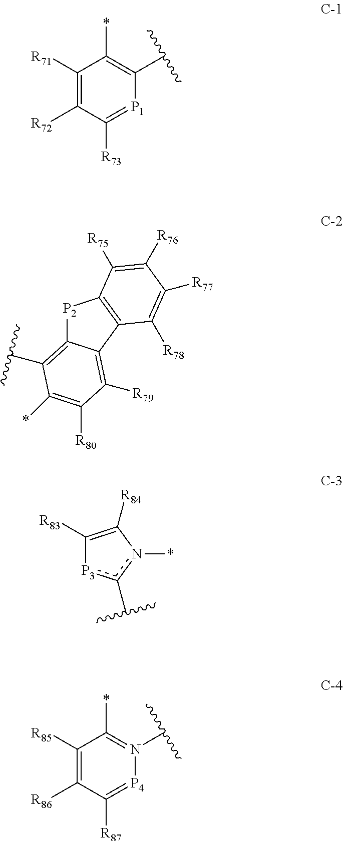

In Formula C-1 to Formula C-4, P₁ may be C—* or C(R₇₄), P₂ may be N—* or N(R₈₁), P₃ may be N—* or N(R₈₂), and P₄ may be C—* or C(R₈₈).

In Formula C-1 to Formula C-4, R₇₁ to R₈₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula C-1 to Formula C-4,

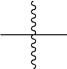

represents a bonding site to a central metal atom of Pt, and -* represents a bonding site to an adjacent ring group (C1 to C4) or to a linker (L₁₁ to L₁₃).

In an embodiment, the emission layer EML may include the first compound, which is a fused polycyclic compound, and may further include at least one of the second compound, the third compound, and the fourth compound. For example, the emission layer EML may include the first compound, the second compound, and the third compound. In the emission layer EML, the second compound and the third compound may form an exciplex, and energy may be transferred from the exciplex to the first compound to achieve light emission.

In another embodiment, the emission layer EML may include the first compound, the second compound, the third compound, and the fourth compound. In the emission layer EML, the second compound and the third compound may form an exciplex, and energy may be transferred to the fourth compound and the first compound to achieve light emission. In an embodiment, the fourth compound may be a sensitizer. In the light emitting device ED, the fourth compound included in the emission layer EML may serve as a sensitizer and may transfer energy from a host to the first compound, which is a light-emitting dopant. For example, the fourth compound, which serves as an auxiliary dopant, may accelerate energy transfer to the first compound, which is a light emitting dopant, and may increase an emission ratio of the first compound. Accordingly, efficiency of the emission layer EML may be improved. If the energy transfer to the first compound increases, excitons formed in the emission layer EML may not accumulate and may rapidly emit light, so that deterioration of a device may be reduced. Accordingly, the service life of the light emitting device ED may increase.

The light emitting device ED may include the first compound, the second compound, the third compound, and the fourth compound, and the emission layer EML may include a combination of two host materials and two dopant materials. In the light emitting device ED, the emission layer EML may include the second compound and the third compound, which are two different hosts, the first compound which emits delayed fluorescence, and the fourth compound may include an organometallic complex, and the emission layer EML may show excellent emission efficiency properties.

In an embodiment, the fourth compound represented by Formula D-1 may be selected from Compound Group 4. In an embodiment, in the light emitting device ED, the fourth compound may include at least one compound selected from Compound Group 4.

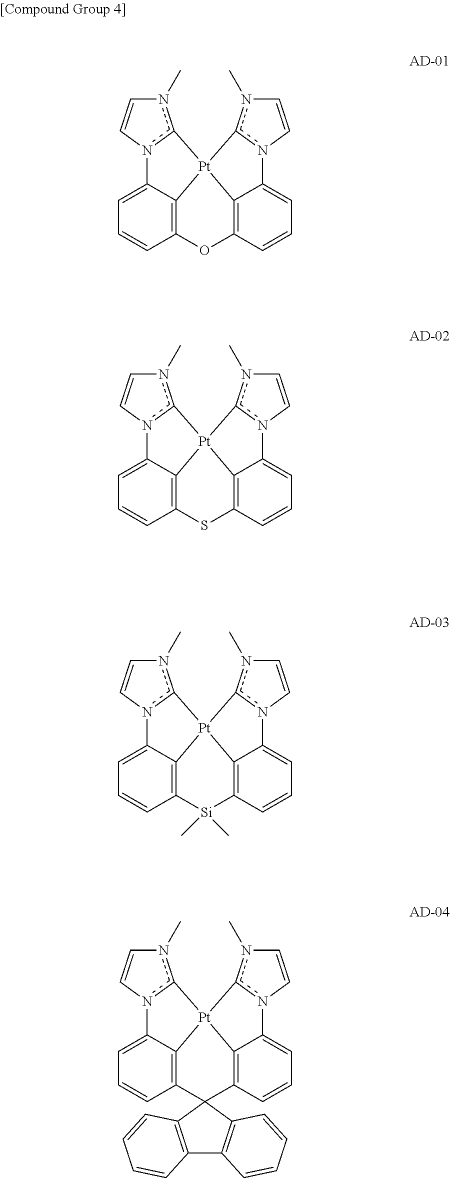

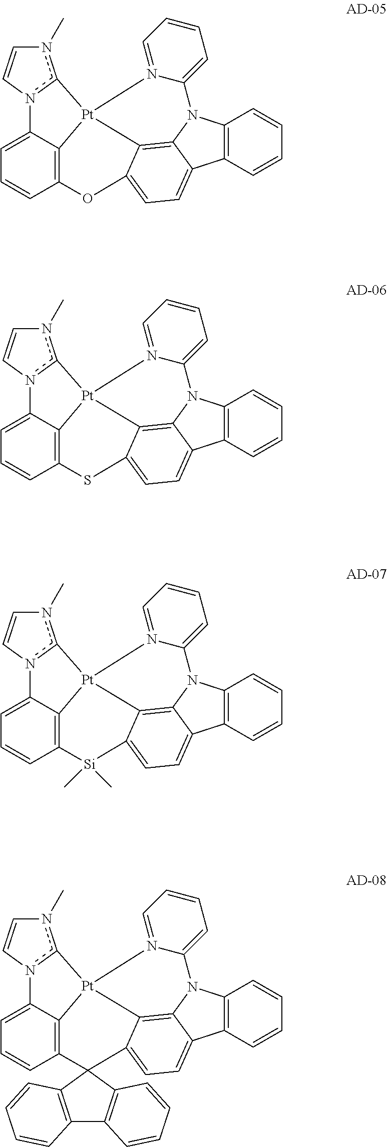

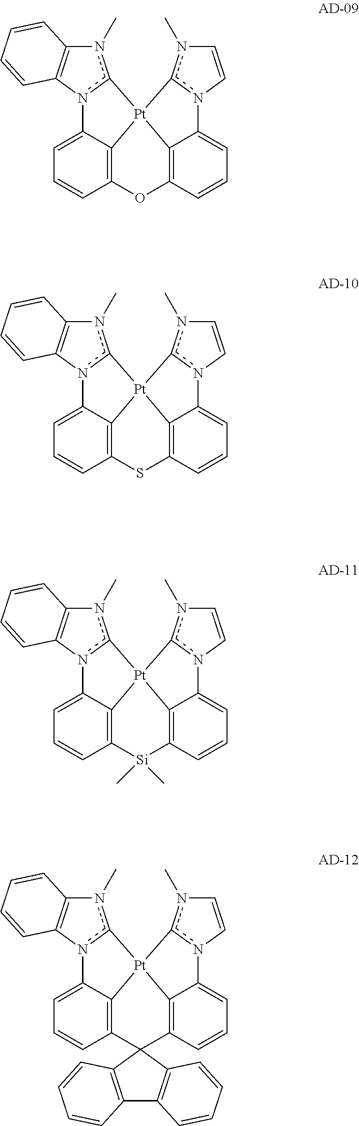

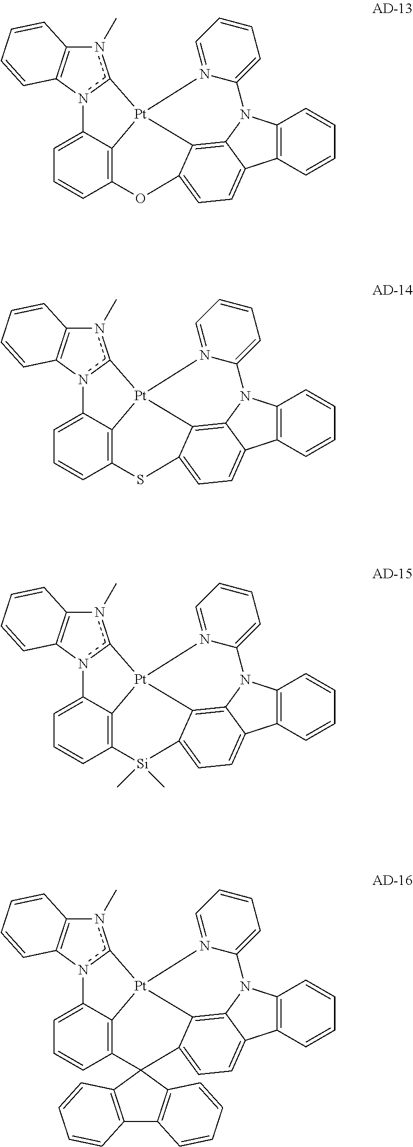

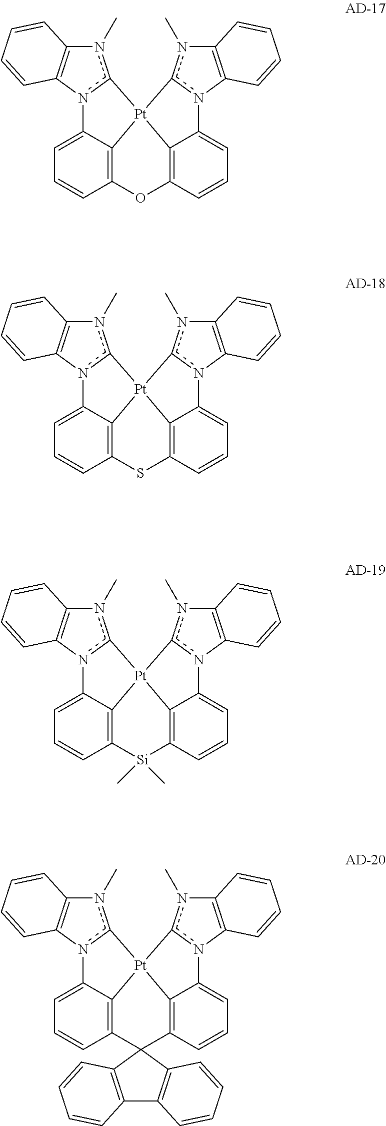

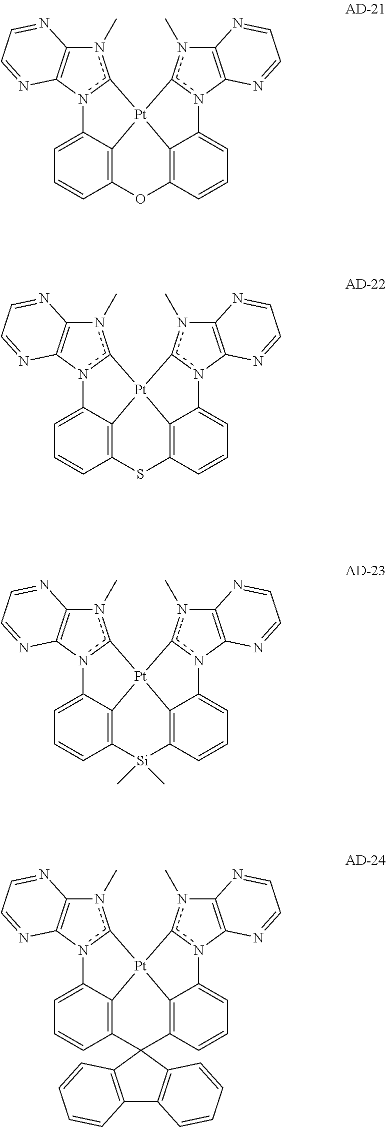

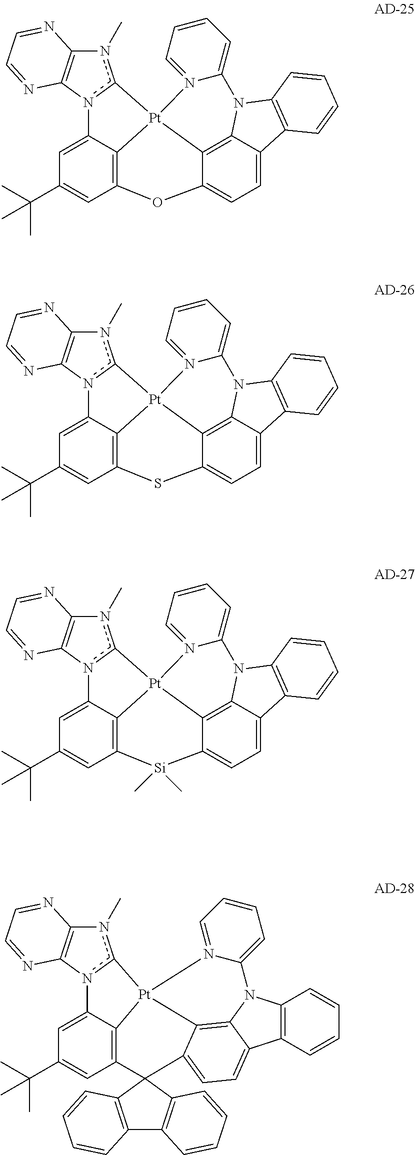

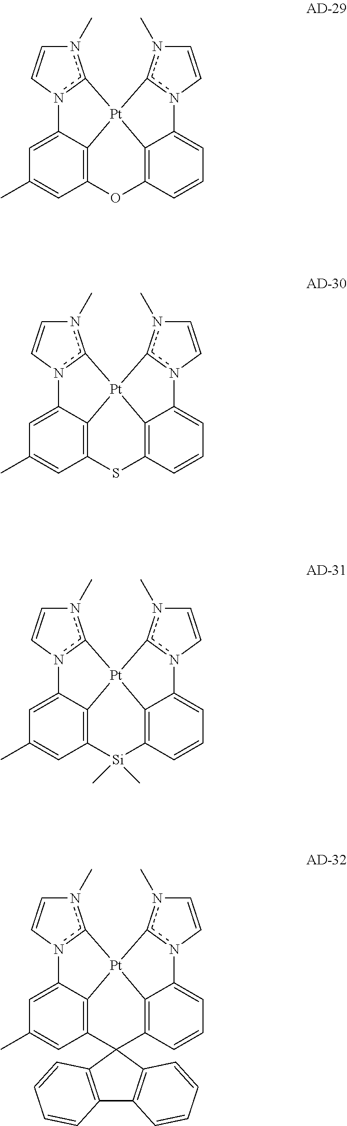

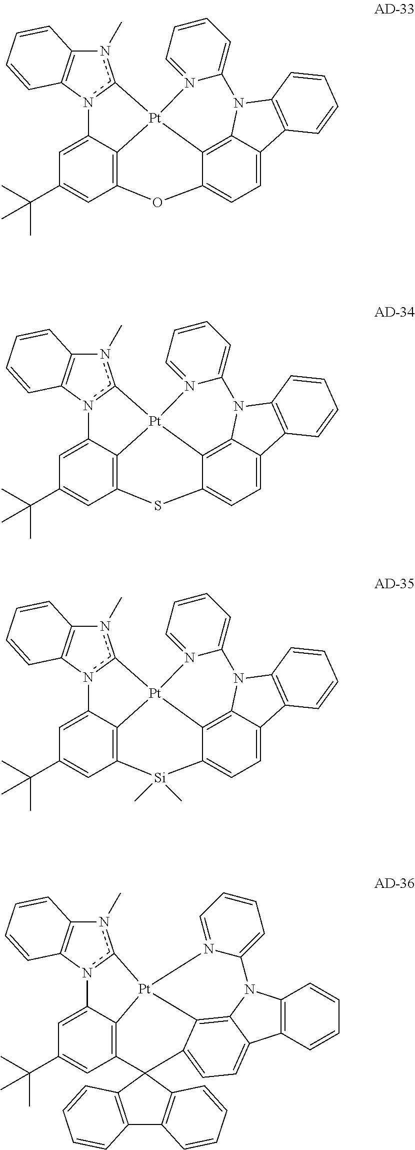

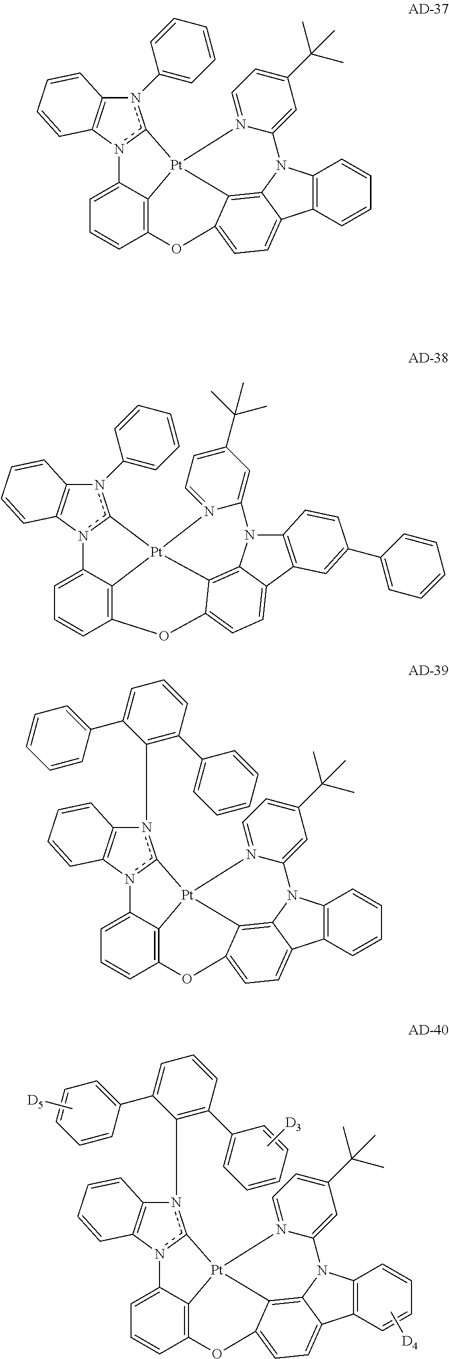

In Compound Group 4, D represents a deuterium atom.

In an embodiment, the light emitting device ED may include multiple emission layers. The emission layers may be provided as a stack of emission layers, so that a light emitting device ED including multiple emission layers may emit white light. The light emitting device ED including multiple emission layers may be a light emitting device having a tandem structure. If the light emitting device ED includes multiple emission layers, at least one emission layer EML may include the first compound represented by Formula 1. If the light emitting device ED includes multiple emission layers, at least one emission layer EML may include the first compound, the second compound, the third compound, and the fourth compound as described above.

In the light emitting device ED, if the emission layer EML includes the first compound, the second compound, and the third compound, an amount of the first compound may be in a range of about 0.1 wt % to about 5 wt %, based on a total weight of the first compound, the second compound, and the third compound. However, embodiments are not limited thereto. If the amount of the first compound satisfies the above-described range, energy transfer from the second compound and the third compound to the first compound may increase, and accordingly, emission efficiency and device lifetime may increase.

In the emission layer EML, a total amount of the second compound and the third compound may be the remainder of the total amount, excluding the amount of the first compound. For example, a total amount of the second compound and the third compound in the emission layer EML may be in a range of about 65 wt % to about 95 wt %, based on a total weight of the first compound, the second compound, and the third compound.

Within the total amount of the second compound and the third compound, a weight ratio of the second compound to the third compound may be in a range of about 3:7 to about 7:3.

If the amounts of the second compound and the third compound satisfy the above-described ranges and ratios, charge balance properties in the emission layer EML may be improved, and emission efficiency and device lifetime may be improved. If the amounts of the second compound and the third compound deviate from the above-described ranges and ratios, charge balance in the emission layer EML may not be achieved, emission efficiency may be reduced, and the device may readily deteriorate.

If the emission layer EML includes the fourth compound, an amount of the fourth compound may be in a range of about 10 wt % to 30 wt %, based on a total weight of the first compound, the second compound, the third compound, and the fourth compound in the emission layer EML. However, embodiments are not limited thereto. If an amount of the fourth compound satisfies the above-described range, energy transfer from a host to the first compound, which is a light emitting dopant, may increase and emission ratio may be improved. Accordingly, the emission efficiency of the emission layer EML may be improved. If the amounts of the first compound, the second compound, the third compound, and the fourth compound in the emission layer EML satisfy the above-described ranges and ratios, excellent emission efficiency and a long device lifetime may be achieved.

In the light emitting device ED, the emission layer EML may further include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting devices ED according to embodiments as shown in each of FIG. 3 to FIG. 6, the emission layer EML may further include hosts of the related art and dopants of the related art, in addition to the above-described host and dopant. For example, the emission layer EML may include a compound represented by Formula E-1. The compound represented by Formula E-1 may be used as a fluorescence host material.

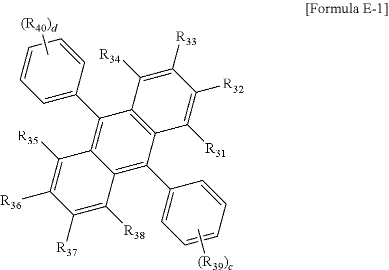

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, in Formula E-1, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19.

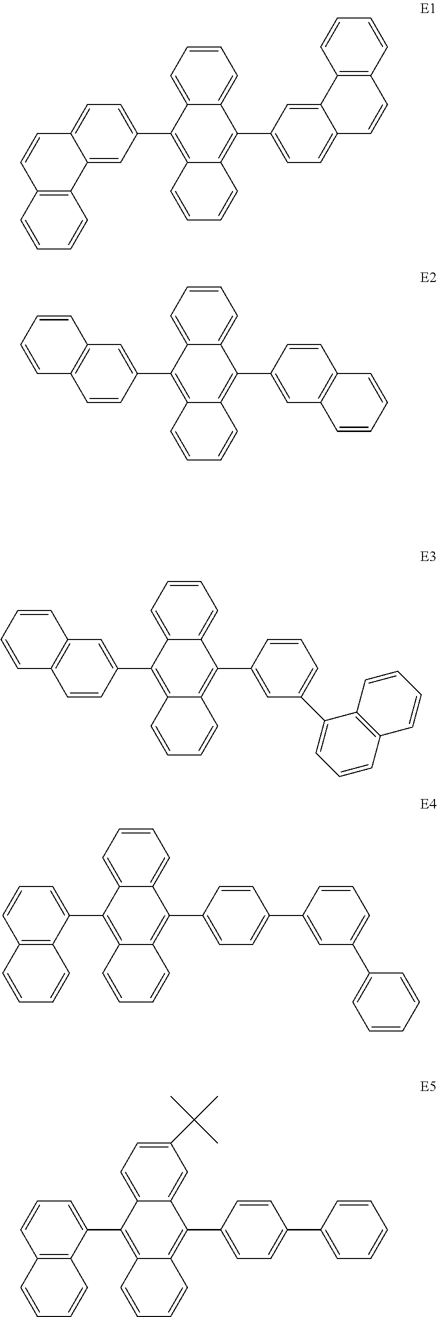

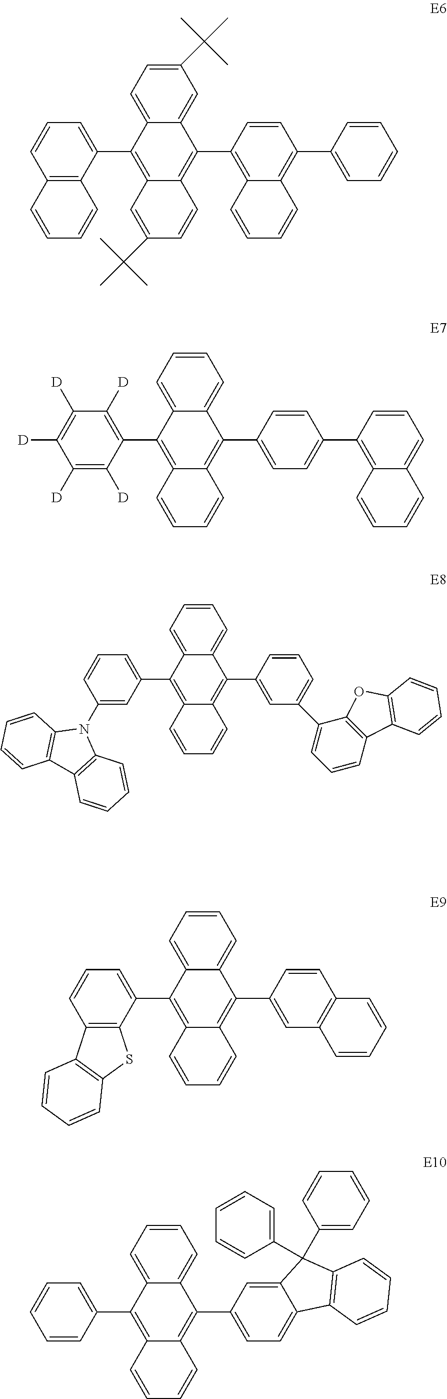

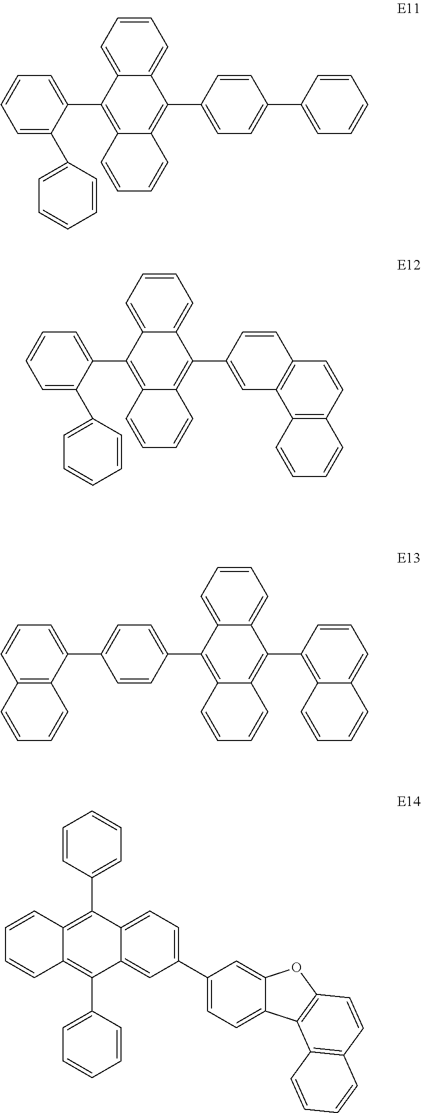

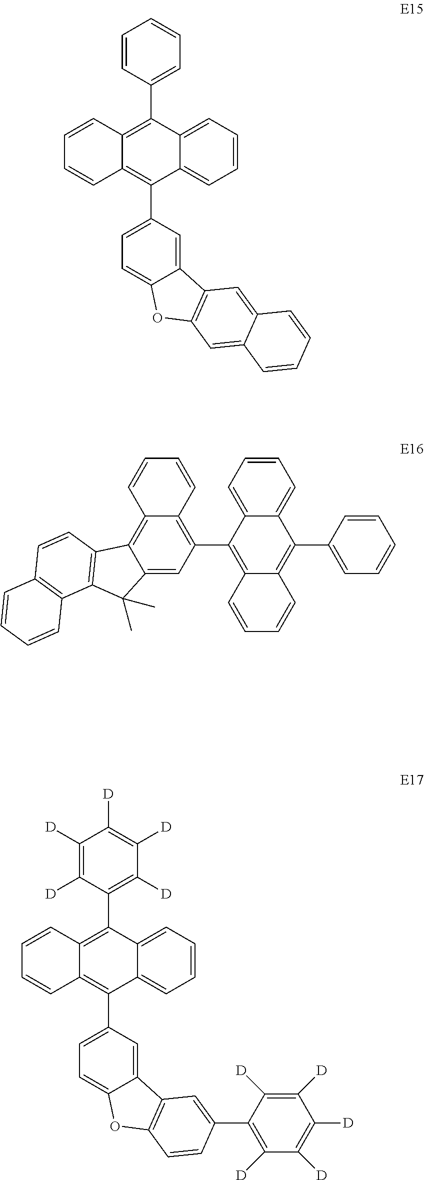

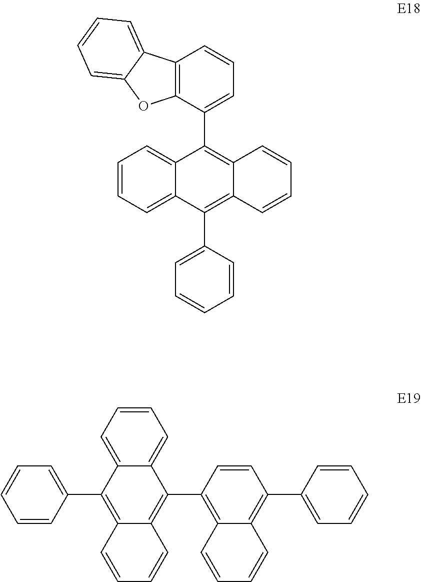

In an embodiment, the emission layer EML may include a compound represented by Formula E-2a or Formula E-2b. The compound represented by Formula E-2a or Formula E-2b may be used as a phosphorescence host material.

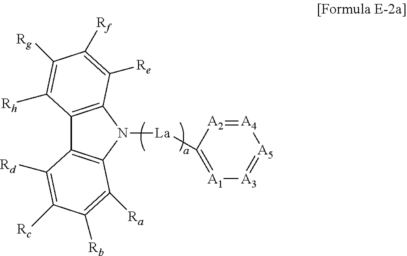

In Formula E-2a, a may be an integer from 0 to 10; and Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple Lₐ groups may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, Rₐ to Rᵢ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

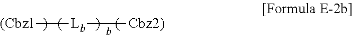

In Formula E-2b, Cbz1 and Cbz2 may each independently be an unsubstituted carbazole group, or a carbazole group substituted with an aryl group of 6 to 30 ring-forming carbon atoms. In Formula E-2b, Le may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10, and if b is 2 or more, multiple Le groups may each independently be a substituted or unsubstituted arylene group of 6 to 30 ring-forming carbon atoms or a substituted or unsubstituted heteroarylene group of 2 to 30 ring-forming carbon atoms.

The compound represented by Formula E-2a or Formula E-2b may be any compound selected from Compound Group E-2. However, the compounds shown in Compound Group E-2 are only examples, and the compound represented by Formula E-2a or Formula E-2b is not limited to Compound Group E-2.

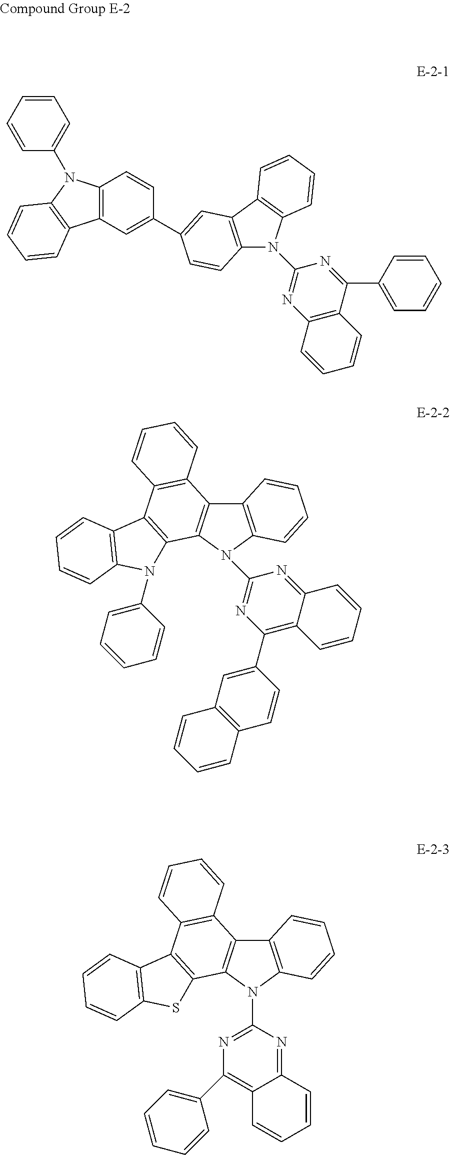 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

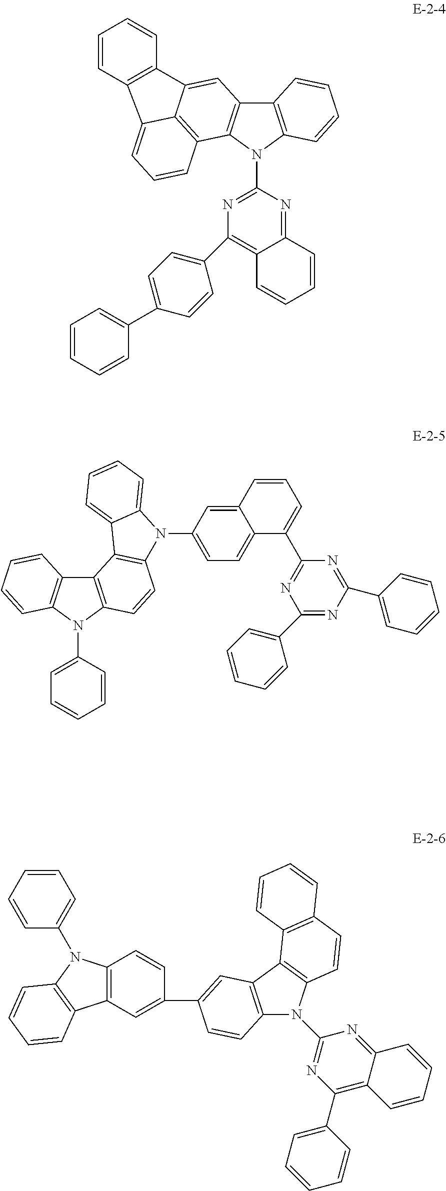 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

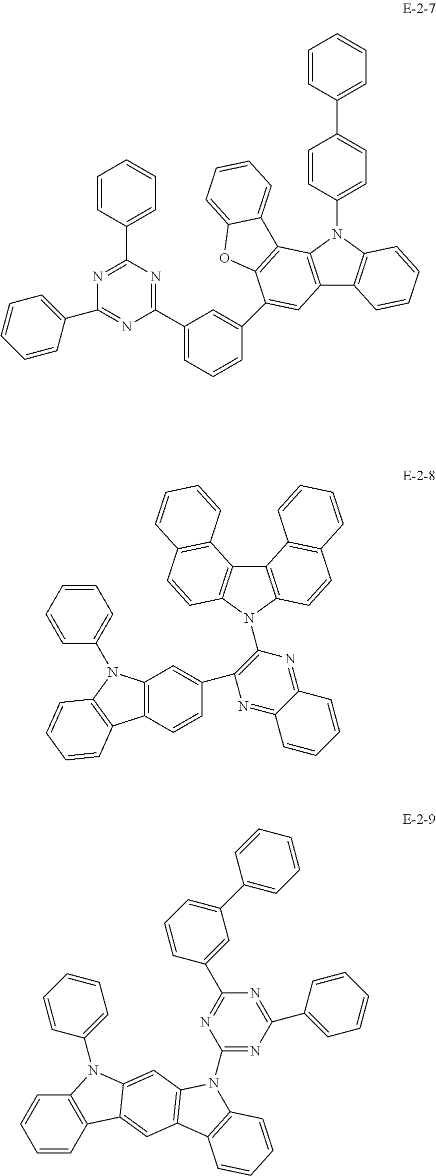 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

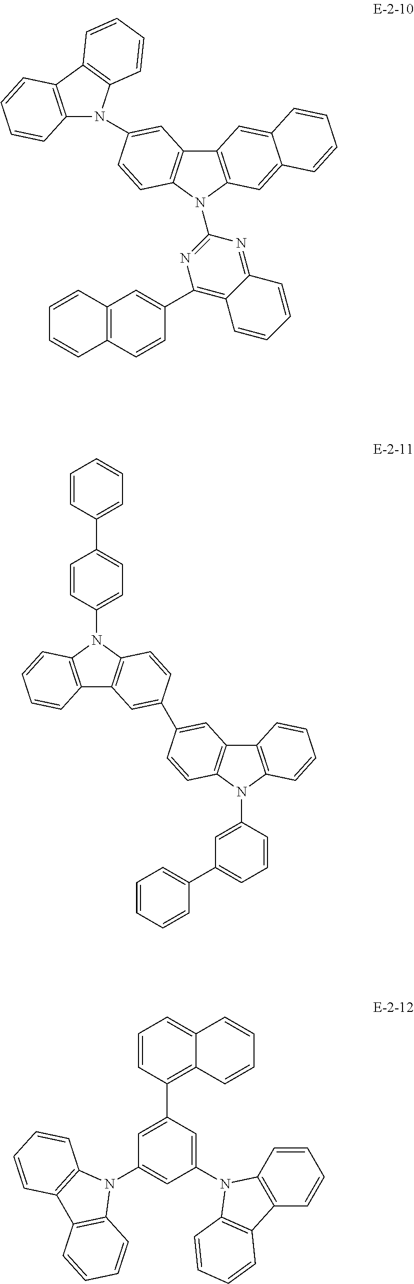 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

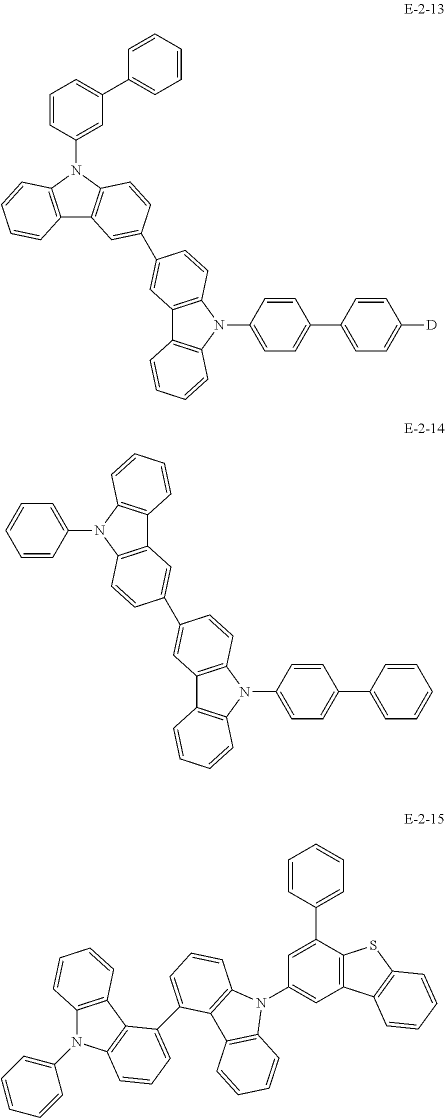 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

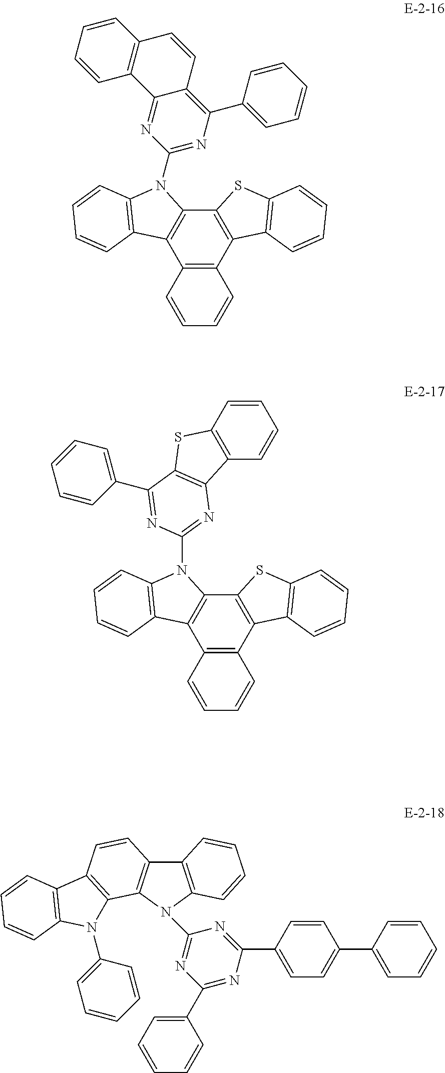 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

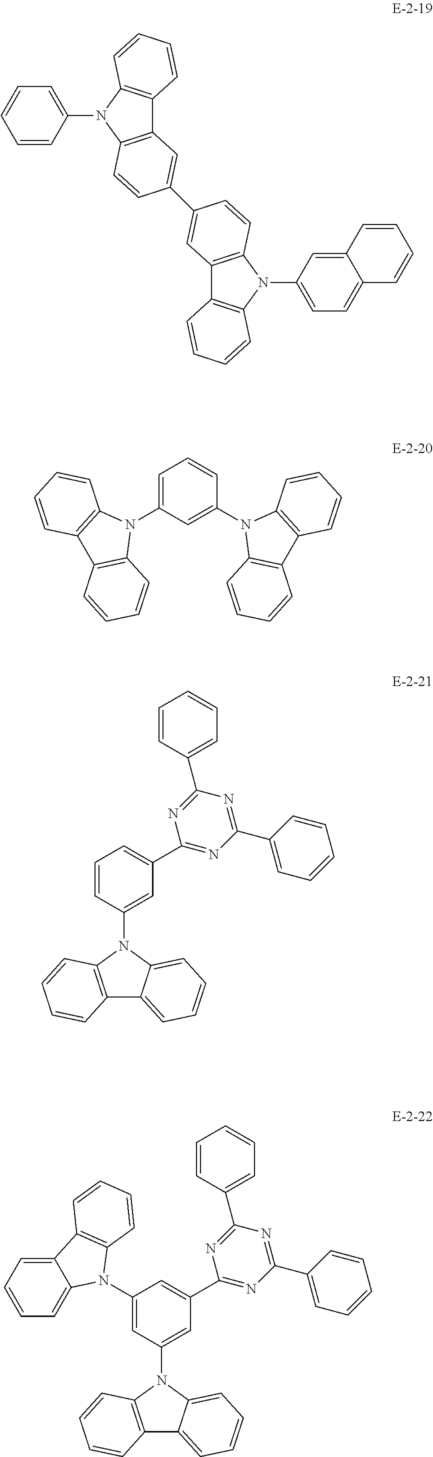 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

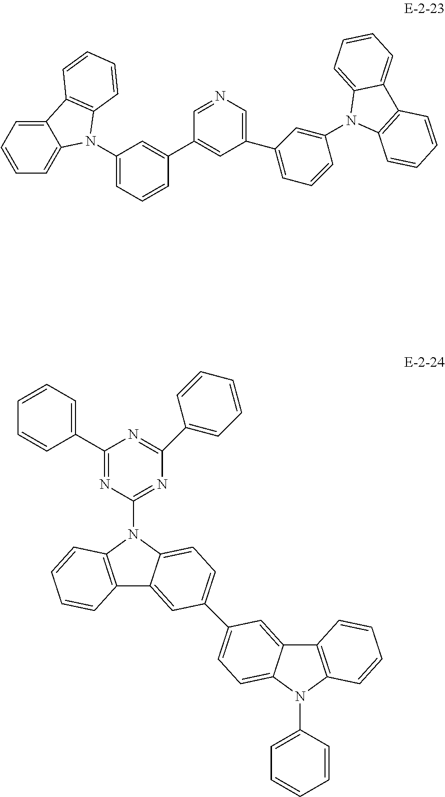 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The emission layer EML may include a compound represented by Formula M-a. The compound represented by Formula M-a may be used as a phosphorescence dopant material.

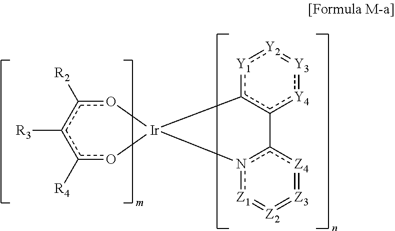

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, m may be 0 or 1, and n may be 2 or 3. In Formula M-a, if m is 0, n may be 3, and if m is 1, may be 2.

The compound represented by Formula M-a may be used as a phosphorescence dopant.

The compound represented by Formula M-a may be any compound selected from Compounds M-a1 to M-a25. However, Compounds M-a1 to M-a25 are only examples, and the compound represented by Formula M-a is not limited to Compounds M-a1 to M-a25.

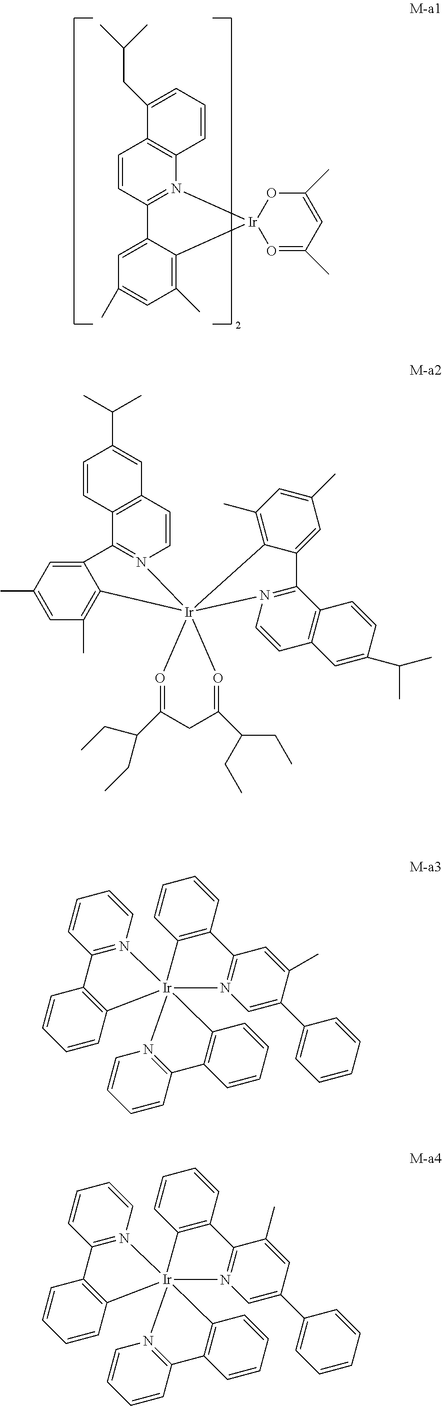

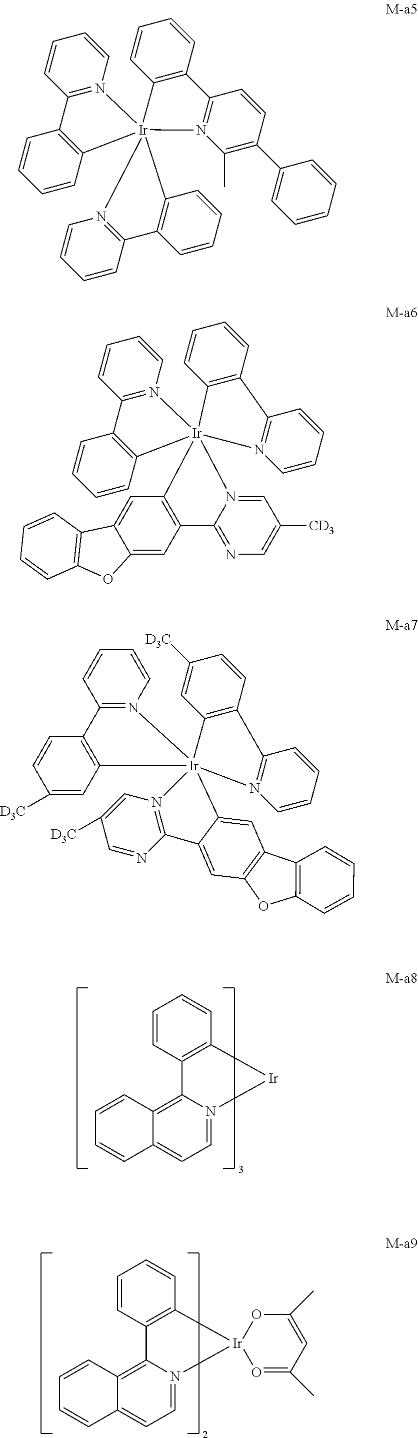

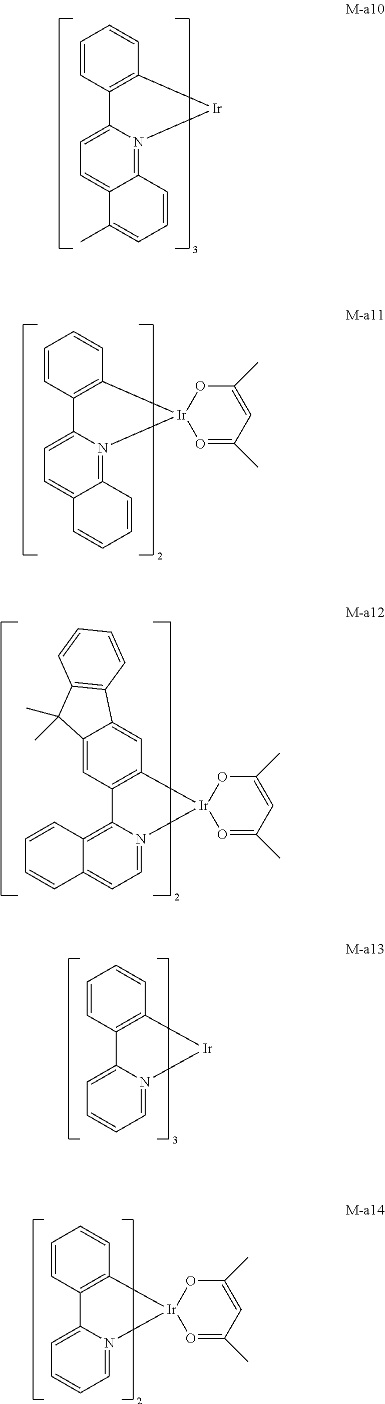

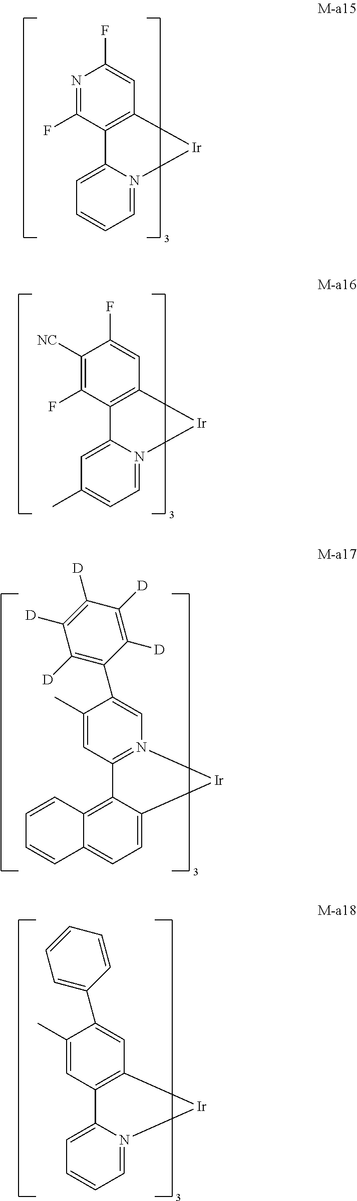

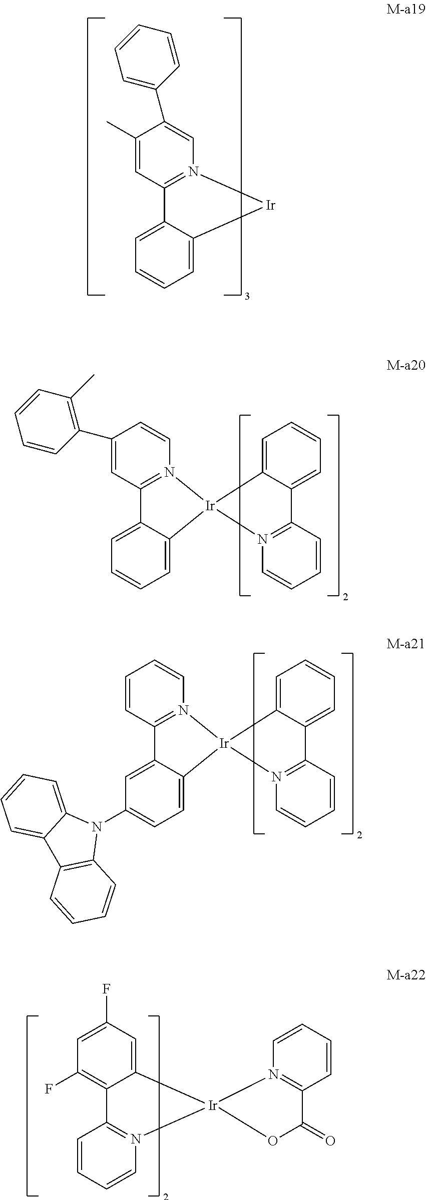

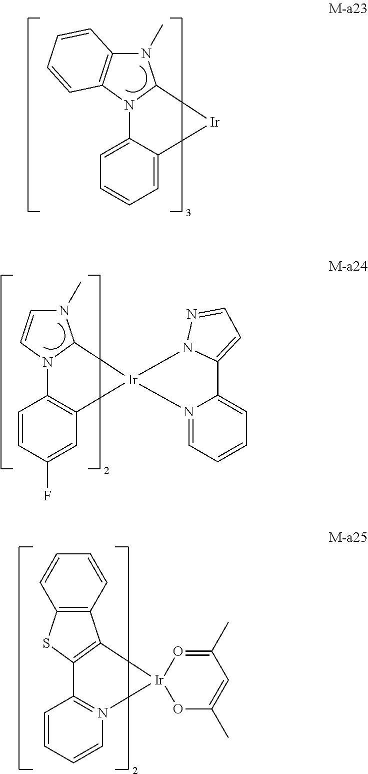

The emission layer EML may further include a compound represented by any one of Formula F-a to Formula F-c. The compounds represented by Formula F-a to Formula F-c may be used as a fluorescence dopant material.

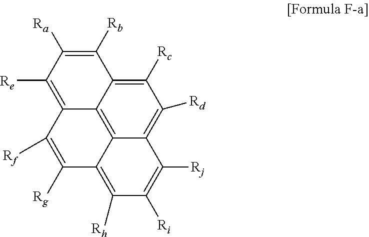

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ and Ar₂ may each independently be a heteroaryl group including O or S as a ring-forming atom.

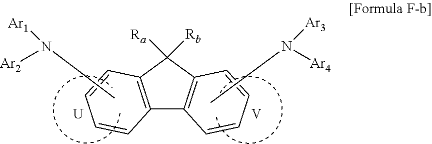

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula F-b, Ar to Ar₄ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ to Ar₄ may be a heteroaryl group including O or S as a ring-forming atom.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. For example, if the number of U or V is 1, a fused ring may be respectively present at the designated part by U or V, and if the number of U or V is 0, a fused ring may not be present at the part designated by U or V. If the number of U is 0 and the number of V is 1, or if the number of U is 1 and the number of V is 0, a fused ring having the fluorene core of Formula F-b may be a cyclic compound with four rings. If the number of U and V is each 0, a fused ring having the fluorene core of Formula F-b may be a cyclic compound with three rings. If the number of U and V is each 1, a fused ring having the fluorene core of Formula F-b may be a cyclic compound with five rings.

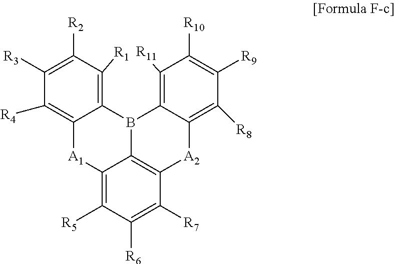

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula F-c, A₁ and A₂ may each independently be combined with a substituent of an adjacent ring to form a fused ring. For example, if A₁ and A₂ are each independently N(Rₘ), A₁ may be combined with R₄ or R₅ to form a ring. For example, A₂ may be combined with R₇ or R₈ to form a ring.

In an embodiment, the emission layer EML may include, as a dopant material of the related art, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and derivatives thereof (for example, 2,5,8,11-tetra-t-butylperylene (TBP)), pyrene and derivatives thereof (for example, 1,1-dipyrene, 1,4-dipyrenylbenzene, and 1,4-bis(N,N-diphenylamino)pyrene), etc.

The emission layer EML may include a phosphorescence dopant material of the related art. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb), or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, embodiments are not limited thereto.

In an embodiment, the emission layer EML may include a quantum dot material. The quantum dot may be a Group II-VI compound, a Group III-VI compound, a Group 1-II-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof; or any combination thereof.

Examples of a Group III-VI compound may include: a binary compound such as In₂S₃, and In₂Se₃; a ternary compound such as InGaS₃, and InGaSe₃; or any combination thereof.

Examples of a Group 1-III-VI compound may include: a ternary compound selected from the group consisting of AgInS, AgInS₂, CuInS, CuInS₂, AgGaS₂, CuGaS₂, CuGaO₂, AgGaO₂, AgAlO₂ and mixtures thereof; a quaternary compound such as AgInGaS₂, and CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; or any combination thereof. In an embodiment, a Group III-V compound may further include a Group II metal. For example, InZnP, etc. may be selected as a Group III-II-V compound.

Examples of a Group IV-VI compound may include: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; a quaternary compound selected from the group consisting of SnPbSSe, SnPbSeTe, SnPbSTe, and mixtures thereof; or any combination thereof. Examples of a Group IV element may include S1, Ge, or any mixture thereof. Examples of a Group IV compound may include a binary compound selected from the group consisting of SiC, SiGe, and any mixture thereof.

A binary compound, a ternary compound, or a quaternary compound may be present in a particle at a uniform concentration, or may be present in a particle at a partially different concentration distribution. In an embodiment, a quantum dot may have a core/shell structure in which a quantum dot surrounds another quantum dot. A quantum dot having a core/shell structure may have a concentration gradient at an interface between the core and the shell in which the concentration of a material that is present in the shell decreases toward the core.

In embodiments, the quantum dot may have the above-described core/shell structure including a core including a nanocrystal and a shell surrounding the core. The shell of the quantum dot may serve as a protection layer that prevents chemical deformation of the core to maintain semiconductor properties and/or may serve as a charging layer that imparts the quantum dot with electrophoretic properties. The shell may be a single layer or a multilayer. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO; a ternary compound such as MgAl₂O₄, CoFe₂O₄, NiFe₂O₄ and CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Within any of the ranges above, color purity or color reproducibility may be improved. Light emitted through a quantum dot may be emitted in all directions, so that light viewing angle properties may be improved.

The shape of the quantum dot may be any form used in the related art, without limitation. For example, the quantum dot may have a spherical shape, a pyramidal shape, a multi-arm shape, or a cubic shape, or the quantum dot may be in the form of a nanoparticle, a nanotube, a nanowire, a nanofiber, a nanoplate particle, etc.

The quantum dot may control the color of emitted light according to a particle size thereof. Accordingly, the quantum dot may have various emission colors such as blue, red, or green.

In the light emitting device ED according to an embodiment as shown in each of FIG. 3 to FIG. 6, the electron transport region ETR may be provided on the emission layer EML. The electron transport region ETR may include at least one of an electron blocking layer HBL, an electron transport layer ETL, or an electron injection layer EIL. However, embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from an emission layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting device ED according to an embodiment, the electron transport region ETR may include a compound represented by Formula ET-2.

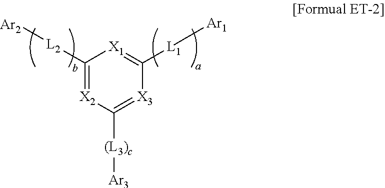

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-2, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), or any mixture thereof, without limitation.

In an embodiment, the electron transport region ETR may include at least one compound selected from Compounds ET1 to ET36.

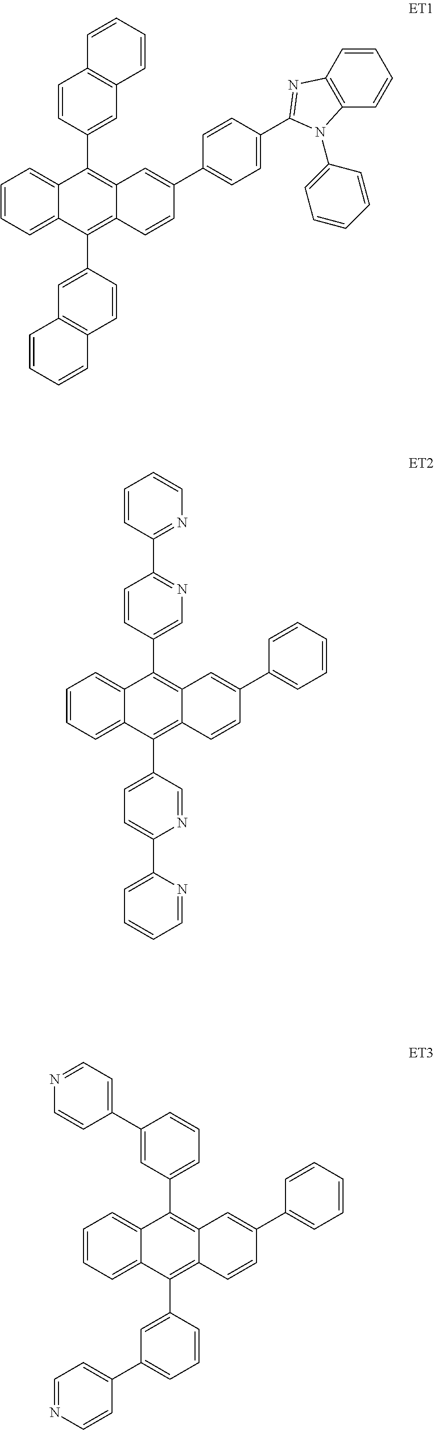 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

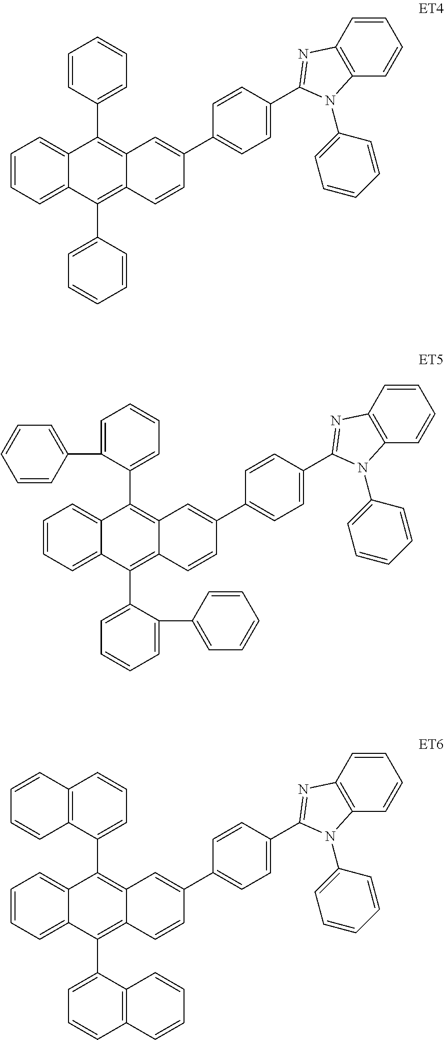 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

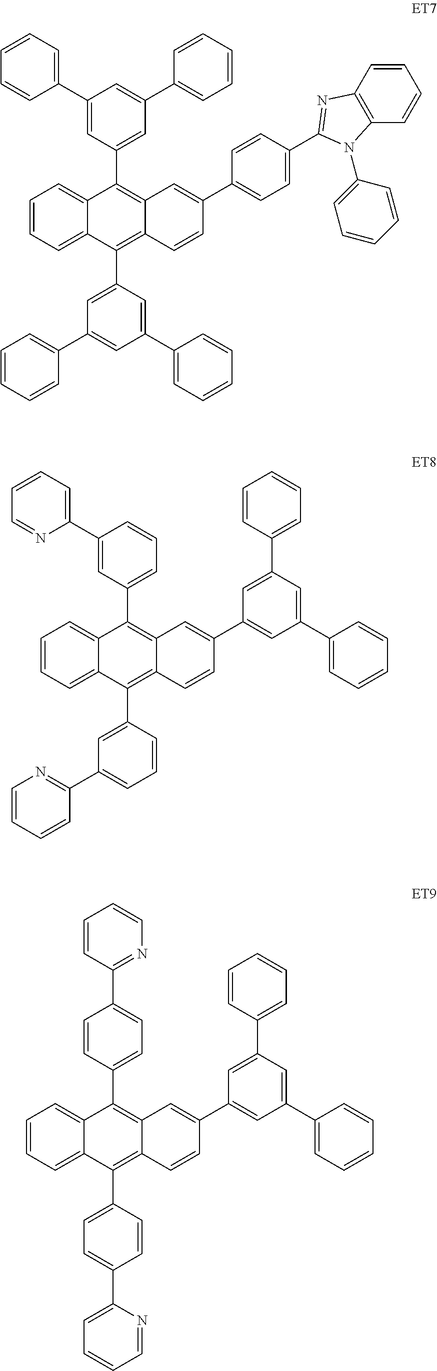 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

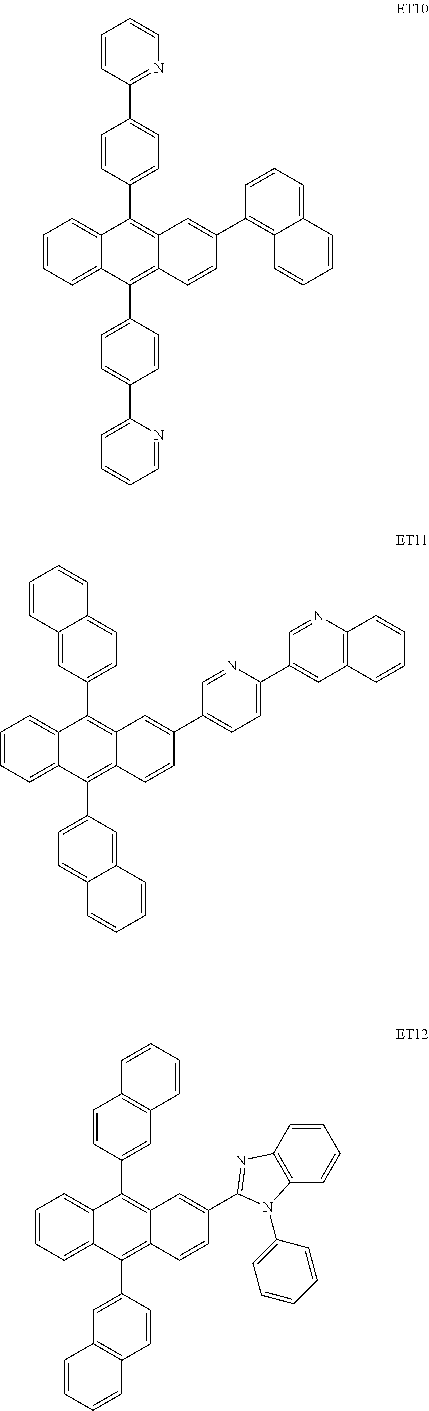 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

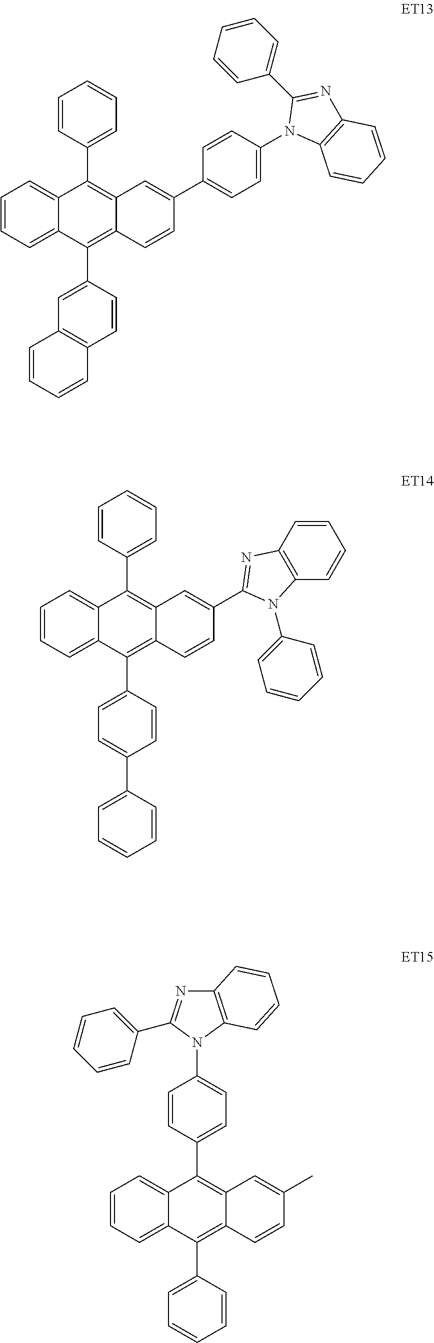 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

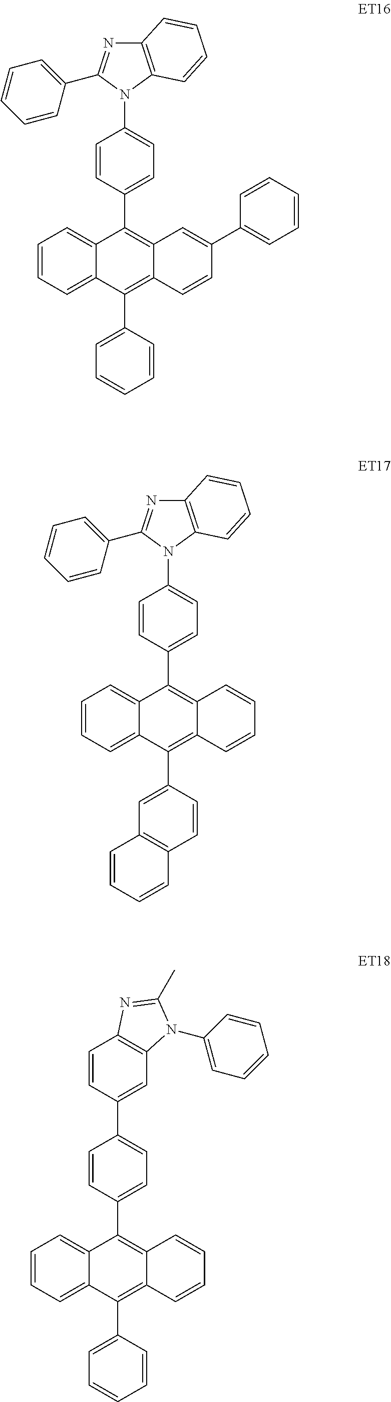 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

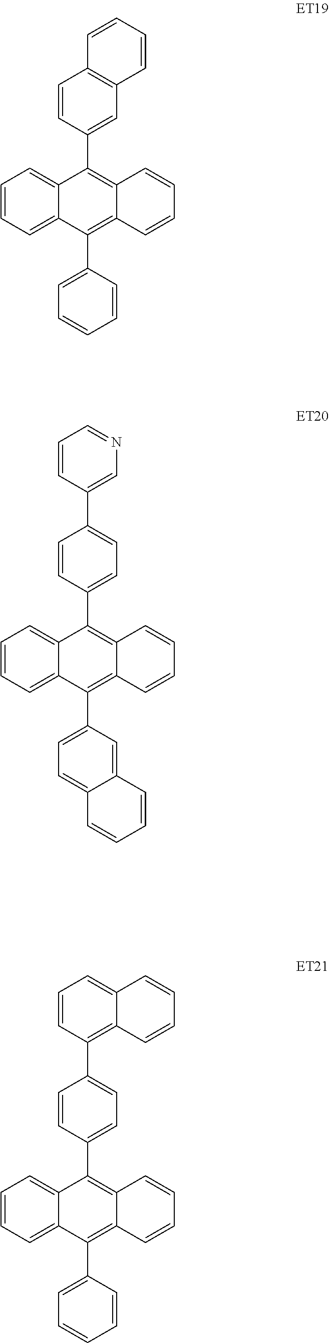

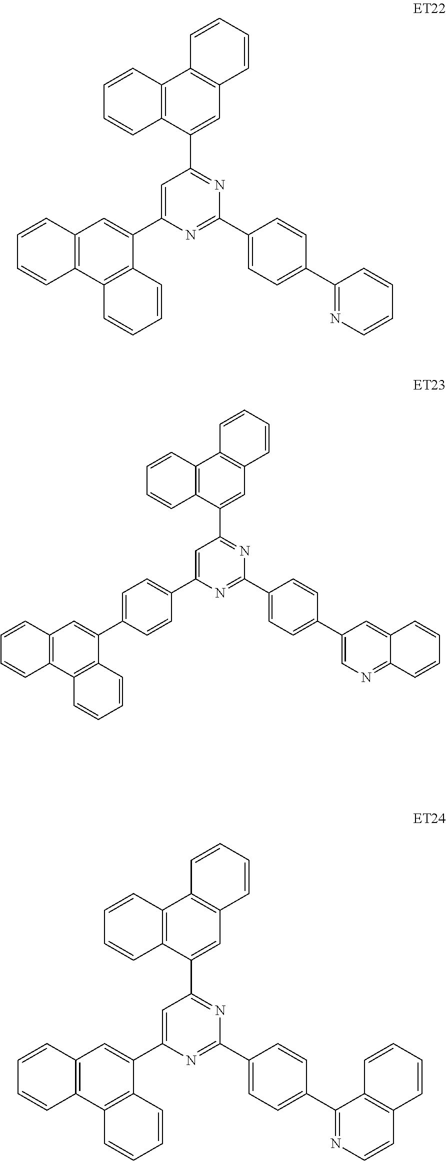 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

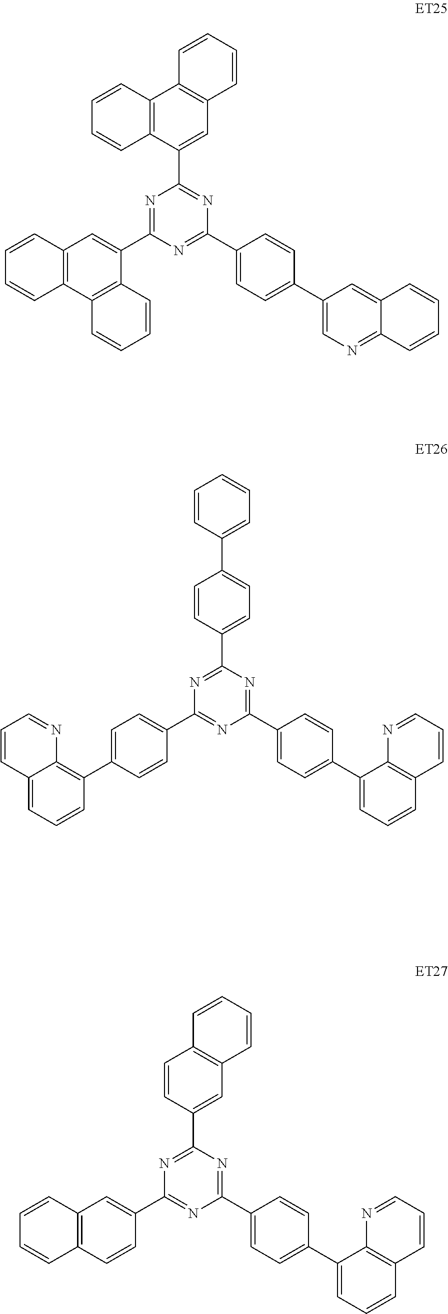 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

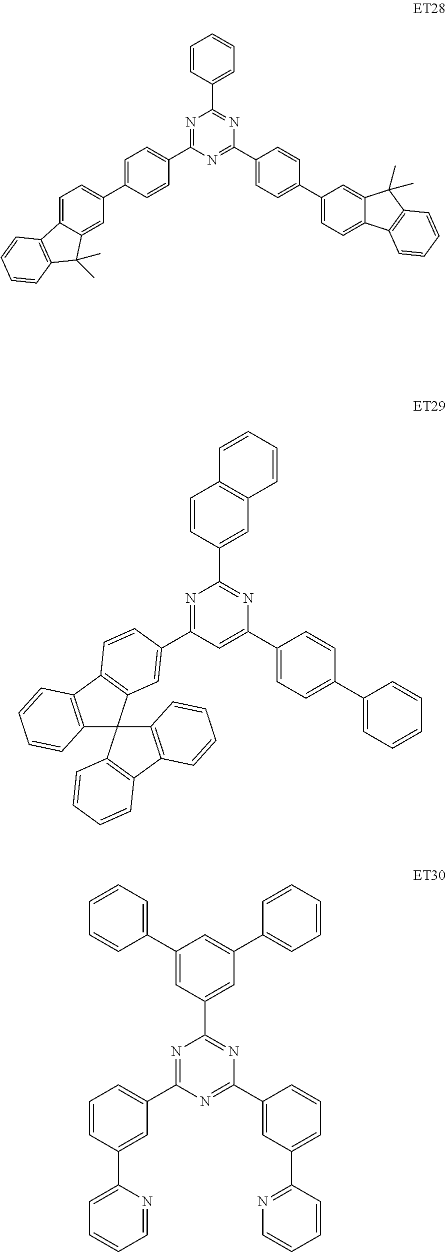 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

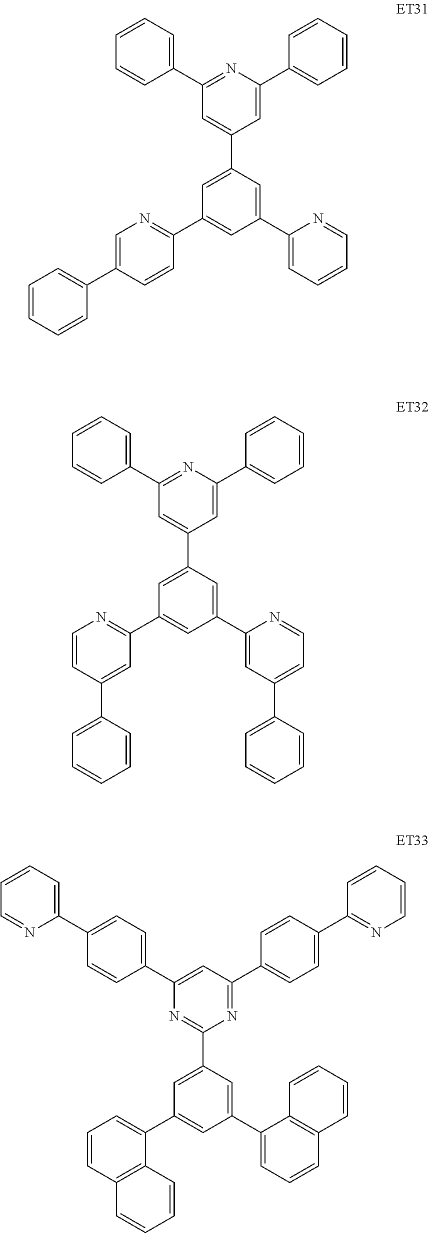 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

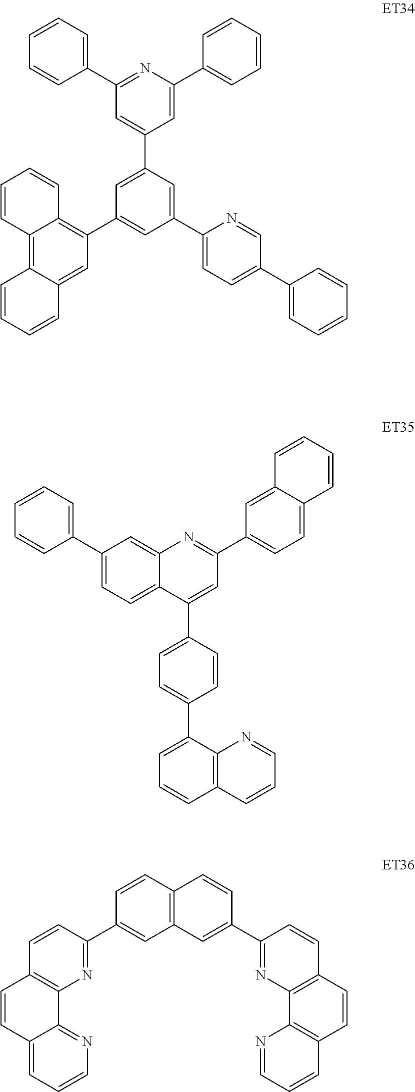 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. In another embodiment, the electron transport region ETR may be formed of a mixture material of an electron transport material and an insulating organometallic salt. The organometallic salt may be a material having an energy band gap equal to or greater than about 4 eV. For example, the organometallic salt may include metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen), in addition to the aforementioned materials. However, embodiments are not limited thereto.

The electron transport region ETR may include the compounds of the electron transport region in at least one of an electron injection layer EIL, an electron transport layer ETL, or a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without a substantial increase in driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure including a reflective layer or a transflective layer formed of the above-described materials and a transparent conductive layer formed of ITO, IZO, ZnO, ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting device ED may further include a capping layer CPL disposed on the second electrode EL2. The capping layer CPL may be a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNx, SiOy, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine(a-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or an acrylate such as methacrylate. A capping layer CPL may include at least one of Compounds P1 to P5, but embodiments are not limited thereto.

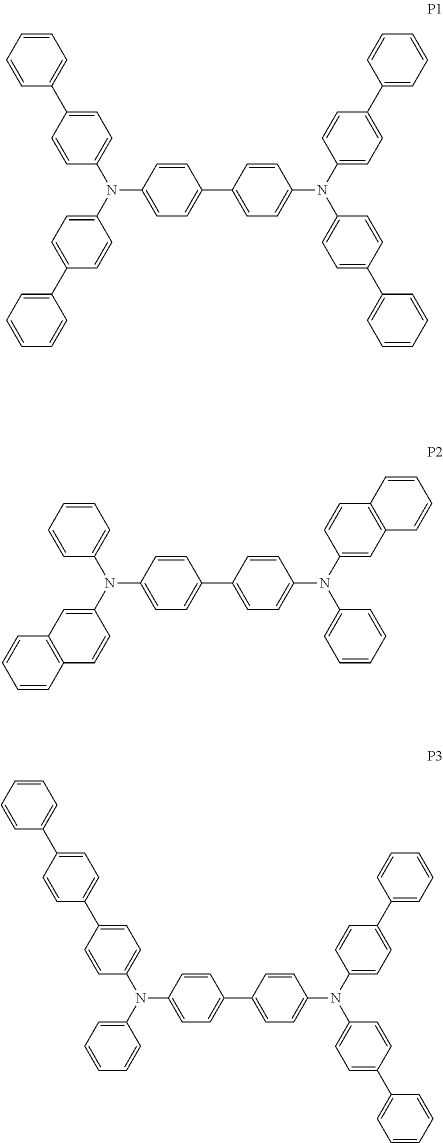 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

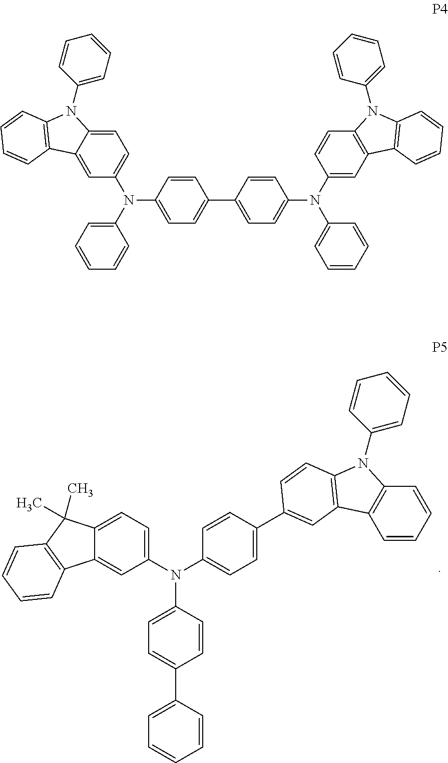 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than about 1.6, with respect to light in a wavelength range of about 550 nm to about 660 nm.

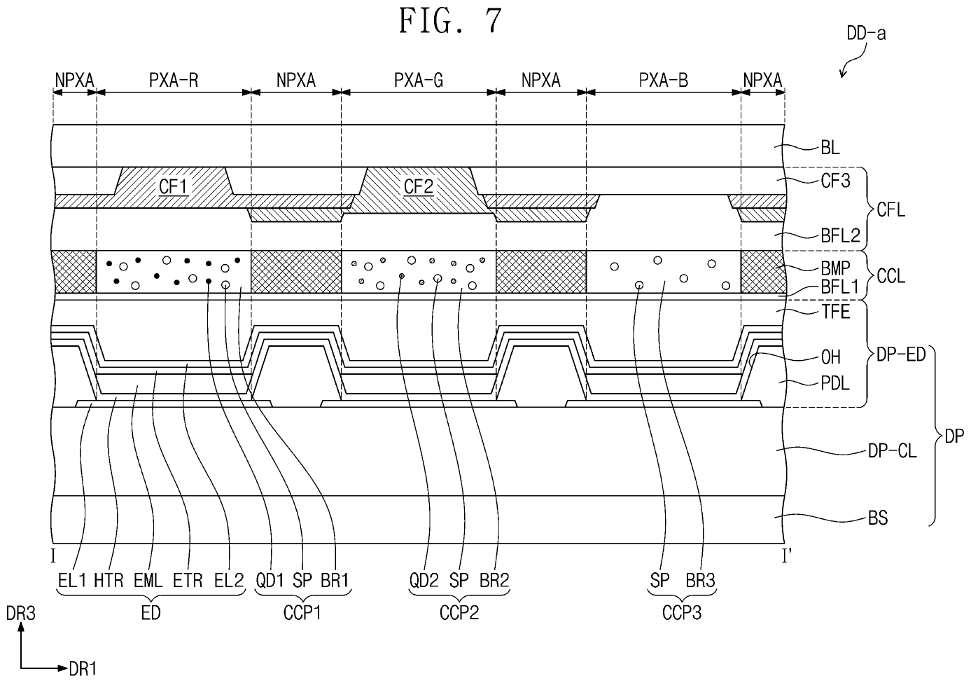

FIG. 7 to FIG. 10 are each a schematic cross-sectional view of a display apparatus according to an embodiment. In the explanation on the display apparatuses according to embodiments in reference to FIG. 7 to FIG. 10, the features which have been described above with respect to FIG. 1 to FIG. 6 will not be explained again, and the differing features will be described.

Referring to FIG. 7, the display apparatus DD-a according to an embodiment may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS, and a display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting device ED shown in FIG. 7 may be the same as a structure of a light emitting device ED according to one of FIG. 3 to FIG. 6 as described herein.

In the display apparatus DD-a, the emission layer EML of the light emitting device ED may include the fused polycyclic compound according to an embodiment.

Referring to FIG. 7, the emission layer EML may be disposed in an opening OH defined in a pixel definition layer PDL. For example, the emission layer EML, which is divided by the pixel definition layer PDL and correspondingly provided to each of the luminous areas PXA-R, PXA-G, and PXA-B, may each emit light in a same wavelength region. In the display apparatus DD-a, the emission layer EML may emit blue light. Although not shown in the drawings, in an embodiment, the emission layer EML may be provided as a common layer for each of the luminous areas PXA-R, PXA-G, and PXA-B.

The light controlling layer CCL may be disposed on the display panel DP. The light controlling layer CCL may include a light converter. The light converter may be a quantum dot or a phosphor. The light converter may transform the wavelength of a provided light and may emit the resulting light. For example, the light controlling layer CCL may be a layer including a quantum dot or a layer including a phosphor.

The light controlling layer CCL may include light controlling parts CCP1, CCP2, and CCP3. The light controlling parts CCP1, CCP2, and CCP3 may be separated from one another.

Referring to FIG. 7, a partition pattern BMP may be disposed between the light controlling parts CCP1, CCP2, and CCP3, which are separated from one another, but embodiments are not limited thereto. In FIG. 7, it is shown that the partition pattern BMP does not overlap the light controlling parts CCP1, CCP2, and CCP3, but at least a portion of the edges of the light controlling parts CCP1, CCP2, and CCP3 may overlap the partition pattern BMP.

The light controlling layer CCL may include a first light controlling part CCP1 including a first quantum dot QD1 that converts first color light provided from the light emitting device ED into second color light, a second light controlling part CCP2 including a second quantum dot QD2 that converts first color light into third color light, and a third light controlling part CCP3 that transmits first color light.

In an embodiment, the first light controlling part CCP1 may provide red light, which is the second color light, and the second light controlling part CCP2 may provide green light, which is the third color light. The third color controlling part CCP3 may transmit and provide blue light, which is the first color light provided from the light emitting device ED. For example, the first quantum dot QD1 may be a red quantum dot, and the second quantum dot QD2 may be a green quantum dot. The quantum dots QD1 and QD2 may each be a quantum dot as described herein.

The light controlling layer CCL may further include a scatterer SP. The first light controlling part CCP1 may include the first quantum dot QD1 and a scatterer SP, the second light controlling part CCP2 may include the second quantum dot QD2 and a scatterer SP, and the third light controlling part CCP3 may not include a quantum dot but may include a scatterer SP.

The scatterer SP may be an inorganic particle. For example, the scatterer SP may include at least one of TiO₂, ZnO, Al₂O₃, SiO₂, or hollow silica. The scatterer SP may include at least one of TiO₂, ZnO, Al₂O₃, SiO₂, or hollow silica, or the scatterer SP may be a mixture of two or more materials selected from TiO₂, ZnO, Al₂O₃, SiO₂, and hollow silica.

The first light controlling part CCP1, the second light controlling part CCP2, and the third light controlling part CCP3 may each include base resins BR1, BR2, and BR3 in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2, and BR3 are each a medium in which the quantum dots QD1 and QD2 and the scatterer SP are dispersed, and may be composed of various resin compositions which may be generally referred to as a binder. For example, the base resins BR1, BR2, and BR3 may be acrylic resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, referred to as “humidity/oxygen”). The barrier layer BFL1 may block the light controlling parts CCP1, CCP2, and CCP3 from exposure to humidity/oxygen. The barrier layer BFL1 may cover the light controlling parts CCP1, CCP2, and CCP3. A color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. The barrier layers BFL1 and BFL2 may each independently further include an organic layer. The barrier layers BFL1 and BFL2 may be formed of a single layer or formed of multiple layers.

In the display apparatus DD-a, the color filter layer CFL may be disposed on the light controlling layer CCL. In an embodiment, the color filter layer CFL may be directly disposed on the light controlling layer CCL. For example, the barrier layer BFL2 may be omitted.

The color filter layer CFL may include filters CF1, CF2, and CF3. The first to third filters CF1, CF2 and CF3 may be disposed to respectively correspond to a red luminous area PXA-R, a green luminous area PXA-G, and a blue luminous area PXA-B.

The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. In an embodiment, the first filter CF1 and the second filter CF2 may be provided in one body without distinction.

Although not shown in the drawings, the color filter layer CFL may further include a light blocking part (not shown). The light blocking part (not shown) may be a black matrix. The light blocking part (not shown) may include an organic light blocking material or an inorganic light blocking material including a black pigment or black dye. The light blocking part (not shown) may prevent light leakage, and may separate the boundaries between adjacent filters CF1, CF2, and CF3.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

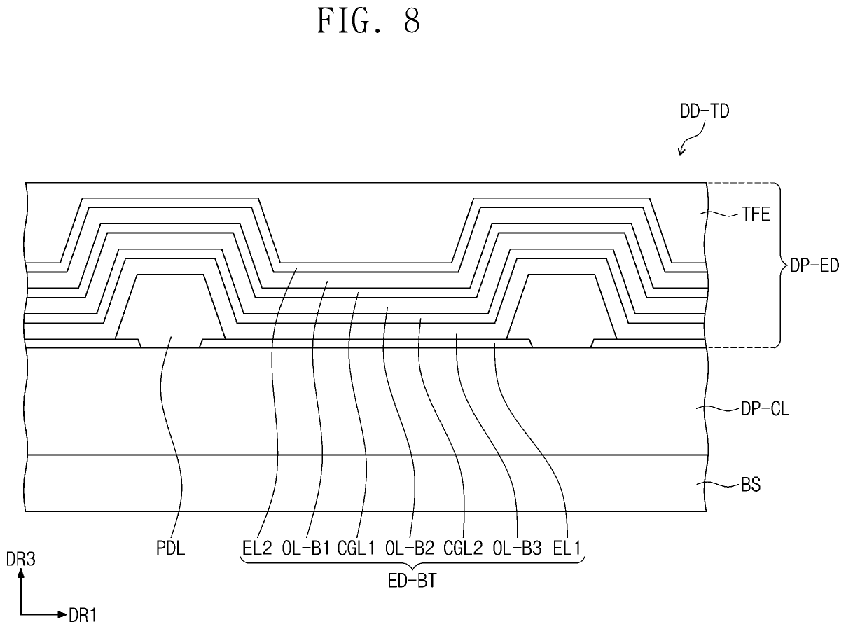

FIG. 8 is a schematic cross-sectional view of a portion of a display apparatus according to an embodiment. In a display apparatus DD-TD according to an embodiment, the light emitting device ED-BT may include light emitting structures OL-B1, OL-B2, and OL-B3. The light emitting device ED-BT may include a first electrode EL1 and an oppositely disposed second electrode EL2, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7), and a hole transport region HTR and an electron transport region ETR disposed with the emission layer EML (FIG. 7) therebetween.

For example, the light emitting device ED-BT included in the display apparatus DD-TD may be a light emitting device having a tandem structure and including multiple emission layers.

In an embodiment shown in FIG. 8, light emitted from the light emitting structures OL-B1, OL-B2, and OL-B3 may each be blue light. However, embodiments are not limited thereto, and the wavelength regions of the light emitted from the light emitting structures OL-B1, OL-B2, and OL-B3 may be different from each other. For example, the light emitting device ED-BT that include the light emitting structures OL-B1, OL-B2, and OL-B3, which emit light having wavelength regions that are different from each other, may emit white light.

Charge generating layers CGL1 and CGL2 may each be disposed between neighboring light emitting structures among OL-B1, OL-B2, and OL-B3. Charge generating layers CGL1 and CGL2 may each independently include a p-type charge generating layer and/or an n-type charge generating layer.

In an embodiment, at least one of the light emitting structures OL-B1, OL-B2, and OL-B3 included in the display apparatus DD-TD may include the fused polycyclic compound according to an embodiment as described herein. For example, at least one of the emission layers included in the light emitting device ED-BT may include the fused polycyclic compound.

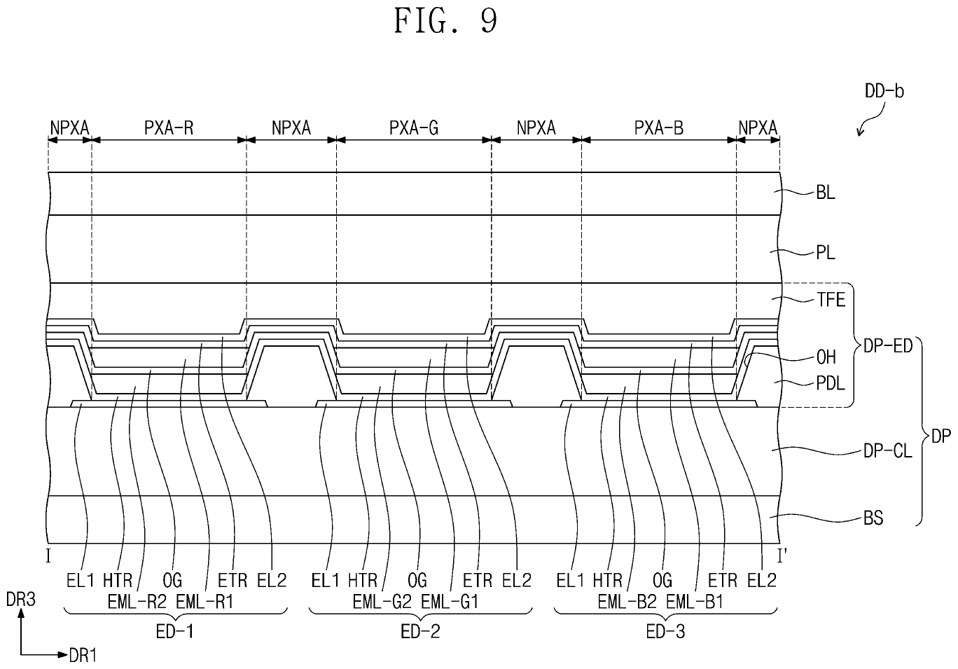

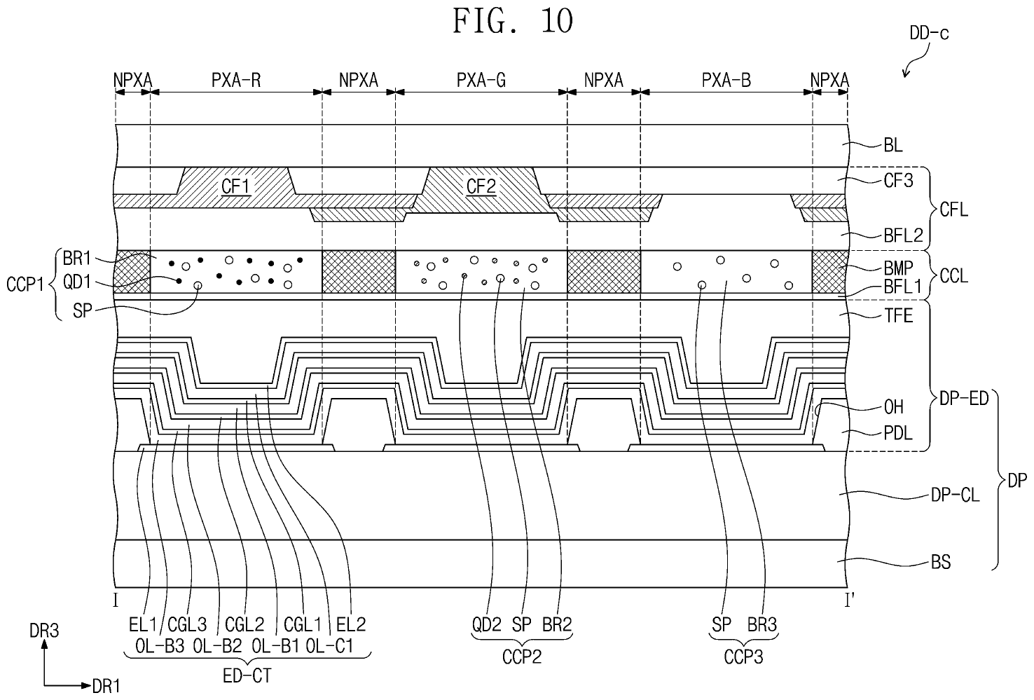

FIG. 9 is a schematic cross-sectional view of a display apparatus according to an embodiment. FIG. 10 is a schematic cross-sectional view of a display apparatus according to an embodiment.

Referring to FIG. 9, a display apparatus DD-b according to an embodiment may include light emitting devices ED-1, ED-2, and ED-3, which may each be formed by stacking two emission layers. In comparison to the display apparatus DD shown in FIG. 2, the embodiment shown in FIG. 9 is different at least in that the first to third light emitting devices ED-1, ED-2, and ED-3 each include two emission layers that are stacked in a thickness direction. In each of the first to third light emitting devices ED-1, ED-2, and ED-3, the two emission layers may emit light in a same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. The third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer for all of the first to third light emitting devices ED-1, ED-2, and ED-3. However, embodiments are not limited thereto, and the emission auxiliary part OG may be provided by being patterned in openings OH defined in a pixel definition layer PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting device ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. For example, the second light emitting device ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. For example, the third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on a display device layer DP-ED. The optical auxiliary layer PL may include a polarization layer. The optical auxiliary layer PL may be disposed on a display panel DP and may control light reflected at the display panel DP from an external light. Although not shown in the drawings, in an embodiment, the optical auxiliary layer PL may be omitted from the display apparatus DD-b.

At least one emission layer included in the display apparatus DD-b shown in FIG. 9 may include the fused polycyclic compound according to an embodiment as described herein. For example, in an embodiment, at least one of a first blue emission layer EML-B1 and a second blue emission layer EML-B2 may include the fused polycyclic compound.

In contrast to FIG. 8 and FIG. 9, FIG. 10 shows a display apparatus DD-c that is different at least in that it includes four light emitting structures OL-B1, OL-B2, OL-B3, and OL-C1. A light emitting device ED-CT may include a first electrode EL1, an oppositely disposed second electrode EL2, and first to fourth light emitting structures OL-B1, OL-B2, OL-B3, and OL-C1 that are stacked in a thickness direction between the first electrode EL1 and the second electrode EL2. Charge generating layers CGL1, CGL2, and CGL3 may be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelengths from each other.

Charge generating layers CGL1, CGL2, and CGL3 which are disposed between neighboring light emitting structures OL-B1, OL-B2, OL-B3, and OL-C1 may each independently include a p-type charge generating layer and/or an n-type charge generating layer.

In the display apparatus DD-c, at least one of the light emitting structures OL-B1, OL-B2, OL-B3, and OL-C1 may each independently include the fused polycyclic compound according to an embodiment as described herein. For example, in an embodiment, at least one of the first to third light emitting structures OL-B1, OL-B2, and OL-B3 may each independently include the fused polycyclic compound.

The light emitting device ED according to an embodiment may include the fused polycyclic compound represented by Formula 1 in at least one functional layer disposed between a first electrode EL1 and a second electrode EL2, thereby exhibiting excellent emission efficiency and improved lifetime characteristics. For example, the emission layer EML of the light emitting device ED may include the fused polycyclic compound, and the light emitting device ED may show long lifetime characteristics.

In an embodiment, an electronic apparatus may include a display apparatus including multiple light emitting devices and a control part which controls the display apparatus. The electronic apparatus may be an apparatus that is activated according to electrical signals. The electronic apparatus may include display apparatuses according to various embodiments. For example, the electronic apparatus may be not only a large-size electronic apparatus such as televisions, monitors, outside billboards, or personal computers, but the electronic apparatus may also be a small- or medium-size electronic apparatus such as laptop computers, personal digital terminals, display apparatuses for automobiles, game consoles, portable electronic devices, or cameras.

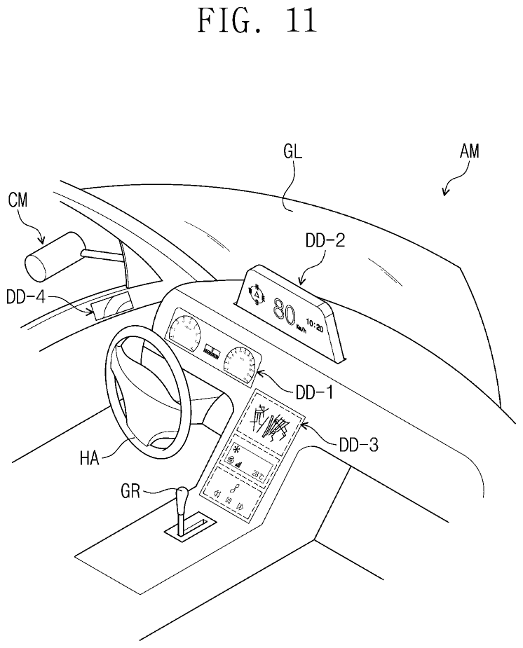

FIG. 11 is a schematic perspective view of a vehicle AM in which first to fourth display apparatuses DD-1, DD-2, DD-3, and DD-4 are disposed. At least one of the first to fourth display apparatuses DD-1, DD-2, DD-3, and DD-4 may have a structure according to one of the display apparatuses DD, DD-TD, DD-a, DD-b, and DD-c as described in reference to FIGS. 1, 2, and 7 to 10.

In FIG. 11, a vehicle AM is shown as an automobile, but this is only an example, and the first to fourth display apparatuses DD-1, DD-2, DD-3, and DD-4 may be disposed in other transport means such as bicycles, motorcycles, trains, ships, and airplanes. At least one of the first to fourth display apparatuses DD-1, DD-2, DD-3, and DD-4 may each independently have a structure according to one of the display apparatuses DD, DD-TD, DD-a, DD-b, and DD-c may be included in various electronic apparatuses, such as personal computers, laptop computers, personal digital terminals, game consoles, portable electronic devices, televisions, monitors, external billboards, or the like. However, the aforementioned electronic apparatuses are only listed as examples, and the display apparatus may be introduced in other electronic devices.

At least one of the first to fourth display apparatuses DD-1, DD-2, DD-3, and DD-4 may include a light emitting device ED according to an embodiment as described with reference to FIG. 3 to FIG. 6. The light emitting device ED may include the heterocyclic compound according to an embodiment. At least one of the first to fourth display apparatuses DD-1, DD-2, DD-3, and DD-4 may include a light emitting device ED that includes a heterocyclic compound according to an embodiment, and may thus show improved display lifetime.

Referring to FIG. 11, a vehicle AM may include a steering wheel HA and a gearshift GR for operating the vehicle AM. The vehicle AM may include a front window GL disposed so as to face a driver.

A first display apparatus DD-1 may be disposed in a first region overlapping the steering wheel HA. For example, the first display apparatus DD-1 may be a digital cluster that displays first information of the vehicle AM. The first information may include a first gauge that displays a driving speed of the vehicle AM, a second gauge that displays the number of revolutions of an engine (for example, as revolutions per minute (RPM)), and images that display the fuel level. The first gauge and the second gauge may each be represented by digital images.

A second display apparatus DD-2 may be disposed in a second region facing a driver's seat and overlapping the front window GL. The driver's seat may be a seat where the steering wheel HA is disposed. For example, the second display apparatus DD-2 may be a head up display (HUD) that displays second information of the vehicle AM. The second display apparatus DD-2 may be optically transparent. The second information may include digital numbers that indicate a driving speed of the vehicle AM and may further include information such as the current time. Although not shown in the drawings, in an embodiment, the second information of the second display apparatus DD-2 may be projected and displayed on the front window GL.

A third display apparatus DD-3 may be disposed in a third region adjacent to the gearshift GR. For example, the third display apparatus DD-3 may be a center information display (CID) that is disposed between a driver's seat and a passenger seat to display third information of the vehicle AM. The passenger seat may be a seat that is spaced apart from the driver's seat with the gearshift GR disposed therebetween. The third information may include information about road conditions (for example, navigation information), information about playing music or radio, information about playing a dynamic image (for example, video), information about the temperature in the vehicle AM, or the like.

A fourth display apparatus DD-4 may be disposed in a fourth region that is spaced apart from the steering wheel HA and the gearshift GR and is adjacent to a side of the vehicle AM. For example, the fourth display apparatus DD-4 may be a digital side view mirror that displays fourth information. The fourth display apparatus DD-4 may display an image of the exterior of the vehicle AM that is taken by a camera module CM disposed outside of the vehicle AM. The fourth information may include an external image of the vehicle AM.

The first to fourth information are described herein only as examples, and the first to fourth display apparatuses DD-1, DD-2, DD-3, and DD-4 may further display information about the interior and exterior of the vehicle AM. The first to fourth information may include information that are different from each other. However, embodiments are not limited thereto, and a portion of the first to fourth information may include a same information.

Hereinafter, a fused polycyclic compound according to an embodiment and a light emitting device according to an embodiment will be explained in detail with reference to the Examples and the Comparative Examples. The Examples described below are only provided as illustrations to assist in understanding the disclosure, and the scope thereof is not limited thereto.

### Examples

### 1. Synthesis of Fused Polycyclic Compound

A synthesis method of the fused polycyclic compound according to an embodiment will be explained in detail by illustrating the synthesis methods of Compounds 1, 98, 110, 140, and 169. The synthesis methods of the fused polycyclic compounds as explained below are only provided as examples, and the synthesis method of the fused polycyclic compound is not limited to the Examples below.

### (1) Synthesis of Compound 1

### (Synthesis of Intermediate 1-a)

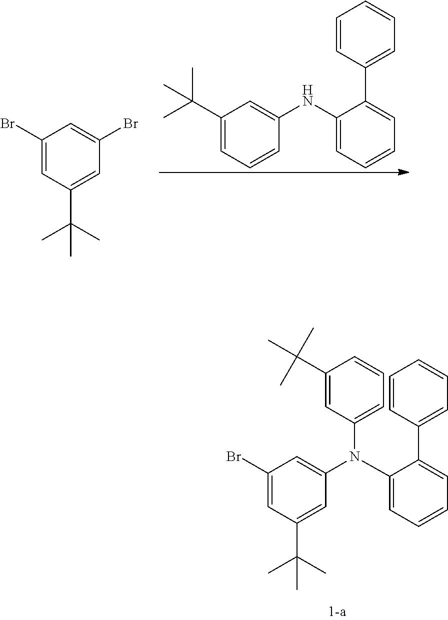

Under an argon atmosphere, to a 2 L flask, N-(3-(tert-butyl)phenyl)-[1,1′-biphenyl]-2-amine (15.1 g, 50 mmol), 1,3-dibromo-5-(tert-butyl)benzene (21.9 g, 75 mmol), pd₂dba₃ (2.3 g, 2.5 mmol), tris-tert-butyl phosphine (2.3 mL, 5 mmol), and sodium tert-butoxide (9.6 g, 100 mmol) were added and dissolved in 750 mL of toluene, and the reaction solution was stirred at about 80 degrees for about 12 hours. After cooling, water (500 mL) was added thereto, the resultant was extracted, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solutions to obtain Intermediate 1-a (white solid, 20.5 g, 40 mmol, 80%). Through ESI-LCMS, the compound thus obtained was identified as Intermediate 1-a.

ESI-LCMS: [M]⁺: C₃₂H₃₄BrN. 513.19.

### (Synthesis of Intermediate 1-b)

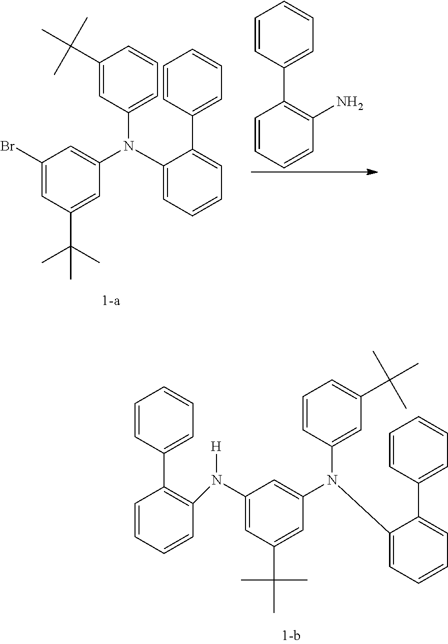

Under an argon atmosphere, to a 1 L flask, Intermediate 1-a (20.5 g, 40 mmol), [1,1′-biphenyl]-2-amine (8.1 g, 48 mmol), pd₂dba₃ (1.8 g, 2.0 mmol), tris-tert-butyl phosphine (1.9 mL, 4.0 mmol), and sodium tert-butoxide (7.7 g, 80 mmol) were added and dissolved in 400 mL of o-xylene, and the reaction solution was stirred at about 140 degrees for about 72 hours. After cooling, water (600 mL) and ethyl acetate (400 mL) were added, the resultant was extracted, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 1-b (white solid, 19.7 g, 32.8 mmol, 82%). Through ESI-LCMS, the compound thus obtained was identified as Intermediate 1-b.

ESI-LCMS: [M]⁺: C₄₄H₄₄N₂. 600.35.

### (Synthesis of Intermediate 1-c)

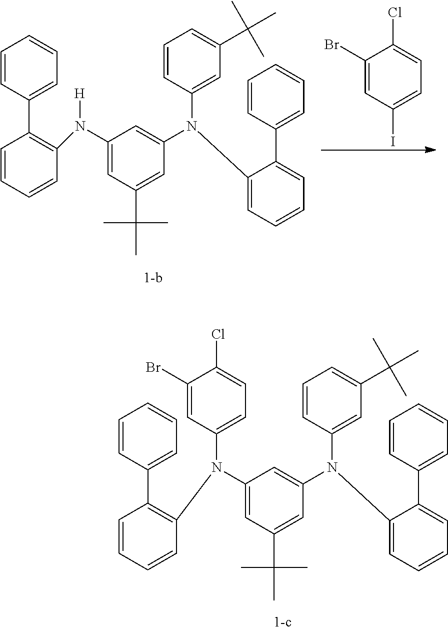 [SMILES: CC(C)(C)c1cccc(N(c2cc(Nc3ccccc3-c3ccccc3)cc(C(C)(C)C)c2)c2ccccc2-c2ccccc2)c1 ; Clc1ccc(I)cc1Br ; CC(C)(C)c1cccc(N(c2cc(N(c3ccc(Cl)c(Br)c3)c3ccccc3-c3ccccc3)cc(C(C)(C)C)c2)c2ccccc2-c2ccccc2)c1]

Under an argon atmosphere, to a 1 L flask, Intermediate 1-b (19.7 g, 32.8 mmol), 2-bromo-1-chloro-4-iodobenzene (12.5 g, 39.4 mmol), pd₂dba₃ (1.5 g, 1.6 mmol), tris-tert-butyl phosphine (1.5 mL, 3.3 mmol), and sodium tert-butoxide (6.3 g, 65.6 mmol) were added and dissolved in 400 mL of toluene, and the reaction solution was stirred at about 100 degrees for about 12 hours. After cooling, water (500 mL) was added, the resultant was extracted, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 1-c (white solid, 20.2 g, 25.6 mmol, 78%). Through ESI-LCMS, the compound thus obtained was identified as Intermediate 1-c.

ESI-LCMS: [M]⁺: C₅₀H₄₆BrClN₂. 790.25.

### (Synthesis of Intermediate 1-d)

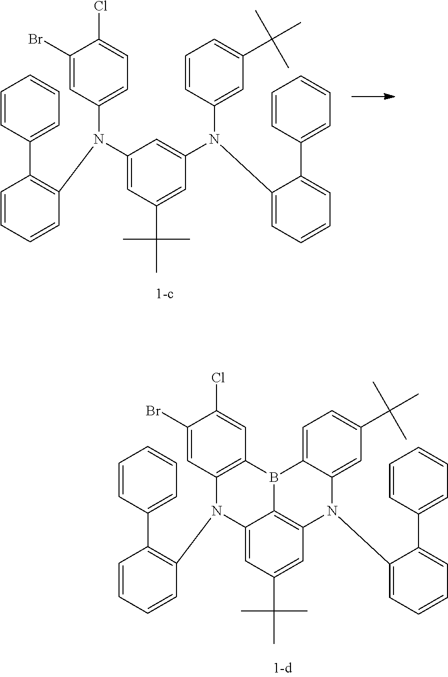 [SMILES: CC(C)(C)c1cccc(N(c2cc(N(c3ccc(Cl)c(Br)c3)c3ccccc3-c3ccccc3)cc(C(C)(C)C)c2)c2ccccc2-c2ccccc2)c1 ; CC(C)(C)c1ccc2c(c1)N(c1ccccc1-c1ccccc1)c1cc(C(C)(C)C)cc3c1B2c1cc(Cl)c(Br)cc1N3c1ccccc1-c1ccccc1]

Under an argon atmosphere, to a 500 mL flask, Intermediate 1-c (20.2 g, 25.6 mmol) was added and dissolved in 200 mL of o-dichlorobenzene, and cooled using ice-water. BBr₃ (5 equiv.) was slowly added thereto, and the reaction solution was stirred at about 180 degrees for about 12 hours. After cooling, triethylamine (5 equiv.) was added to quench the reaction, the resultant was extracted with water and CH₂Cl₂, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 1-d (yellow solid, 6.7 g, 8.5 mmol, 33%). Through ESI-LCMS, the compound thus obtained was identified as Intermediate 1-d.

ESI-LCMS: [M]⁺: C₅₀H₄₃BBrClN₂. 798.24.

### (Synthesis of Intermediate 1-e)

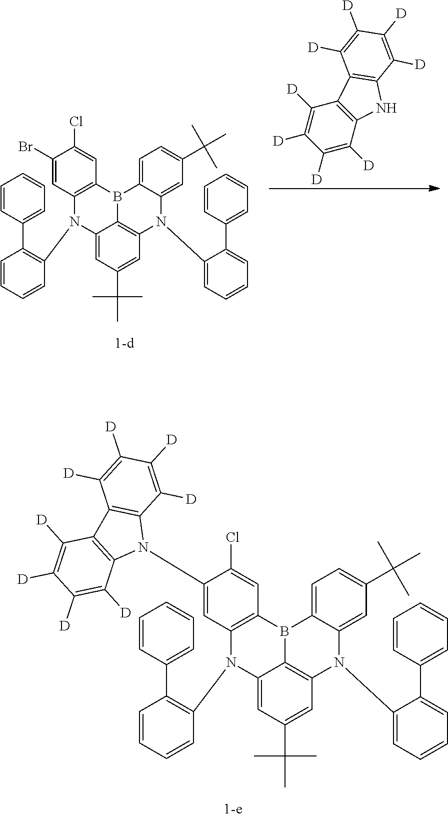 [SMILES: CC(C)(C)c1ccc2c(c1)N(c1ccccc1-c1ccccc1)c1cc(C(C)(C)C)cc3c1B2c1cc(Cl)c(Br)cc1N3c1ccccc1-c1ccccc1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1cc2c(cc1Cl)B1c3ccc(C(C)(C)C)cc3N(c3ccccc3-c3ccccc3)c3cc(C(C)(C)C)cc(c31)N2c1ccccc1-c1ccccc1]

Under an argon atmosphere, to a 250 mL flask, Intermediate 1-d (6.7 g, 8.5 mmol), 9H-carbazole-1,2,3,4,5,6,7,8-d8 (1.8 g, 10.2 mmol), pd₂dba₃ (0.39 g, 0.43 mmol), tris-tert-butyl phosphine (0.4 mL, 0.9 mmol) and sodium tert-butoxide (2.5 g, 25.5 mmol) were added and dissolved in 100 mL of o-xylene, and the reaction solution was stirred at about 150 degrees for about 12 hours. After cooling, the resultant was filtered using a celite filter, and the solvent in the filtrate solution was removed under a reduced pressure. The solid thus obtained was separated and purified by column chromatography using silica gel by using CH₂Cl₂ and hexane as developing solvents to obtain Intermediate 1-e (yellow solid, 5.4 g, 6.04 mmol, 71%). Through ESI-LCMS, the compound thus obtained was identified as Intermediate 1-e.

ESI-LCMS: [M]⁺: C₆₂H₄₃D₈BClN₃. 891.44.

### (Synthesis of Compound 1)

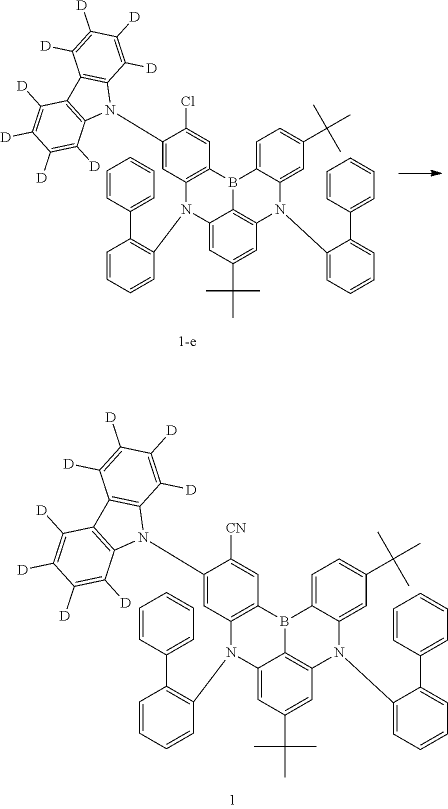 [SMILES: [2H]c1c([2H])c([2H])c2c(c1[2H])c1c([2H])c([2H])c([2H])c([2H])c1n2-c1cc2c(cc1Cl)B1c3ccc(C(C)(C)C)cc3N(c3ccccc3-c3ccccc3)c3cc(C(C)(C)C)cc(c31)N2c1ccccc1-c1ccccc1 ; [2H]c1c([2H])c([2H])c2c(c1[2H])c1c([2H])c([2H])c([2H])c([2H])c1n2-c1cc2c(cc1C#N)B1c3ccc(C(C)(C)C)cc3N(c3ccccc3-c3ccccc3)c3cc(C(C)(C)C)cc(c31)N2c1ccccc1-c1ccccc1]

Under an argon atmosphere, in a 1 L flask, Intermediate 1-e (5.4 g, 6.04 mmol), dichlorobis[di-tert-butyl(p-dimethylaminophenyl)phosphino]palladium(II) (0.43 g, 0.6 mmol), potassium hexacyanoferrate(II) (8.9 g, 24 mmol) and sodium carbonate (1.0 g, 9.7 mmol) were dissolved in 60 mL of N,N-dimethylacetamide, and the reaction solution was stirred at about 140 degrees for about 24 hours. 500 mL of toluene was added at about 0° C. for dilution, and the same quantity of water was added for quenching the reaction. The resultant was extracted with toluene, and organic layers were collected, dried over MgSO₄, and filtered. The solvent was removed under a reduced pressure and the solid thus obtained was separated and purified by column chromatography using silica gel by using ethyl acetate and hexane as developing solvents to obtain Compound 1 (yellow solid, 2.1 g, 2.4 mmol, 39%). Through ESI-LCMS, the compound thus obtained was identified as Compound 1.

ESI-LCMS: [M]⁺: C₆₃H₄₃D₈BN₄. 882.47.

### (2) Synthesis of Compound 98

### (Synthesis of Intermediate 98-a)

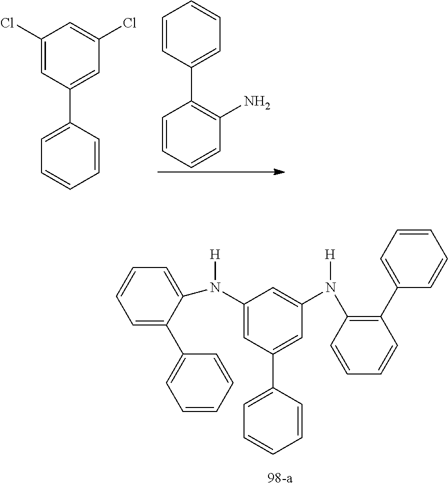

Under an argon atmosphere, to a 2 L flask, [1,1′-biphenyl]-2-amine (18.6 g, 110 mmol), 3,5-dichloro-1,1′-biphenyl (11.2 g, 50 mmol), pd₂dba₃ (2.3 g, 2.5 mmol), tris-tert-butyl phosphine 50% in toluene (2.3 mL, 5 mmol), and sodium tert-butoxide (14.4 g, 150 mmol) were added and dissolved in 1 L of toluene, and the reaction solution was stirred at about 100 degrees for about 12 hours. After cooling, water (500 mL) was added, the resultant was extracted, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 98-a (white solid, 20.0 g, 41 mmol, 82%). Through ESI-LCMS, the compound thus obtained was identified as Intermediate 98-a.

ESI-LCMS: [M]⁺: C₃₆H₂₈N₂. 488.23.

### (Synthesis of Intermediate 98-b)

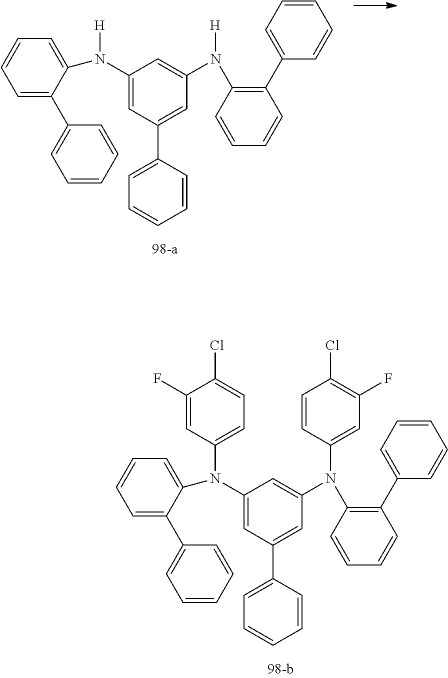 [SMILES: c1ccc(-c2cc(Nc3ccccc3-c3ccccc3)cc(Nc3ccccc3-c3ccccc3)c2)cc1 ; Fc1cc(N(c2cc(-c3ccccc3)cc(N(c3ccc(Cl)c(F)c3)c3ccccc3-c3ccccc3)c2)c2ccccc2-c2ccccc2)ccc1Cl]

Under an argon atmosphere, to a 2 L flask, Intermediate 98-a (20.0 g, 41 mmol), 1-chloro-2-fluoro-4-iodobenzene (23.1 g, 90.2 mmol), pd₂dba₃ (1.9 g, 2.1 mmol), tris-tert-butyl phosphine 50% in toluene (1.9 mL, 4.1 mmol), and sodium tert-butoxide (11.8 g, 123 mmol) were added and dissolved in 1 L of toluene, and the reaction solution was stirred at about 100 degrees for about 12 hours. After cooling, water (500 mL) was added, the resultant was extracted, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 98-b (white solid, 24.2 g, 32.4 mmol, 79%). Through ESI-LCMS, the compound thus obtained was identified as Intermediate 98-b.

ESI-LCMS: [M]⁺: C₄₈H₃₂Cl₂F₂N₂. 744.19.

### (Synthesis of Intermediate 98-c)

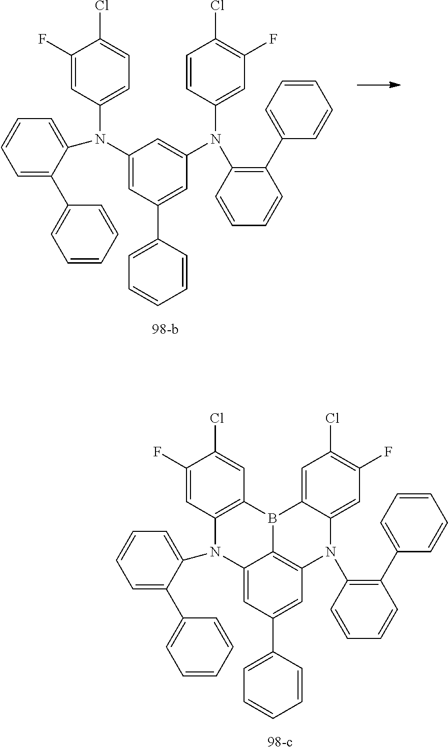 [SMILES: Fc1cc(N(c2cc(-c3ccccc3)cc(N(c3ccc(Cl)c(F)c3)c3ccccc3-c3ccccc3)c2)c2ccccc2-c2ccccc2)ccc1Cl ; Fc1cc2c(cc1Cl)B1c3cc(Cl)c(F)cc3N(c3ccccc3-c3ccccc3)c3cc(-c4ccccc4)cc(c31)N2c1ccccc1-c1ccccc1]

Under an argon atmosphere, to a 500 mL flask, Intermediate 98-b (24.2 g, 32.4 mmol) was dissolved in 250 mL of o-dichlorobenzene, and cooled using ice-water. BBr₃ (5 equiv.) was slowly added thereto, and the reaction solution was stirred at about 180 degrees for about 12 hours. After cooling, triethylamine (5 equiv.) was added to quench the reaction, the resultant was extracted with water and CH₂Cl₂, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 98-c (yellow solid, 9.3 g, 12.3 mmol, 38%). Through ESI-LCMS, the compound thus obtained was identified as Intermediate 98-c.

ESI-LCMS: [M]⁺: C₄₈H₂₉BCl₂F₂N₂. 752.18.

### (Synthesis of Intermediate 98-d)

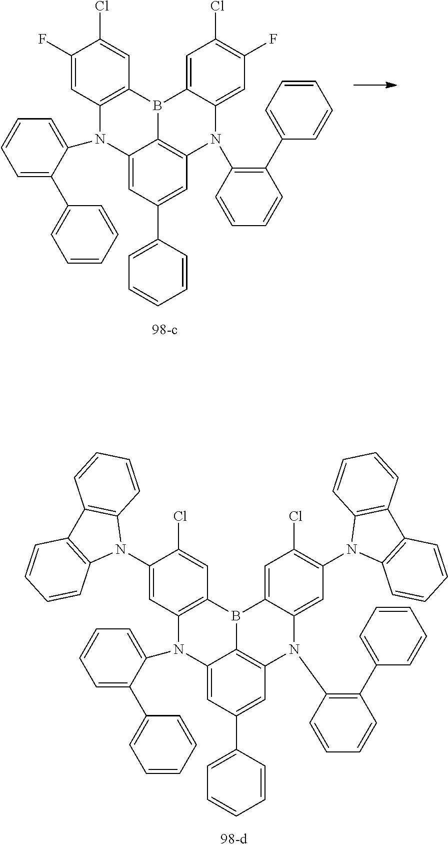 [SMILES: Fc1cc2c(cc1Cl)B1c3cc(Cl)c(F)cc3N(c3ccccc3-c3ccccc3)c3cc(-c4ccccc4)cc(c31)N2c1ccccc1-c1ccccc1 ; Clc1cc2c(cc1-n1c3ccccc3c3ccccc31)N(c1ccccc1-c1ccccc1)c1cc(-c3ccccc3)cc3c1B2c1cc(Cl)c(-n2c4ccccc4c4ccccc42)cc1N3c1ccccc1-c1ccccc1]

Under an argon atmosphere, to a 500 mL flask, Intermediate 98-c (9.3 g, 12.3 mmol), 9H-carbazole (5.2 g, 30.8 mmol) and potassium carbonate (5.1 g, 36.9 mmol) were added and dissolved in 200 mL of DMF, and the reaction solution was stirred at about 140 degrees for about 24 hours. The solvent was removed under a reduced pressure, water was added, and the resultant was extracted. Organic layers were collected, dried over MgSO₄, and filtered. The solvent was removed under a reduced pressure from the filtrate solution. The solid thus obtained was separated and purified by column chromatography using silica gel by using CH₂Cl₂ and hexane as developing solvents to obtain Intermediate 98-d (yellow solid, 9.3 g, 8.9 mmol, 72%). Through ESI-LCMS, the compound thus obtained was identified as Intermediate 98-d.

ESI-LCMS: [M]⁺: C₇₂H₄₅BCl₂N₄. 1046.31.

### (Synthesis of Compound 98)

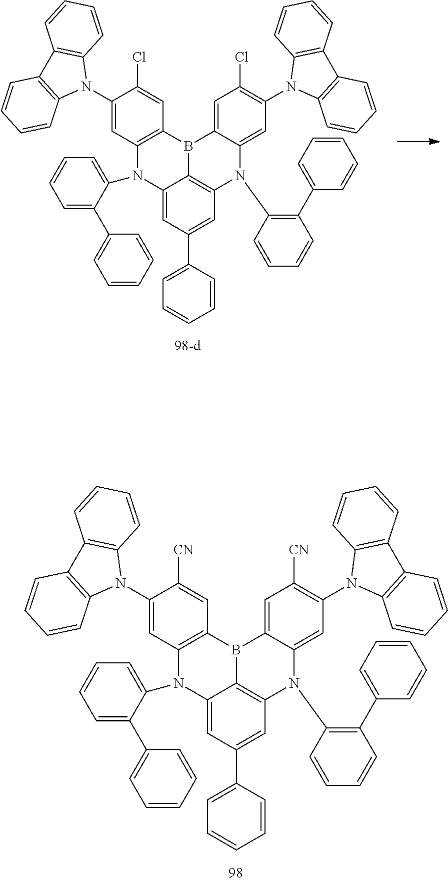 [SMILES: Clc1cc2c(cc1-n1c3ccccc3c3ccccc31)N(c1ccccc1-c1ccccc1)c1cc(-c3ccccc3)cc3c1B2c1cc(Cl)c(-n2c4ccccc4c4ccccc42)cc1N3c1ccccc1-c1ccccc1 ; N#Cc1cc2c(cc1-n1c3ccccc3c3ccccc31)N(c1ccccc1-c1ccccc1)c1cc(-c3ccccc3)cc3c1B2c1cc(C#N)c(-n2c4ccccc4c4ccccc42)cc1N3c1ccccc1-c1ccccc1]

Under an argon atmosphere, in a 1 L flask, Intermediate 98-d (9.3 g, 8.9 mmol), dichlorobis[di-tert-butyl(p-dimethylaminophenyl)phosphino]palladium(II) (0.64 g, 0.9 mmol), potassium hexacyanoferrate(II) (11.7 g, 35.6 mmol) and sodium carbonate (1.9 g, 17.8 mmol) were dissolved in 100 mL of N,N-dimethylacetamide, and the reaction solution was stirred at about 140 degrees for about 24 hours. 500 mL of toluene was added at about 0° C. for dilution, and the same quantity of water was added for quenching the reaction. The resultant was extracted with toluene, and organic layers were collected, dried over MgSO₄, and filtered. The solvent was removed under a reduced pressure and the solid thus obtained was separated and purified by column chromatography using silica gel by using ethyl acetate and hexane as developing solvents to obtain Compound 98 (yellow solid, 3.8 g, 3.6 mmol, 41%). Through ESI-LCMS, the compound thus obtained was identified as Compound 98.

ESI-LCMS: [M]⁺: C₇₄H₄₅BN₆. 1028.38.

### (3) Synthesis of Compound 110

### (Synthesis of Intermediate 110-a)

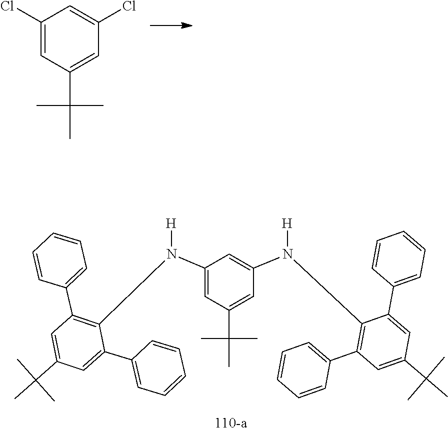 [SMILES: CC(C)(C)c1cc(Cl)cc(Cl)c1 ; CC(C)(C)c1cc(Nc2c(-c3ccccc3)cc(C(C)(C)C)cc2-c2ccccc2)cc(Nc2c(-c3ccccc3)cc(C(C)(C)C)cc2-c2ccccc2)c1]

Under an argon atmosphere, to a 2 L flask, 1-(tert-butyl)-3,5-dichlorobenzene (10.0 g, 49.2 mmol), 5′-(tert-butyl)-[1,1′:3′,1″-terphenyl]-2′-amine (31.1 g, 103.3 mmol), pd₂dba₃ (2.3 g, 2.5 mmol), tris-tert-butyl phosphine 50% in toluene (2.3 mL, 4.9 mmol), and sodium tert-butoxide (14.2 g, 147.6 mmol) were added and dissolved in 1 L of toluene, and the reaction solution was stirred at about 100 degrees for about 12 hours. After cooling, water (500 mL) was added, the resultant was extracted, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 110-a (white solid, 28.9 g, 39.4 mmol, 80%). Through ESI-LCMS, the compound thus obtained was identified as Intermediate 110-a.

ESI-LCMS: [M]⁺: C₅₄H₅₆N₂. 732.44.

### (Synthesis of Intermediate 110-b)

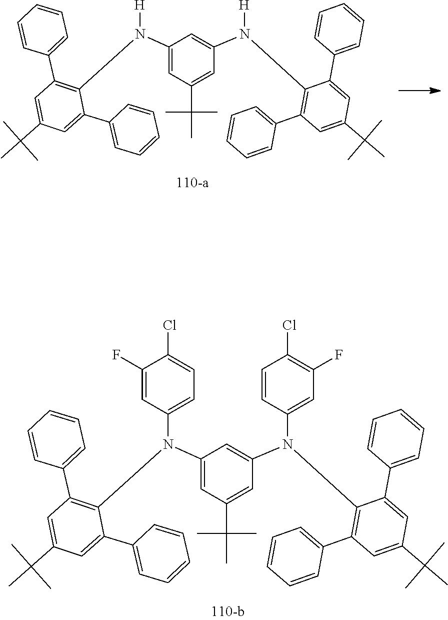

Under an argon atmosphere, to a 2 L flask, Intermediate 110-a (28.9 g, 39.4 mmol), 1-chloro-2-fluoro-4-iodobenzene (50.5 g, 197 mmol), pd₂dba₃ (1.8 g, 2.0 mmol), tris-tert-butyl phosphine 50% in toluene (1.8 mL, 3.9 mmol), and sodium tert-butoxide (11.4 g, 118 mmol) were added and dissolved in 1 L of xylene, and the reaction solution was stirred at about 150 degrees for about 12 hours. After cooling, water (500 mL) was added, the resultant was extracted, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 110-b (white solid, 22.2 g, 22.5 mmol, 57%). Through ESI-LCMS, the compound thus obtained was identified as Intermediate 110-b.

ESI-LCMS: [M]⁺: C₆₆H₆₀C₂F₂N₂. 988.41.

### (Synthesis of Intermediate 110-c)

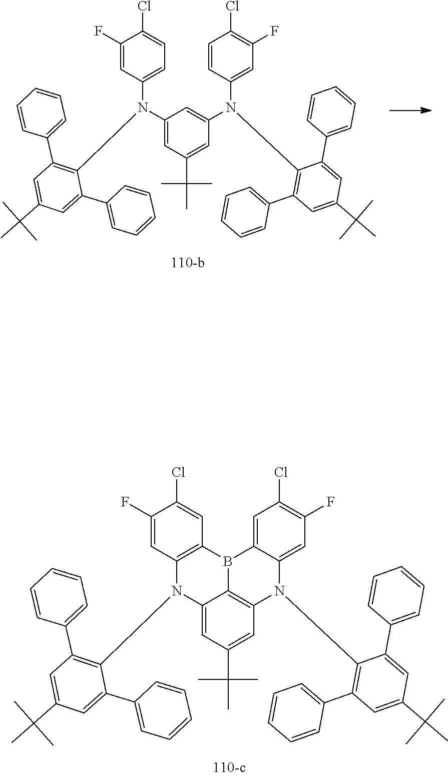

Under an argon atmosphere, to a 500 mL flask, Intermediate 110-b (22.2 g, 22.5 mmol) was added and dissolved in 220 mL of o-dichlorobenzene, and cooled using ice-water. BBr₃ (5 equiv.) was slowly added thereto, and the reaction solution was stirred at about 180 degrees for about 12 hours. After cooling, triethylamine (5 equiv.) was added to quench the reaction, the resultant was extracted with water and CH₂Cl₂, and organic layers were collected, dried over MgSO₄, and filtered. The solvent in the filtrate solution was removed under a reduced pressure, and the solid thus obtained was separated and purified by column chromatography using silica gel by using CH₂Cl₂ and hexane as developing solvents to obtain Intermediate 110-c (yellow solid, 9.0 g, 9.0 mmol, 40%). Through ESI-LCMS, the compound thus obtained was identified as Intermediate 110-c.

ESI-LCMS: [M]⁺: C₆₆H₅₇BCl₂F₂N₂. 996.40.

### (Synthesis of Intermediate 110-d)

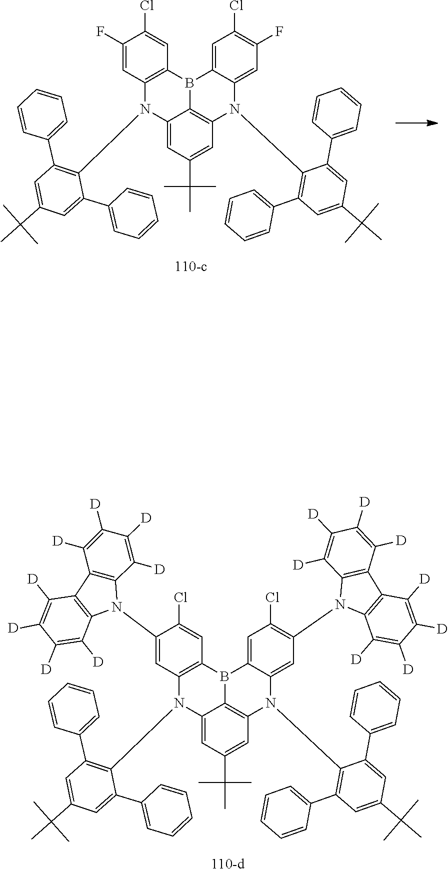 [SMILES: CC(C)(C)c1cc(-c2ccccc2)c(N2c3cc(F)c(Cl)cc3B3c4cc(Cl)c(F)cc4N(c4c(-c5ccccc5)cc(C(C)(C)C)cc4-c4ccccc4)c4cc(C(C)(C)C)cc2c43)c(-c2ccccc2)c1 ; [2H]c1c([2H])c([2H])c2c(c1[2H])c1c([2H])c([2H])c([2H])c([2H])c1n2-c1cc2c(cc1Cl)B1c3cc(Cl)c(-n4c5c([2H])c([2H])c([2H])c([2H])c5c5c([2H])c([2H])c([2H])c([2H])c54)cc3N(c3c(-c4ccccc4)cc(C(C)(C)C)cc3-c3ccccc3)c3cc(C(C)(C)C)cc(c31)N2c1c(-c2ccccc2)cc(C(C)(C)C)cc1-c1ccccc1]

Under an argon atmosphere, to a 500 mL flask, Intermediate 110-c (9.0 g, 9.0 mmol), 9H-carbazole-1,2,3,4,5,6,7,8-d8 (3.9 g, 22.5 mmol) and potassium carbonate (3.7 g, 27.0 mmol) were added and dissolved in 100 mL of DMF, and the reaction solution was stirred at about 140 degrees for about 24 hours. The solvent was removed under a reduced pressure, water was added, and the resultant was extracted. Organic layers were collected, dried over MgSO₄, and filtered. The solvent was removed under a reduced pressure from the filtrate solution. The solid thus obtained was separated and purified by column chromatography using silica gel by using CH₂Cl₂ and hexane as developing solvents to obtain Intermediate 110-d (yellow solid, 7.7 g, 5.9 mmol, 65%). Through ESI-LCMS, the compound thus obtained was identified as Intermediate 110-d.

ESI-LCMS: [M]⁺: C₉₀H₅₇D₁₆BCl₂N₄. 1307.63.

### (Synthesis of Compound 110)

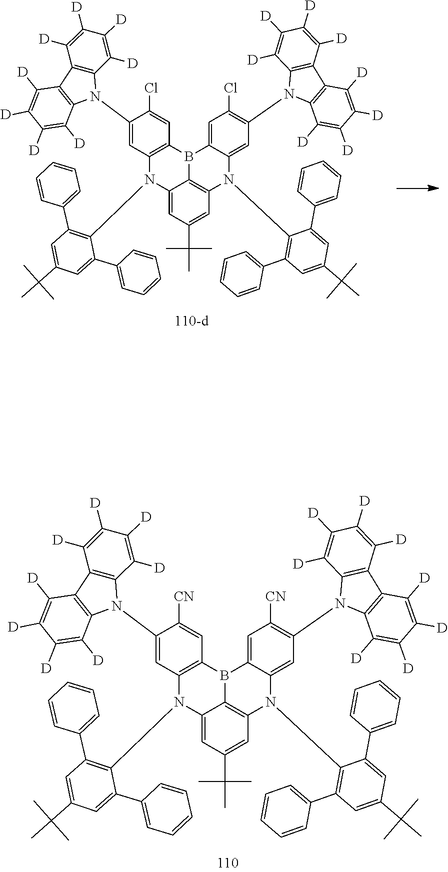

Under an argon atmosphere, in a 1 L flask, Intermediate 110-d (7.7 g, 5.9 mmol), dichlorobis[di-tert-butyl(p-dimethylaminophenyl)phosphino]palladium(II) (0.42 g, 0.6 mmol), potassium hexacyanoferrate(II) (7.8 g, 23.6 mmol) and sodium carbonate (1.3 g, 11.8 mmol) were dissolved in 100 mL of N,N-dimethylacetamide, and the reaction solution was stirred at about 140 degrees for about 24 hours. 500 mL of toluene was added at about 0° C. for dilution, and the same quantity of water was added for quenching the reaction. The resultant was extracted with toluene, and organic layers were collected, dried over MgSO₄, and filtered. The solvent was removed under a reduced pressure and the solid thus obtained was separated and purified by column chromatography using silica gel by using ethyl acetate and hexane as developing solvents to obtain Compound 110 (yellow solid, 2.5 g, 1.9 mmol, 33%). Through ESI-LCMS, the compound thus obtained was identified as Compound 110.

ESI-LCMS: [M]⁺: C₉₂H₅₇D₁₆BN₆. 1289.70.

### (4) Synthesis of Compound 140

### (Synthesis of Intermediate 140-a)

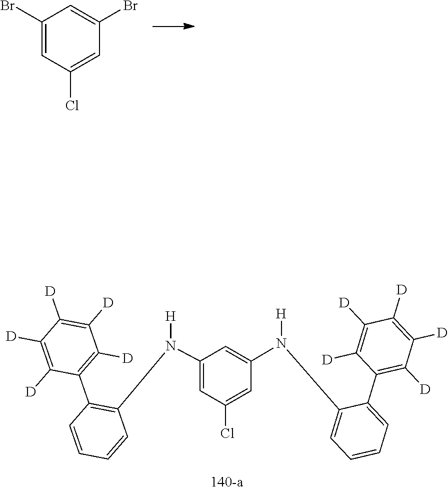 [SMILES: Clc1cc(Br)cc(Br)c1 ; [2H]c1c([2H])c([2H])c(-c2ccccc2Nc2cc(Cl)cc(Nc3ccccc3-c3c([2H])c([2H])c([2H])c([2H])c3[2H])c2)c([2H])c1[2H]]

Under an argon atmosphere, to a 2 L flask, 1,3-dibromo-5-chlorobenzene (10.0 g, 37.0 mmol), [1,1′-biphenyl]-2′,3′,4′,5′,6′-d5-2-amine (12.9 g, 74.0 mmol), pd₂dba₃ (1.7 g, 1.9 mmol), tris-tert-butyl phosphine 50% in toluene (1.7 mL, 3.7 mmol), and sodium tert-butoxide (10.7 g, 111 mmol) were added and dissolved in 1 L of toluene, and the reaction solution was stirred at about 80 degrees for about 12 hours. After cooling, water (500 mL) was added, the resultant was extracted, and organic layers were collected, dried over MgSO₄, and filtered. The solvent was removed under a reduced pressure from the filtrate solution, and the solid thus obtained was separated and purified by column chromatography using silica gel by using CH₂Cl₂ and hexane as developing solvents to obtain Intermediate 140-a (white solid, 13.0 g, 28.5 mmol, 77%). Through ESI-LCMS, the compound thus obtained was identified as Intermediate 140-a.

ESI-LCMS: [M]⁺: C₃₀H₁₃D₁₀ClN₂. 456.22.

### (Synthesis of Intermediate 140-b)

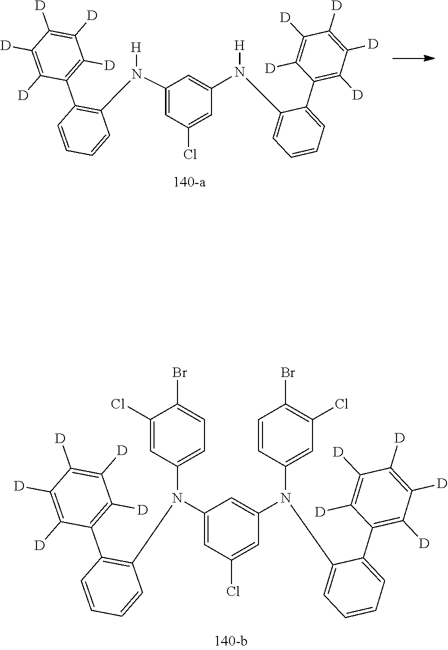 [SMILES: [2H]c1c([2H])c([2H])c(-c2ccccc2Nc2cc(Cl)cc(Nc3ccccc3-c3c([2H])c([2H])c([2H])c([2H])c3[2H])c2)c([2H])c1[2H] ; [2H]c1c([2H])c([2H])c(-c2ccccc2N(c2cc(Cl)cc(N(c3ccc(Br)c(Cl)c3)c3ccccc3-c3c([2H])c([2H])c([2H])c([2H])c3[2H])c2)c2ccc(Br)c(Cl)c2)c([2H])c1[2H]]

Under an argon atmosphere, to a 2 L flask, Intermediate 140-a (13.0 g, 28.5 mmol), 1-bromo-2-chloro-4-iodobenzene (27.1 g, 85.5 mmol), pd₂dba₃ (1.3 g, 1.4 mmol), tris-tert-butyl phosphine 50% in toluene (1.3 mL, 2.9 mmol), and sodium tert-butoxide (8.2 g, 85.5 mmol) were added and dissolved in 1 L of toluene, and the reaction solution was stirred at about 100 degrees for about 12 hours. After cooling, water (500 mL) was added, the resultant was extracted, and organic layers were collected, dried over MgSO₄, and filtered. The solvent was removed under a reduced pressure from the filtrate solution, and the solid thus obtained was separated and purified by column chromatography using silica gel by using CH₂Cl₂ and hexane as developing solvents to obtain Intermediate 140-b (white solid, 20.2 g, 24.2 mmol, 85%). Through ESI-LCMS, the compound thus obtained was identified as Intermediate 140-b.

ESI-LCMS: [M]⁺: C₄₂H₁₇D₁₀Br₂Cl₃N₂. 836.02.

### (Synthesis of Intermediate 140-c)

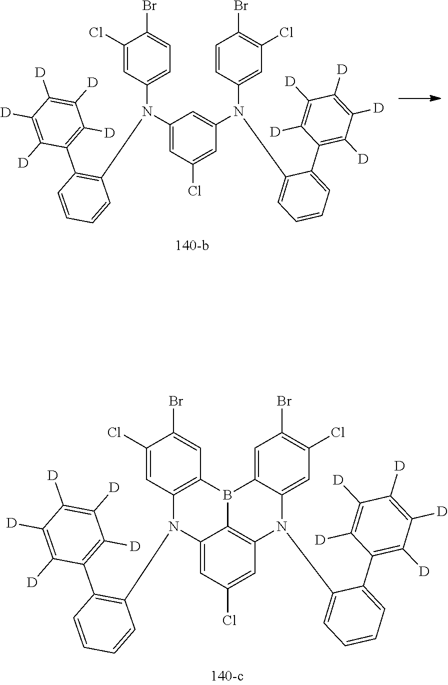 [SMILES: [2H]c1c([2H])c([2H])c(-c2ccccc2N(c2cc(Cl)cc(N(c3ccc(Br)c(Cl)c3)c3ccccc3-c3c([2H])c([2H])c([2H])c([2H])c3[2H])c2)c2ccc(Br)c(Cl)c2)c([2H])c1[2H] ; [2H]c1c([2H])c([2H])c(-c2ccccc2N2c3cc(Cl)c(Br)cc3B3c4cc(Br)c(Cl)cc4N(c4ccccc4-c4c([2H])c([2H])c([2H])c([2H])c4[2H])c4cc(Cl)cc2c43)c([2H])c1[2H]]

Under an argon atmosphere, to a 500 mL flask, Intermediate 140-b (20.2 g, 24.2 mmol) was dissolved in 200 mL of o-dichlorobenzene, and cooled using ice-water. BBr₃ (5 equiv.) was slowly added thereto, and the reaction solution was stirred at about 180 degrees for about 12 hours. After cooling, triethylamine (5 equiv.) was added to quench the reaction, the resultant was extracted with water and CH₂Cl₂, and organic layers were collected, dried over MgSO₄, and filtered. The solvent was removed under a reduced pressure from the filtrate solution, and the solid thus obtained was separated and purified by column chromatography using silica gel by using CH₂Cl₂ and hexane as developing solvents to obtain Intermediate 140-c (yellow solid, 6.9 g, 8.2 mmol, 34%). Through ESI-LCMS, the compound thus obtained was identified as Intermediate 140-c.

ESI-LCMS: [M]⁺: C₄₂H₁₄D₁₀BBr₂Cl₃N₂. 842.01.

### (Synthesis of Intermediate 140-d)

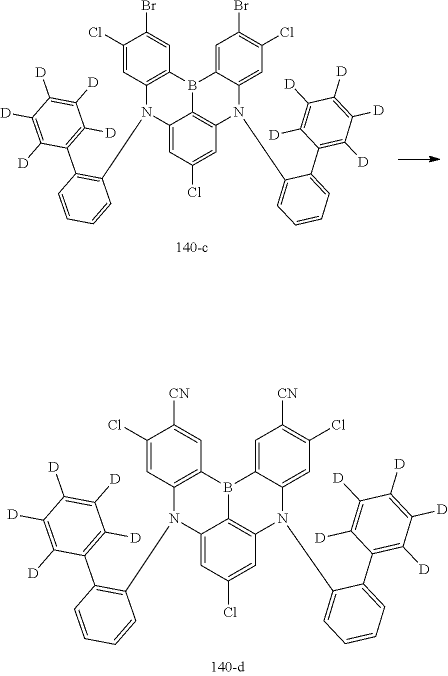 [SMILES: [2H]c1c([2H])c([2H])c(-c2ccccc2N2c3cc(Cl)c(Br)cc3B3c4cc(Br)c(Cl)cc4N(c4ccccc4-c4c([2H])c([2H])c([2H])c([2H])c4[2H])c4cc(Cl)cc2c43)c([2H])c1[2H] ; [2H]c1c([2H])c([2H])c(-c2ccccc2N2c3cc(Cl)c(C#N)cc3B3c4cc(C#N)c(Cl)cc4N(c4ccccc4-c4c([2H])c([2H])c([2H])c([2H])c4[2H])c4cc(Cl)cc2c43)c([2H])c1[2H]]

Under an argon atmosphere, to a 100 mL flask, Intermediate 140-c (6.9 g, 8.2 mmol), CuCN (2.9 g, 32.8 mmol) and L-proline (1.9 g, 16.4 mmol) were added and dissolved in 25 mL of DMF, and the reaction solution was stirred at about 120 degrees for about 48 hours. Ethyl acetate and water were added, and the resultant was extracted. Organic layers were collected, dried over MgSO₄, and filtered. The solvent was removed under a reduced pressure from the filtrate solution. The solid thus obtained was separated and purified by column chromatography using silica gel by using ethyl acetate and hexane as developing solvents to obtain Intermediate 140-d (yellow solid, 4.0 g, 5.4 mmol, 66%). Through ESI-LCMS, the compound thus obtained was identified as Intermediate 140-d.

ESI-LCMS: [M]⁺: C₄₄H₁₄D₁₀BCl₃N₄. 736.18.

### (Synthesis of Compound 140)

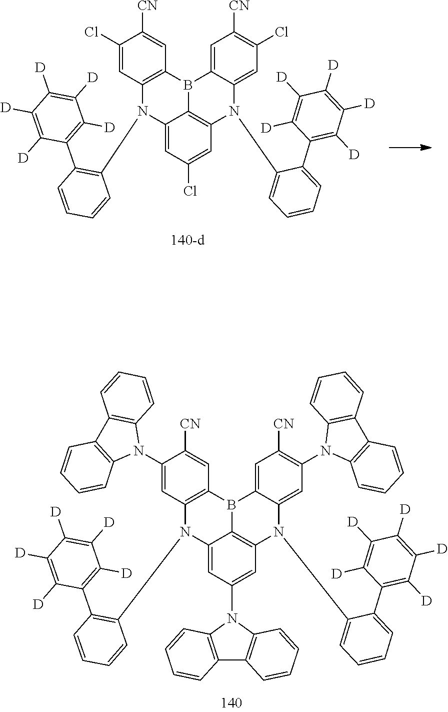 [SMILES: [2H]c1c([2H])c([2H])c(-c2ccccc2N2c3cc(Cl)c(C#N)cc3B3c4cc(C#N)c(Cl)cc4N(c4ccccc4-c4c([2H])c([2H])c([2H])c([2H])c4[2H])c4cc(Cl)cc2c43)c([2H])c1[2H] ; [2H]c1c([2H])c([2H])c(-c2ccccc2N2c3cc(-n4c5ccccc5c5ccccc54)c(C#N)cc3B3c4cc(C#N)c(-n5c6ccccc6c6ccccc65)cc4N(c4ccccc4-c4c([2H])c([2H])c([2H])c([2H])c4[2H])c4cc(-n5c6ccccc6c6ccccc65)cc2c43)c([2H])c1[2H]]

Under an argon atmosphere, in a 250 mL flask, Intermediate 140-d (4.0 g, 5.4 mmol), 9H-carbazole (4.5 g, 27.0 mmol), pd₂dba₃ (0.5 g, 0.54 mmol), tris-tert-butyl phosphine (0.5 mL, 1.1 mmol) and sodium tert-butoxide (2.6 g, 27 mmol) were dissolved in 100 mL of o-xylene, and the reaction solution was stirred at about 150 degrees for about 12 hours. After cooling, the resultant was filtered using a celite filter, and the solvent was removed under a reduced pressure from the filtrate solution. The solid thus obtained was separated and purified by column chromatography using silica gel by using ethyl acetate and hexane as developing solvents to obtain Compound 140 (yellow solid, 4.0 g, 3.5 mmol, 65%). Through ESI-LCMS, the compound thus obtained was identified as Compound 140.

ESI-LCMS: [M]⁺: C₈₀H₃₈D₁₀BN₇. 1127.47.

### (5) Synthesis of Compound 169

### (Synthesis of Intermediate 169-a)

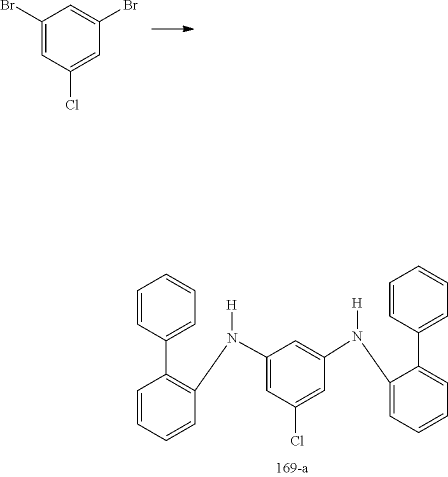 [SMILES: Clc1cc(Br)cc(Br)c1 ; Clc1cc(Nc2ccccc2-c2ccccc2)cc(Nc2ccccc2-c2ccccc2)c1]

Under an argon atmosphere, to a 2 L flask, 1,3-dibromo-5-chlorobenzene (10.0 g, 37.0 mmol), [1,1′-biphenyl]-2-amine (12.5 g, 74.0 mmol), pd₂dba₃ (1.7 g, 1.9 mmol), tris-tert-butyl phosphine 50% in toluene (1.7 mL, 3.7 mmol), and sodium tert-butoxide (10.7 g, 111 mmol) were added and dissolved in 1 L of toluene, and the reaction solution was stirred at about 80 degrees for about 12 hours. After cooling, water (500 mL) was added, the resultant was extracted, and organic layers were collected, dried over MgSO₄, and filtered. The solvent was removed under a reduced pressure from the filtrate solution, and the solid thus obtained was separated and purified by column chromatography using silica gel by using CH₂Cl₂ and hexane as developing solvents to obtain Intermediate 169-a (white solid, 13.2 g, 29.6 mmol, 80%). Through ESI-LCMS, the compound thus obtained was identified as Intermediate 169-a.

ESI-LCMS: [M]⁺: C₃₀H₂₃ClN₂. 446.15.

### (Synthesis of Intermediate 169-b)

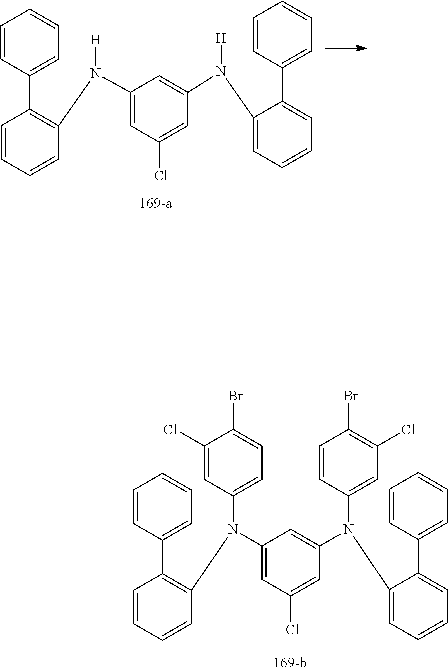 [SMILES: Clc1cc(Nc2ccccc2-c2ccccc2)cc(Nc2ccccc2-c2ccccc2)c1 ; Clc1cc(N(c2ccc(Br)c(Cl)c2)c2ccccc2-c2ccccc2)cc(N(c2ccc(Br)c(Cl)c2)c2ccccc2-c2ccccc2)c1]

Under an argon atmosphere, to a 2 L flask, Intermediate 169-a (13.2 g, 29.6 mmol), 1-bromo-2-chloro-4-iodobenzene (28.2 g, 88.8 mmol), pd₂dba₃ (1.4 g, 1.5 mmol), tris-tert-butyl phosphine 50% in toluene (1.4 mL, 3.0 mmol), and sodium tert-butoxide (8.5 g, 88.8 mmol) were added and dissolved in 1 L of toluene, and the reaction solution was stirred at about 100 degrees for about 12 hours. After cooling, water (500 mL) was added, the resultant was extracted, and organic layers were collected, dried over MgSO₄, and filtered. The solvent was removed under a reduced pressure from the filtrate solution, and the solid thus obtained was separated and purified by column chromatography using silica gel by using CH₂Cl₂ and hexane as developing solvents to obtain Intermediate 169-b (white solid, 21.8 g, 26.3 mmol, 89%). Through ESI-LCMS, the compound thus obtained was identified as Intermediate 169-b.

ESI-LCMS: [M]⁺: C₄₂H₂₇Br₂Cl₃N₂. 825.96.

### (Synthesis of Intermediate 169-c)

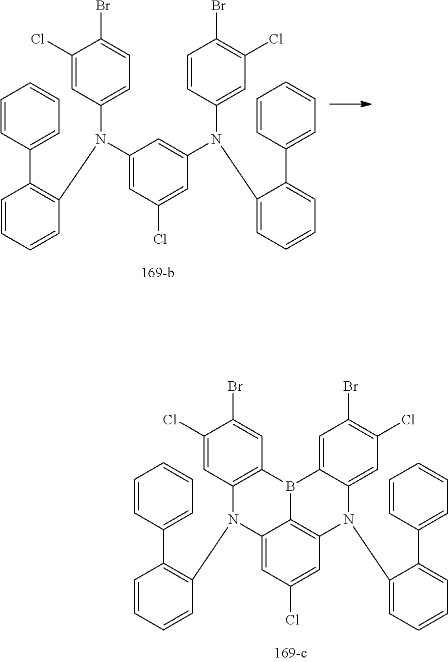 [SMILES: Clc1cc(N(c2ccc(Br)c(Cl)c2)c2ccccc2-c2ccccc2)cc(N(c2ccc(Br)c(Cl)c2)c2ccccc2-c2ccccc2)c1 ; Clc1cc2c3c(c1)N(c1ccccc1-c1ccccc1)c1cc(Cl)c(Br)cc1B3c1cc(Br)c(Cl)cc1N2c1ccccc1-c1ccccc1]

Under an argon atmosphere, to a 500 mL flask, Intermediate 169-b (21.8 g, 26.3 mmol) was added and dissolved in 220 mL of o-dichlorobenzene, and cooled using ice-water. BBr₃ (5 equiv.) was slowly added thereto, and the reaction solution was stirred at about 180 degrees for about 12 hours. After cooling, triethylamine (5 equiv.) was added to quench the reaction, the resultant was extracted with water and CH₂Cl₂, and organic layers were collected, dried over MgSO₄, and filtered. The solvent was removed under a reduced pressure from the filtrate solution, and the solid thus obtained was separated and purified by column chromatography using silica gel by using CH₂Cl₂ and hexane as developing solvents to obtain Intermediate 169-c (yellow solid, 9.6 g, 11.6 mmol, 44%). Through ESI-LCMS, the compound thus obtained was identified as Intermediate 169-c.

ESI-LCMS: [M]⁺: C₄₂H₂₄BBr₂Cl₃N₂. 833.94.

### (Synthesis of Intermediate 169-d)

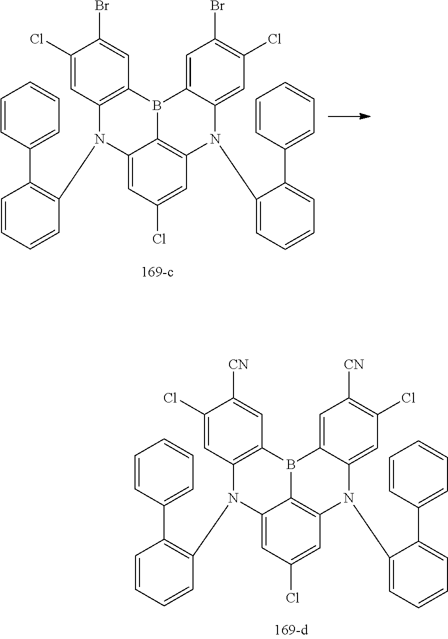 [SMILES: Clc1cc2c3c(c1)N(c1ccccc1-c1ccccc1)c1cc(Cl)c(Br)cc1B3c1cc(Br)c(Cl)cc1N2c1ccccc1-c1ccccc1 ; N#Cc1cc2c(cc1Cl)N(c1ccccc1-c1ccccc1)c1cc(Cl)cc3c1B2c1cc(C#N)c(Cl)cc1N3c1ccccc1-c1ccccc1]

Under an argon atmosphere, to a 100 mL flask, Intermediate 169-c (9.6 g, 11.6 mmol), CuCN (4.2 g, 46.4 mmol) and L-proline (2.7 g, 23.2 mmol) were added and dissolved in 35 mL of DMF, and the reaction solution was stirred at about 120 degrees for about 48 hours. Ethyl acetate and water were added, and the resultant was extracted. Organic layers were collected, dried over MgSO₄, and filtered. The solvent was removed under a reduced pressure from the filtrate solution. The solid thus obtained was separated and purified by column chromatography using silica gel by using ethyl acetate and hexane as developing solvents to obtain Intermediate 169-d (yellow solid, 5.9 g, 8.1 mmol, 70%). Through ESI-LCMS, the compound thus obtained was identified as Intermediate 169-d.

ESI-LCMS: [M]⁺: C₄₄H₂₄BCl₃N₄. 724.12.

### (Synthesis of Compound 169)

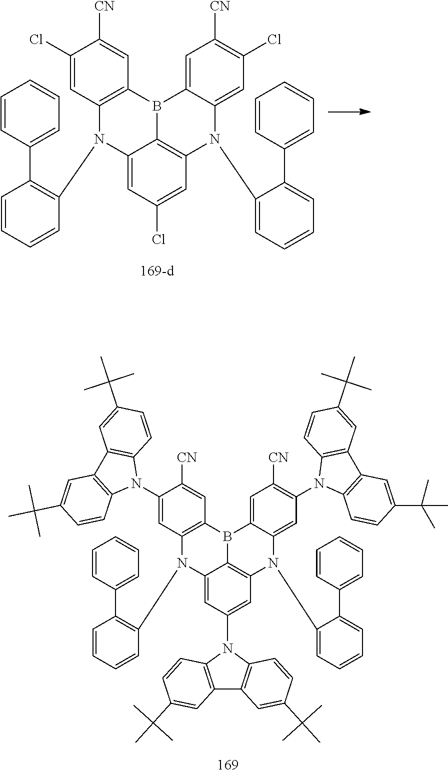 [SMILES: N#Cc1cc2c(cc1Cl)N(c1ccccc1-c1ccccc1)c1cc(Cl)cc3c1B2c1cc(C#N)c(Cl)cc1N3c1ccccc1-c1ccccc1 ; CC(C)(C)c1ccc2c(c1)c1cc(C(C)(C)C)ccc1n2-c1cc2c3c(c1)N(c1ccccc1-c1ccccc1)c1cc(-n4c5ccc(C(C)(C)C)cc5c5cc(C(C)(C)C)ccc54)c(C#N)cc1B3c1cc(C#N)c(-n3c4ccc(C(C)(C)C)cc4c4cc(C(C)(C)C)ccc43)cc1N2c1ccccc1-c1ccccc1]

Under an argon atmosphere, in a 500 mL flask, Intermediate 169-d (5.9 g, 8.1 mmol), 3,6-di-tert-butyl-9H-carbazole (11.3 g, 40.5 mmol), pd₂dba₃ (0.7 g, 0.81 mmol), tris-tert-butyl phosphine (0.8 mL, 1.6 mmol) and sodium tert-butoxide (3.9 g, 40.5 mmol) were dissolved in 200 mL of o-xylene, and the reaction solution was stirred at about 150 degrees for about 12 hours. After cooling, the resultant was filtered using a celite filter, and the solvent was removed under a reduced pressure from the filtrate solution. The solid thus obtained was separated and purified by column chromatography using silica gel by using ethyl acetate and hexane as developing solvents to obtain Compound 169 (yellow solid, 6.2 g, 4.3 mmol, 53%). Through ESI-LCMS, the compound thus obtained was identified as Compound 169.

ESI-LCMS: [M]⁺: C₁₀₄H₉₆BN₇. 1454.79.

### 2. Manufacture and Evaluation of Light Emitting Device

### (1) Manufacture of Light Emitting Device

The light emitting device according to an embodiment, including the fused polycyclic compound according to an embodiment in an emission layer was manufactured by a method below. Light emitting devices of Example 1 to Example 5 were manufactured using the fused polycyclic compounds of Example Compounds 1, 98, 110, 140, and 169 as the dopant materials of an emission layer. Comparative Example 1 to Comparative Example 8 correspond to light emitting devices manufactured using Comparative Compound C1 to Comparative Compound C8 as the dopant materials of an emission layer.

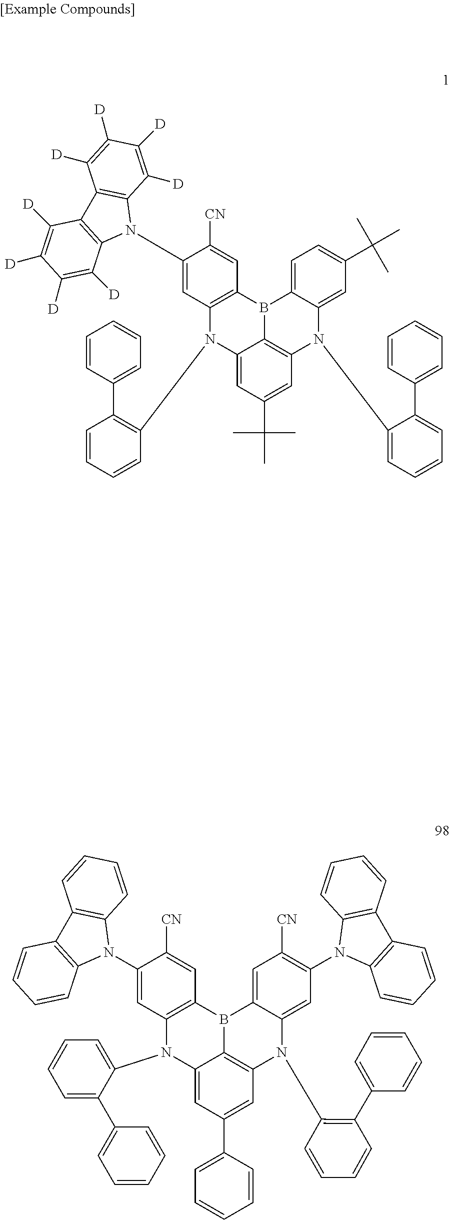 [SMILES: [2H]c1c([2H])c([2H])c2c(c1[2H])c1c([2H])c([2H])c([2H])c([2H])c1n2-c1cc2c(cc1C#N)B1c3ccc(C(C)(C)C)cc3N(c3ccccc3-c3ccccc3)c3cc(C(C)(C)C)cc(c31)N2c1ccccc1-c1ccccc1 ; N#Cc1cc2c(cc1-n1c3ccccc3c3ccccc31)N(c1ccccc1-c1ccccc1)c1cc(-c3ccccc3)cc3c1B2c1cc(C#N)c(-n2c4ccccc4c4ccccc42)cc1N3c1ccccc1-c1ccccc1]

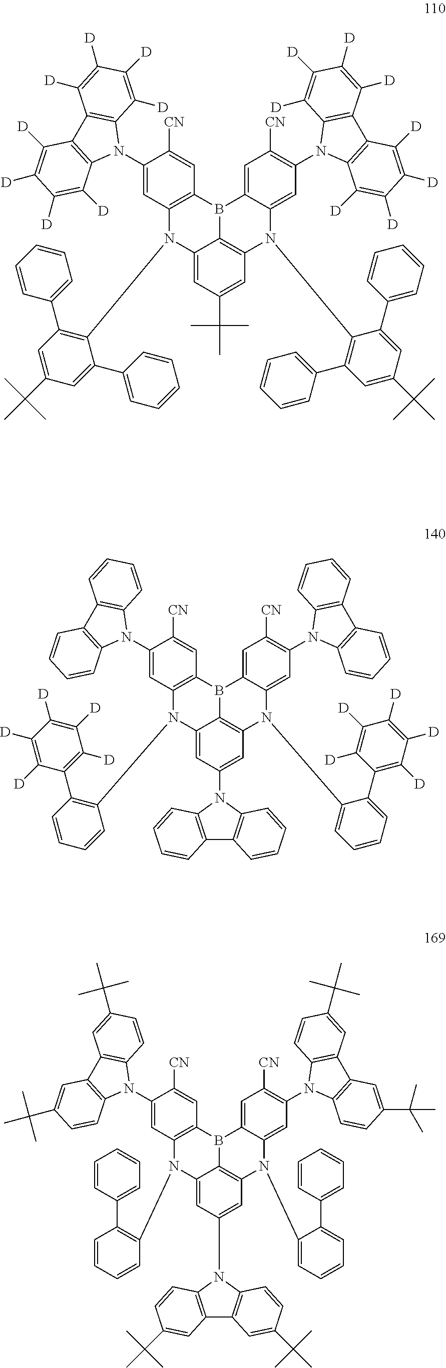

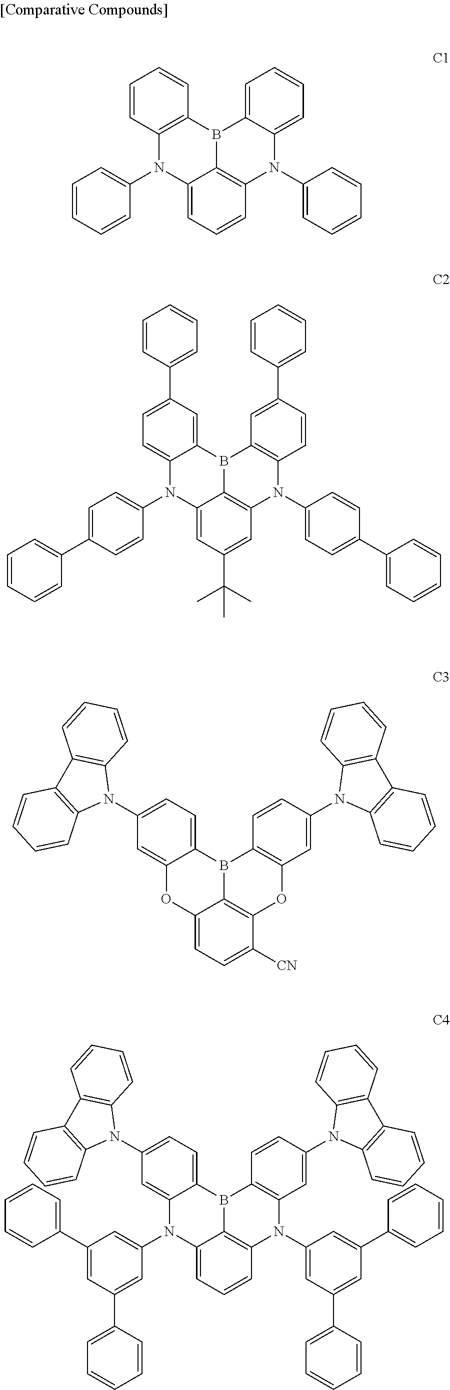 [SMILES: c1ccc(N2c3ccccc3B3c4ccccc4N(c4ccccc4)c4cccc2c43)cc1 ; CC(C)(C)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; N#Cc1ccc2c3c1Oc1cc(-n4c5ccccc5c5ccccc54)ccc1B3c1ccc(-n3c4ccccc4c4ccccc43)cc1O2 ; c1ccc(-c2cc(-c3ccccc3)cc(N3c4cc(-n5c6ccccc6c6ccccc65)ccc4B4c5ccc(-n6c7ccccc7c7ccccc76)cc5N(c5cc(-c6ccccc6)cc(-c6ccccc6)c5)c5cccc3c54)c2)cc1]

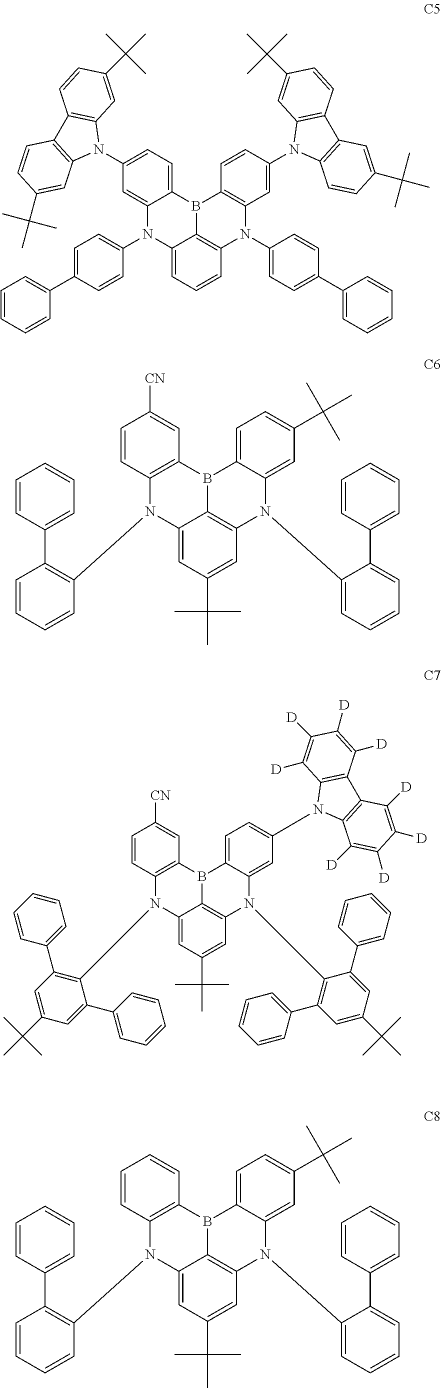

### (Manufacture of Light Emitting Device)

For the manufacture of the light emitting devices of the Examples and the Comparative Examples, a glass substrate (product of Corning Co.) on which an ITO electrode with about 15 Ω/cm² (about 1,200 Å) was formed as an anode, was cut into a size of about 50 mm×50 mm×0.7 mm, washed by ultrasonic waves using isopropyl alcohol and pure water for about 5 minutes each, and cleansed by irradiating ultraviolet rays for about 30 minutes and by exposure to ozone. The ITO glass substrate was installed in a vacuum deposition apparatus.

On the anode, NPD was deposited to form a hole injection layer with a thickness of about 300 Å, and on the hole injection layer, H-1-19 was deposited to form a hole transport layer with a thickness of about 200 Å. On the hole transport layer, CzSi was deposited to form an emission auxiliary layer with a thickness of about 100 Å.

A host mixture of a second compound and a third compound in a ratio of 1:1, a fourth compound, and the Example Compound or Comparative Compound were co-deposited in a weight ratio of about 82:15:3 to form an emission layer EML with a thickness of about 200 Å. On the emission layer, TSPO1 was deposited to form an electron transport layer with a thickness of about 200. On the electron transport layer, TPBI was deposited to form a buffer layer with a thickness of about 300 Å, and on the buffer layer, LiF was deposited to form an electron injection layer with a thickness of about 10 Å. On the electron injection layer, Al was deposited to form a cathode with a thickness of about 3,000 Å, and on the cathode, P4 was deposited to form a capping layer with a thickness of about 700 Å to manufacture a light emitting device.

All layers were formed by a vacuum deposition method. Among the compounds in Compound Group 2, HT1 was as used the second compound; among the compounds in Compound Group 3, ETH85 was used as the third compound; and among the compounds in Compound Group 4, AD-37 was used as the fourth compound.

The compounds used for the manufacture of the light emitting devices of the Examples and the Comparative Examples are shown below. The materials below were used after purchasing commercial products and performing sublimation purification.

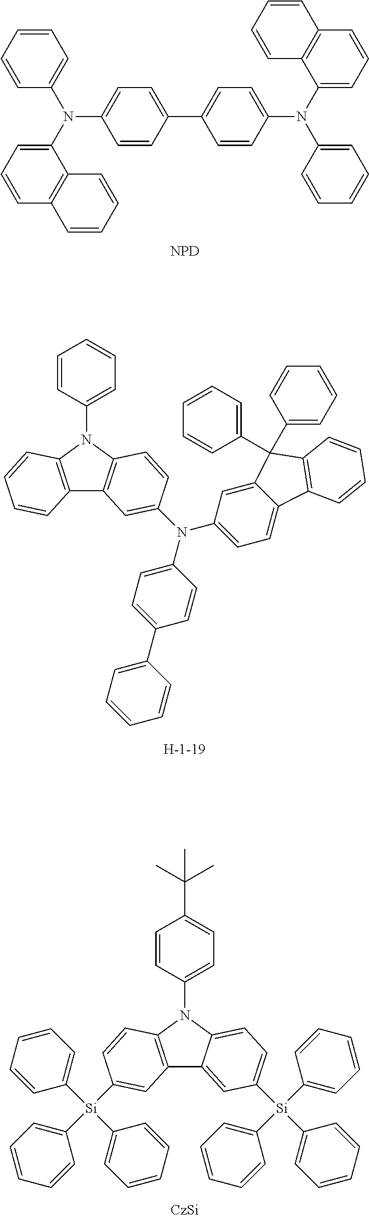

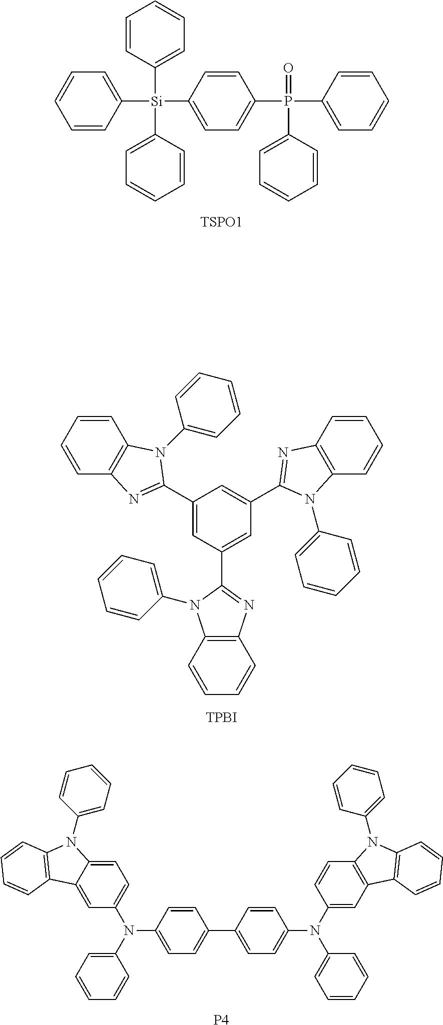

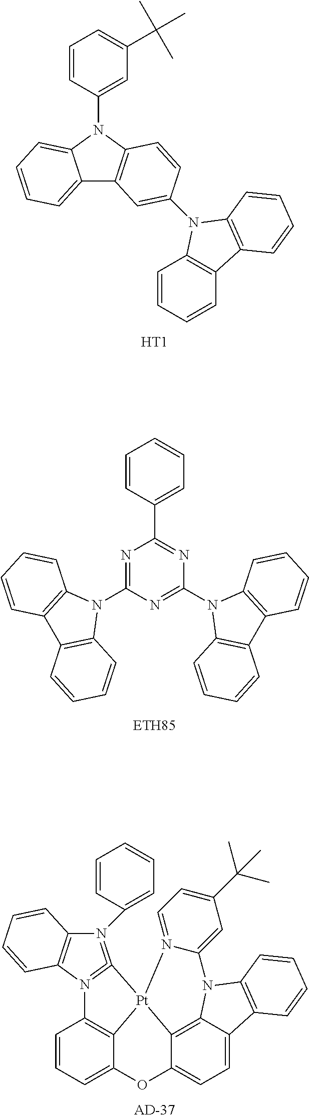

### (2) Evaluation of Properties of Light Emitting Devices

The device efficiency and device lifetime of the light emitting devices manufactured using Example Compounds 1, 98, 110, 140, and 169, and Comparative Compounds C1 to C8 were evaluated. In Table 1, the evaluation results on the light emitting devices of Examples 1 to 5, and Comparative Examples 1 to 8 are shown. In order to evaluate the properties of the light emitting devices manufactured in Examples 1 to 5 and Comparative Examples 1 to 8, a driving voltage (V) at a current density of about 1,000 cd/m², emission efficiency (cd/A), maximum external quantum efficiency (%), and emission color were measured using Keithley MU 236 and a luminance meter PR650. The time consumed to reach about 95% luminance in contrast to an initial luminance was measured as the lifetime (T95), relative lifetime was calculated based on the device of Comparative Example 1, and the results are shown in Table 1.

TABLE 1

| | Host (second | | | | | | |
|---|---|---|---|---|---|---|---|
| | compound:third | | | Driving | | Emission | Lifetime |
| | compound = | Fourth | First | voltage | Efficiency | wavelength | ratio |
| | 5:5) | compound | compound | (V) | (cd/A) | (nm) | (T95) |
| Example 1 | HT1/ETH85 | AD-37 | Compound 1 | 4.2 | 27.2 | 457 | 3.3 |
| Example 2 | HT1/ETH85 | AD-37 | Compound 98 | 4.3 | 28.6 | 462 | 4.5 |
| Example 3 | HT1/ETH85 | AD-37 | Compound 110 | 4.1 | 28.3 | 460 | 4.8 |
| Example 4 | HT1/ETH85 | AD-37 | Compound 140 | 4.2 | 28.9 | 457 | 4.2 |
| Example 5 | HT1/ETH85 | AD-37 | Compound 169 | 4.2 | 29.1 | 457 | 4.9 |
| Comparative | HT1/ETH85 | AD-37 | Comparative | 4.8 | 15.8 | 457 | 1 |
| Example 1 | | | Compound C1 | | | | |
| Comparative | HT1/ETH85 | AD-37 | Comparative | 4.7 | 19.7 | 465 | 1.8 |
| Example 2 | | | Compound C2 | | | | |
| Comparative | HT1/ETH85 | AD-37 | Comparative | 4.7 | 15.9 | 451 | 1.2 |
| Example 3 | | | Compound C3 | | | | |
| Comparative | HT1/ETH85 | AD-37 | Comparative | 4.6 | 20.5 | 460 | 2.1 |
| Example 4 | | | Compound C4 | | | | |
| Comparative | HT1/ETH85 | AD-37 | Comparative | 4.5 | 20.2 | 460 | 2.3 |
| Example 5 | | | Compound C5 | | | | |
| Comparative | HT1/ETH85 | AD-37 | Comparative | 4.7 | 19.0 | 458 | 1.9 |
| Example 6 | | | Compound C6 | | | | |
| Comparative | HT1/ETH85 | AD-37 | Comparative | 4.6 | 20.3 | 458 | 3.0 |
| Example 7 | | | Compound C7 | | | | |
| Comparative | HT1/ETH85 | AD-37 | Comparative | 4.7 | 17.5 | 457 | 1.5 |
| Example 8 | | | Compound C8 | | | | |

Referring to the results of Table 1, it could be confirmed that the Examples of the light emitting devices using the fused polycyclic compounds according to embodiments as light emitting materials showed improved emission efficiency and lifetime characteristics when compared to the Comparative Examples.

The Example Compounds have a structure in which a first substituent and a second substituent are bonded to a fused ring core at defined positions, and if applied to a light emitting device, it could be confirmed that high emission efficiency and improved lifetime characteristics are shown when compared to the Comparative Examples. The Example Compounds include a fused ring core in which first to third aromatic rings are fused via a boron atom, a first nitrogen atom, and a second nitrogen atom and have a structure in which a first substituent and a second substituent are bonded at defined positions of the first aromatic ring. Accordingly, a deep HOMO energy level may be exhibited, trap-assisted recombination that is a factor in deteriorating the device may be suppressed, and emission efficiency may be improved. The Example Compounds have a structure in which the first substituent is connected at a para position to the boron atom, and the second substituent is connected at an ortho position to the first substituent and at a para position to the first nitrogen atom, and accordingly, a nitrogen-carbon bond between the first substituent and the fused ring core may be reinforced to improve material stability. Accordingly, if the Example Compounds are applied to a light emitting device, high emission efficiency and long lifetime may be achieved.

The light emitting device according to an embodiment includes the first compound according to an embodiment as the light emitting dopant of a thermally activated delayed fluorescence (TADF) light emitting device, and high device efficiency may be achieved even in a blue light wavelength range.

Referring to Comparative Example 1 and Comparative Example 2, Comparative Compound C1 and Comparative Compound C2 each include a plate-type core including a boron atom and two nitrogen atoms, and the first substituent and the second substituent according to embodiments are not included in the plate-type skeleton. Accordingly, when applied to a device, driving voltage was high, and emission efficiency and device lifetime were degraded when compared to the Examples.

When comparing Comparative Example 3 to the Examples, it could be confirmed that Comparative Example 3 showed a high driving voltage, and markedly degraded emission efficiency and lifetime characteristics. Comparative Compound C3 included in Comparative Example 3 includes a fused ring core in which three aromatic rings were fused via a boron atom in the center and has a structure in which a first substituent is bonded to a fused ring core at the para position with respect to the boron atom, but does not include a structure in which a cyano group that is the second substituent at the position as defined according to embodiments. Accordingly, if applied to a device, it could be confirmed that emission efficiency and device lifetime were degraded when compared to the Examples. By contrast, in the cases of the Example Compounds, the second substituent is bonded at an ortho position to the first substituent, and it could be confirmed that emission efficiency and the relative lifetime of the device were markedly increased when compared to Comparative Example 3. As in the fused polycyclic compound according to embodiments, if the first substituent and the second substituent are substituted at defined positions of the fused ring core, device lifetime could be effectively improved.

It could be confirmed that Comparative Example 3 showed lower emission efficiency than Comparative Example 4 and Comparative Example 5. In the case of the polycyclic compound not including a nitrogen atom as a constituent atom of a fused ring core, as in Comparative Compound C3, multiple resonance effects may be reduced when compared to the Examples, and emission efficiency may be deteriorated. As in the fused polycyclic compound according to embodiments, if a nitrogen atom is included as a constituent element of a fused ring core, and first and second substituents are bonded to the fused ring core, as in the fused polycyclic compound according to embodiments, high emission efficiency and long lifetime could be achieved in a blue light wavelength range.

When comparing the Examples with Comparative Example 4 and Comparative Example 5, in the cases of Comparative Compound C4 and Comparative Compound C5, included in Comparative Example 4 and Comparative Example 5, a fused ring core with one boron atom and two nitrogen atoms in the center is included, and further including a first substituent that is bonded to the fused ring core at a para position to the boron atom. However, a second substituent according to embodiments is not included. Accordingly, it could be confirmed that, if applied to a device, emission efficiency and device lifetime were degraded when compared to the Examples. In Comparative Compounds C4 and C5, a carbazole group that is an electron donating group is bonded to a fused ring core, and multiple resonance effects could be improved when compared to Comparative Compounds C1 and C2. However, a second substituent that is an electron withdrawing group is not included, and trap-assisted recombination suppressing effects and nitrogen-carbon bond reinforcing effects are degraded when compared to the Example Compounds. Therefore, it can be seen that emission efficiency and life-characteristics were degraded when compared to the Examples. If both the first substituent and the second substituent bonded to a fused ring core are included as in the fused polycyclic compound according to embodiments, high emission efficiency and long lifetime in a blue light wavelength range could be achieved.

In the case of Comparative Example 6, it could be confirmed that a driving voltage was high, and emission efficiency and device lifetime were degraded when compared to Example 1. The fused polycyclic compound used in Comparative Example 6 is different from the fused polycyclic compound used in Example 1 in that it does not include a first substituent according to embodiments. In the case of the fused polycyclic compound used in Example 1, the first substituent is bonded at a para position to the boron atom, and multiple resonance effects were improved. Furthermore, the second substituent is bonded at an ortho position to the first substituent, and the trap-assisted recombination suppressing effects and nitrogen-carbon bond reinforcing effects were synergistically achieved, thereby contributing to the improvement of emission efficiency and lifetime when applied to a light emitting device.

In the case of Comparative Example 7, it could be found that a driving voltage was high, and emission efficiency and device lifetime were degraded when compared to Example 3. The fused polycyclic compound used in Comparative Example 7 corresponds to a polycyclic compound having different characteristics with respect to the bonding positions of the first and second substituents, when compared to the fused polycyclic compound used in Example 3. Thus, in the case of the fused polycyclic compound used in Example 3, the first and second substituents are bonded to a same aromatic ring, the first substituent is bonded at a para position to the boron atom, and the second substituent is bonded at an ortho position to the first substituent, and marked effects of the substituents were shown when compared to Comparative Compound C7 in which the first substituent and the second substituent are substituted at different aromatic rings, respectively. Accordingly, trap-assisted recombination suppressing effects and nitrogen-carbon bond reinforcing effects were high while maintaining multiple resonance effects, to show improved emission efficiency and device lifetime.

In the case of Comparative Example 8, it could be found that a driving voltage was high, and emission efficiency and device lifetime were degraded when compared to Example 1. The fused polycyclic compound used in Comparative Example 8 is different from the fused polycyclic compound used in Example 1 with respect to the first and second substituents. The fused polycyclic compound used in Example 1 includes the first and second substituents according to embodiments, and may show improved emission efficiency and device lifetime due to the effects of the substituents.

The light emitting device of an embodiment may show improved device properties of high efficiency and long lifetime.

The fused polycyclic compound according to an embodiment may be included in the emission layer of a light emitting device and may contribute to the increase of the efficiency and lifetime of the light emitting device.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting device, comprising:
a first electrode;
a second electrode facing the first electrode; and
an emission layer disposed between the first electrode and the second electrode, wherein
the emission layer comprises a first compound represented by Formula 1: 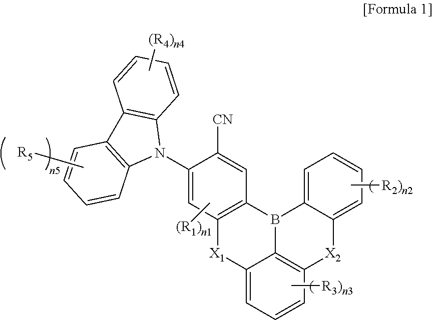
wherein in Formula 1,
X₁ and X₂ are each independently N(Rₐ),
Rₐ is a substituted or unsubstituted aryl group of 6 to 30 ring-forming carbon atoms or a substituted or unsubstituted heteroaryl group of 2 to 30 ring-forming carbon atoms,
R₁ to R₅ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring,
n1 is an integer from 0 to 2,
n2, n4, and n5 are each independently an integer from 0 to 4, and
n3 is an integer from 0 to 3.

2. The light emitting device of claim 1, wherein a substituent represented by R₂ is a hydrogen atom, a deuterium atom, a cyano group, a substituted or unsubstituted alkyl group of 1 to 10 carbon atoms, or a group represented by Formula A-1 or Formula A-2: 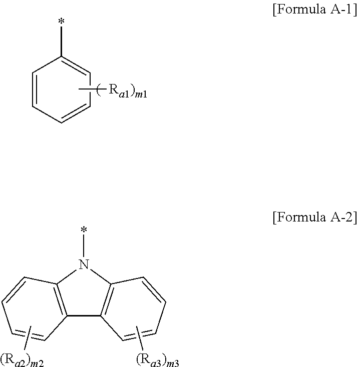
wherein in Formula A-1 and Formula A-2,
Rₐ₁ to Rₐ₃ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1 is an integer from 0 to 5,
m2 and m3 are each independently an integer from 0 to 4, and
-* represents a bond to Formula 1.

3. The light emitting device of claim 1, wherein the first compound is represented by Formula 2-1 or Formula 2-2: 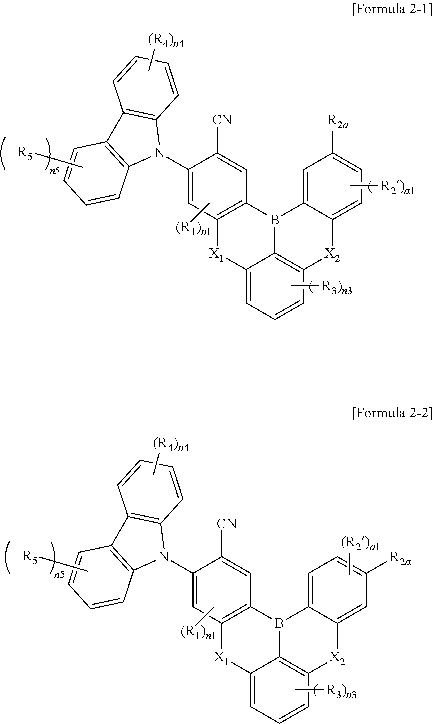
wherein in Formula 2-1 and Formula 2-2,
R₂′ is a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or is combined with an adjacent group to form a ring,
R₂ₐ is a cyano group, a substituted or unsubstituted t-butyl group, a substituted or unsubstituted phenyl group, or a substituted or unsubstituted carbazole group,
a1 is an integer from 0 to 3, and
X₁, X₂, R₁, R₃ to R₅, n1, and n3 to n5 are the same as defined in Formula 1.

4. The light emitting device of claim 1, wherein the first compound is represented by one of Formula 3-1 to Formula 3-5: 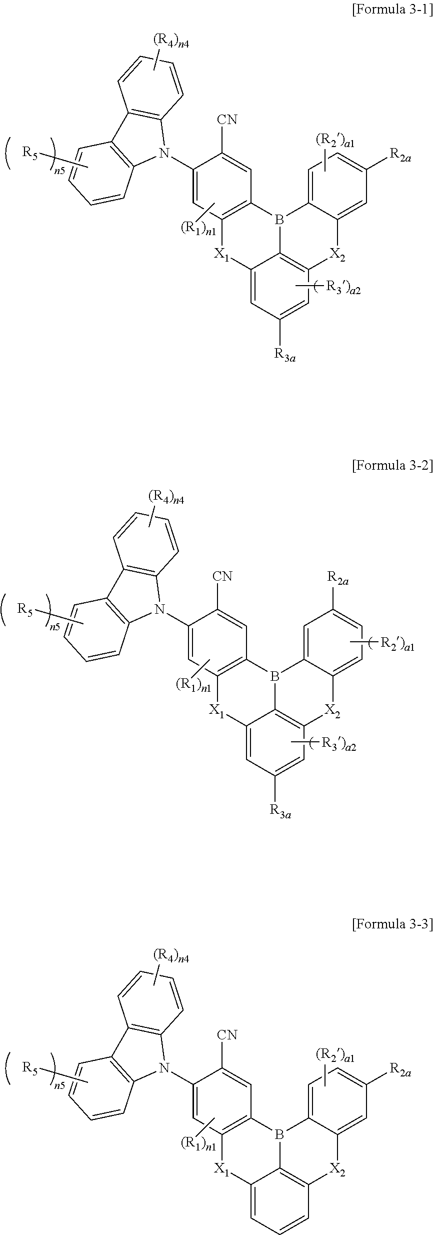 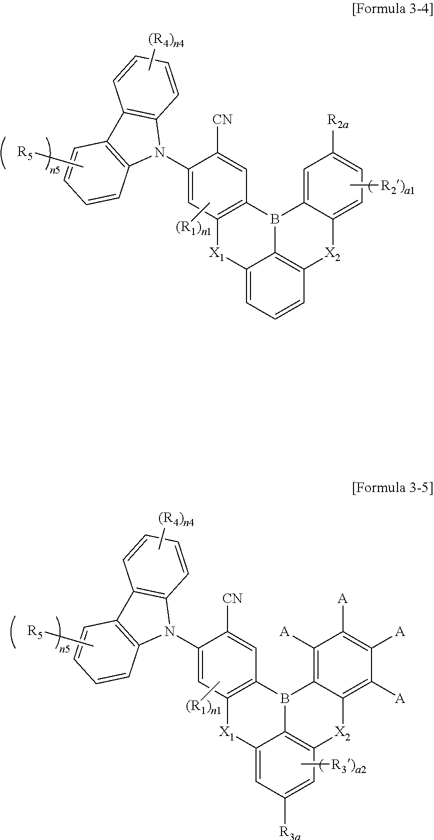
wherein in Formula 3-1 to Formula 3-5,
A is each independently a hydrogen atom or a deuterium atom,
R₂ₐ is a cyano group, a substituted or unsubstituted t-butyl group, a substituted or unsubstituted phenyl group, or a substituted or unsubstituted carbazole group,
R₂′ and R₃′ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring,
a1 is an integer from 0 to 3,
a2 is an integer from 0 to 2,
X₁, X₂, R₁, R₄, R₅, n1, n4, and n5 are the same as defined in Formula 1, and
R₃ₐ is a substituted or unsubstituted t-butyl group or a group represented by Formula B-1 or Formula B-2: 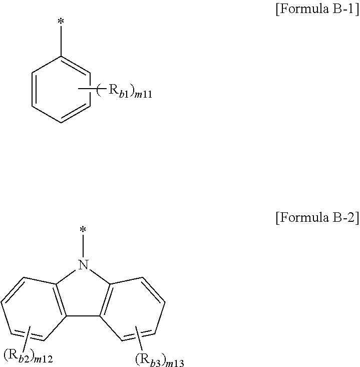
wherein in Formula B-1 and Formula B-2,
R_{b1} to R_{b3} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m11 is an integer from 0 to 5,
m12 and m13 are each independently an integer from 0 to 4, and
-* represents a bond to Formula 3-1, Formula 3-2, or Formula 3-5.

5. The light emitting device of claim 1, wherein the first compound is represented by Formula 4-1 or Formula 4-2: 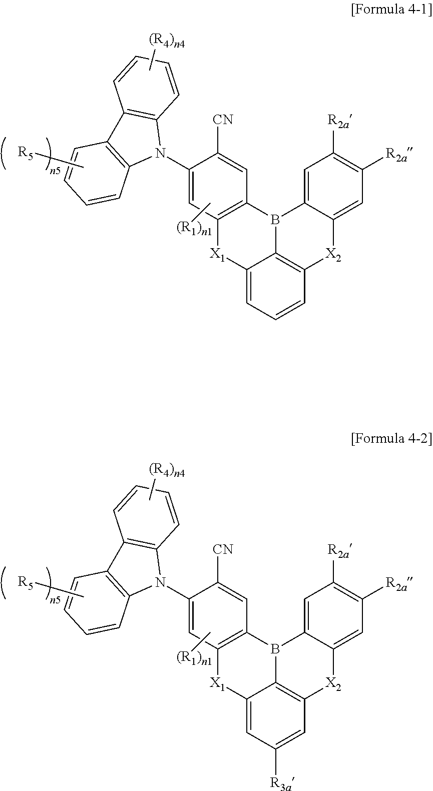
wherein in Formula 4-1 and Formula 4-2,
R₂ₐ′ and R₂ₐ″ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
at least one of R₂ₐ′ and R₂ₐ″ is each independently a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₃ₐ′ is a substituted or unsubstituted t-butyl group, a substituted or unsubstituted phenyl group, or a substituted or unsubstituted carbazole group, and
X₁, X₂, R₁, R₄, R₅, n1, n4, and n5 are the same as defined in Formula 1.

6. The light emitting device of claim 1, wherein the first compound is represented by Formula 5: 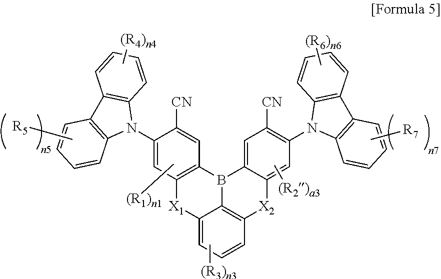
wherein in Formula 5,
R₂″, R₆, and R₇ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring,
n6 and n7 are each independently an integer from 0 to 4,
a3 is an integer from 0 to 2, and
X₁, X₂, R₁, R₃, R₄, R₅, n1, n3, n4, and n5 are the same as defined in Formula 1.

7. The light emitting device of claim 6, wherein the first compound is represented by Formula 6-1 or Formula 6-2: 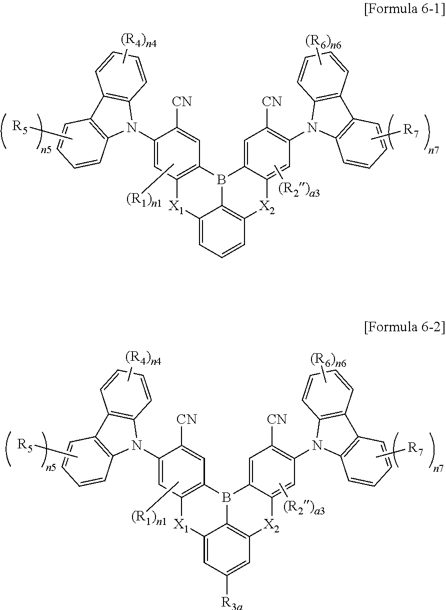
wherein in Formula 6-1 and Formula 6-2,
X₁, X₂, R₁, R₄, R₅, n1, n4, and n5 are the same as defined in Formula 1,
R₂″, R₆, R₇, n6, n7, and a3 are the same as defined in Formula 5, and
R₃ₐ is a substituted or unsubstituted t-butyl group, or a group represented by Formula B-1 or Formula B-2: 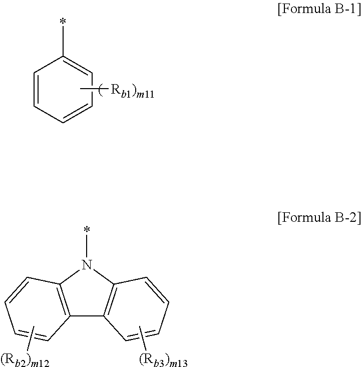
wherein in Formula B-1 and Formula B-2,
R_{b1} to R_{b3} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m11 is an integer from 0 to 5, and
m12 and m13 are each independently an integer from 0 to 4, and
-* represents a bond to Formula 6-2.

8. The light emitting device of claim 1, wherein X₁ and X₂ are each independently represented by Formula X-1 or Formula X-2: 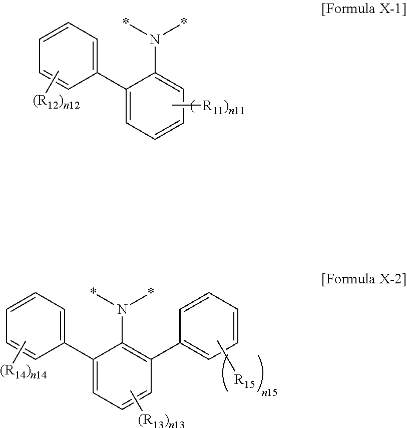
wherein in Formula X-1 and Formula X-2,
R₁₁ to R₁₅ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n11 is an integer from 0 to 4,
n12, n14, and m15 are each independently an integer from 0 to 5,
n13 is an integer from 0 to 3, and
-* represents a bond to Formula 1.

9. The light emitting device of claim 1, wherein the first compound is represented by one of Formula 7-1 to Formula 7-4: 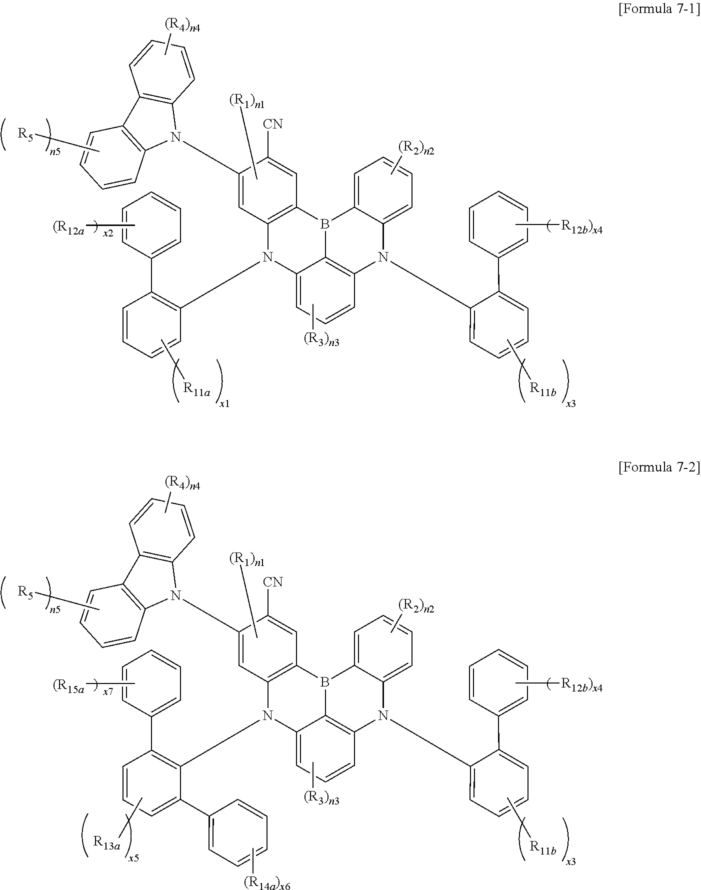 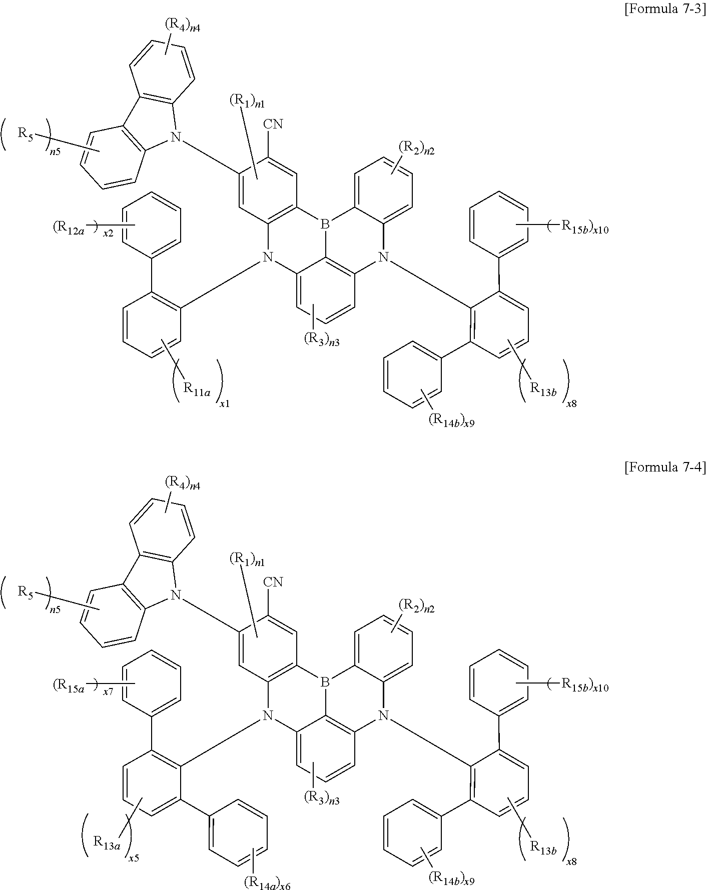
wherein in Formula 7-1 to Formula 7-4,
R₁₁ₐ to R₁₅ₐ and R_{11b} to R_{15b} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
x1 and x3 are each independently an integer from 0 to 4,
x2, x4, x6, x7, x9, and x10 are each independently an integer from 0 to 5,
x5 and x8 are each independently an integer from 0 to 3, and
R₁ to R₅ and n1 to n5 are the same as defined in Formula 1

10. The light emitting device of claim 1, wherein the first compound comprises at least one compound selected from Compound Group 1:

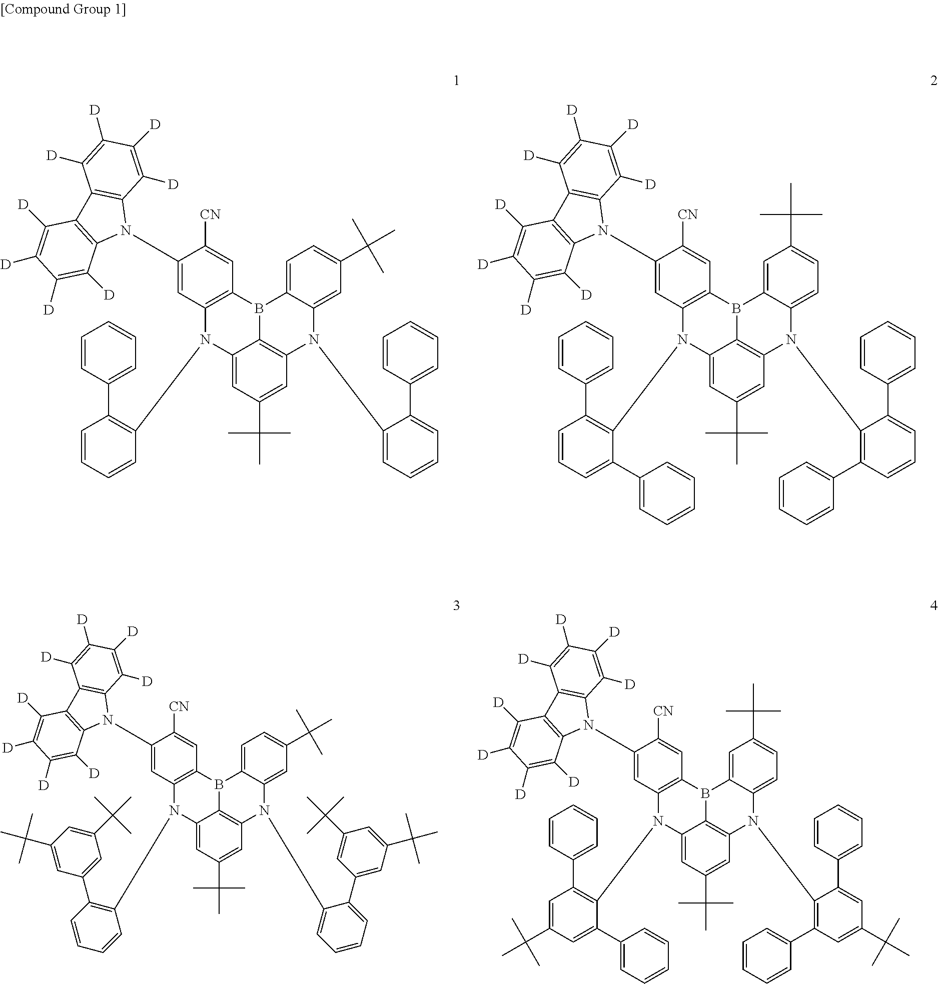

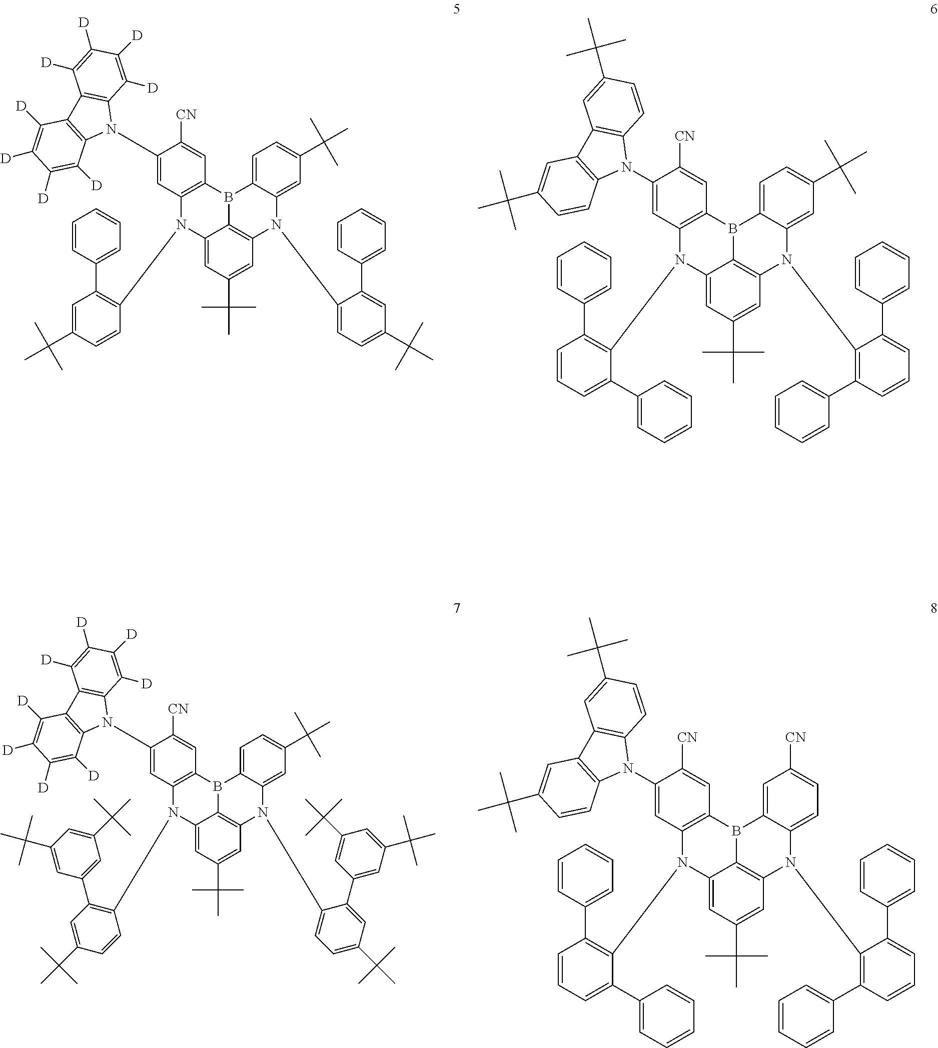

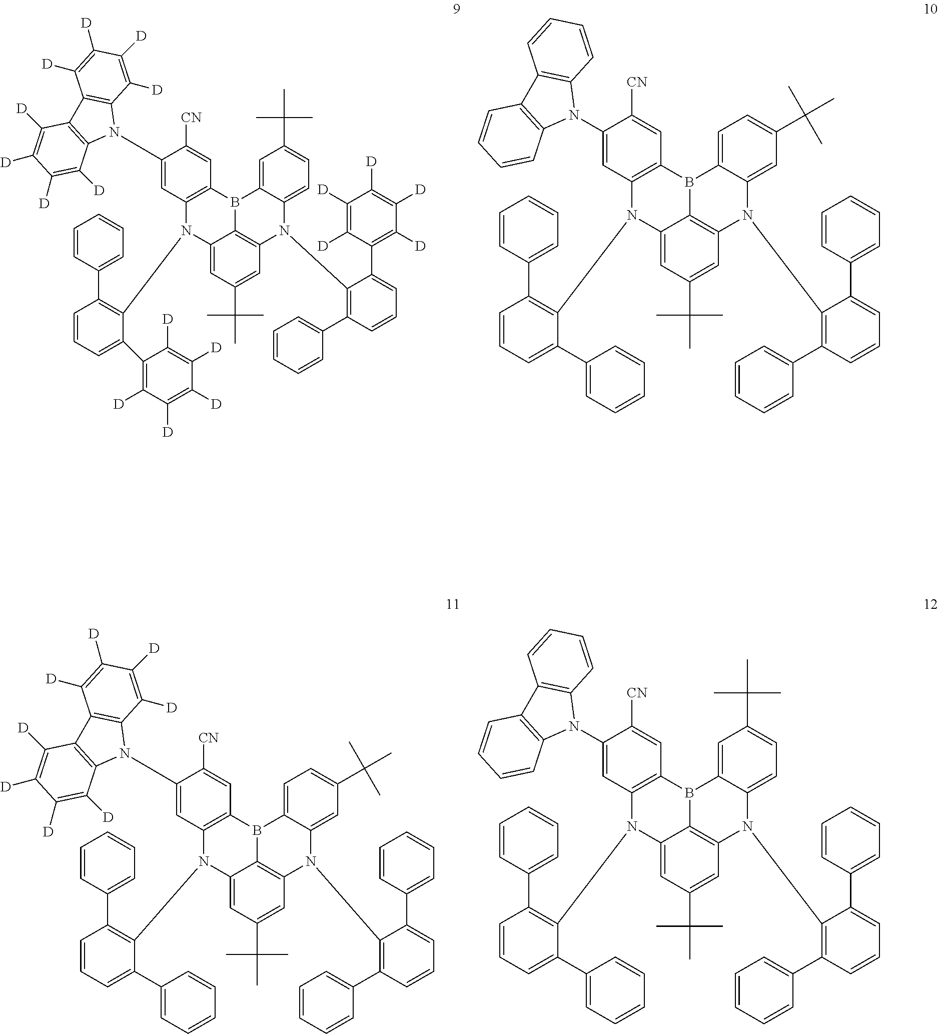

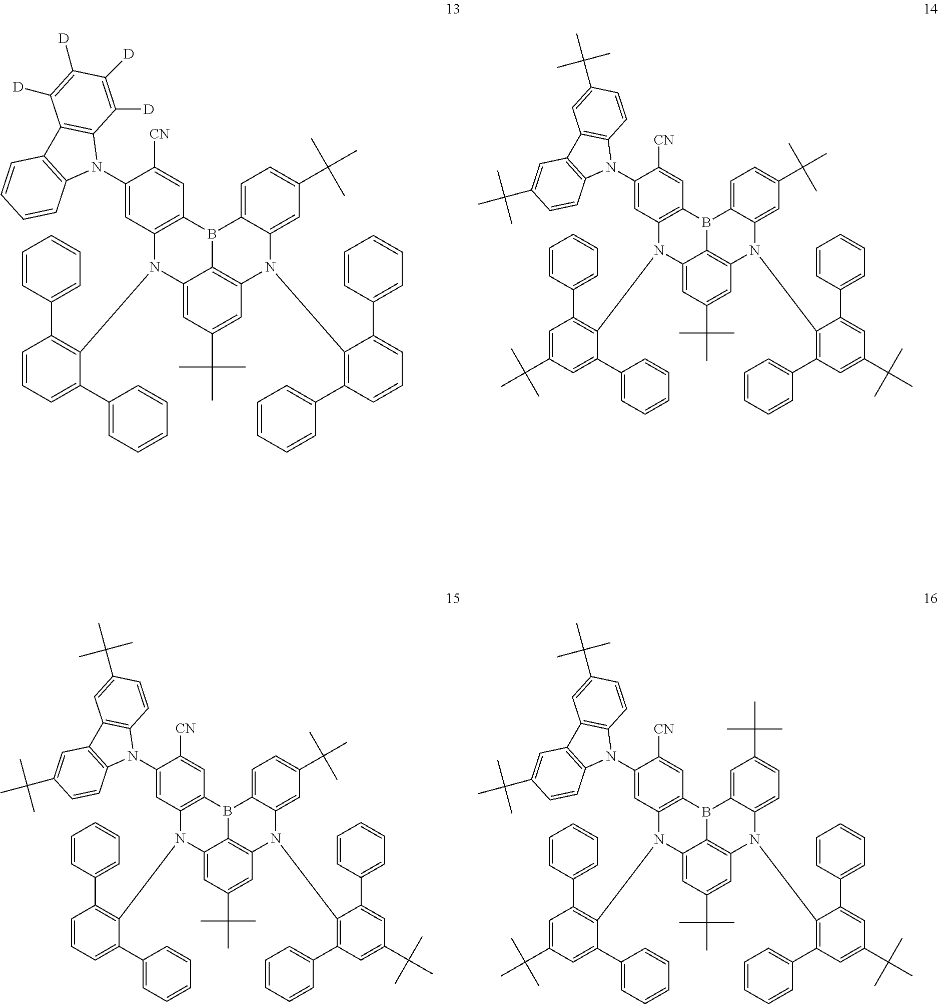

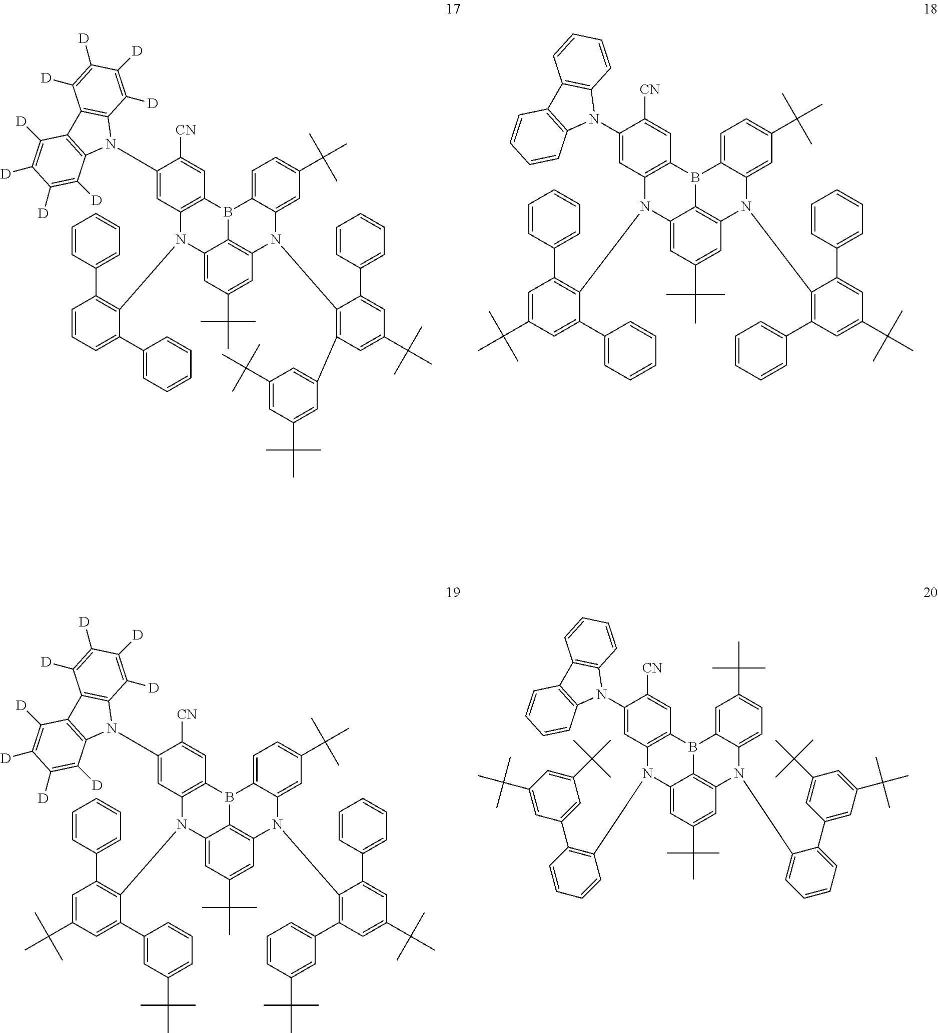

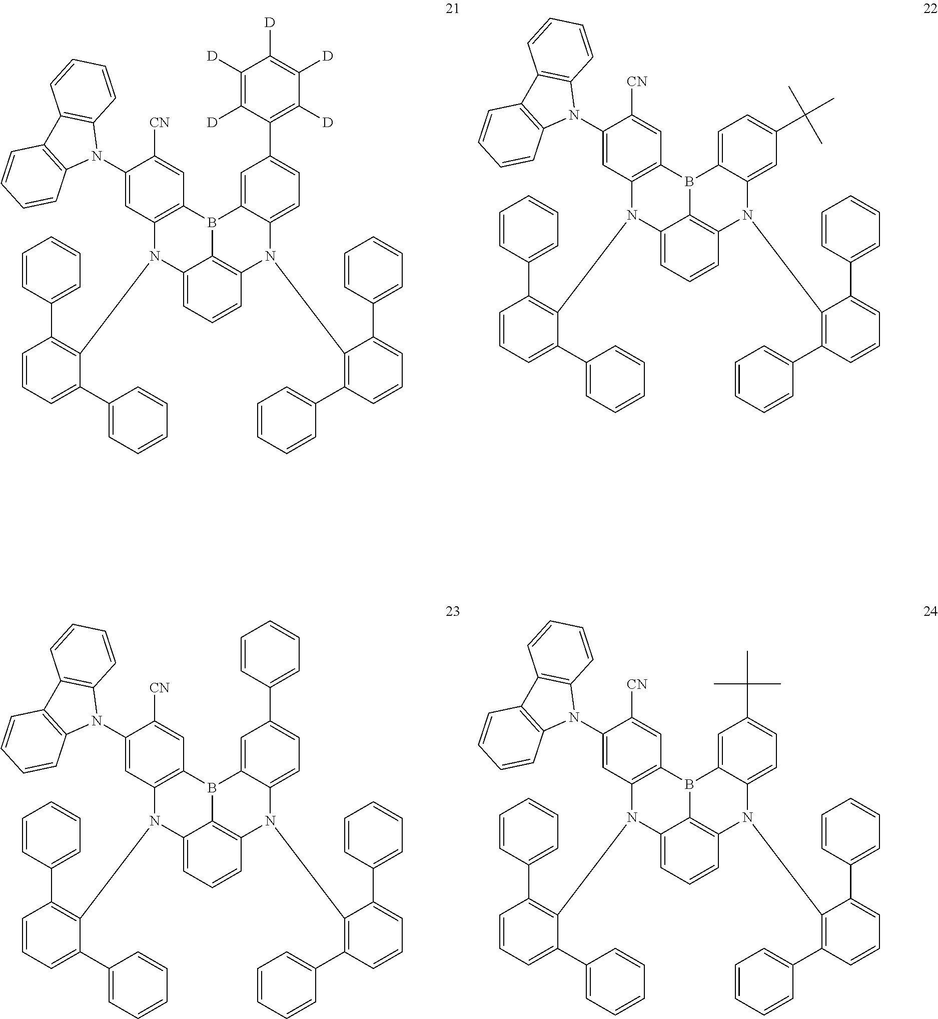

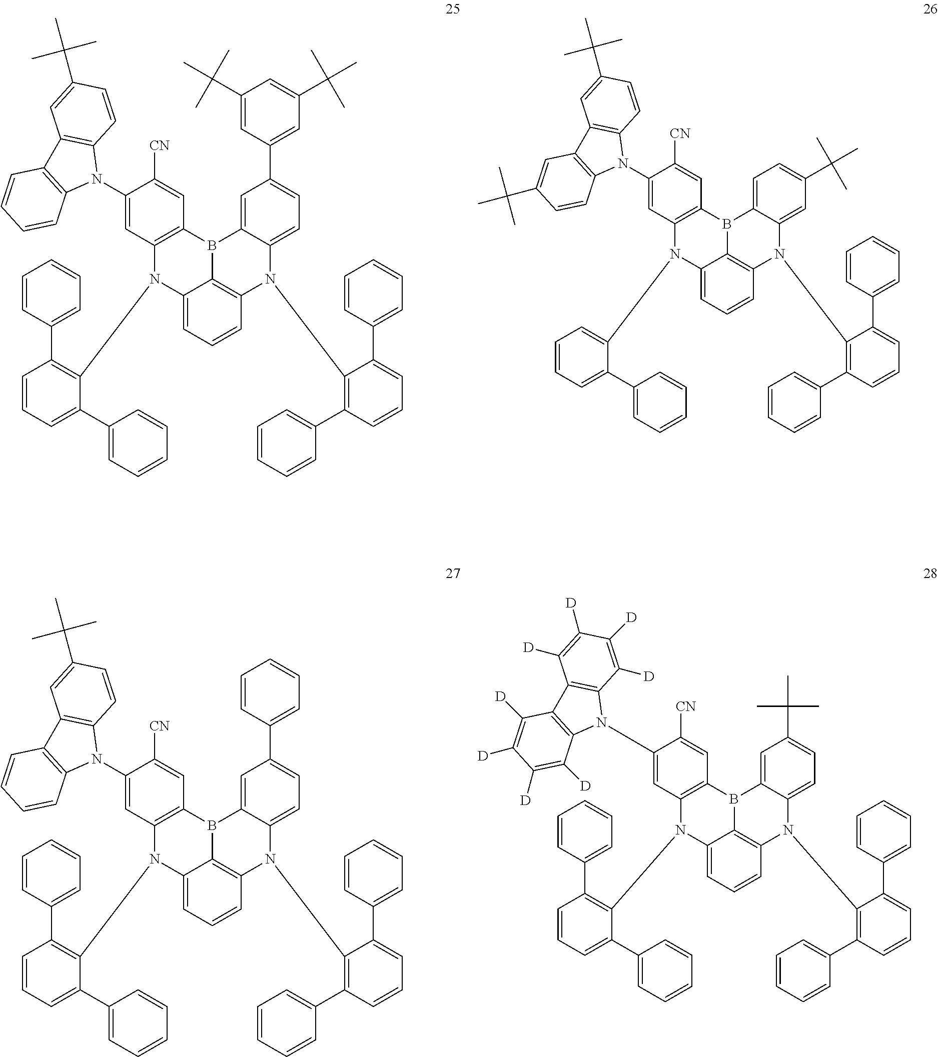

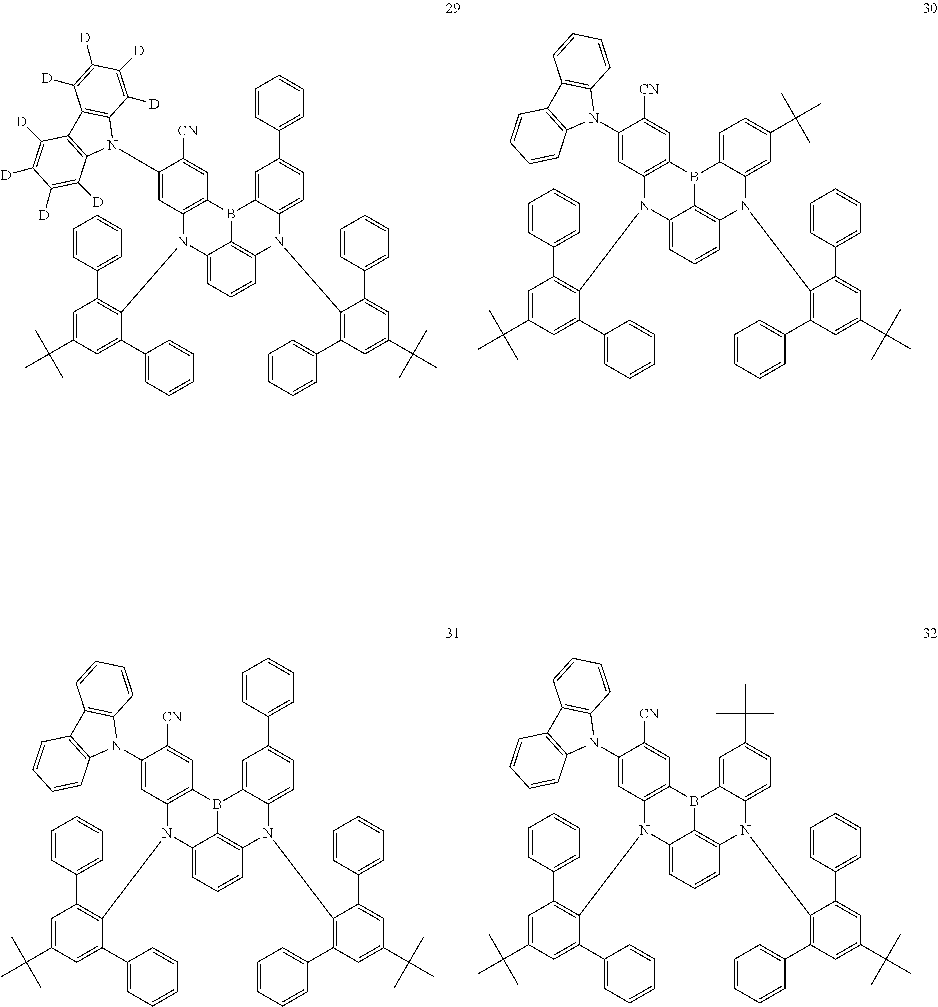

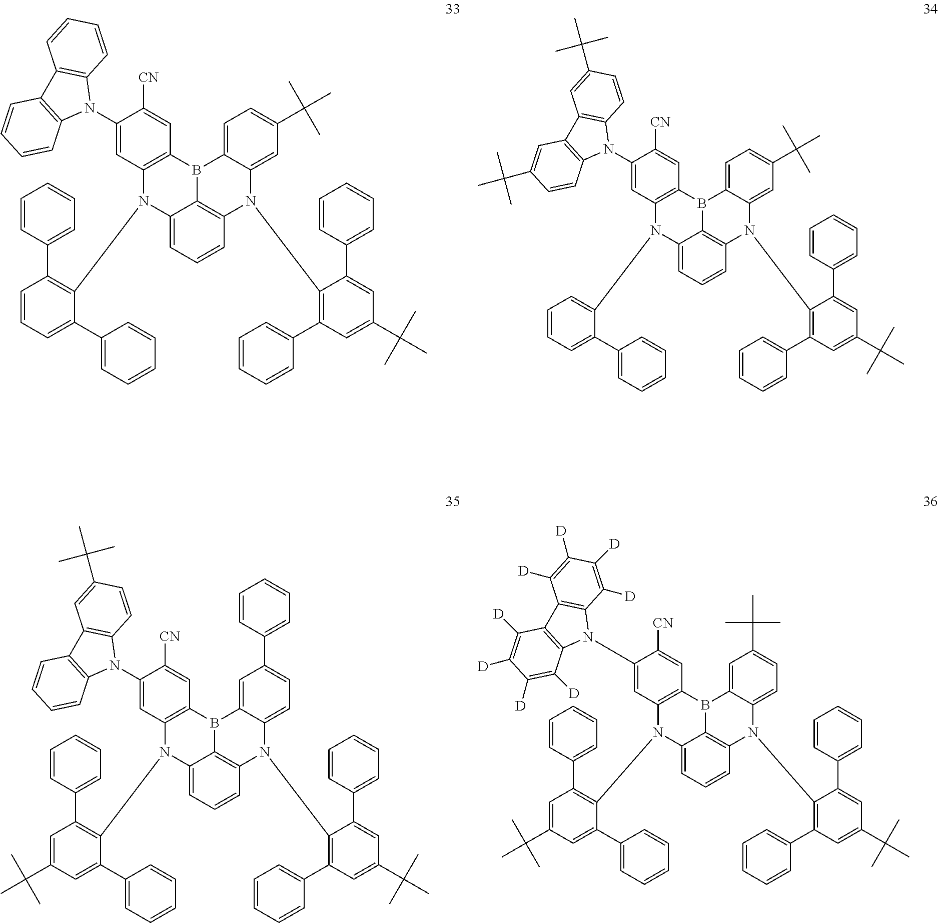

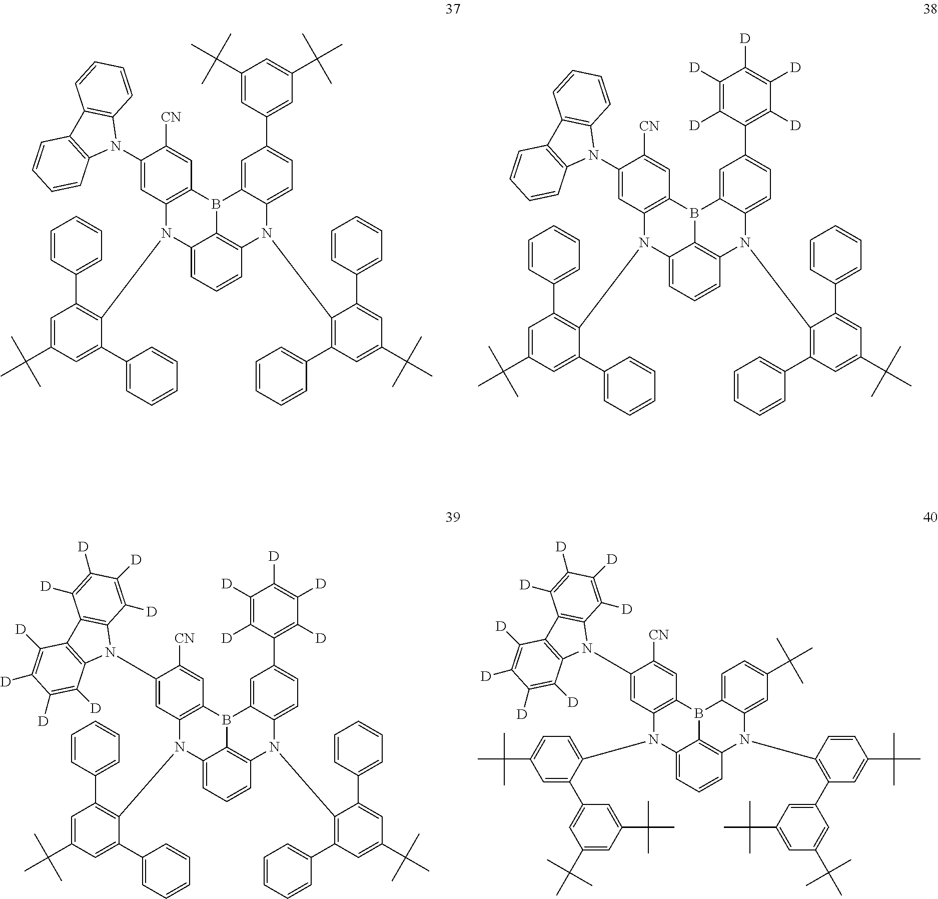

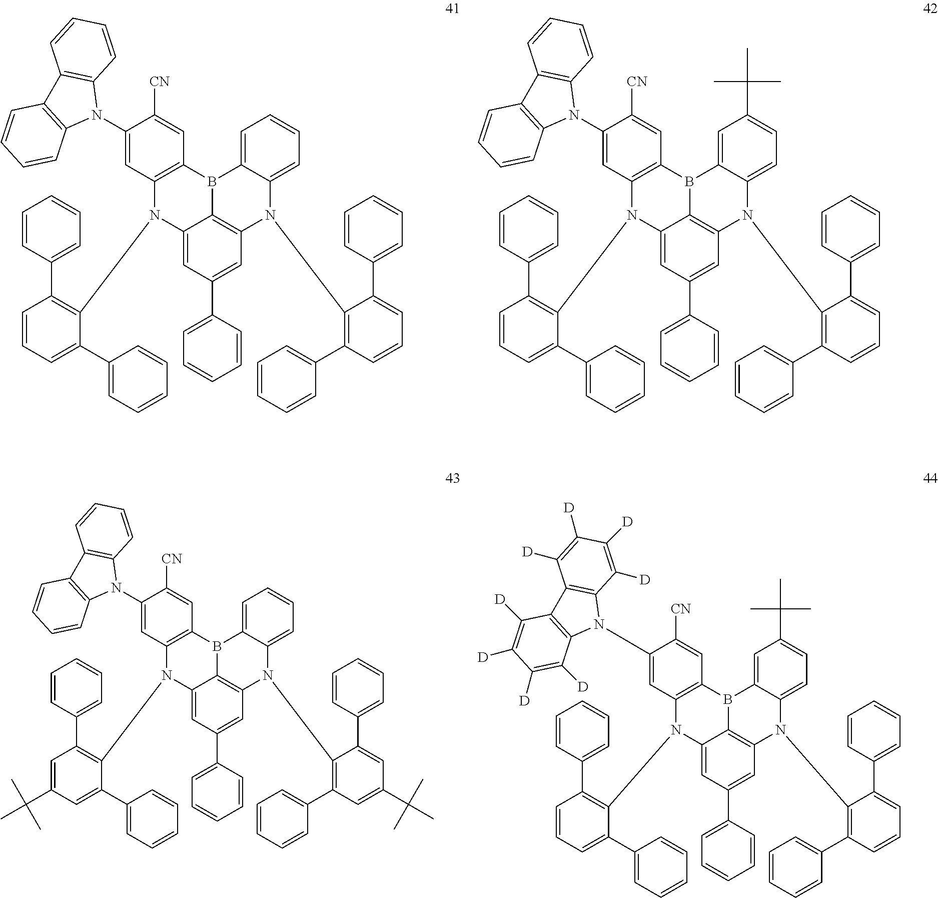

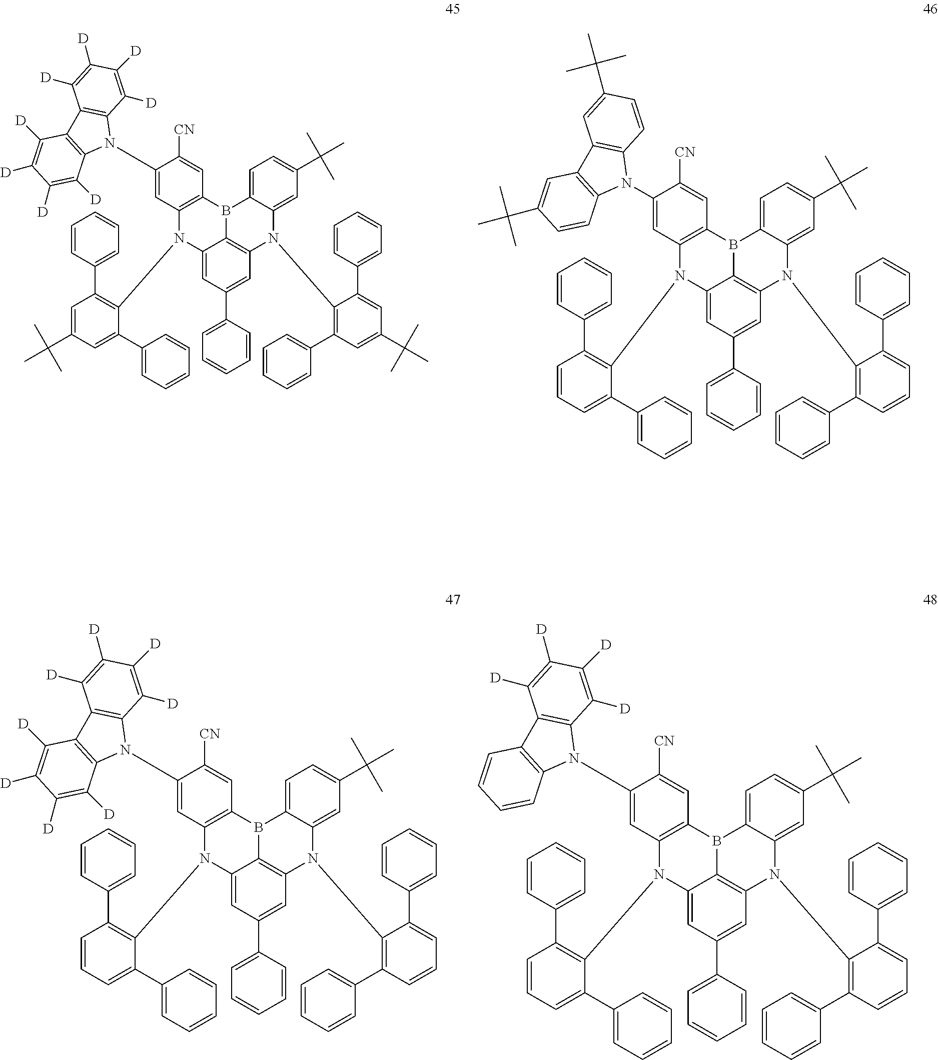

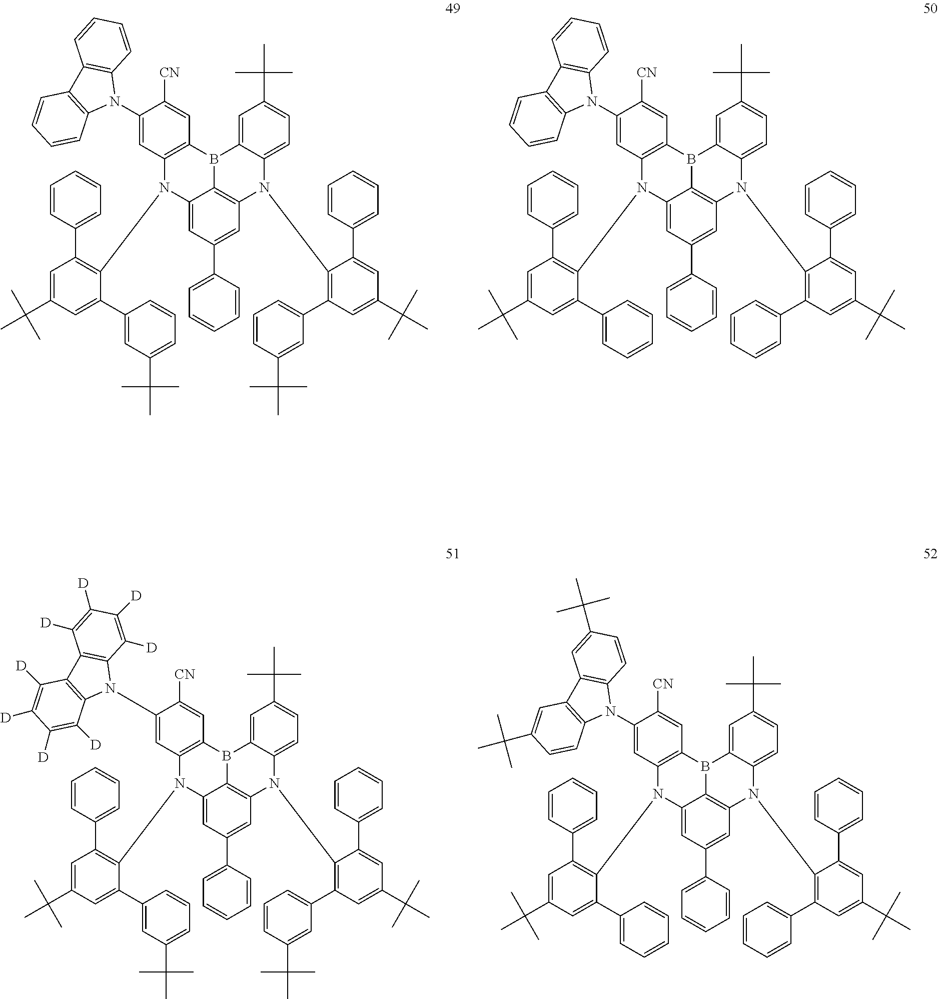

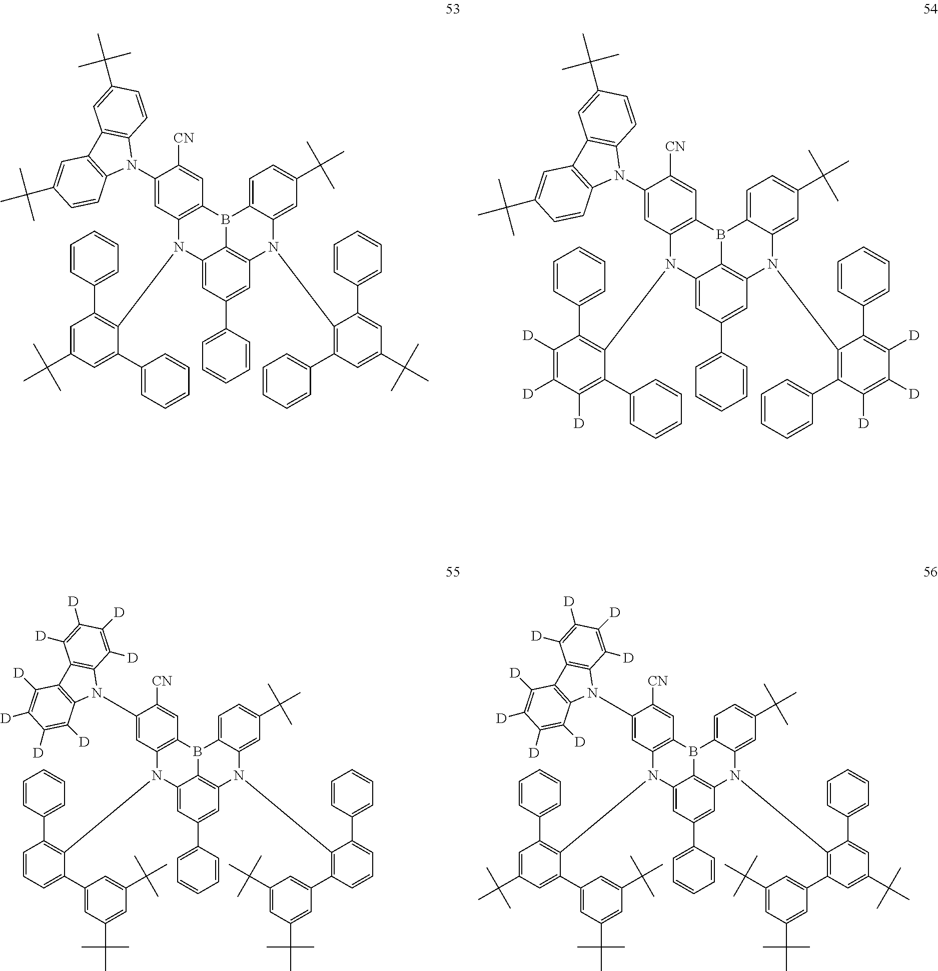

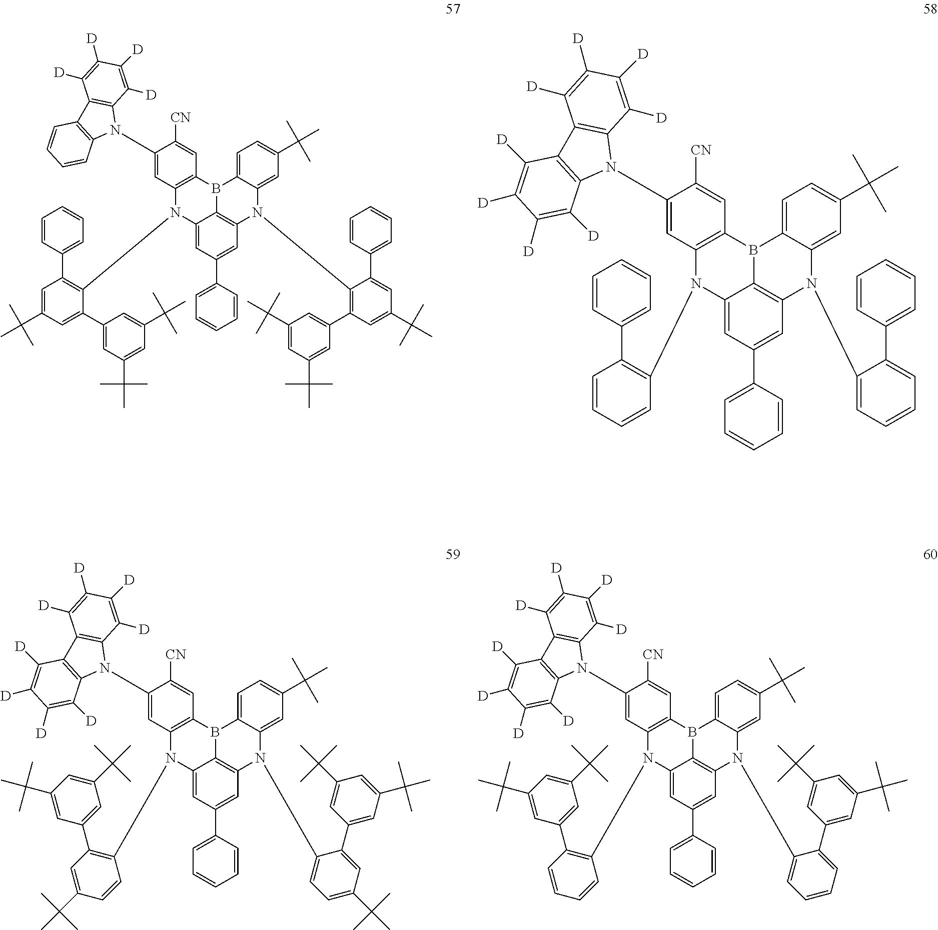

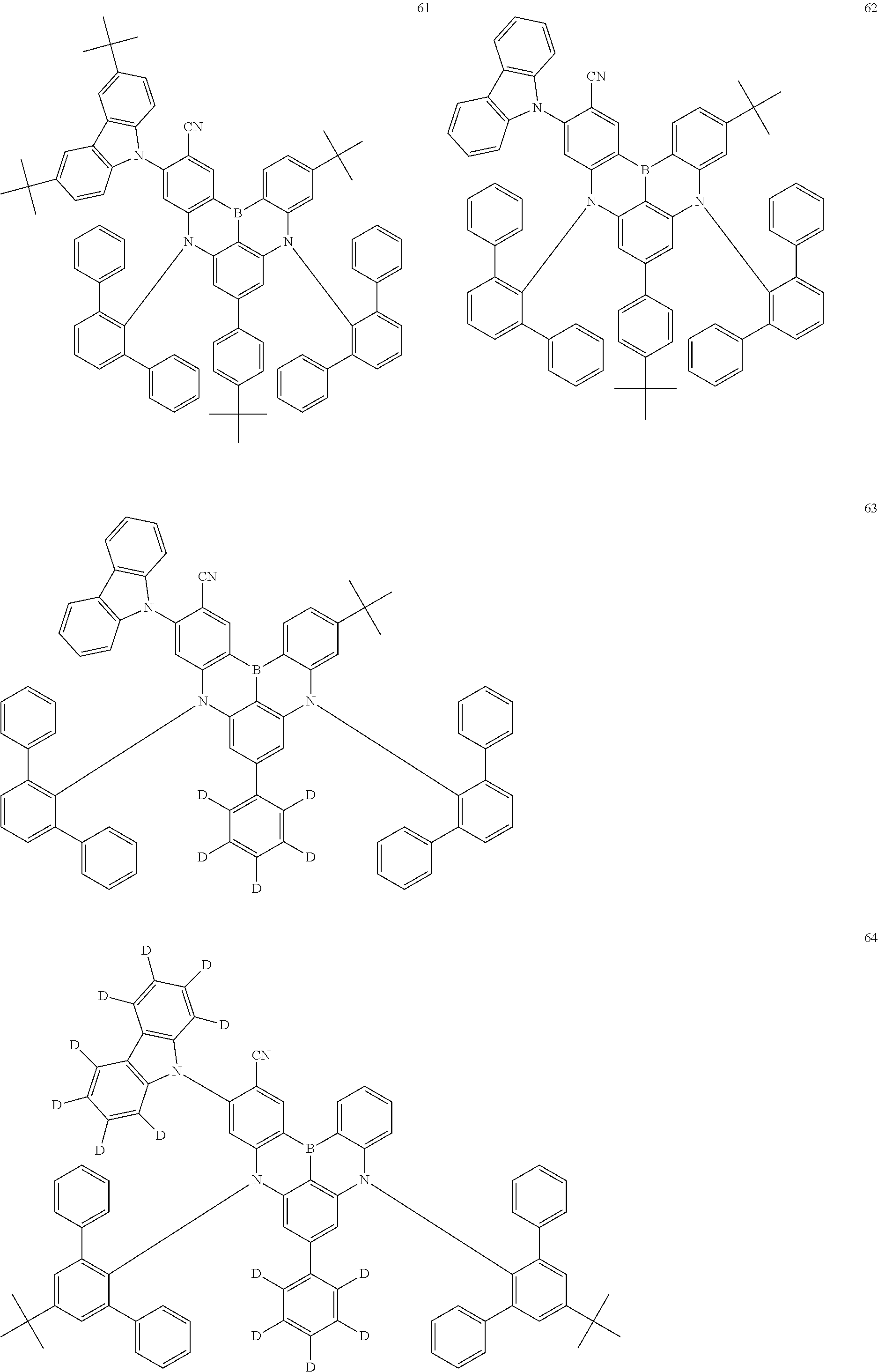

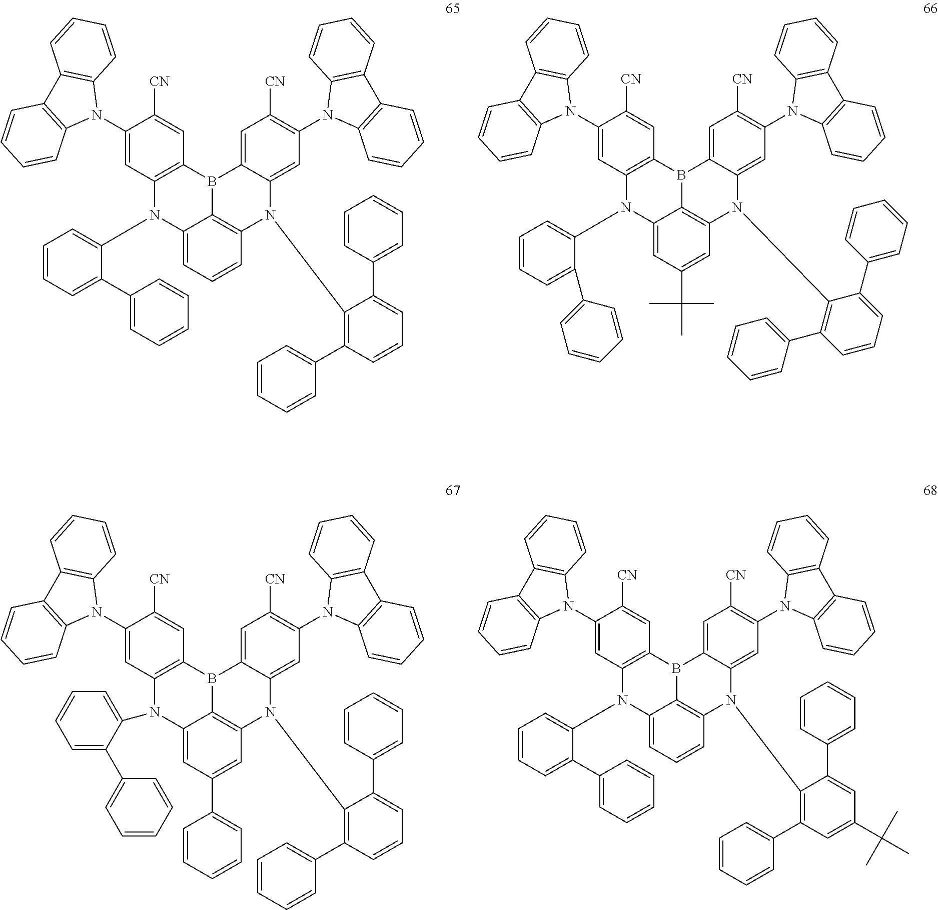

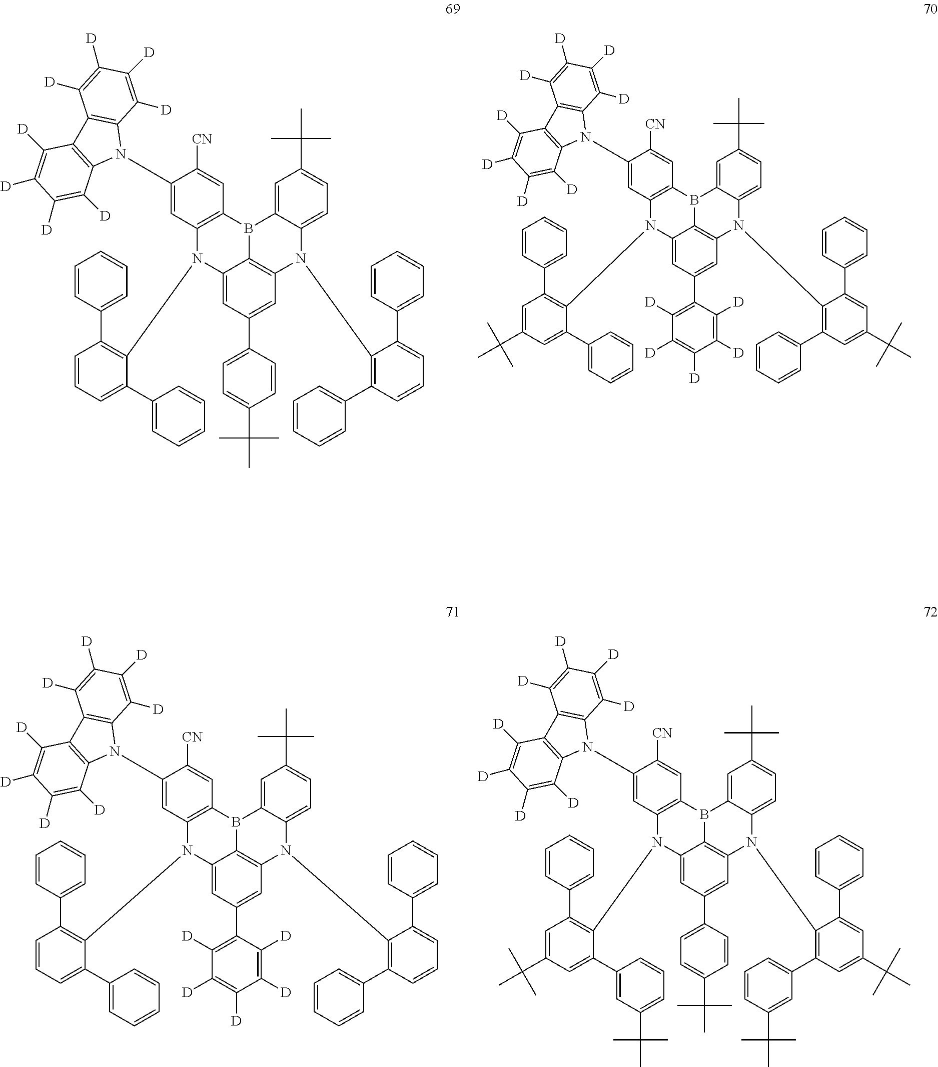

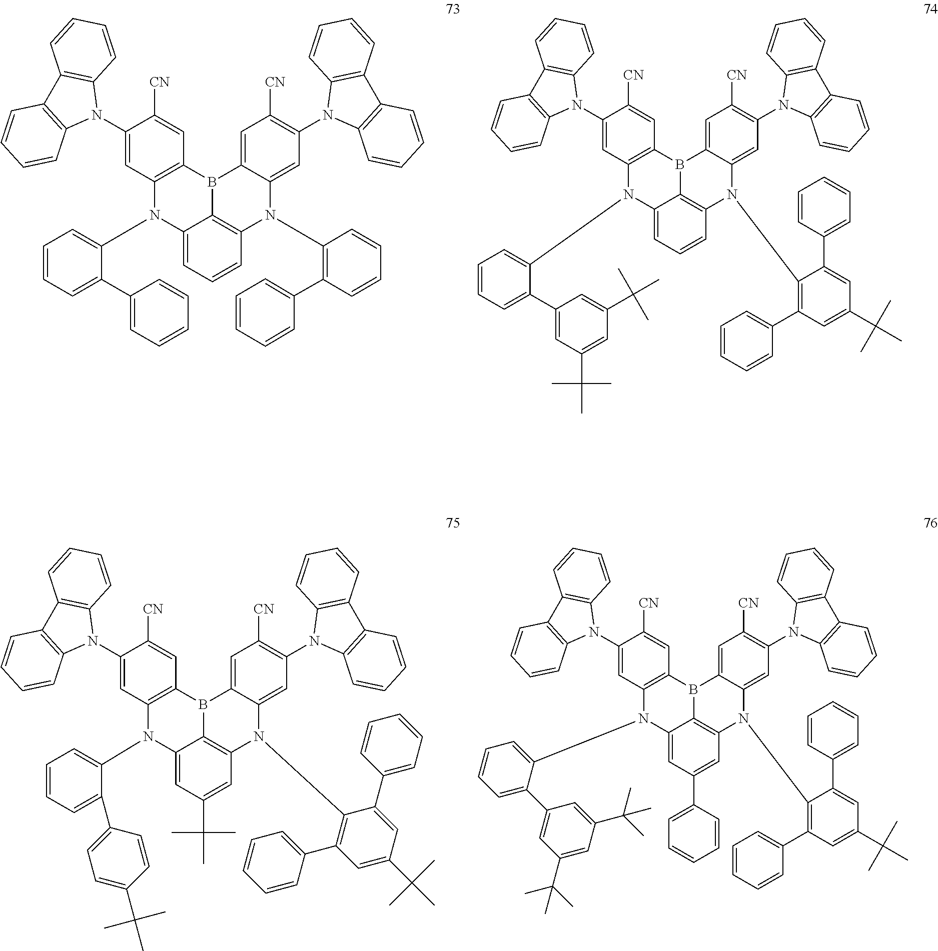

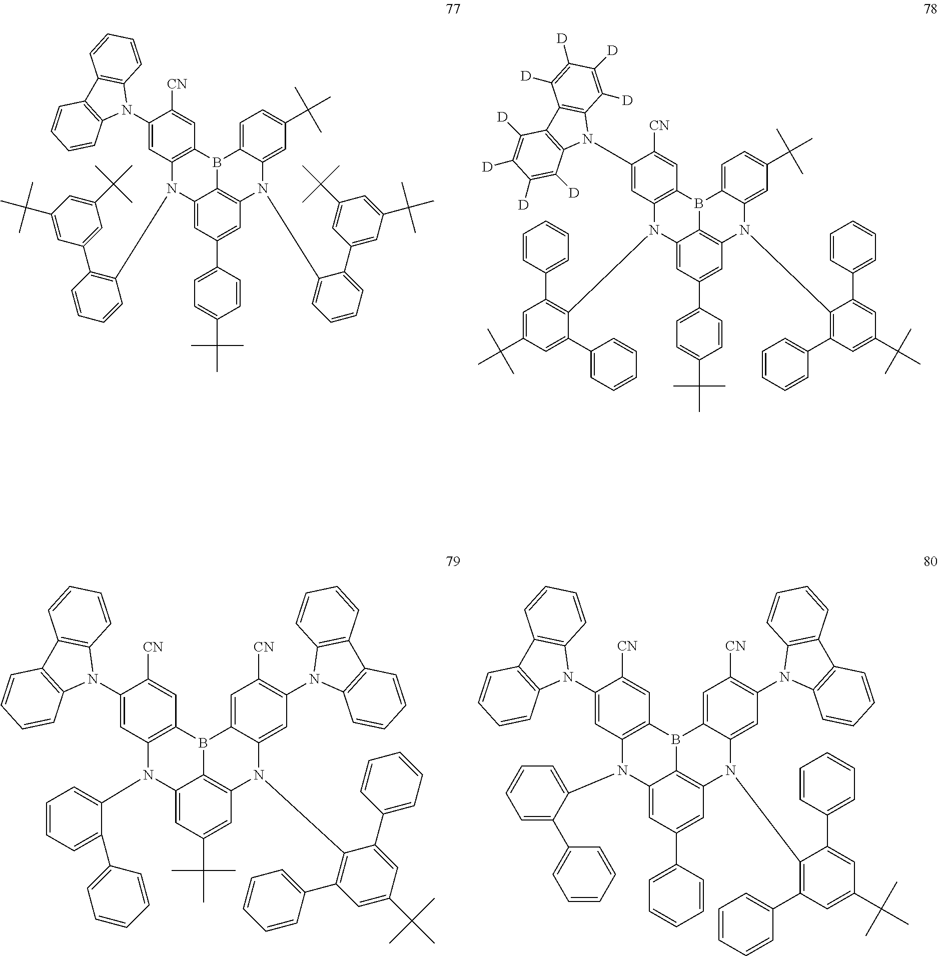

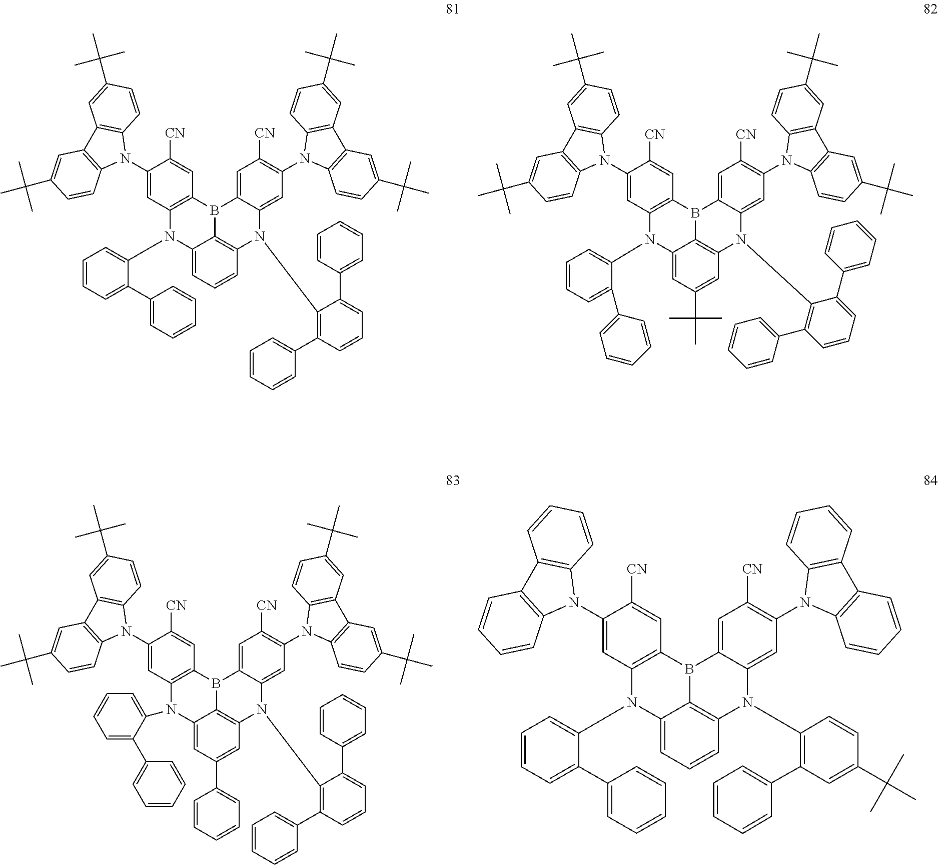

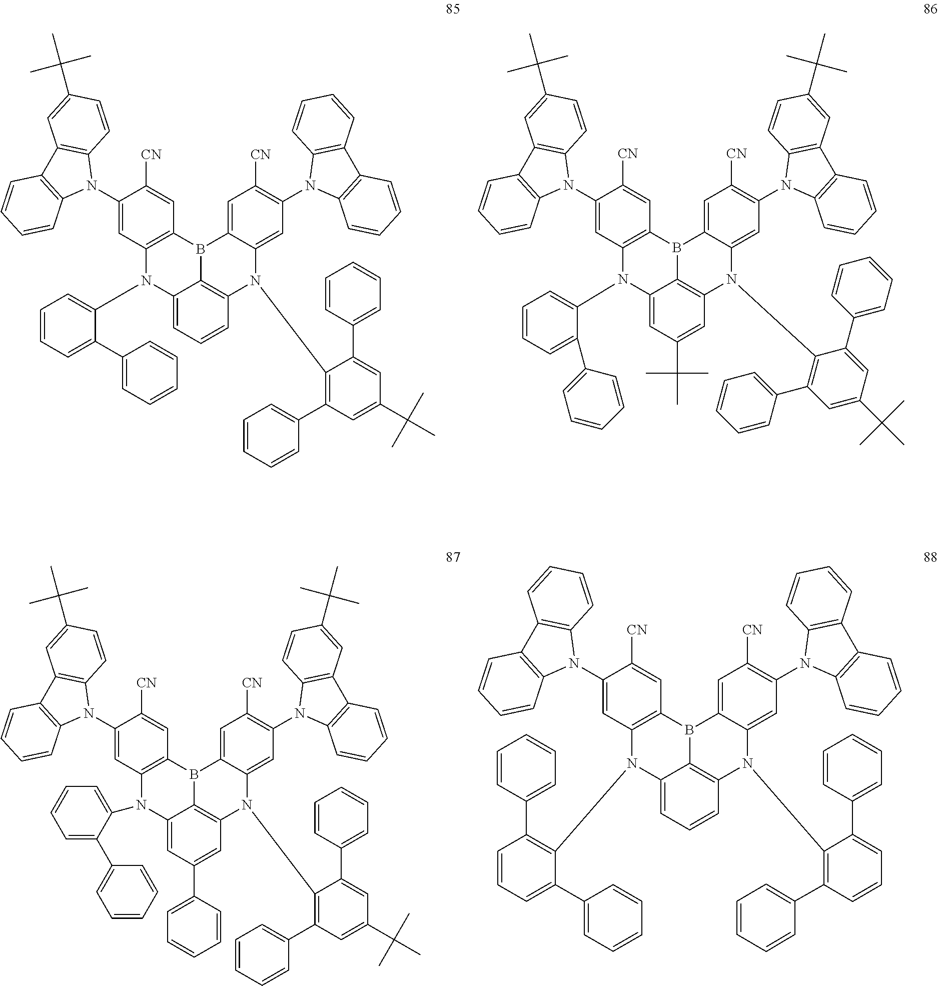

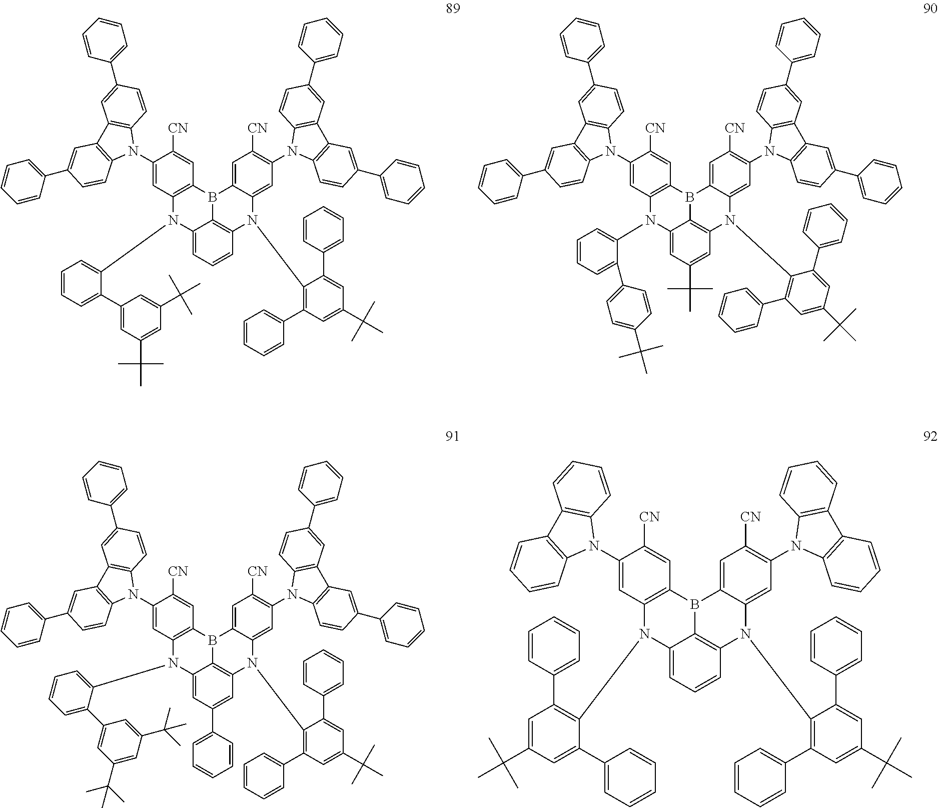

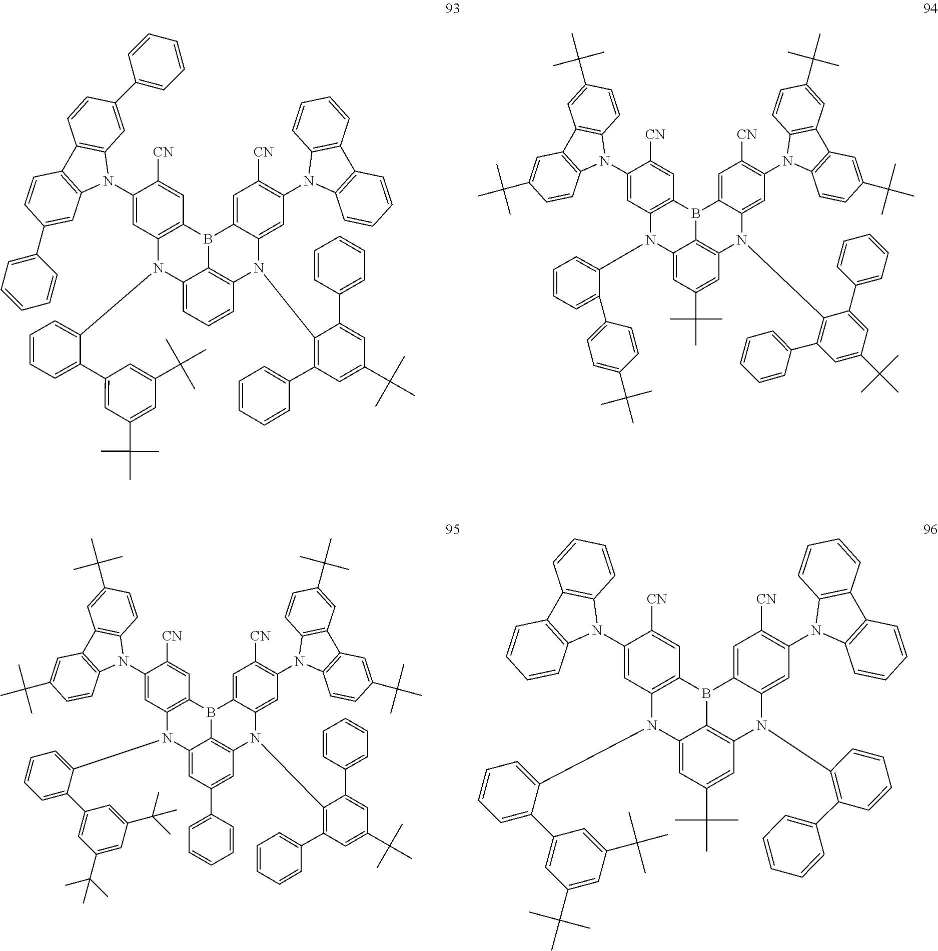

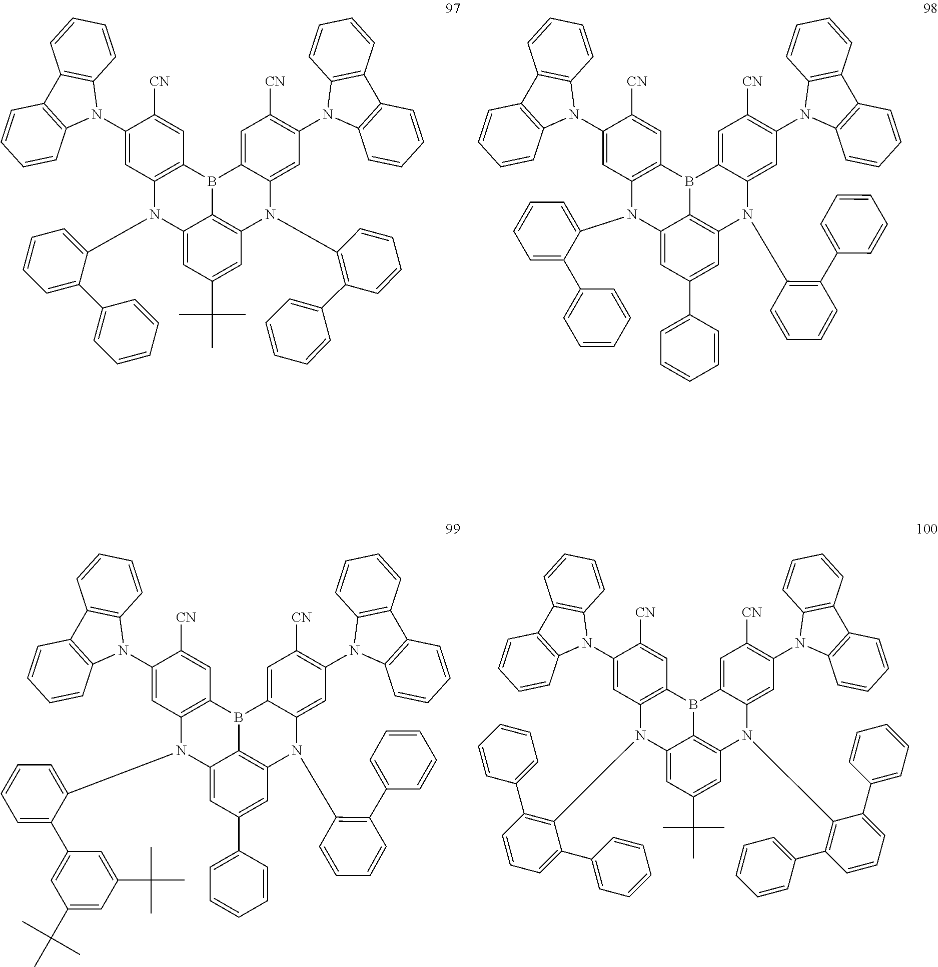

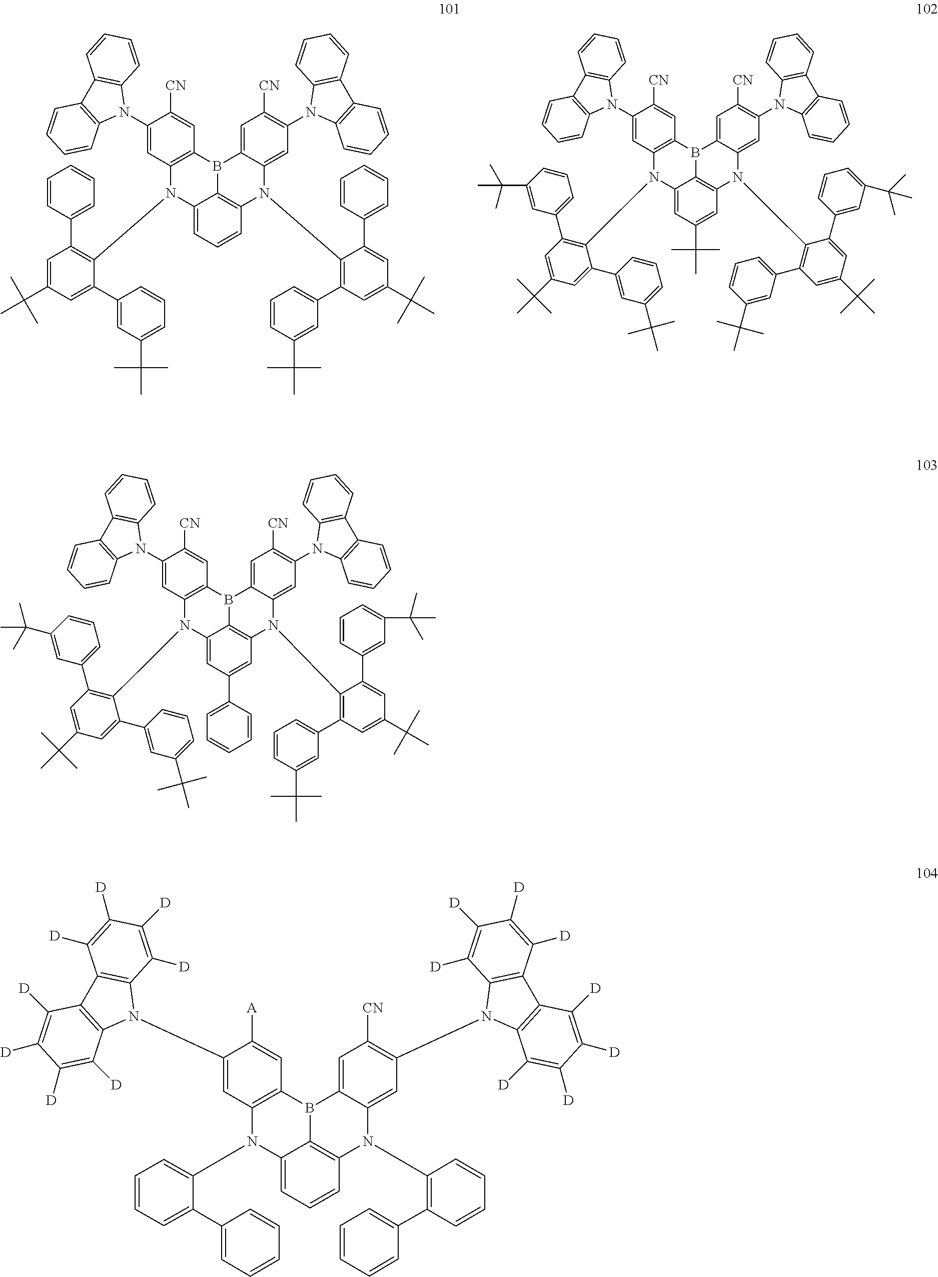

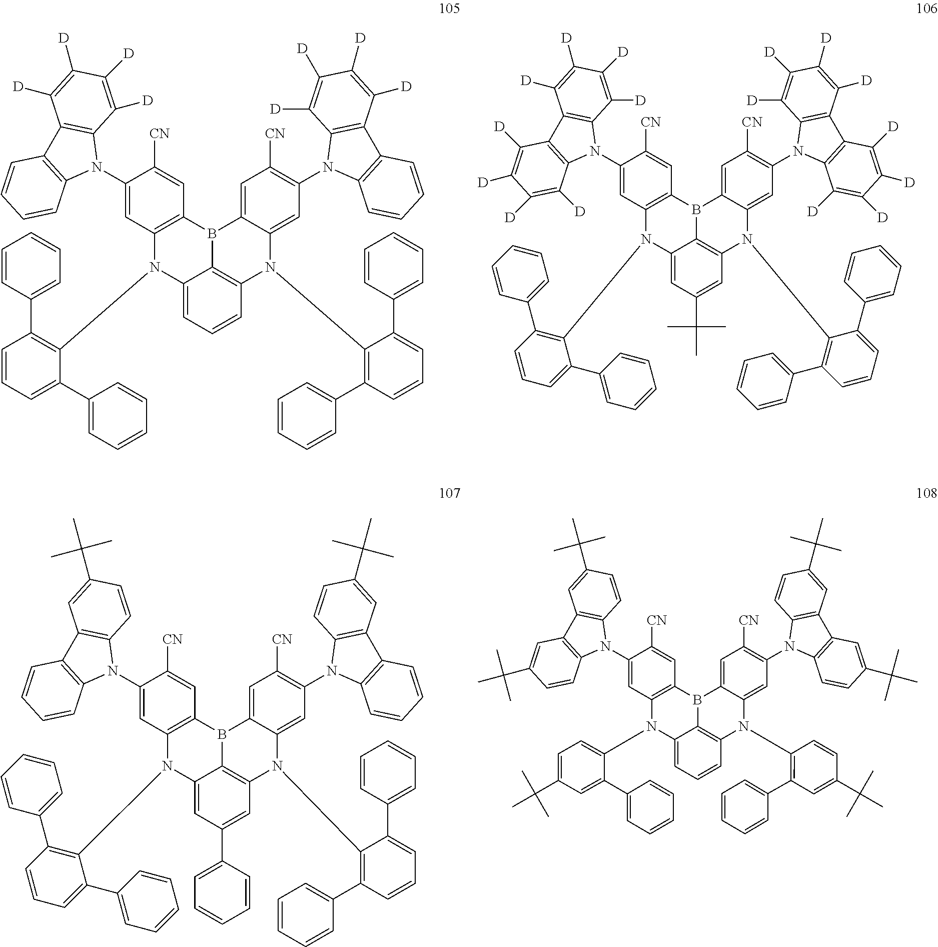

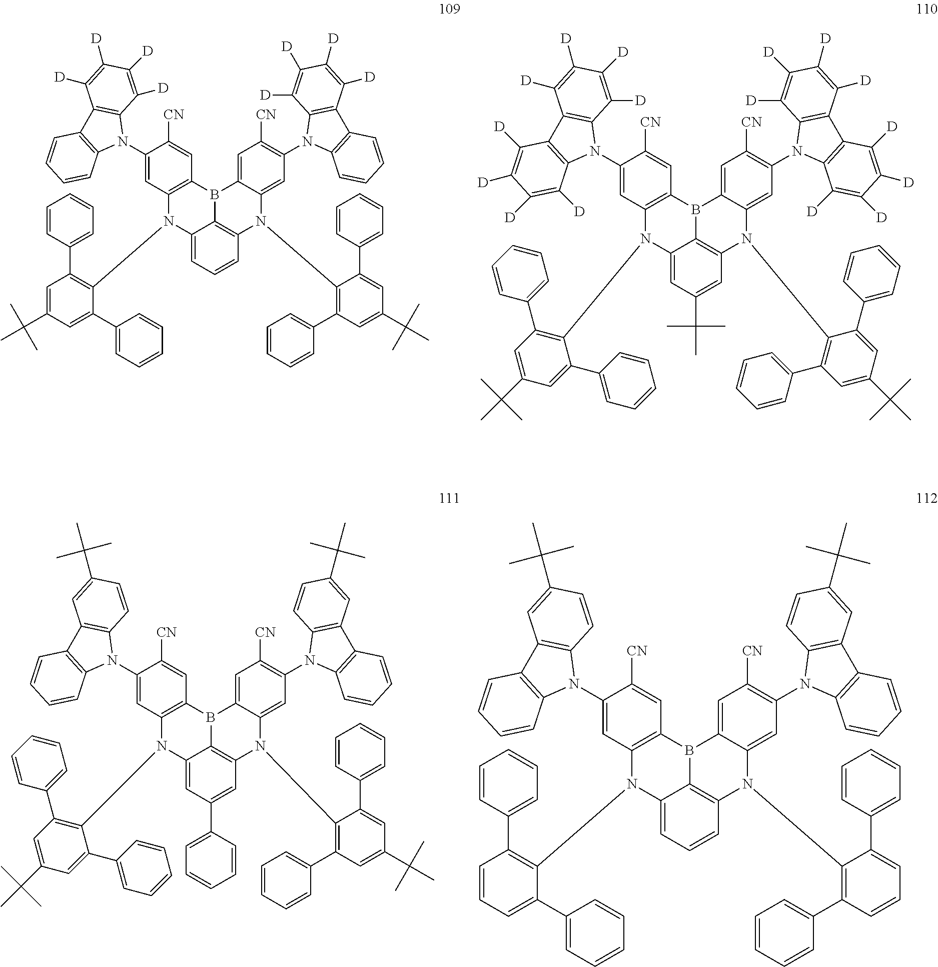

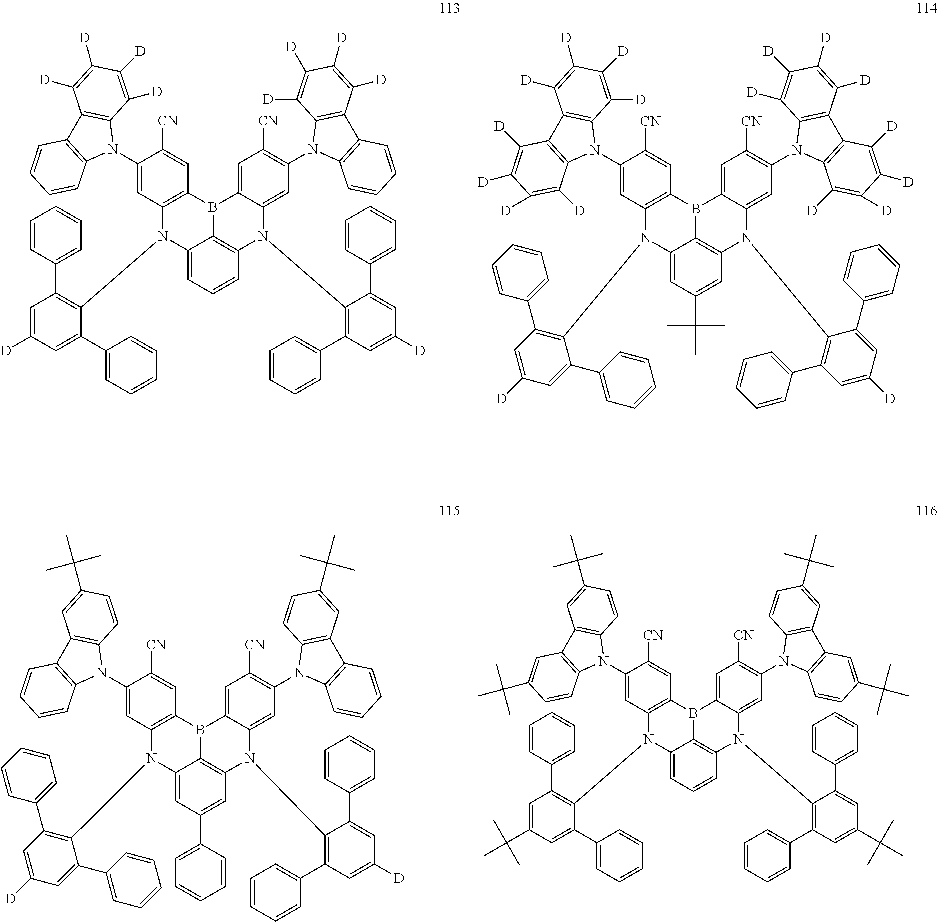

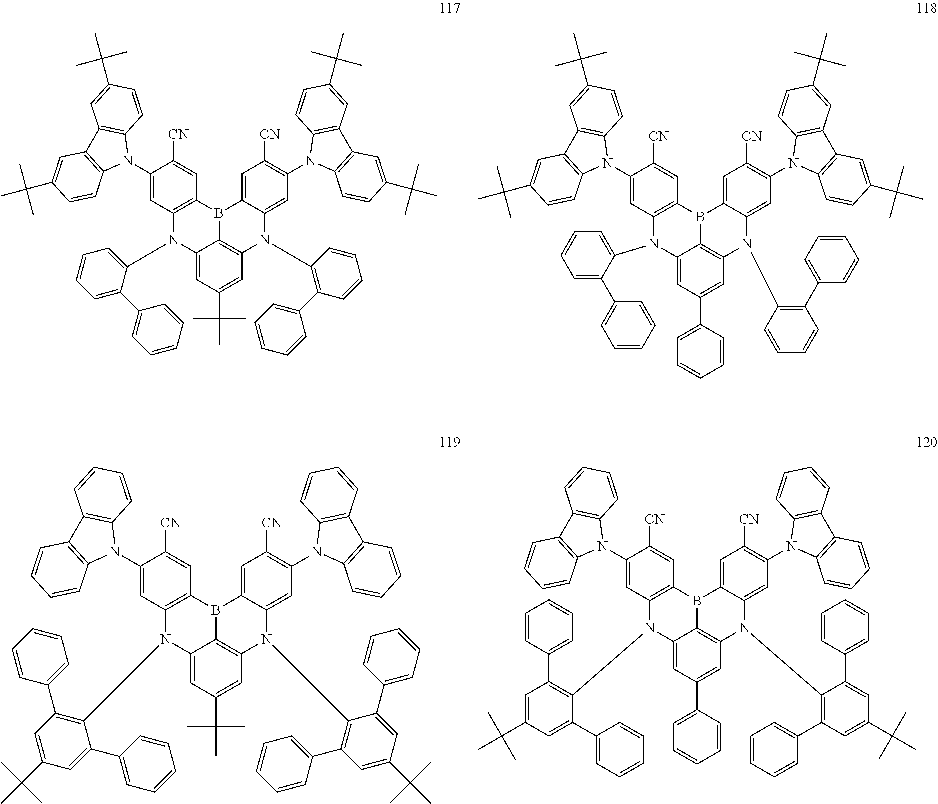

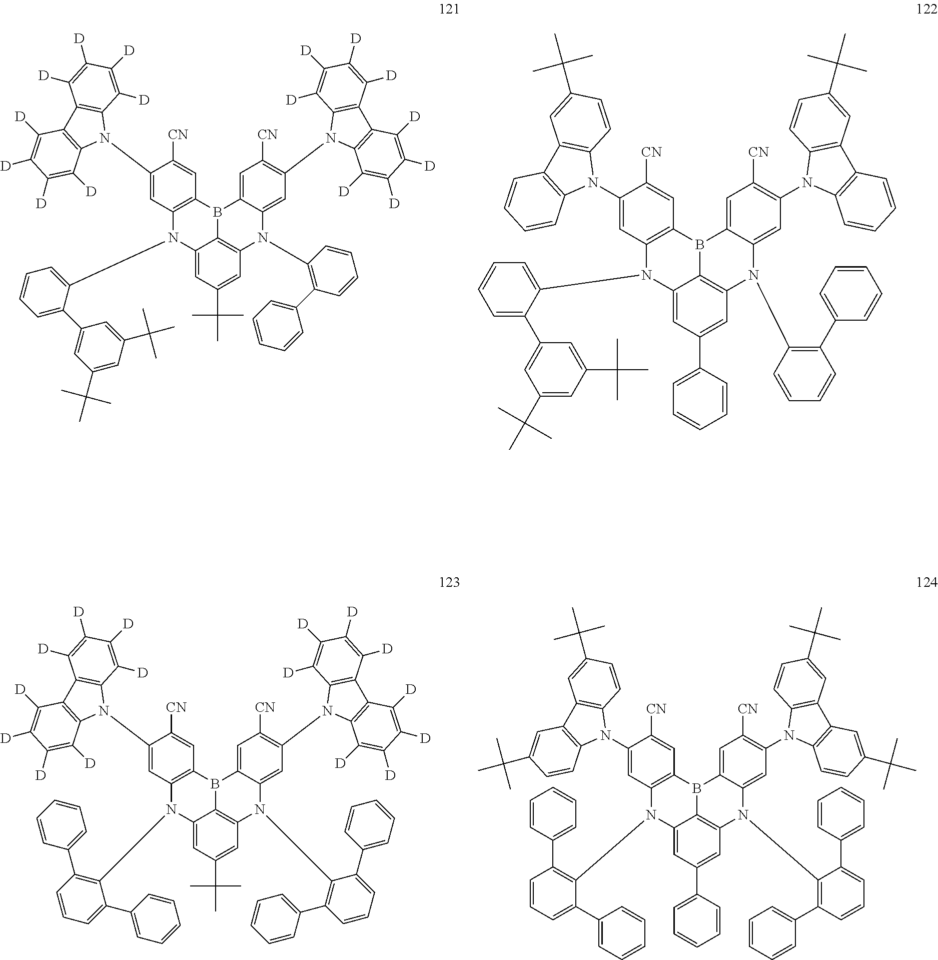

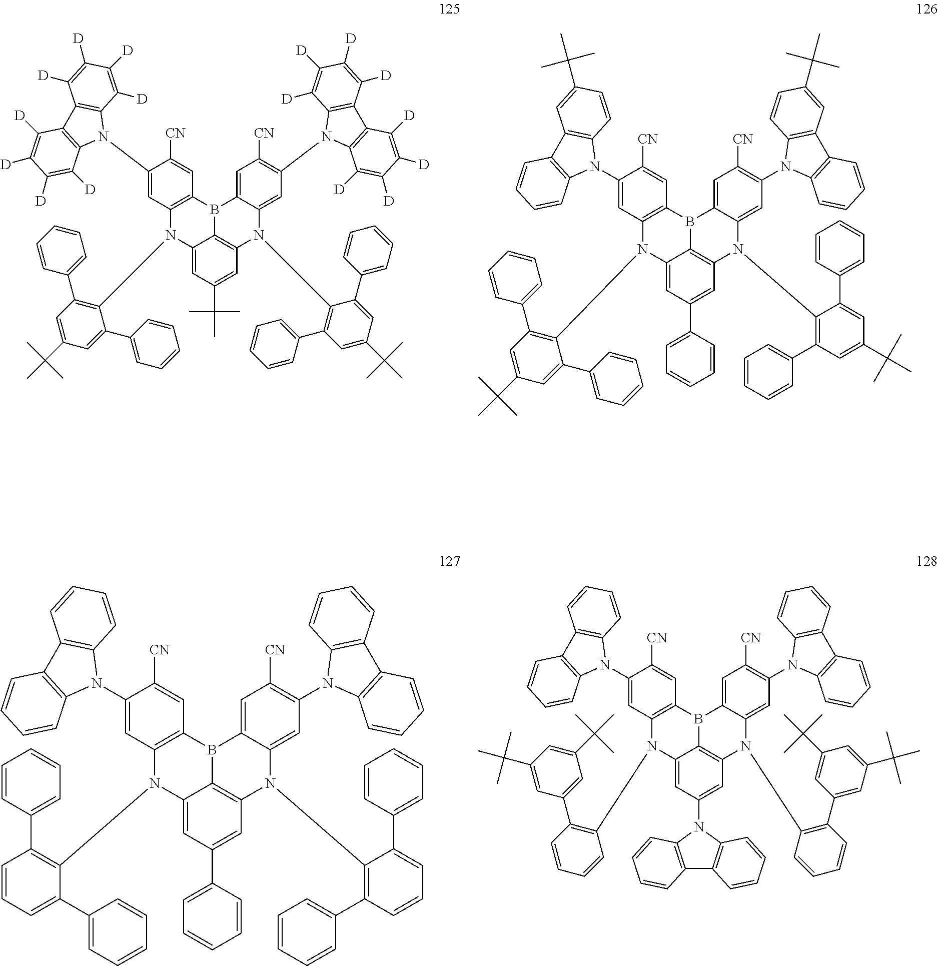

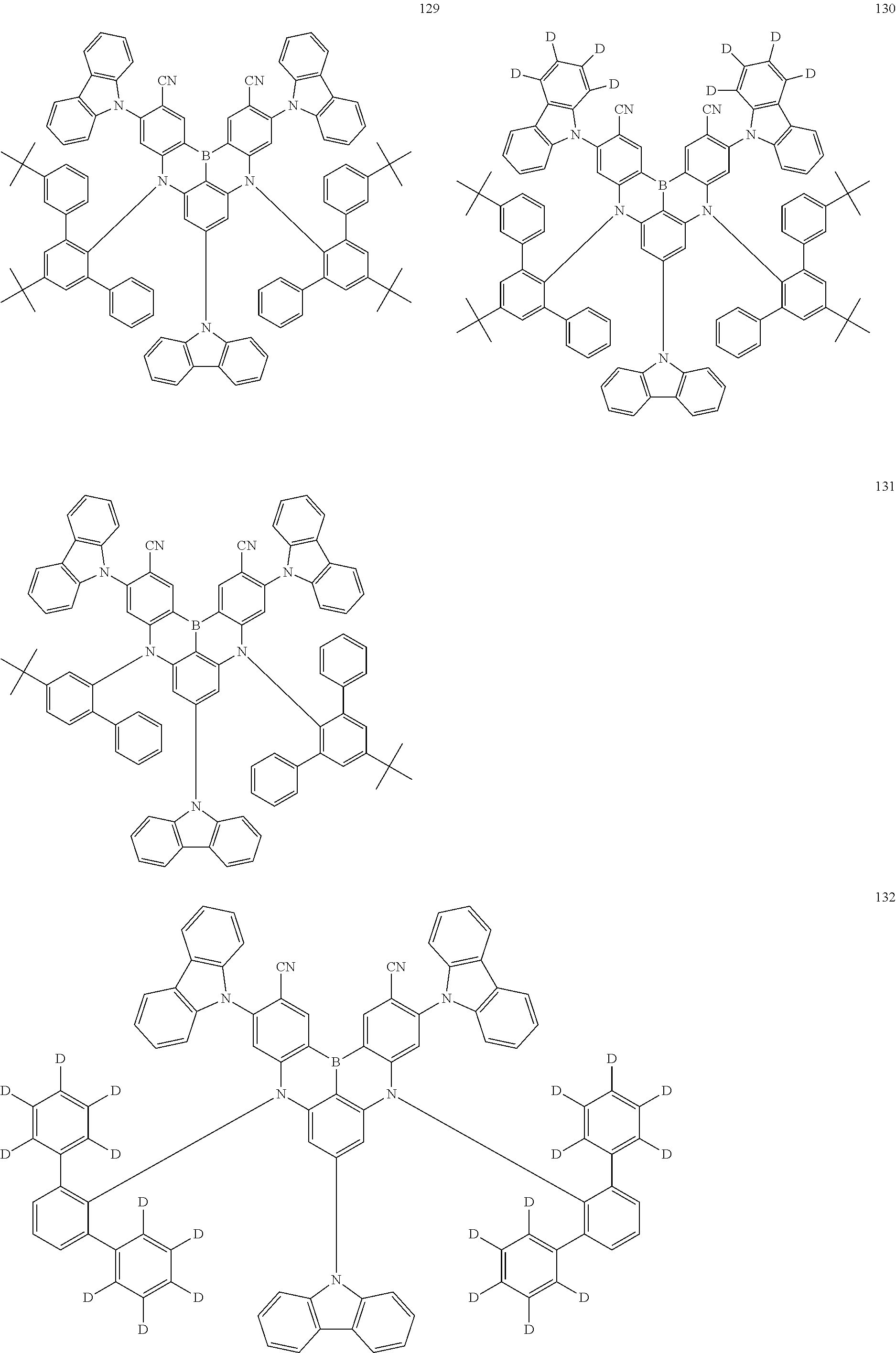

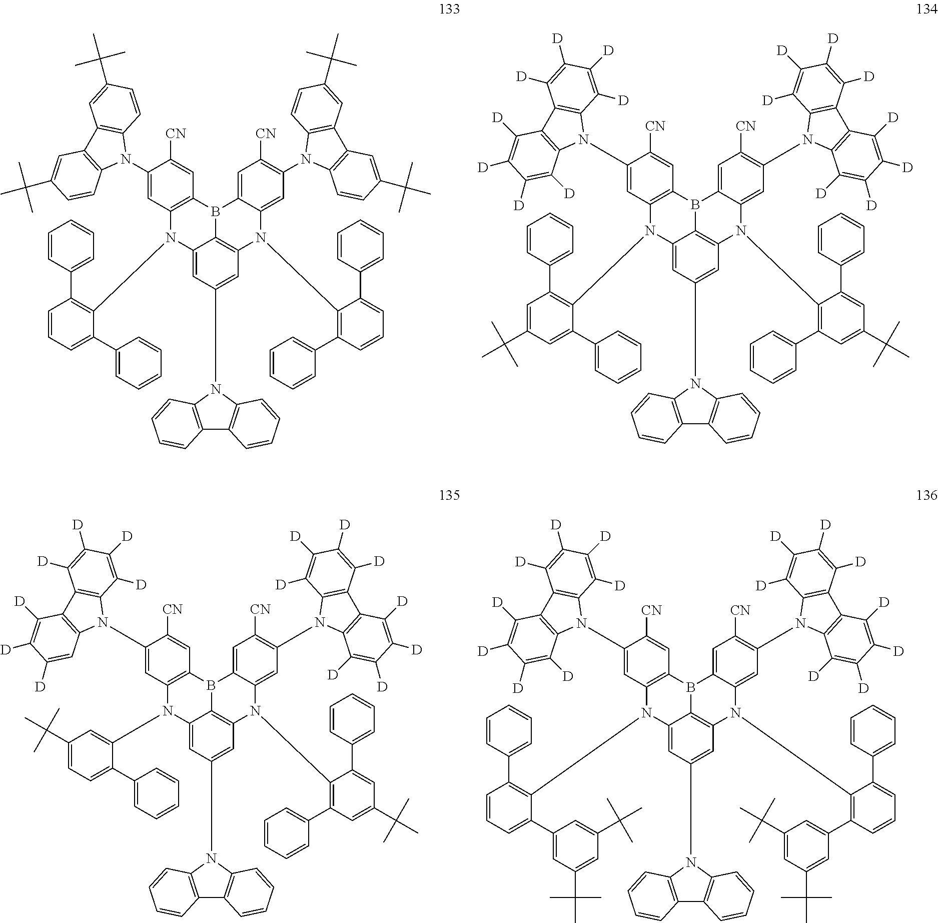

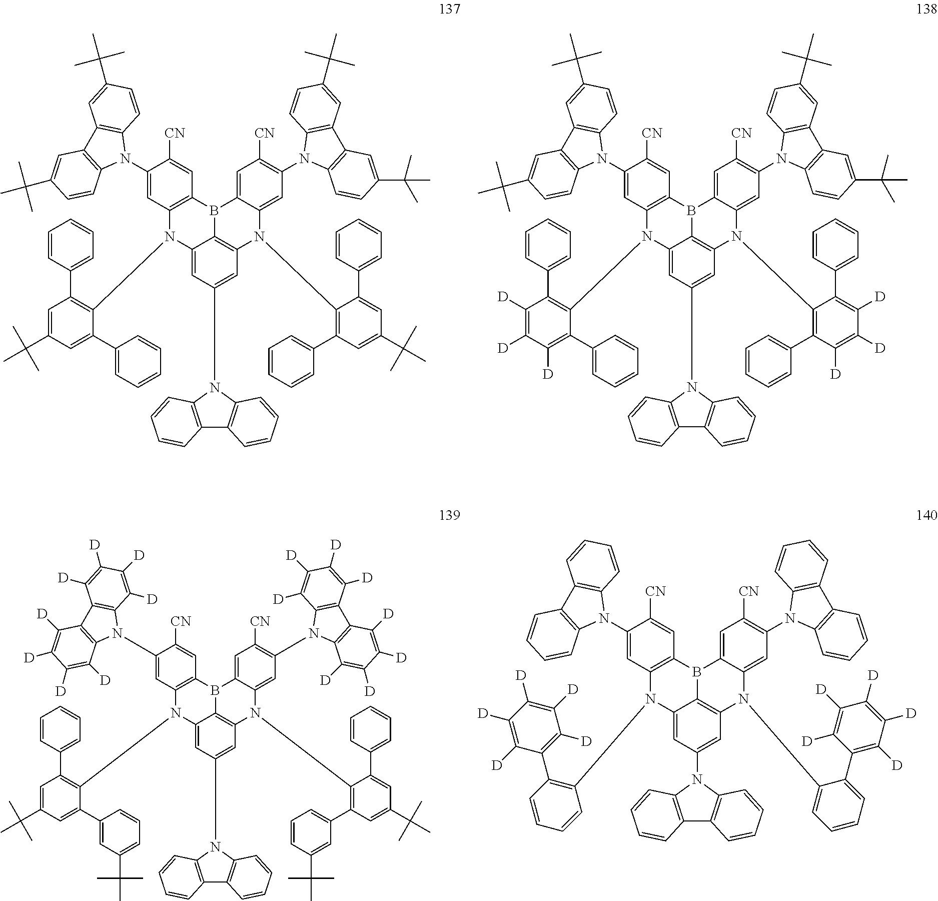

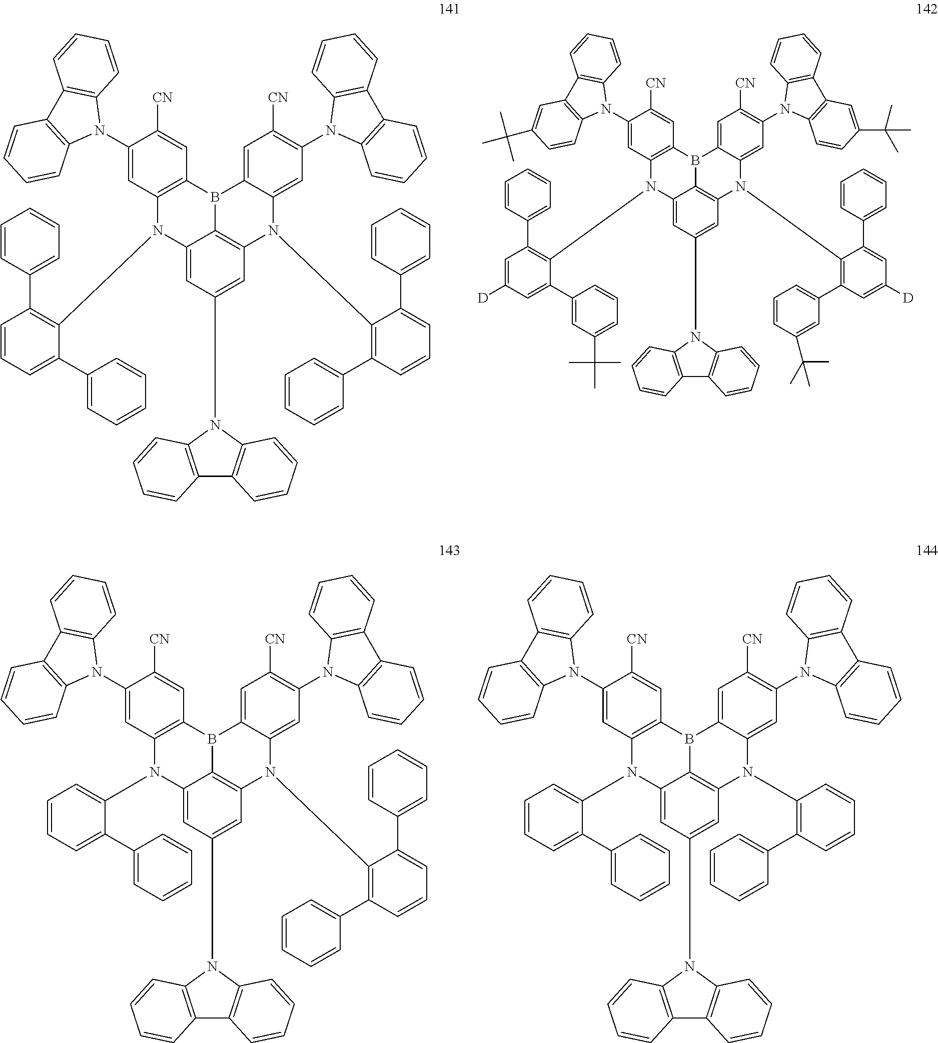

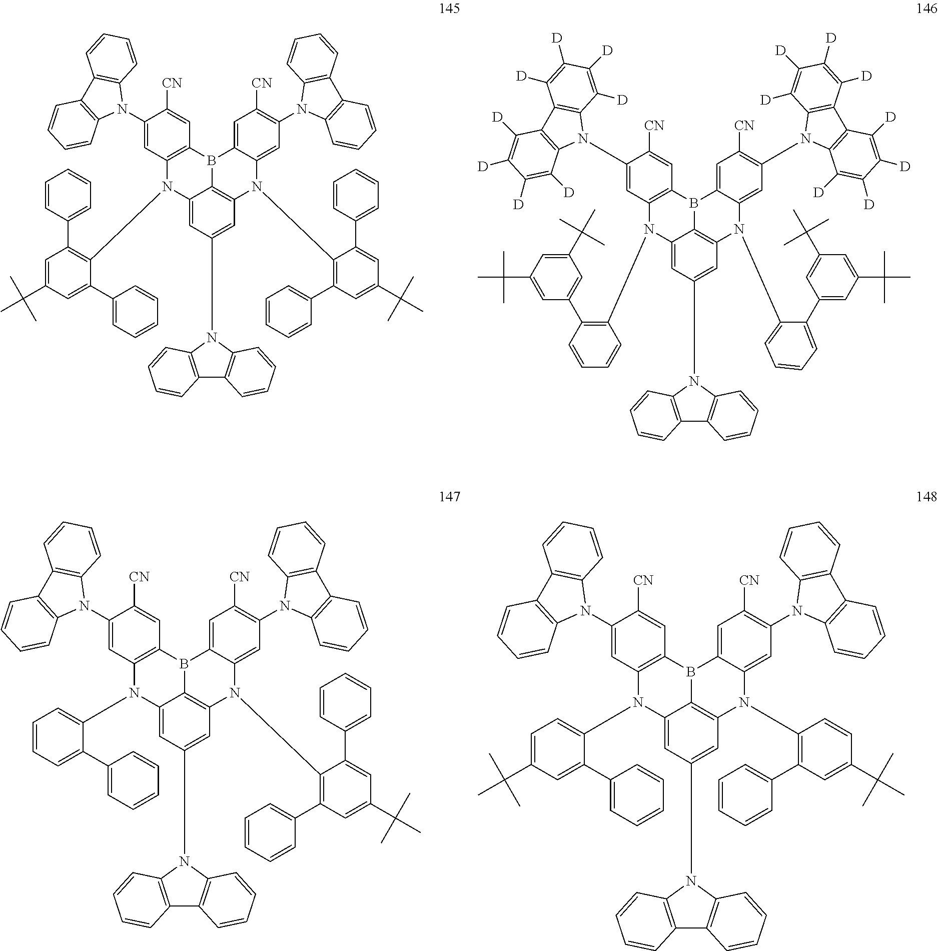

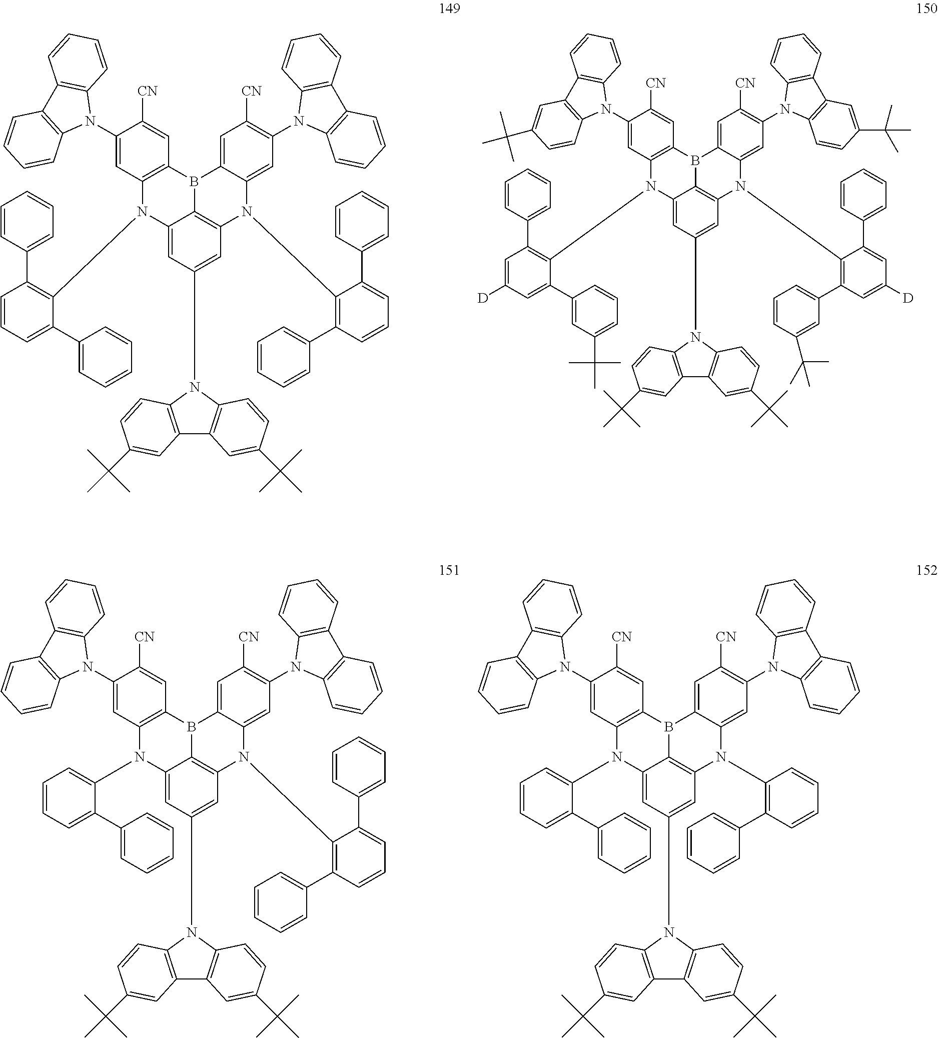

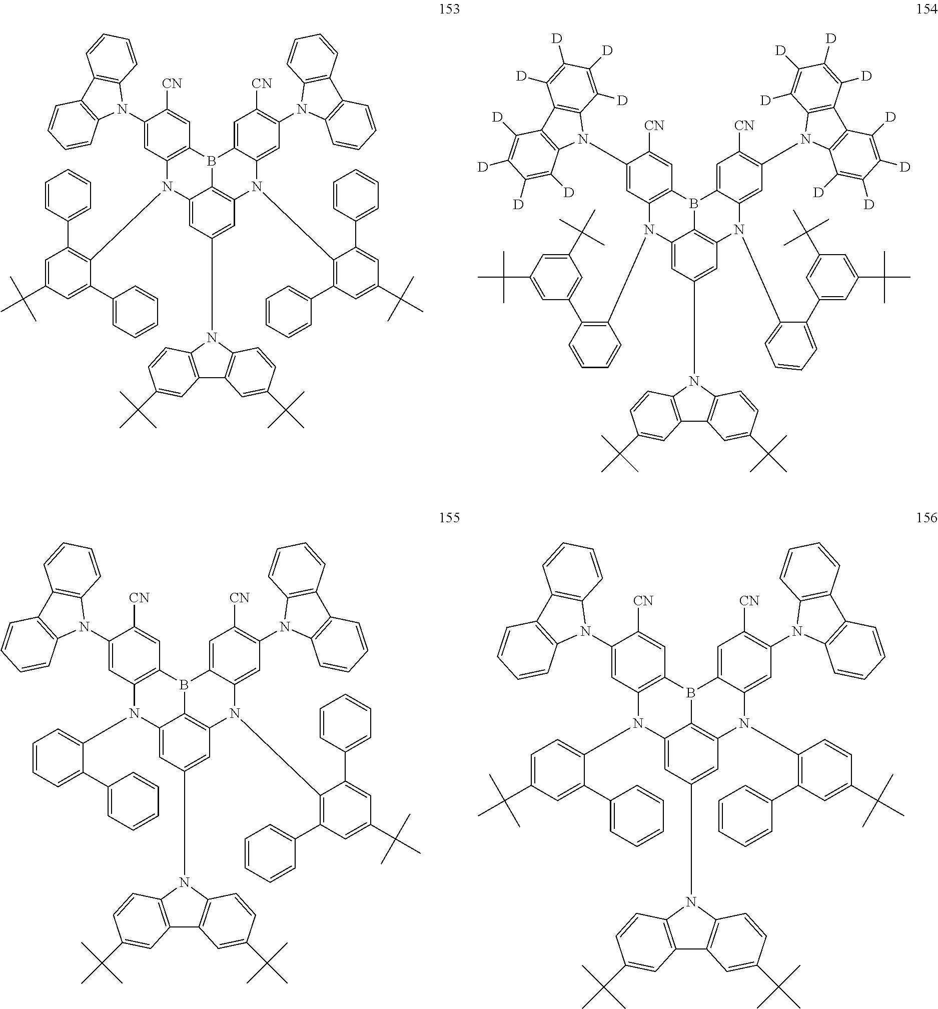

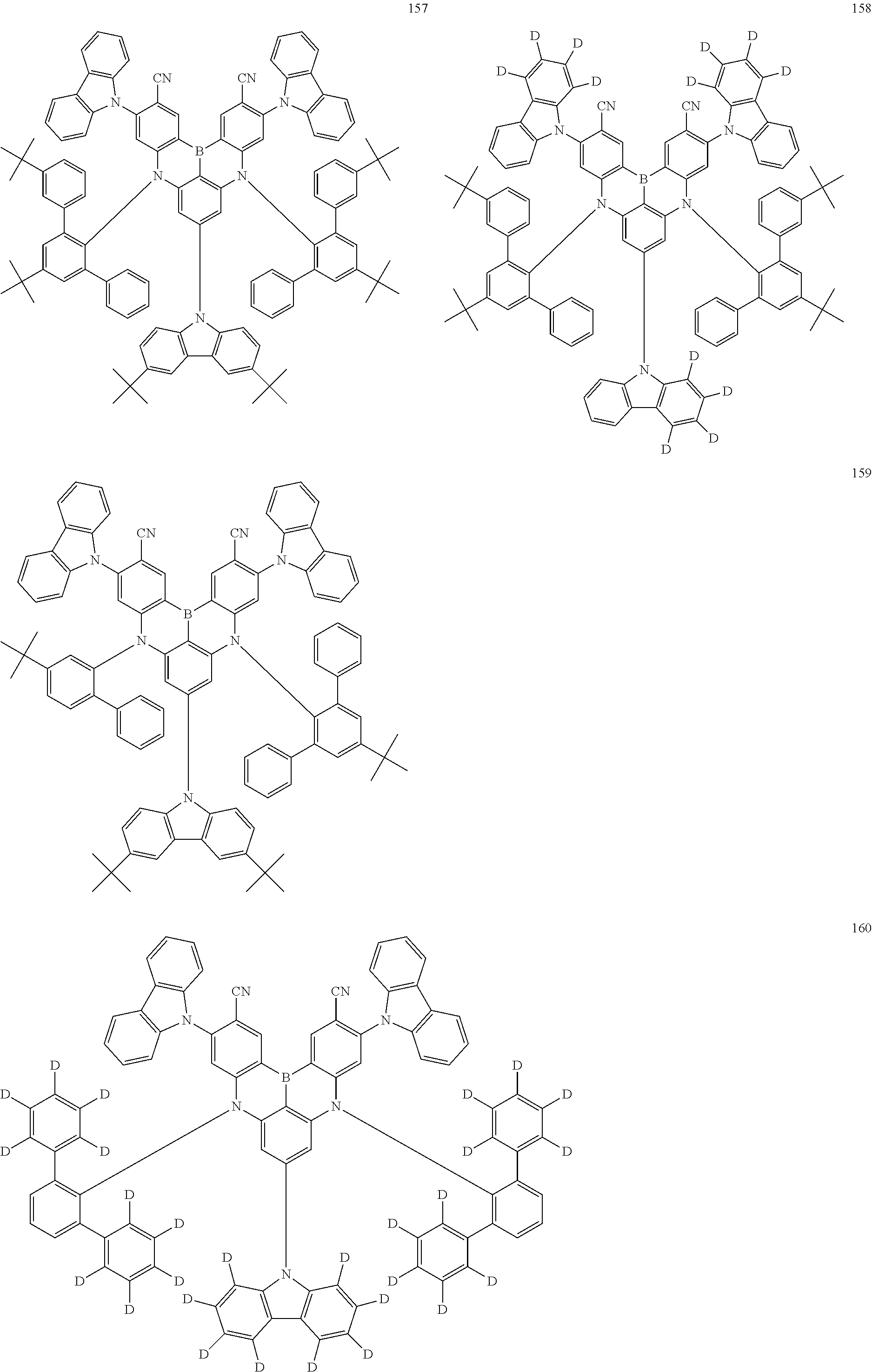

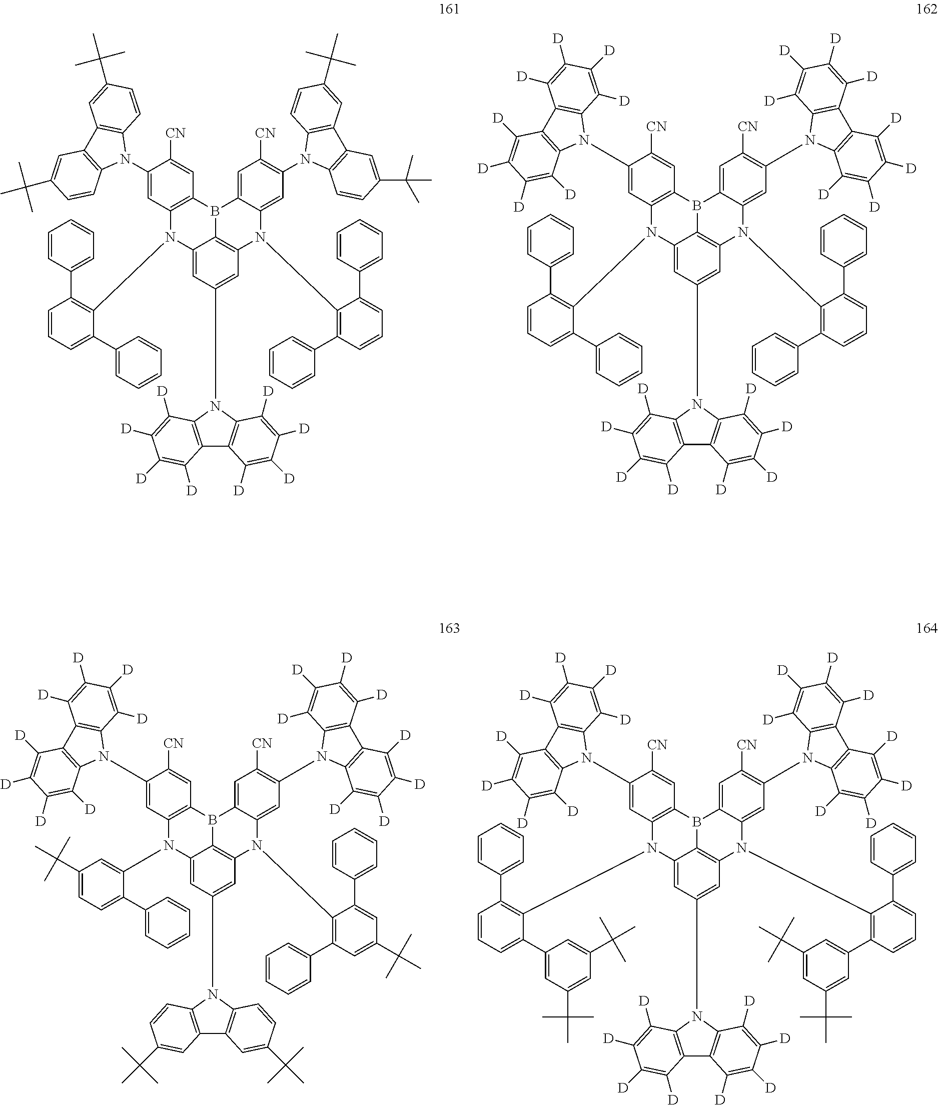

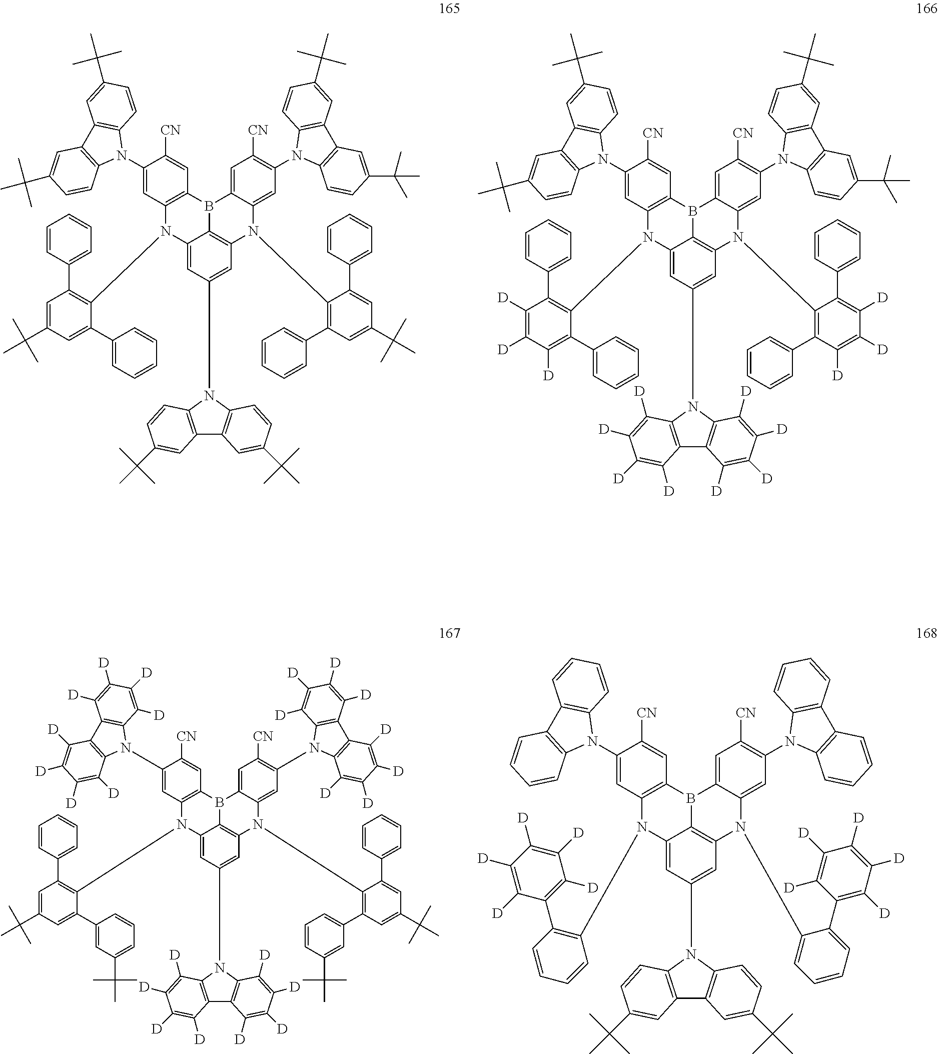

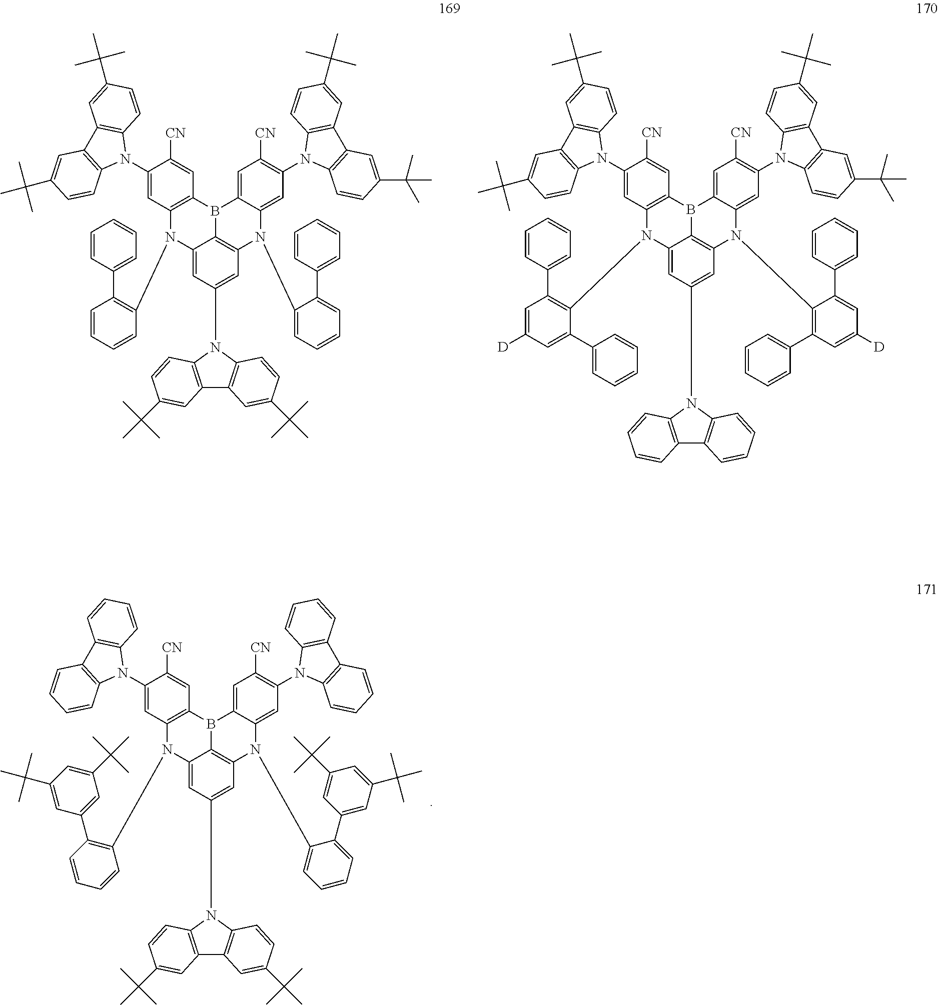

11. The light emitting device of claim 1, wherein the emission layer further comprises at least one of a second compound represented by Formula HT-1, and a third compound represented by Formula ET-1: 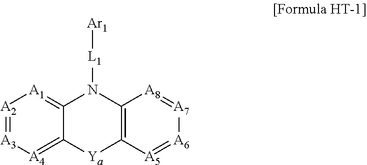
wherein in Formula HT-1,
A₁ to A₈ are each independently N or C(R₅₁),
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, C(R₅₂)(R₅₃), or Si(R₅₄)(R₅₅),
Ar is a substituted or unsubstituted aryl group of 6 to 30 ring-forming carbon atoms or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring; 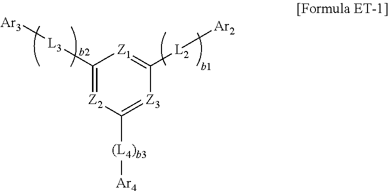
wherein in Formula ET-1,
at least one of Z₁ to Z₃ is each N,
the remainder of Z₁ to Z₃ is each independently C(R₅₆),
R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms,
b1 to b3 are each independently an integer from 0 to 10, and
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

12. The light emitting device of claim 1, wherein the emission layer further comprises a fourth compound represented by Formula D-1: 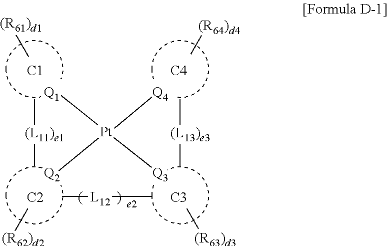
wherein in Formula D-1,
Q₁ to Q₄ are each independently C or N,
C1 to C4 are each independently a substituted or unsubstituted hydrocarbon ring of 5 to 30 ring-forming carbon atoms or a substituted or unsubstituted heterocycle of 2 to 30 ring-forming carbon atoms,
L₁₁ to L₁₃ are each independently a direct linkage, *—O—*, *—S—*, 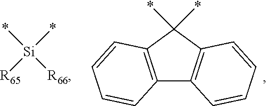
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
e1 to e3 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or are combined with an adjacent group to form a ring, and
d1 to d4 are each independently an integer from 0 to 4.

13. A fused polycyclic compound represented by Formula 1: 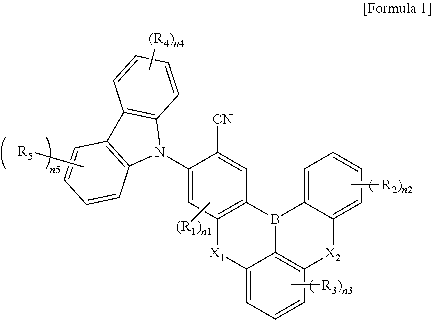
wherein in Formula 1,
X₁ and X₂ are each independently N(Rₐ),
Rₐ is a substituted or unsubstituted aryl group of 6 to 30 ring-forming carbon atoms or a substituted or unsubstituted heteroaryl group of 2 to 30 ring-forming carbon atoms,
R₁ to R₅ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring,
n1 is an integer from 0 to 2,
n2, n4, and n5 are each independently an integer from 0 to 4, and
n3 is an integer from 0 to 3.

14. The fused polycyclic compound of claim 13, wherein a substituent represented by R₂ is a hydrogen atom, a deuterium atom, a cyano group, a substituted or unsubstituted alkyl group of 1 to 10 carbon atoms, or a group represented by Formula A-1 or Formula A-2: 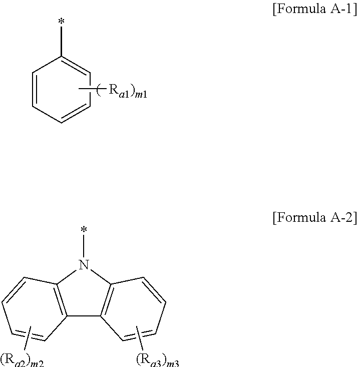
wherein in Formula A-1 and Formula A-2,
Rₐ₁ to Rₐ₃ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1 is an integer from 0 to 5,
m2 and m3 are each independently an integer from 0 to 4, and
-* represents a bond to Formula 1.

15. The fused polycyclic compound of claim 13, wherein the fused polycyclic compound represented by Formula 1 is represented by Formula 2-1 or Formula 2-2: 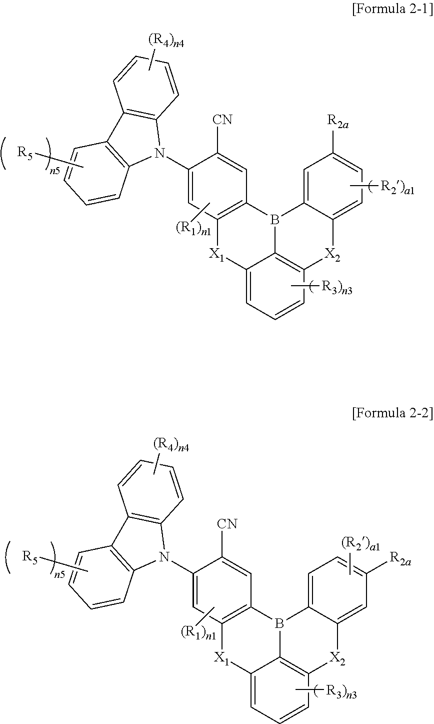
wherein in Formula 2-1 and Formula 2-2,
R₂′ is a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or is combined with an adjacent group to form a ring,
R₂ₐ is a cyano group, a substituted or unsubstituted t-butyl group, a substituted or unsubstituted phenyl group, or a substituted or unsubstituted carbazole group,
a1 is an integer from 0 to 3, and
X₁, X₂, R₁, R₃ to R₅, n1, and n3 to n5 are the same as defined in Formula 1.

16. The fused polycyclic compound of claim 13, wherein the fused polycyclic compound represented by Formula 1 is represented by one of Formula 3-1 to Formula 3-5: 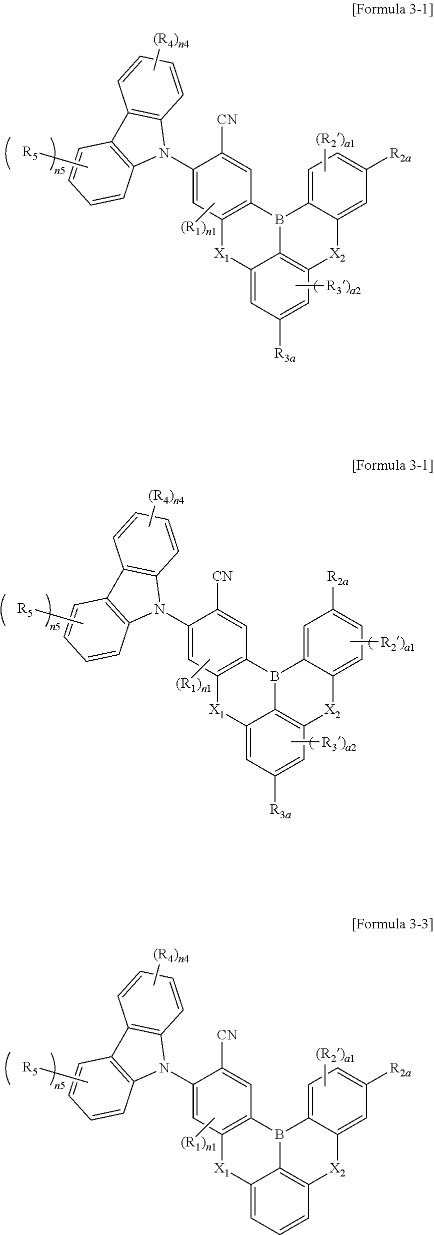 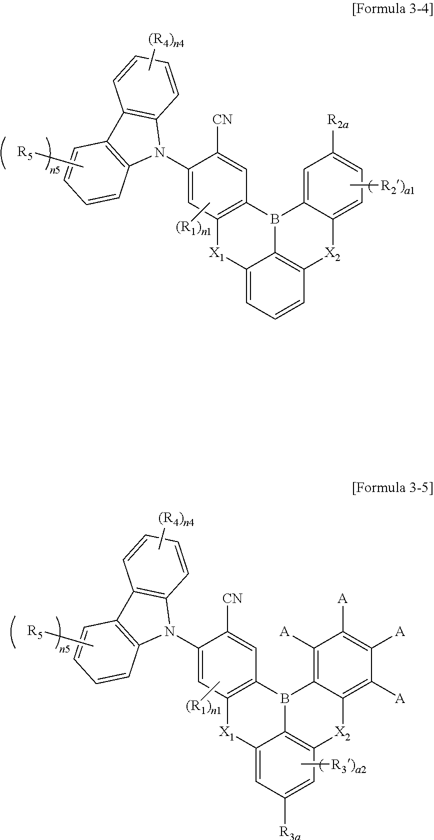
wherein in Formula 3-1 to Formula 3-5,
A is each independently a hydrogen atom or a deuterium atom,
R₂ₐ is a cyano group, a substituted or unsubstituted t-butyl group, a substituted or unsubstituted phenyl group, or a substituted or unsubstituted carbazole group,
R₂′ and R₃′ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring,
a1 is an integer from 0 to 3,
a2 is an integer from 0 to 2,
X₁, X₂, R₁, R₄, R₅, n1, n4, and n5 are the same as defined in Formula 1, and
R₃ₐ is a substituted or unsubstituted t-butyl group or a group represented by Formula B-1 or Formula B-2: 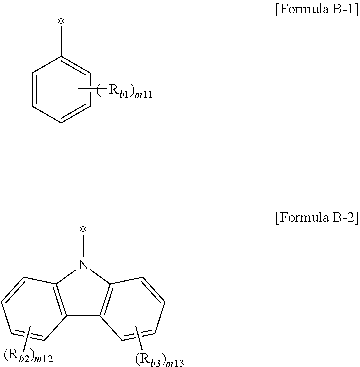
wherein in Formula B-1 and Formula B-2,
R_{b1} to R_{b3} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m11 is an integer from 0 to 5, and
m12 and m13 are each independently an integer from 0 to 4, and
-* represents a bond to Formula 3-1, Formula 3-2, or Formula 3-5.

17. The fused polycyclic compound of claim 13, wherein the fused polycyclic compound represented by Formula 1 is represented by Formula 5: 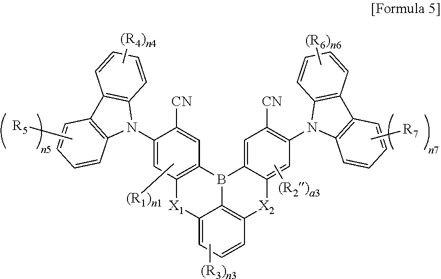
wherein in Formula 5,
R₂″, R₆, and R₇ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring,
n6 and n7 are each independently an integer from 0 to 4,
a3 is an integer from 0 to 2, and
X₁, X₂, R₁, R₃, R₄, R₅, n1, n3, n4, and n5 are the same as defined in Formula 1.

18. The fused polycyclic compound of claim 13, wherein X₁ and X₂ are each independently represented by Formula X-1 or Formula X-2: 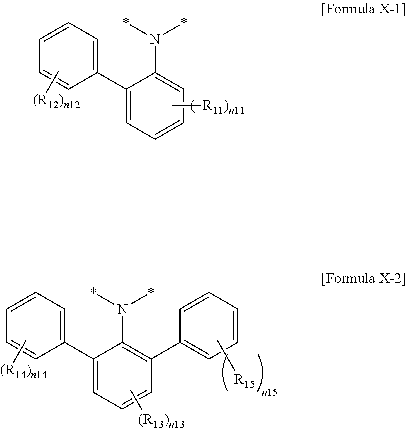
wherein in Formula X-1 and Formula X-2,
R₁₁ to R₁₅ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, n11 is an integer from 0 to 4,
n12, n14, and m15 are each independently an integer from 0 to 5,
n13 is an integer from 0 to 3, and
-* represents a bond to Formula 1.

19. The fused polycyclic compound of claim 13, wherein the fused polycyclic compound represented by Formula 1 is represented by one of Formula 7-1 to Formula 7-4: 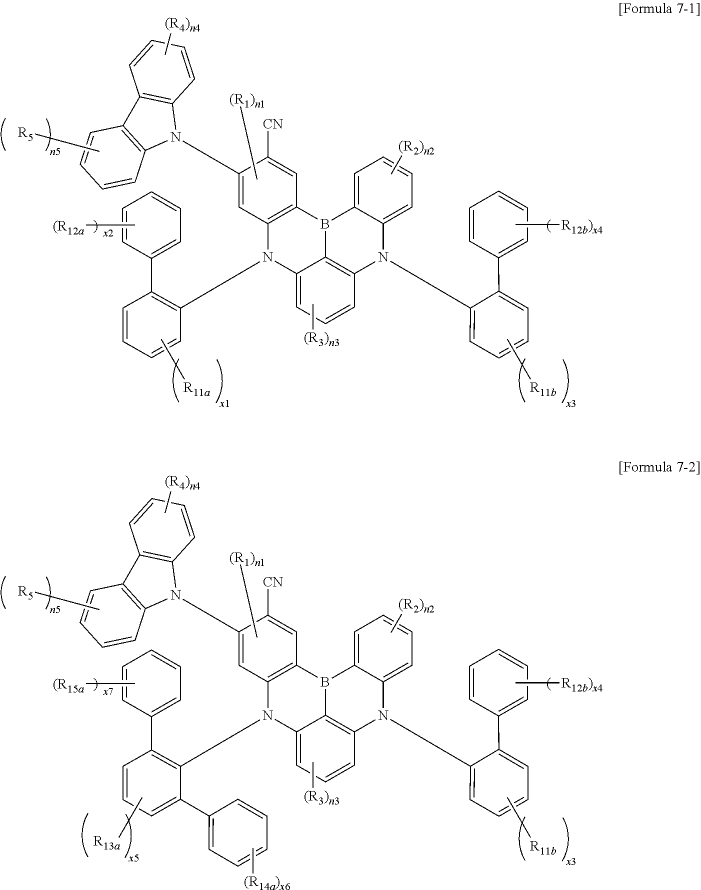 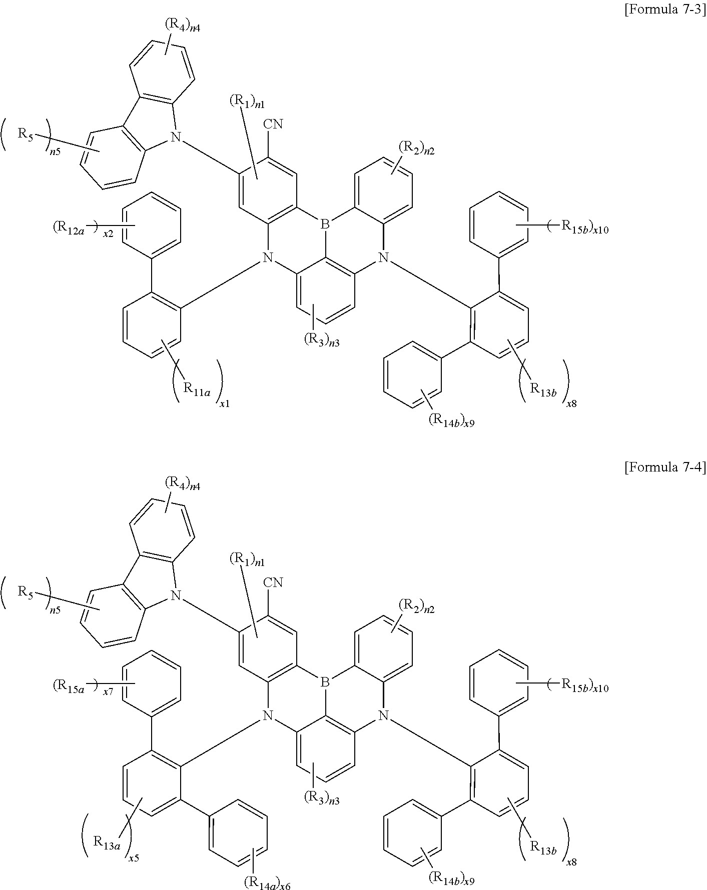
wherein in Formula 7-1 to Formula 7-4,
R₁₁ₐ to R₁₅ₐ and R_{11b} to R_{15b} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
x1 and x3 are each independently an integer from 0 to 4,
x2, x4, x6, x7, x9, and x10 are each independently an integer from 0 to 5,
x5 and x8 are each independently an integer from 0 to 3, and
R₁ to R₅ and n1 to n5 are the same as defined in Formula 1

20. The fused polycyclic compound of claim 13, wherein the fused polycyclic compound is selected from Compound Group 1: 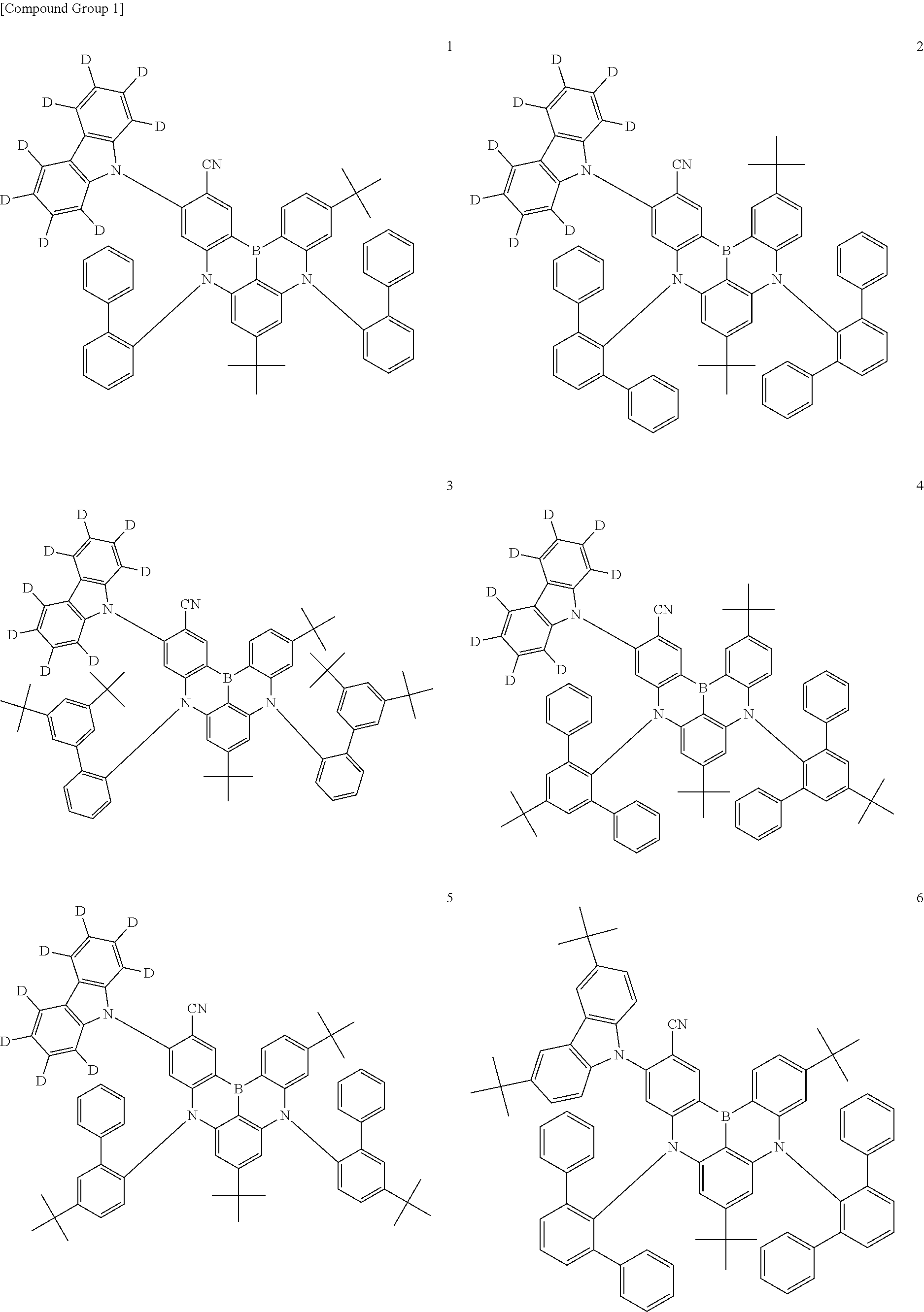 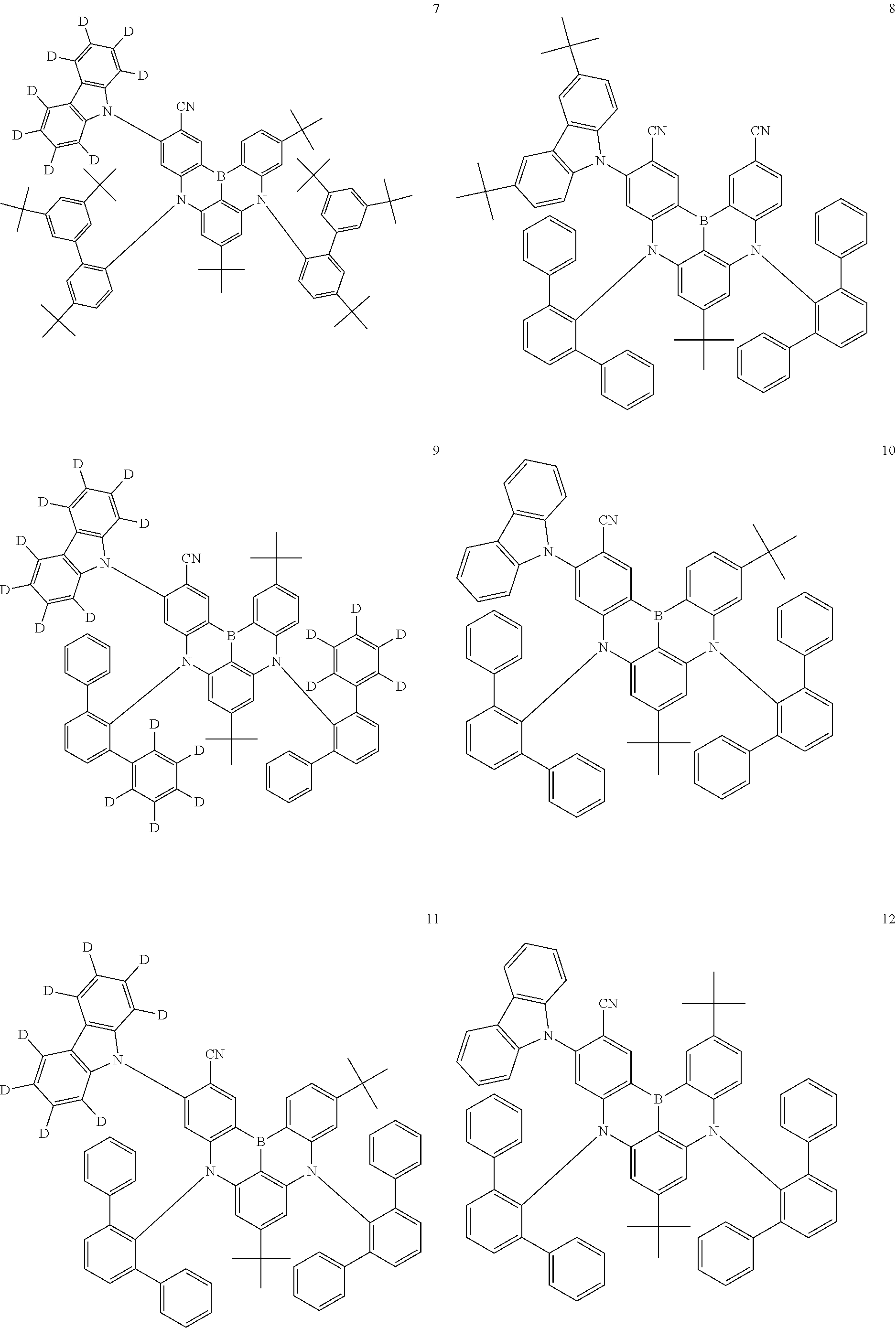 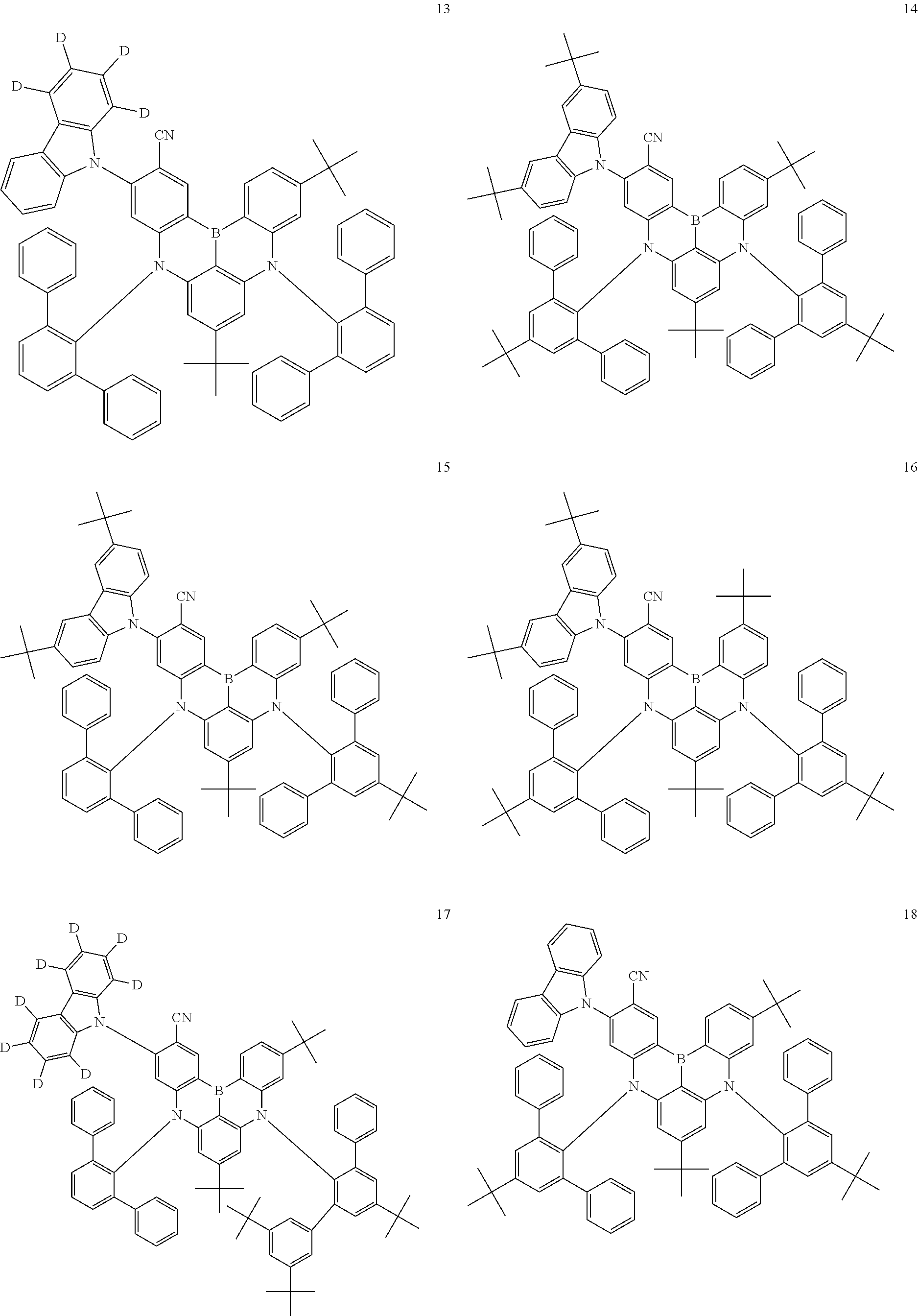 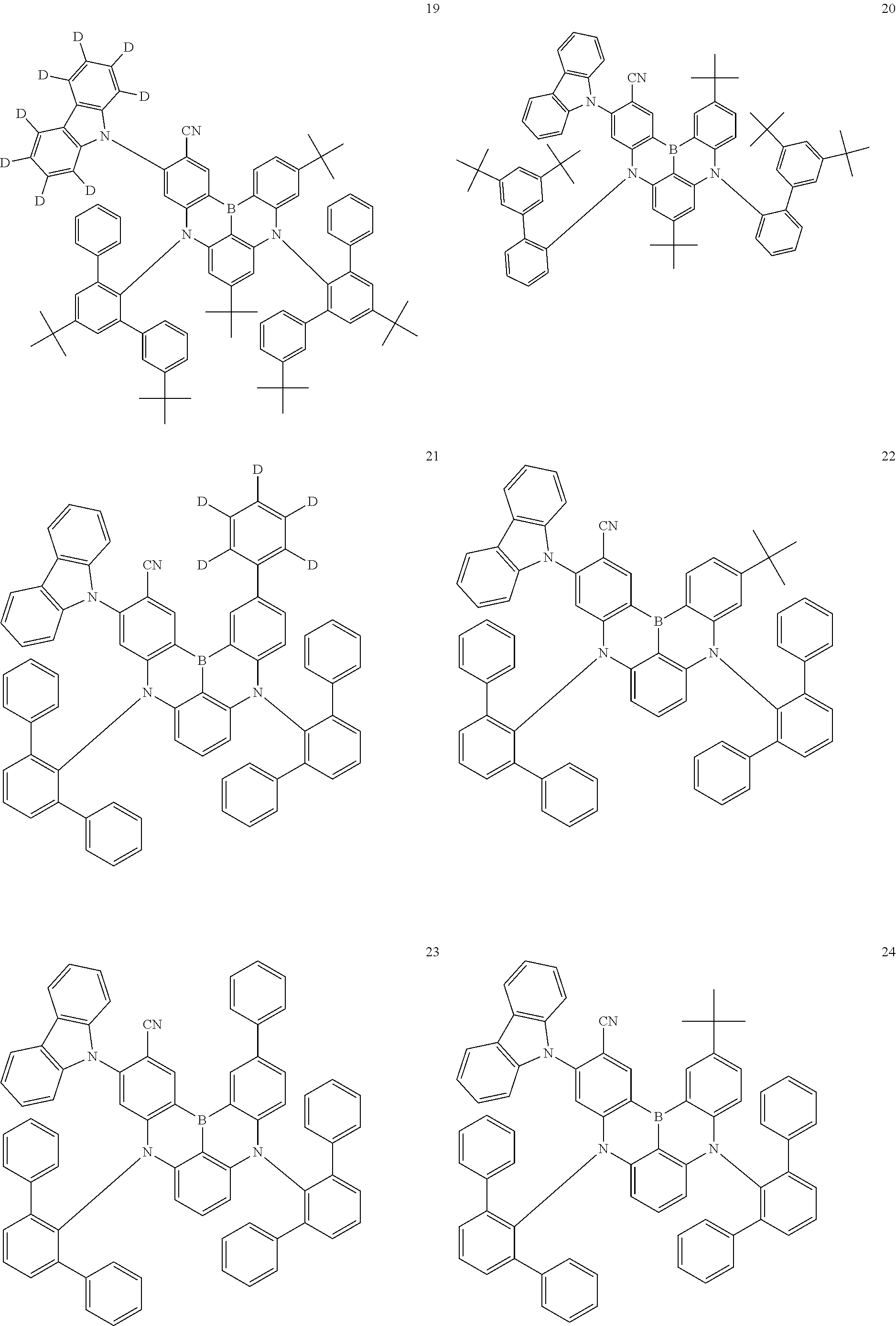 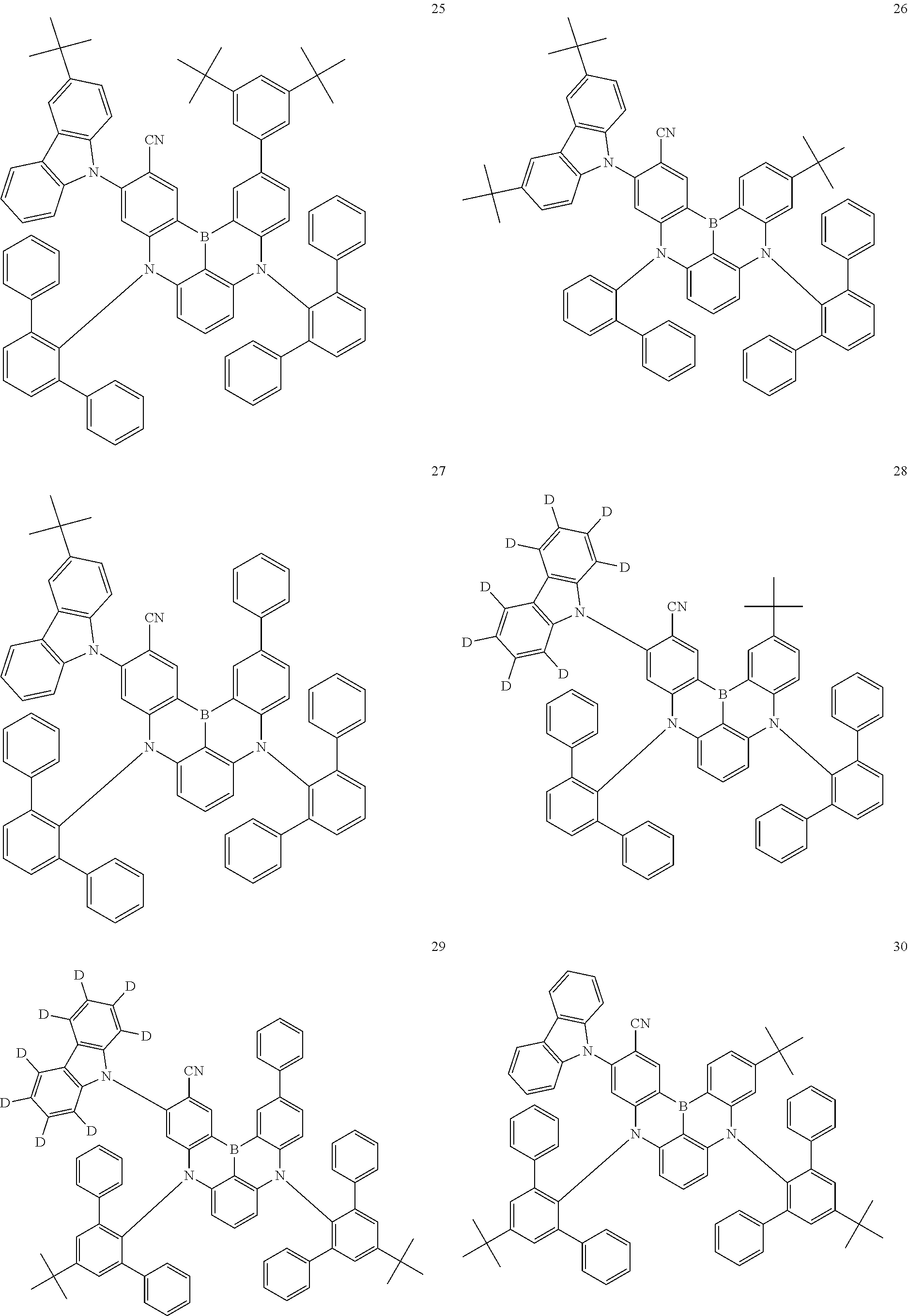 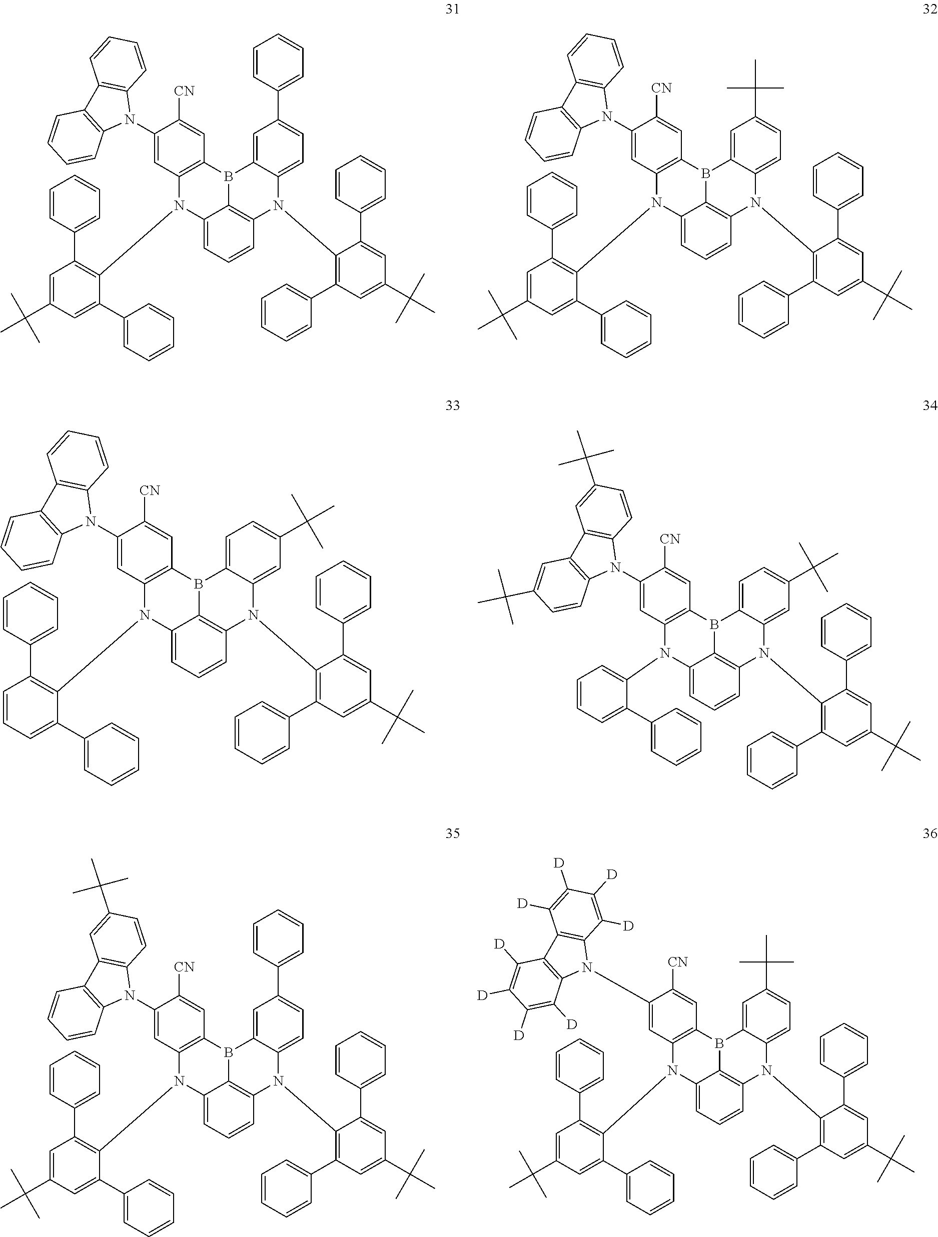 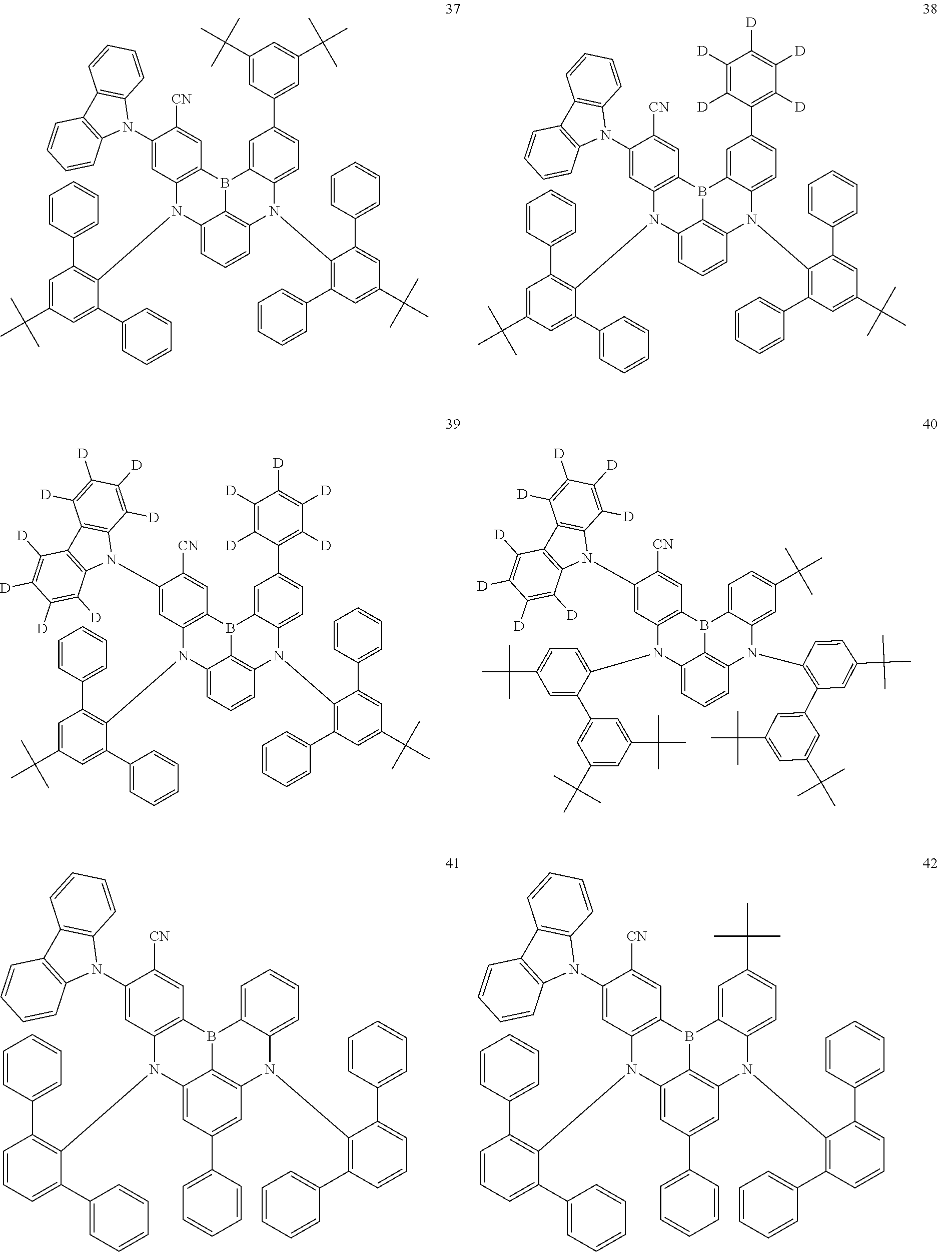 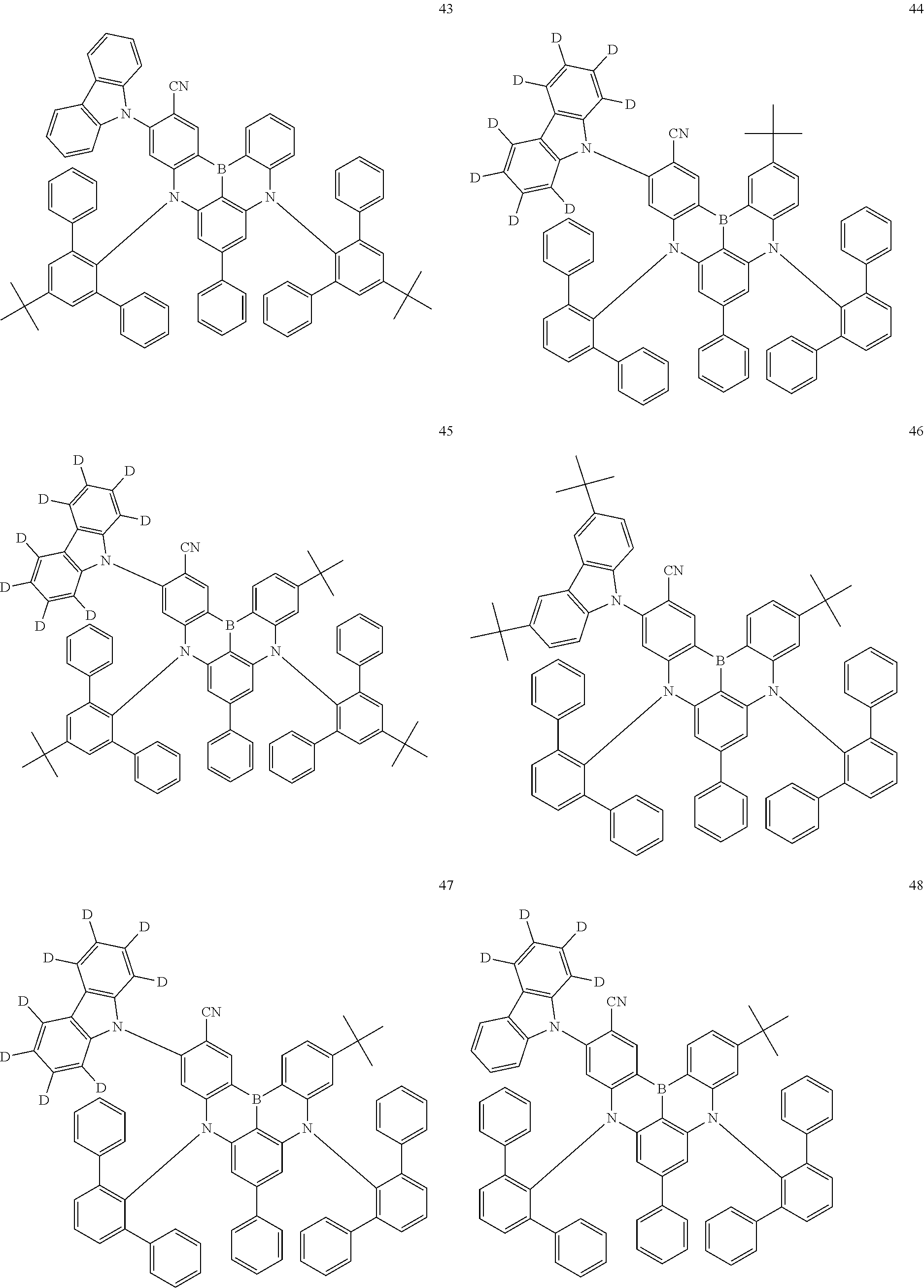 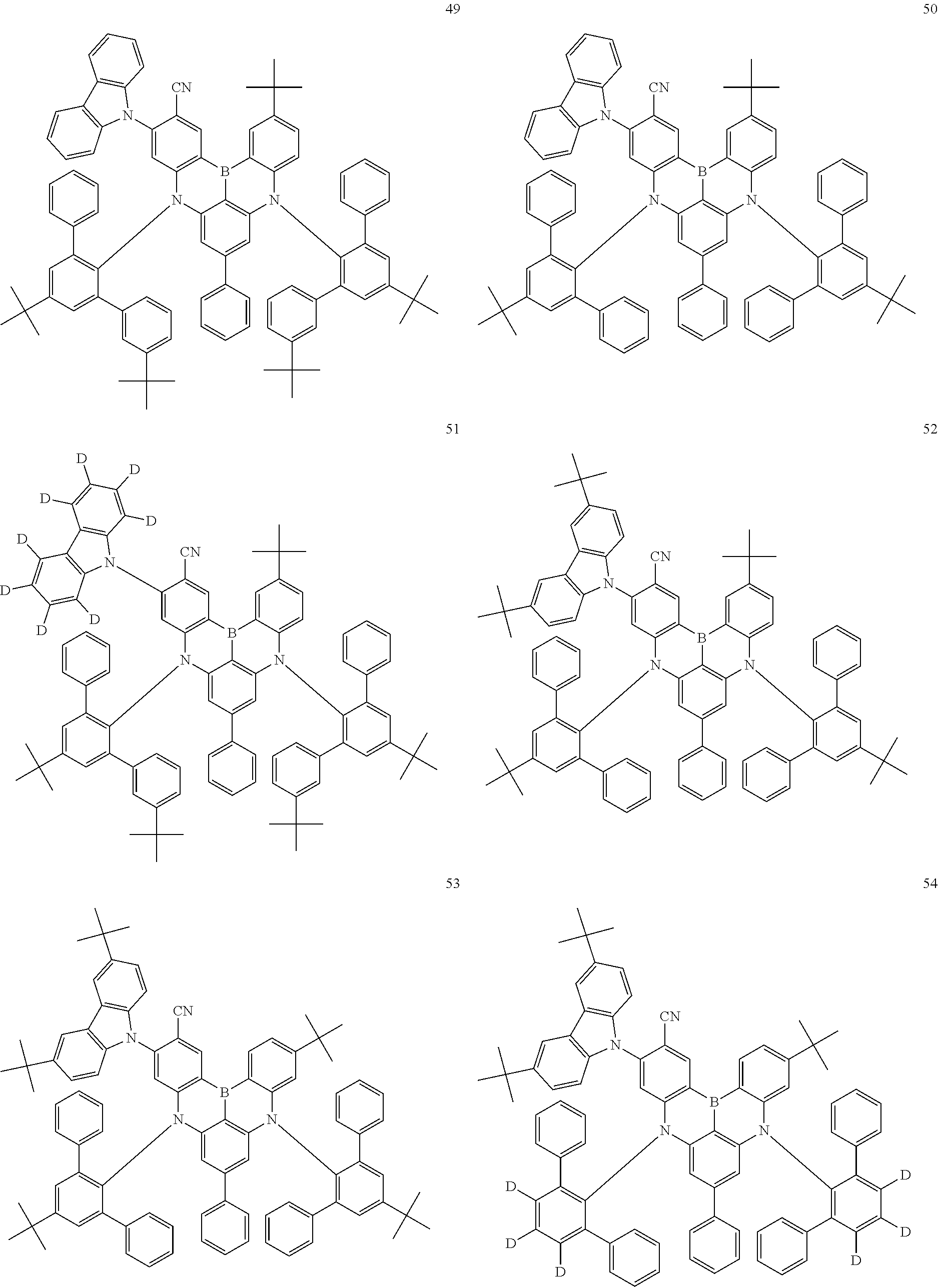 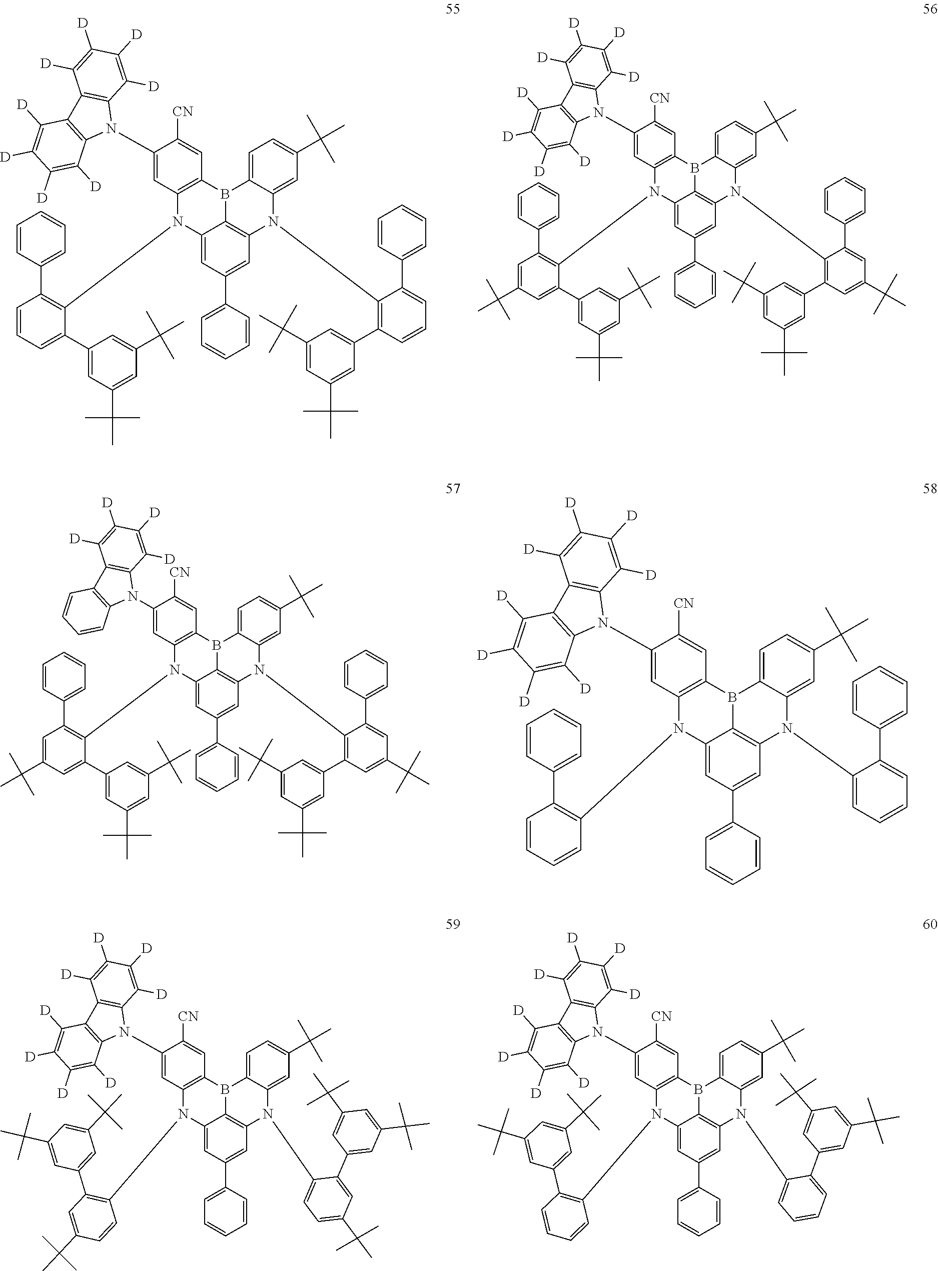 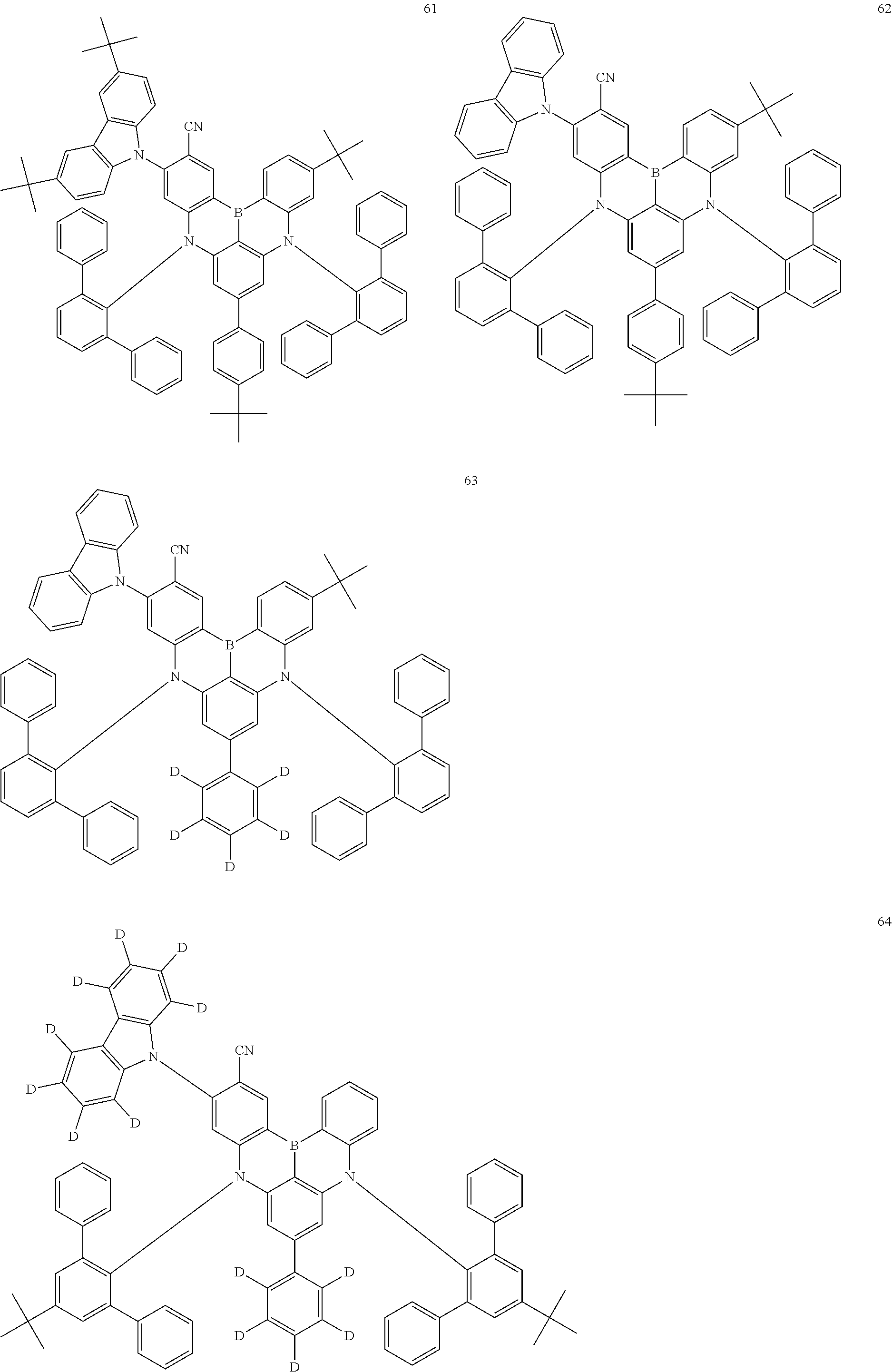 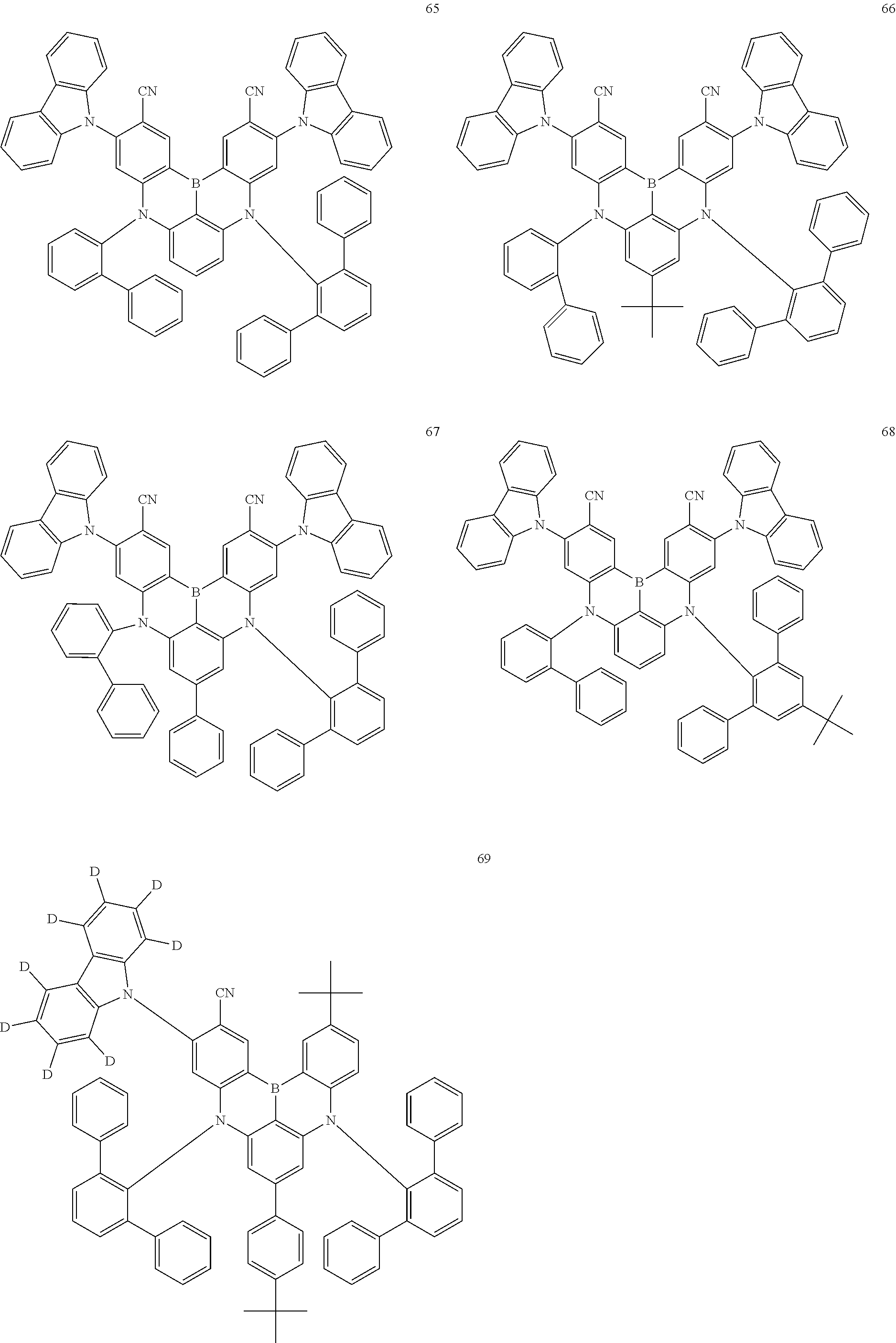 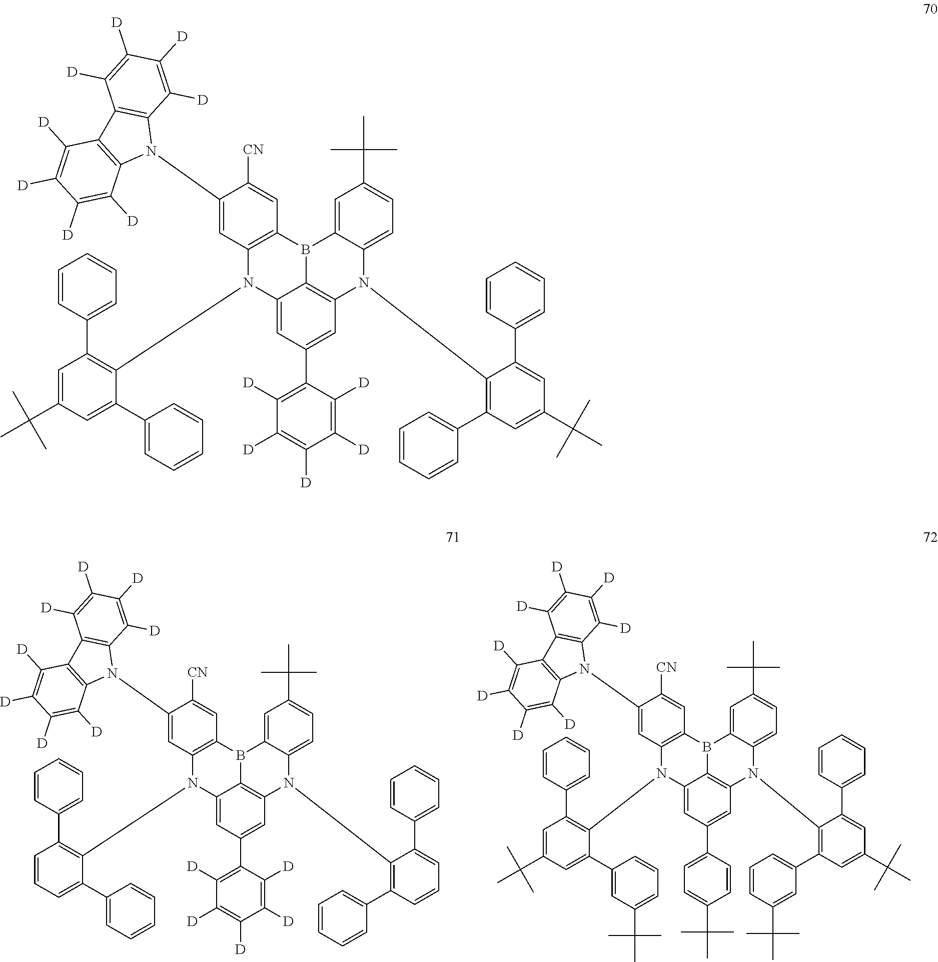 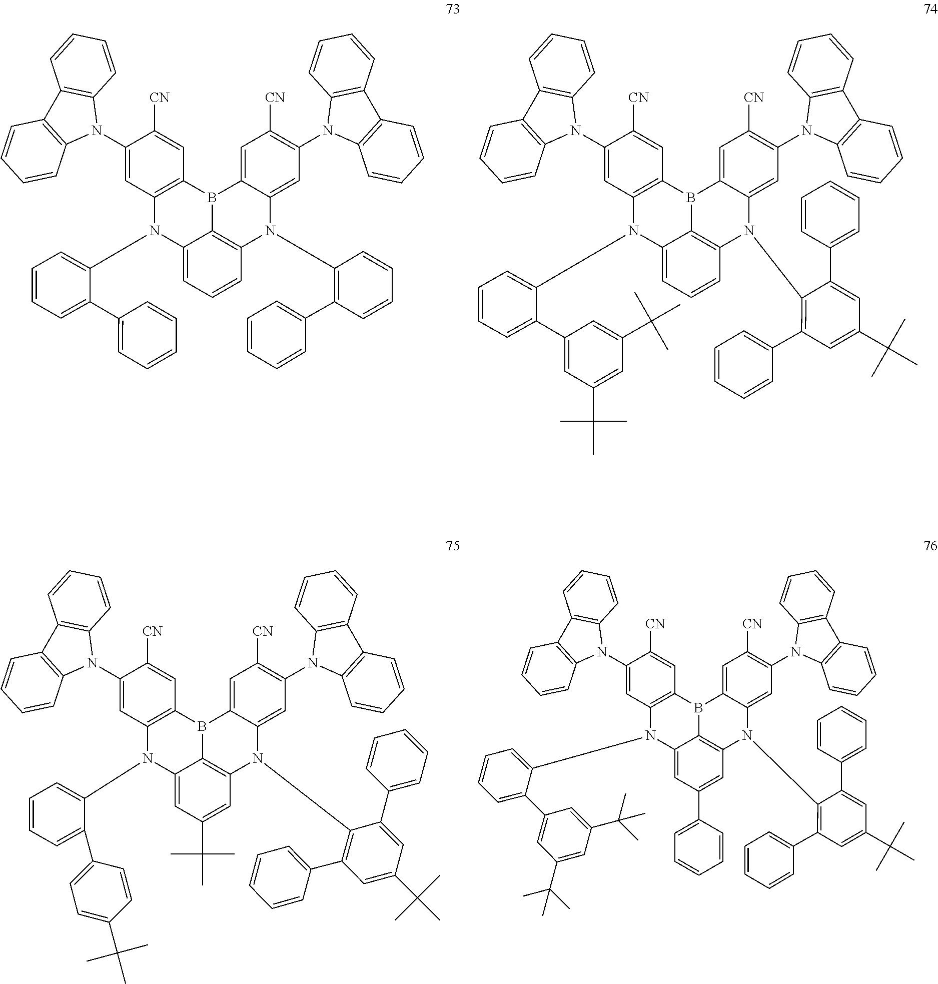 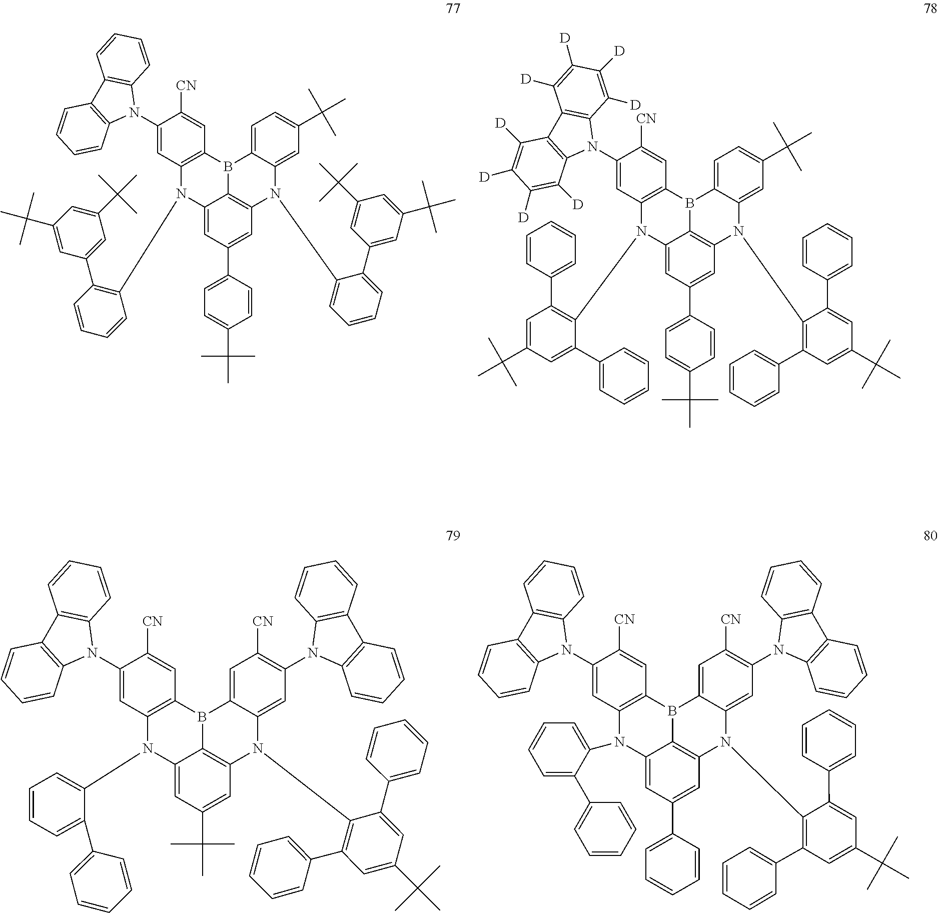 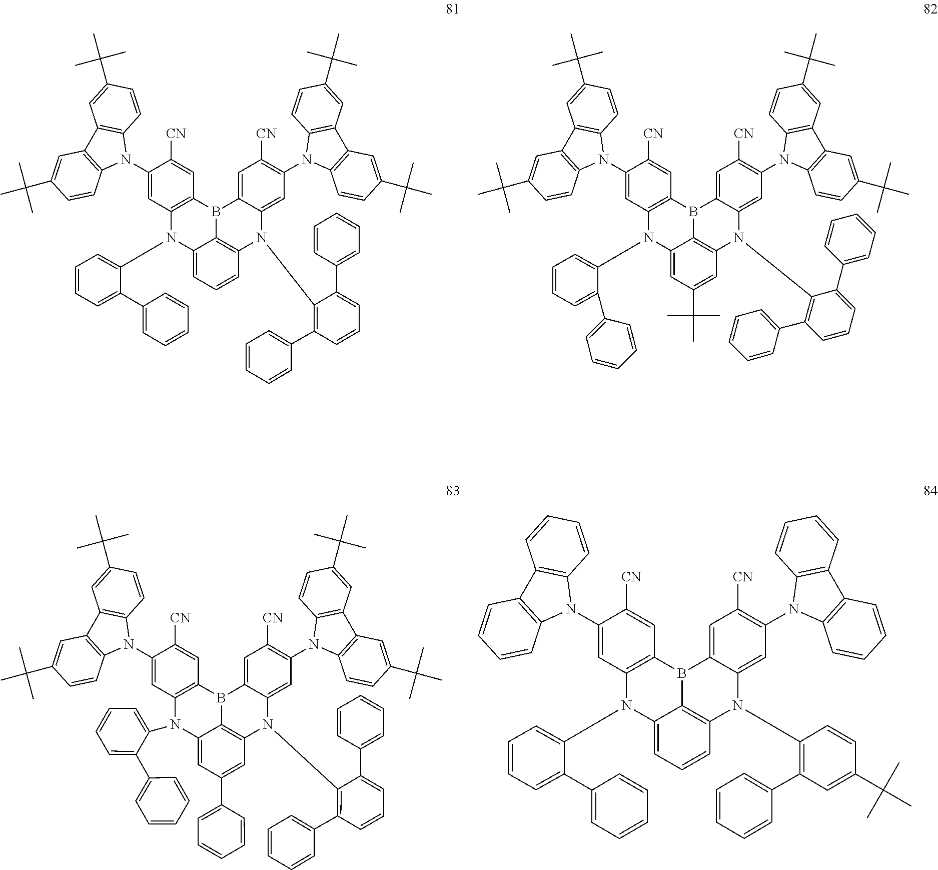 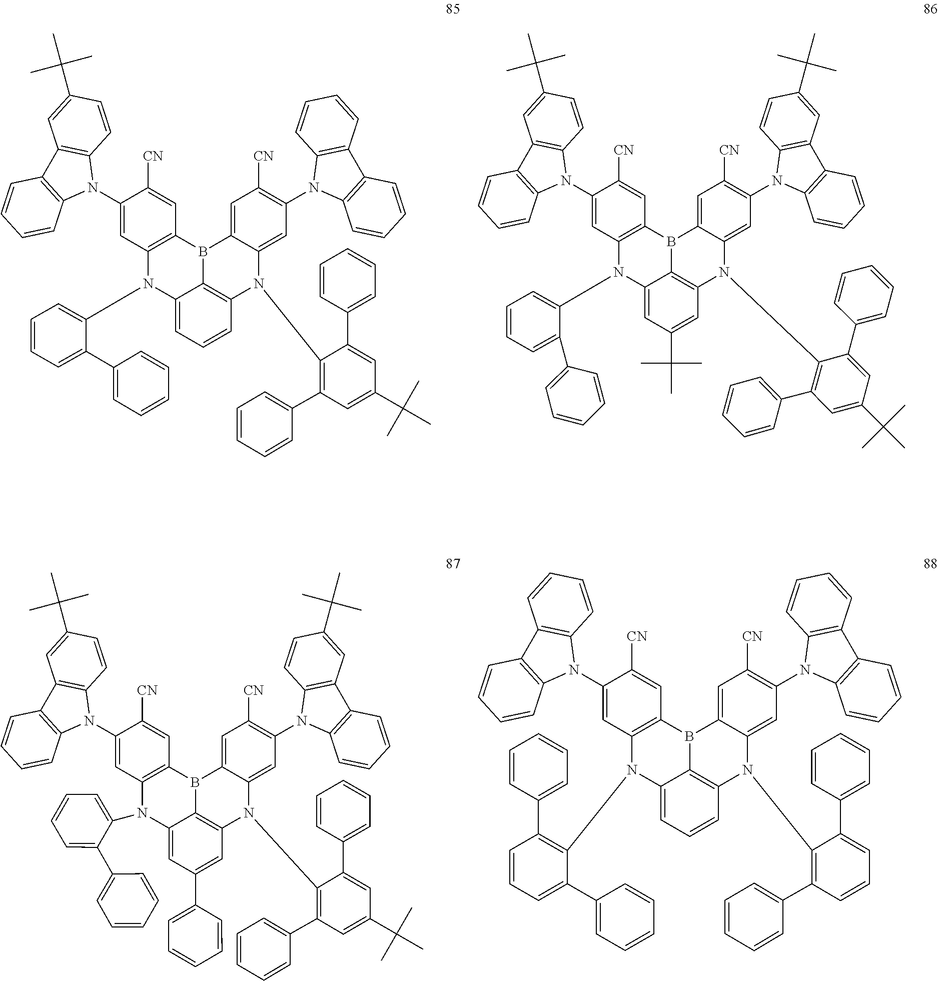 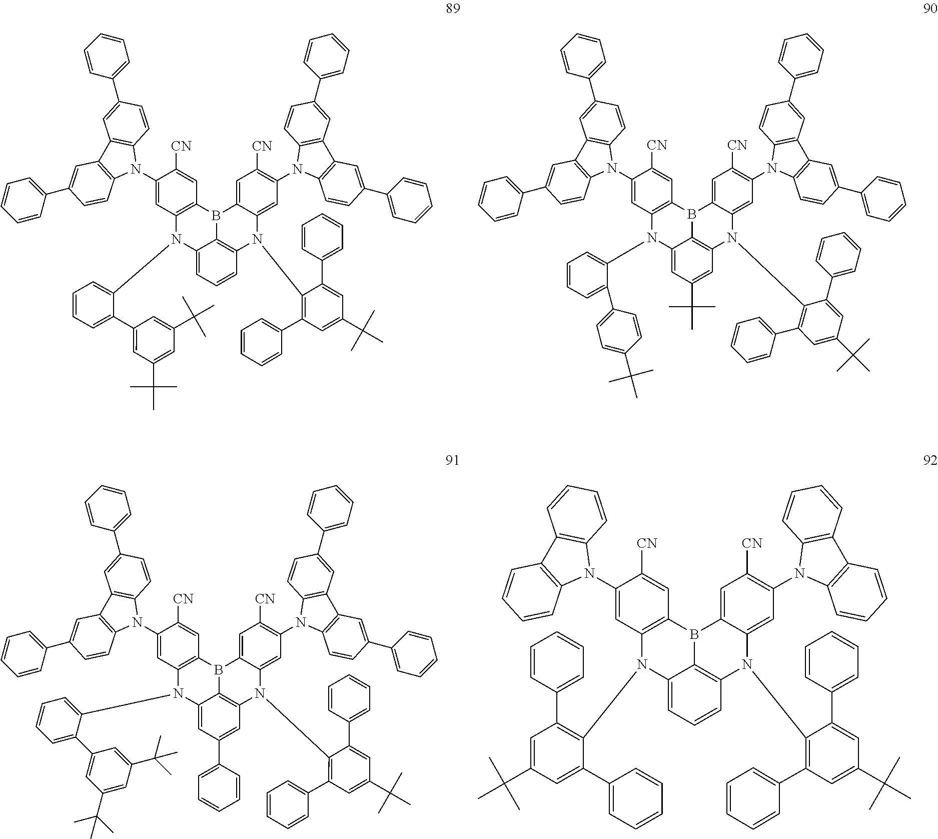 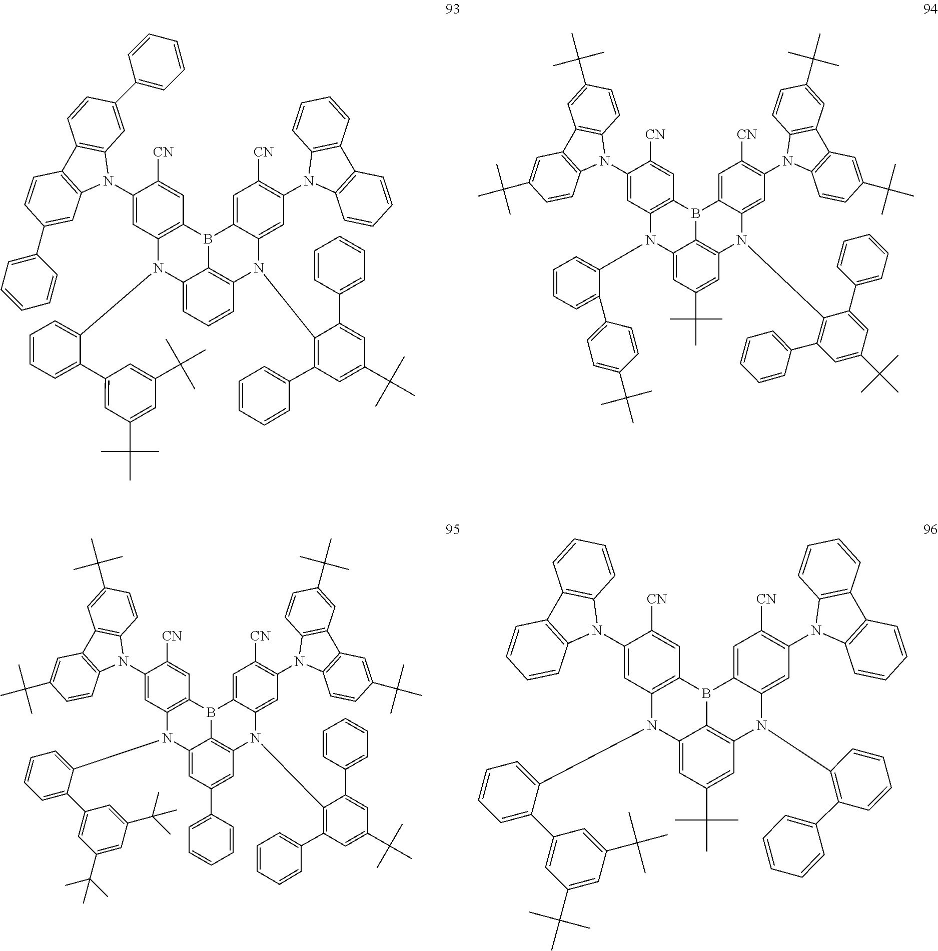 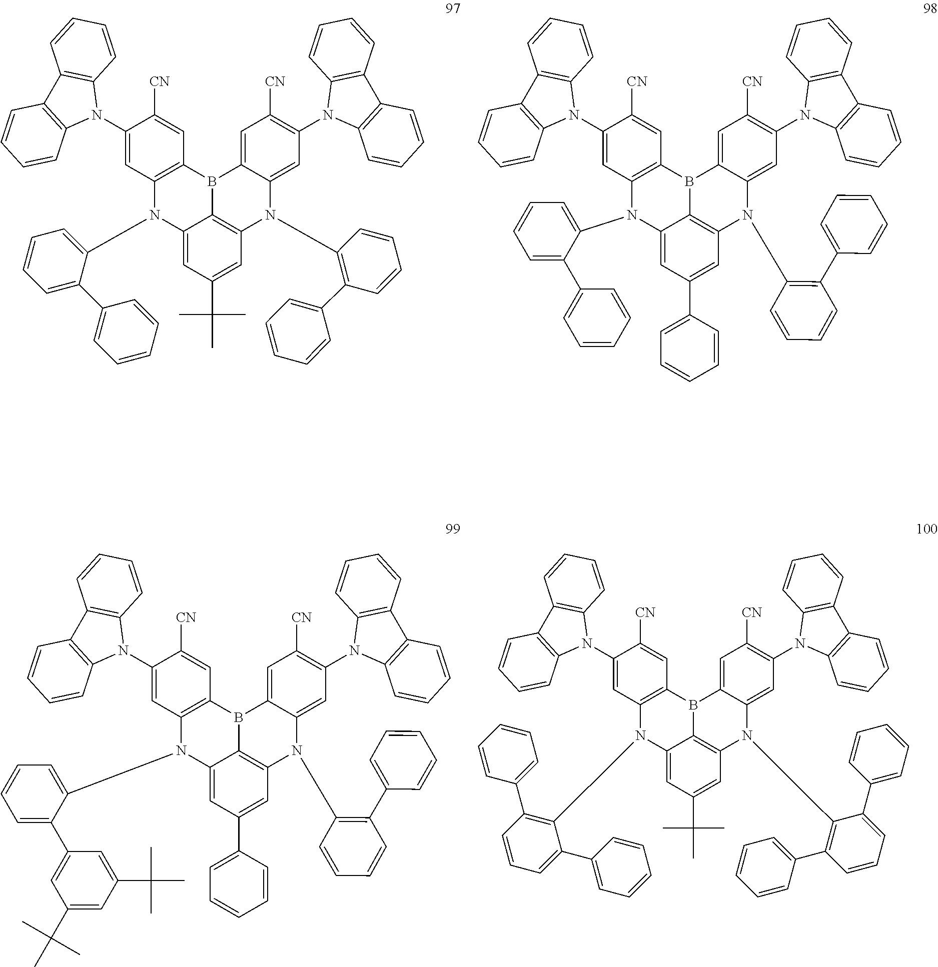 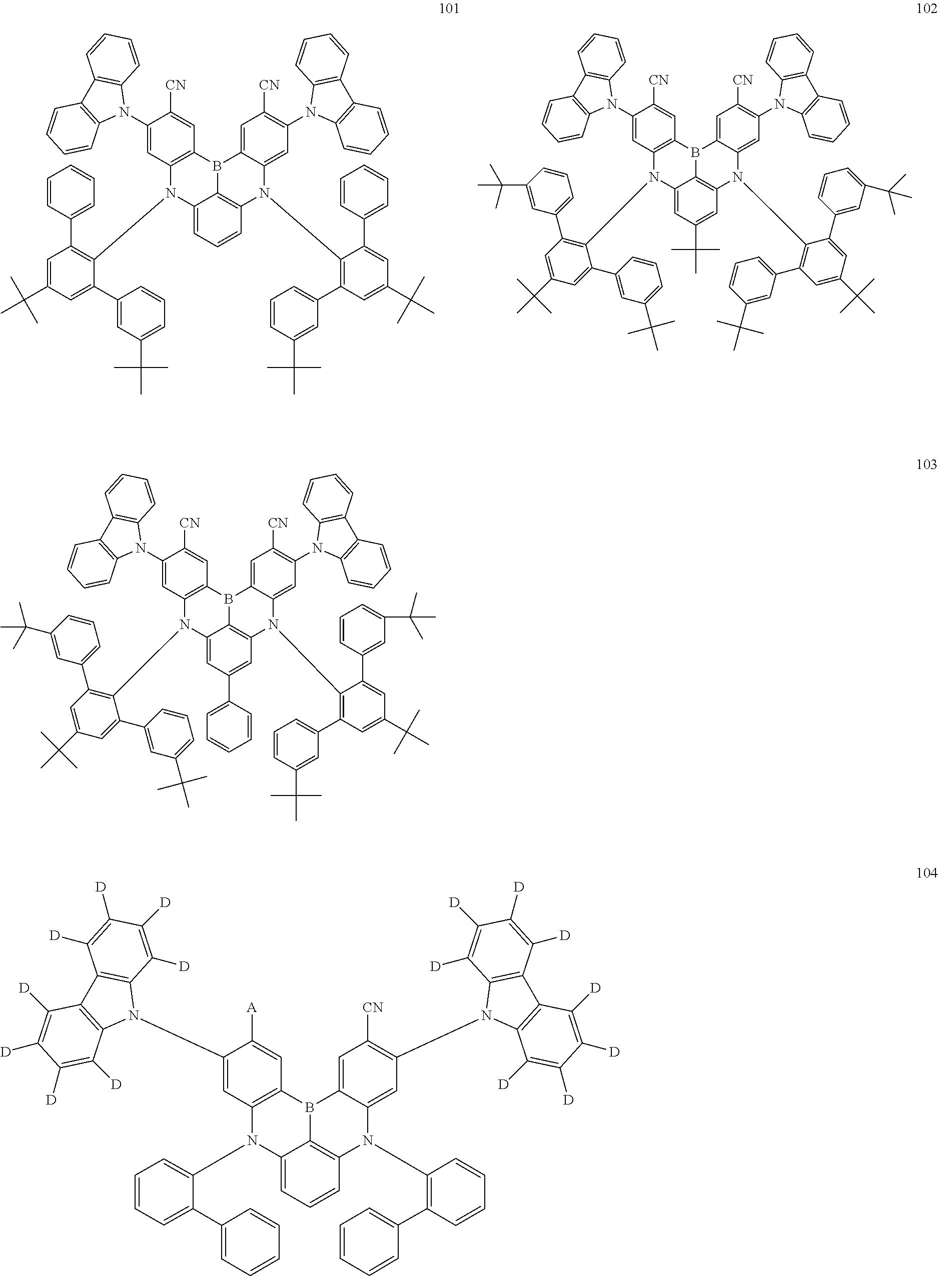 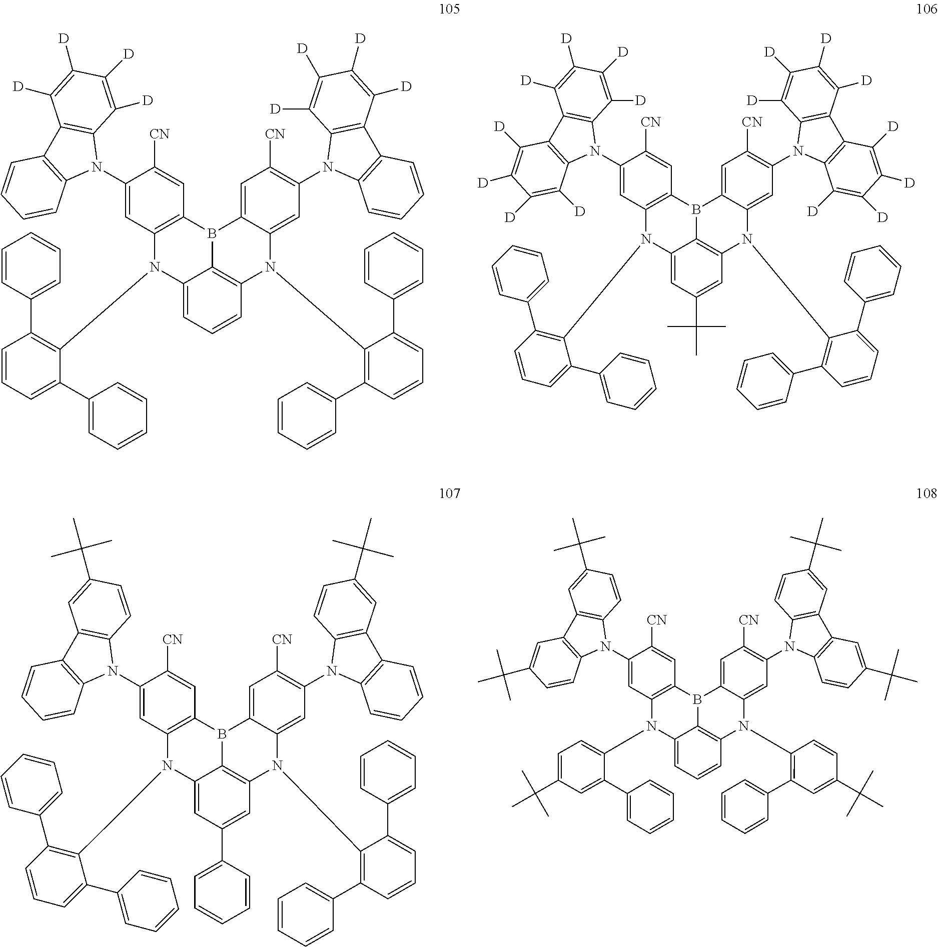 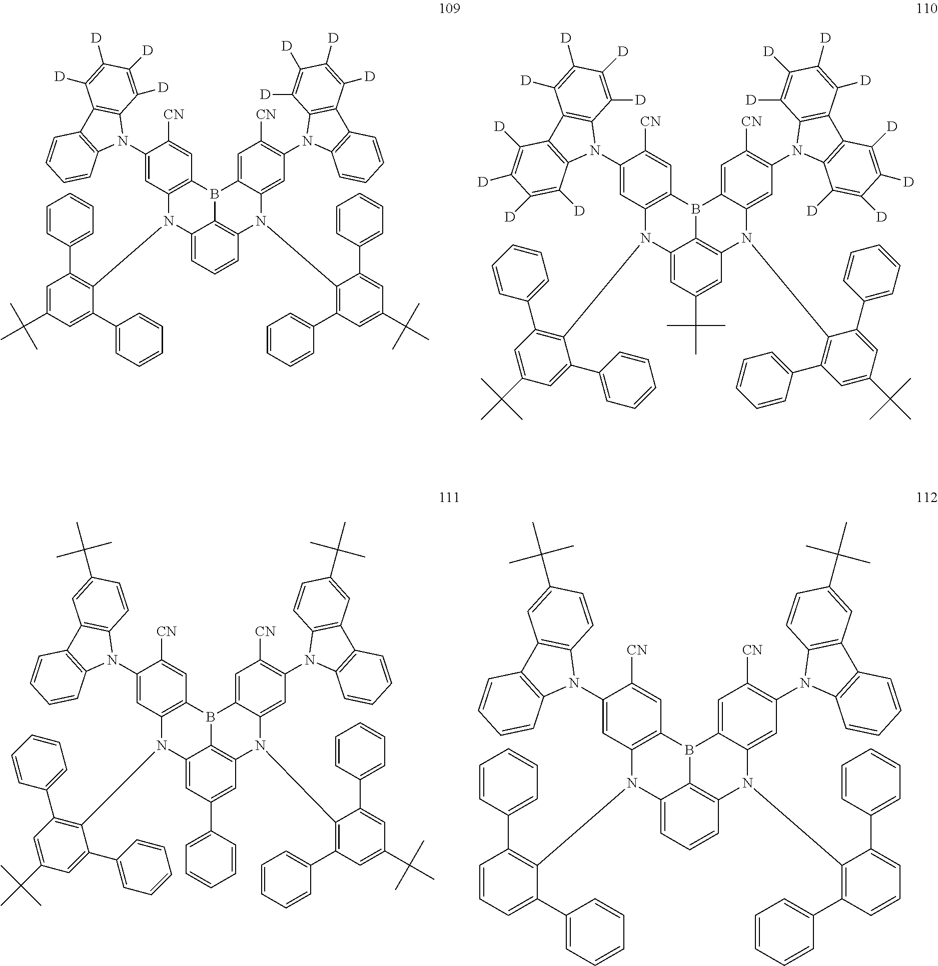 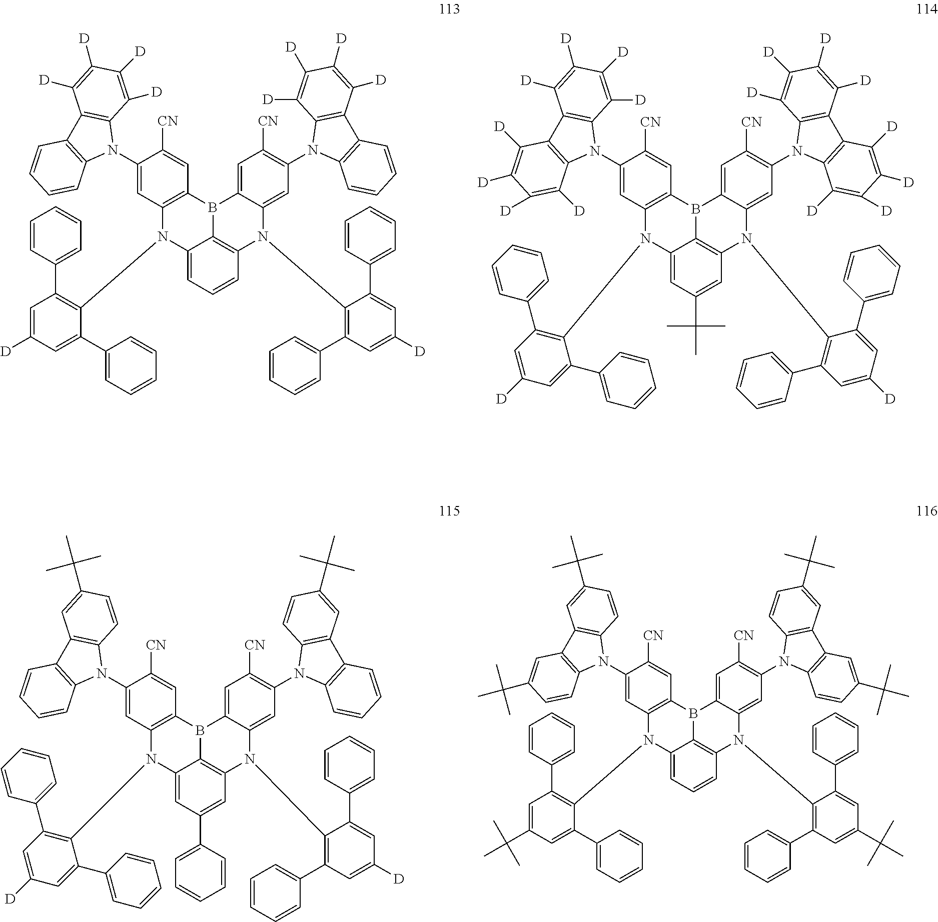 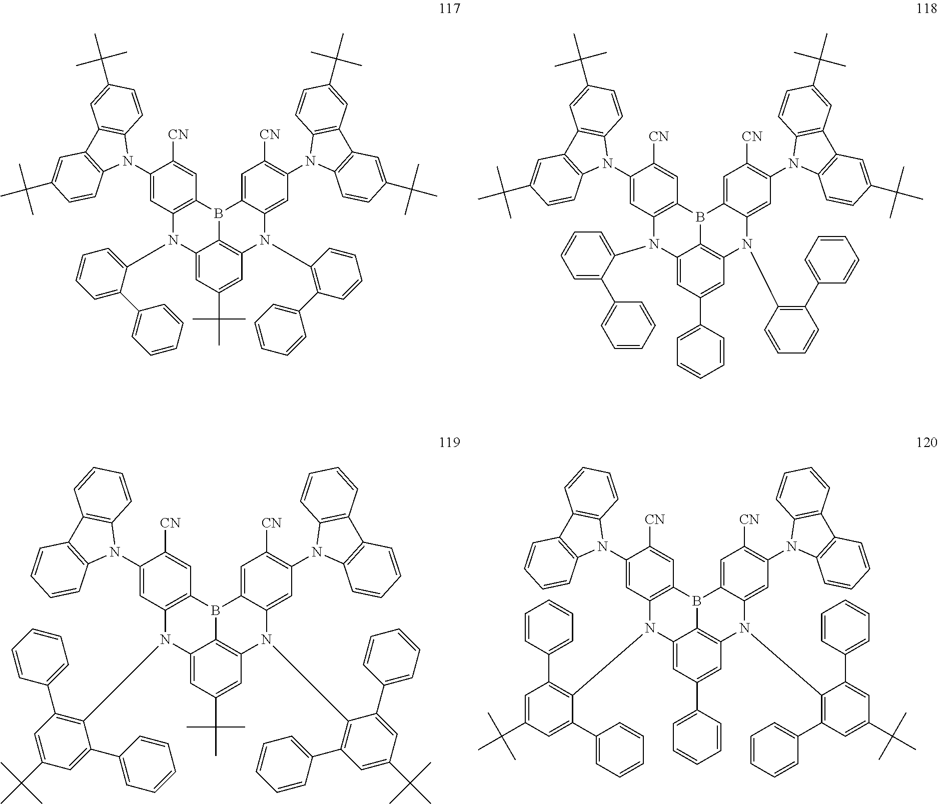 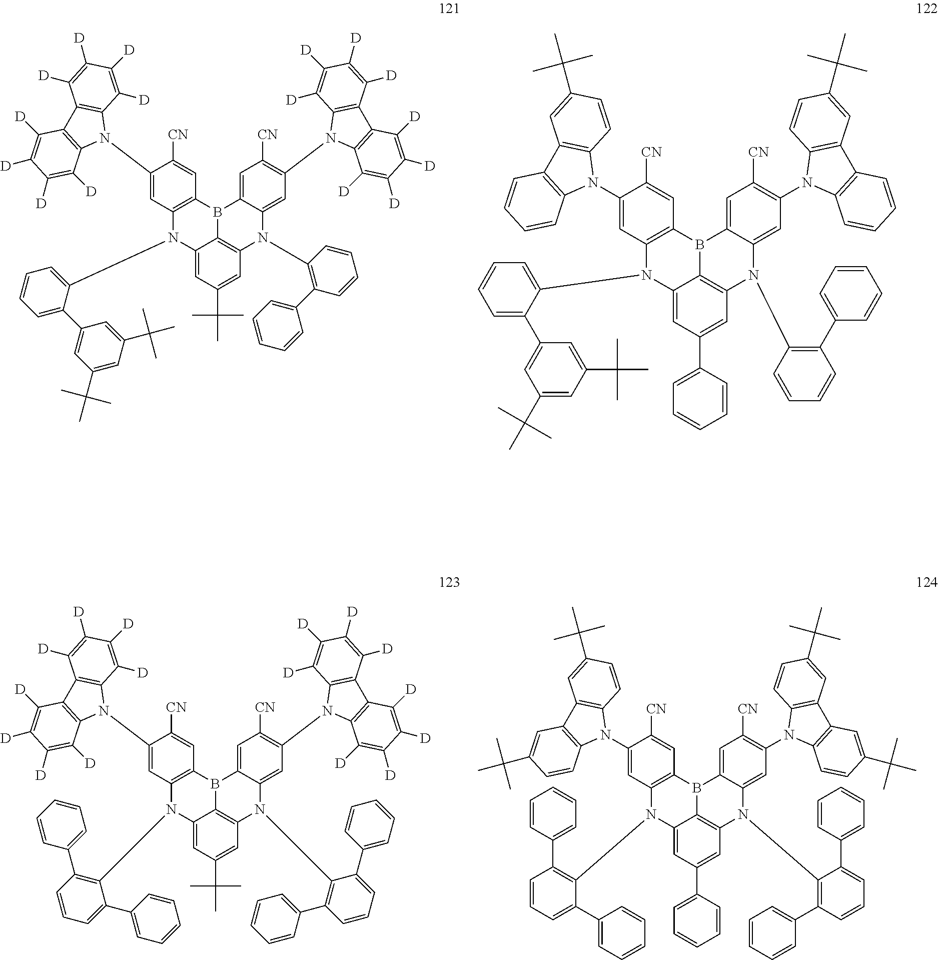 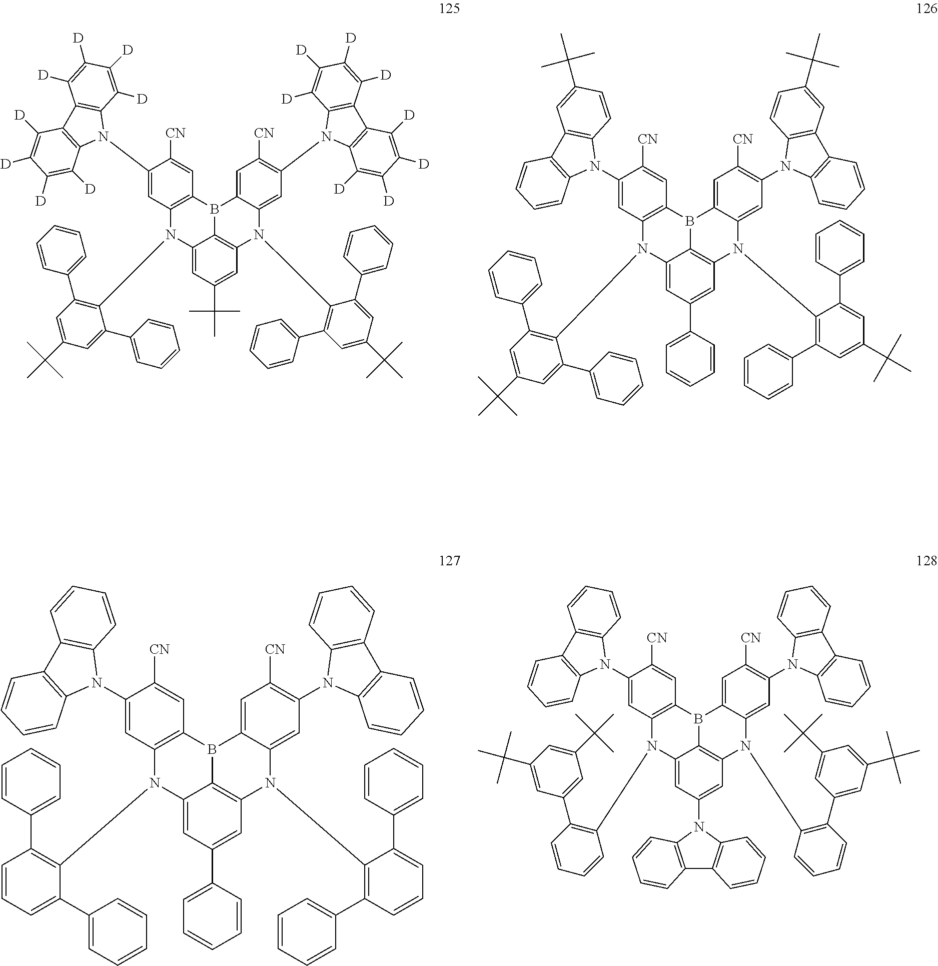 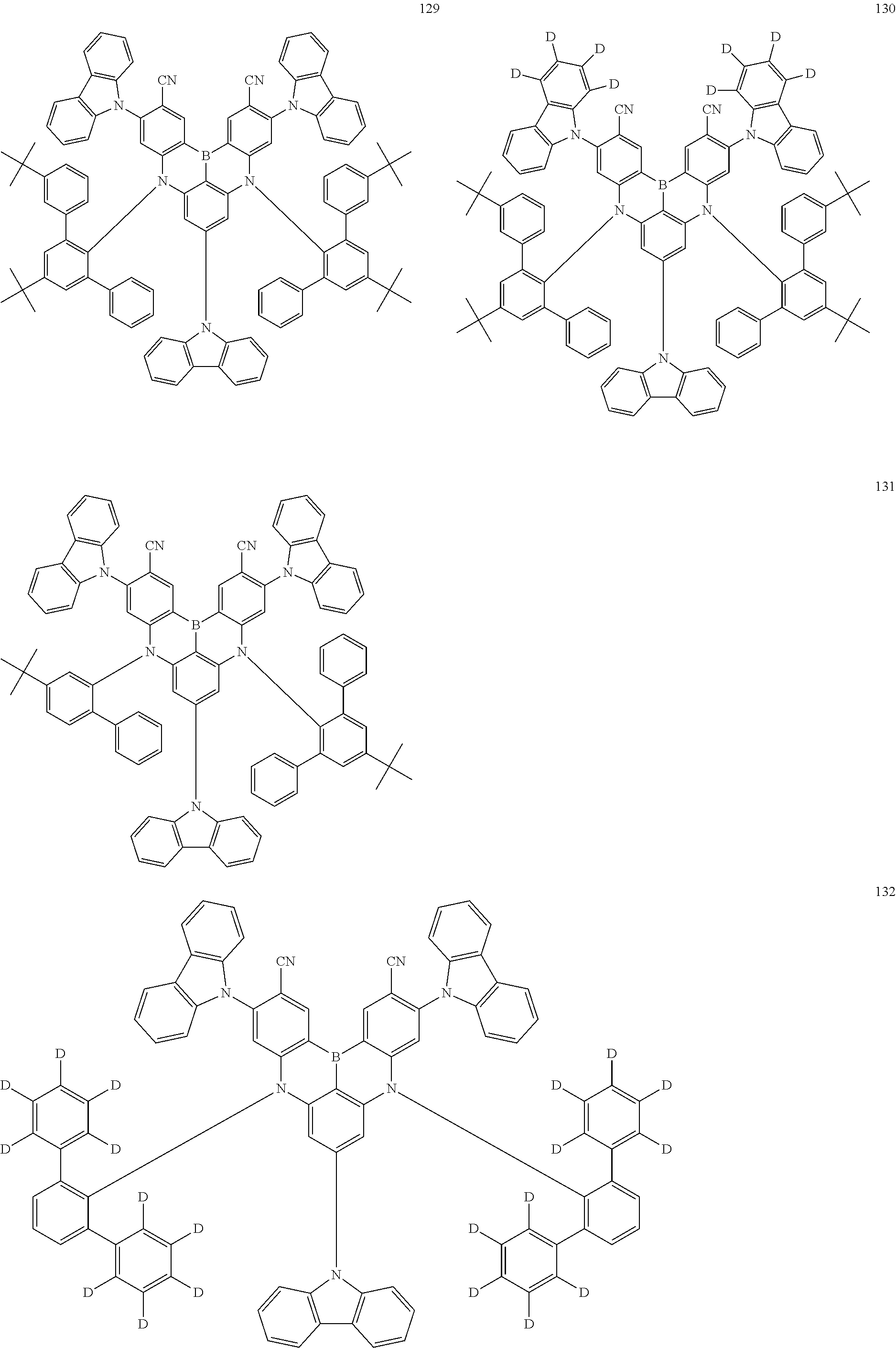 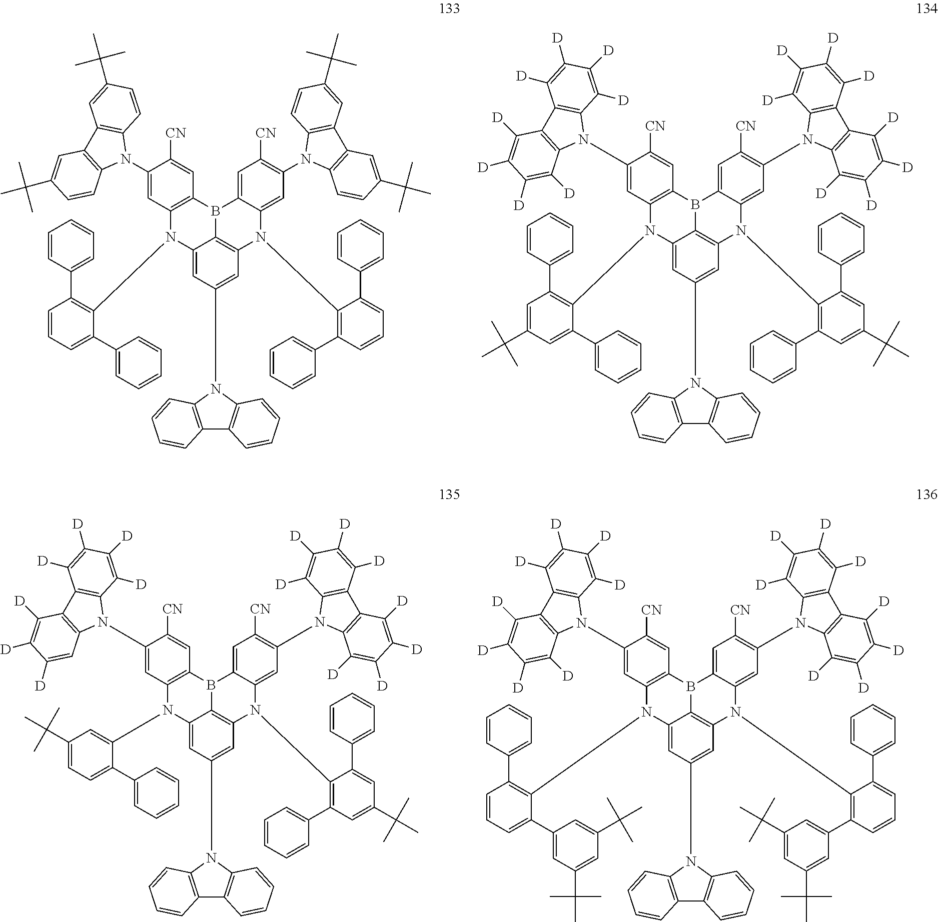 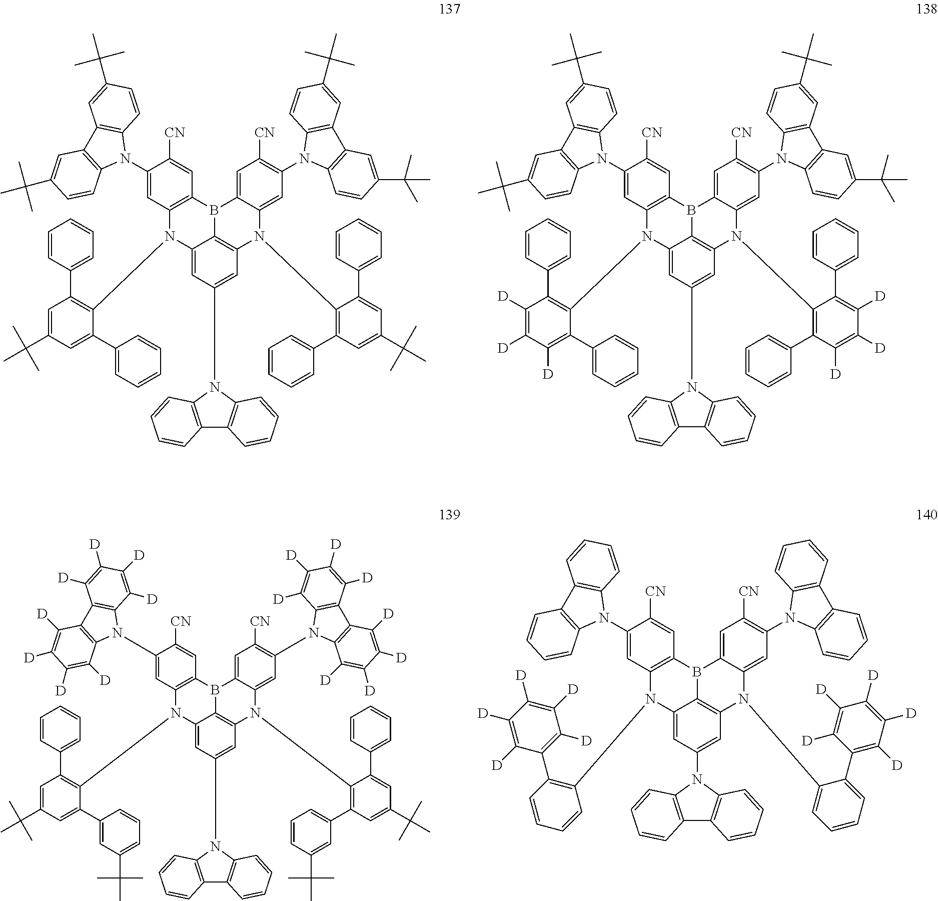 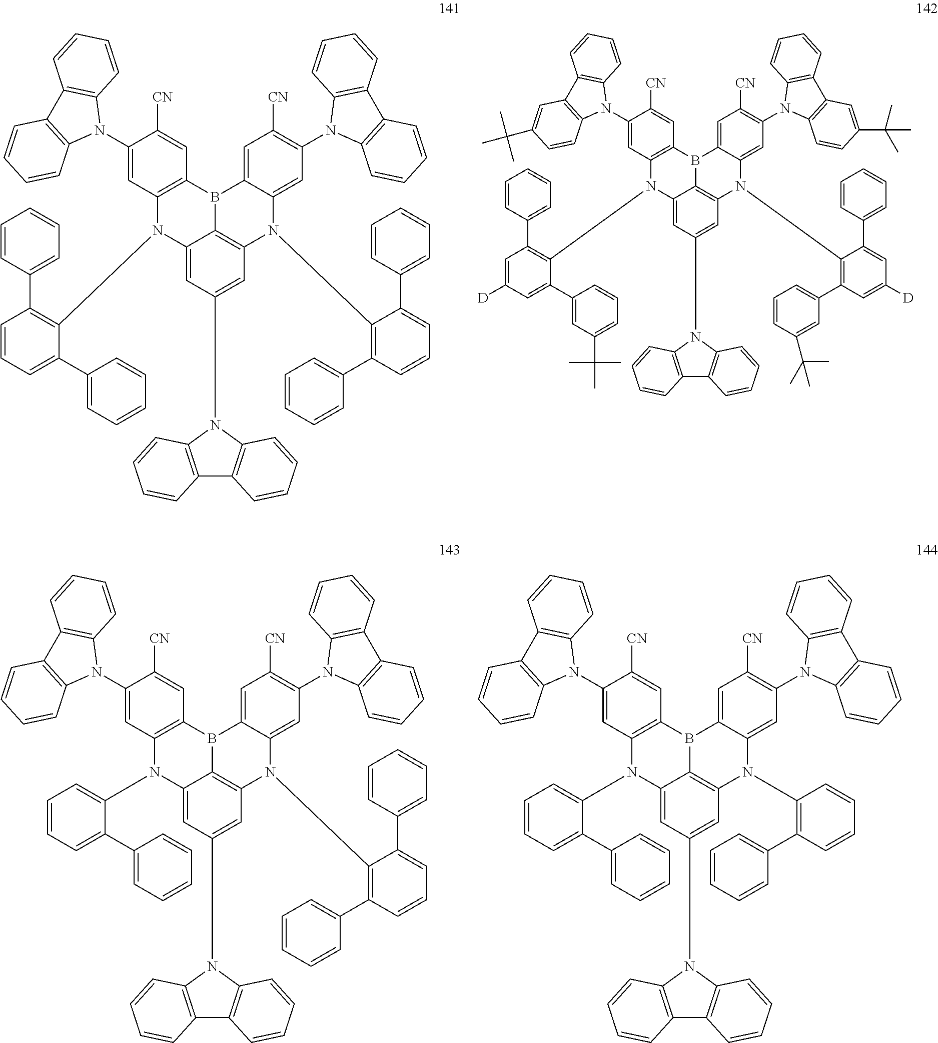 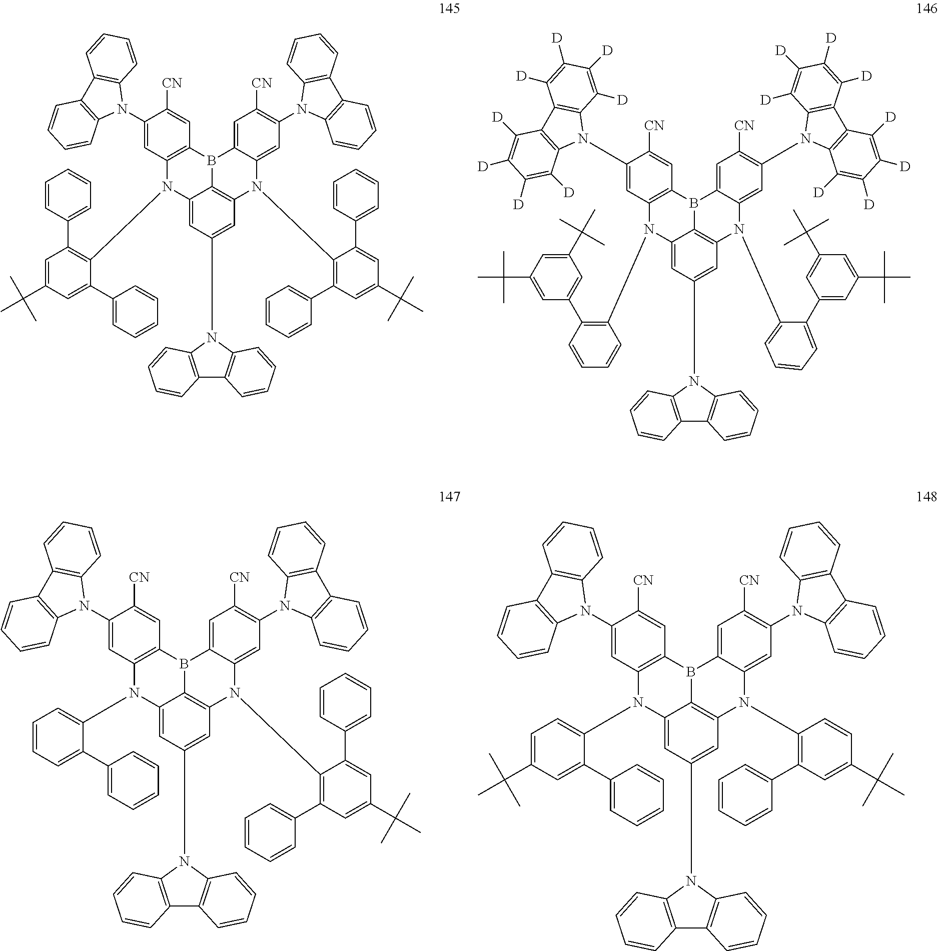 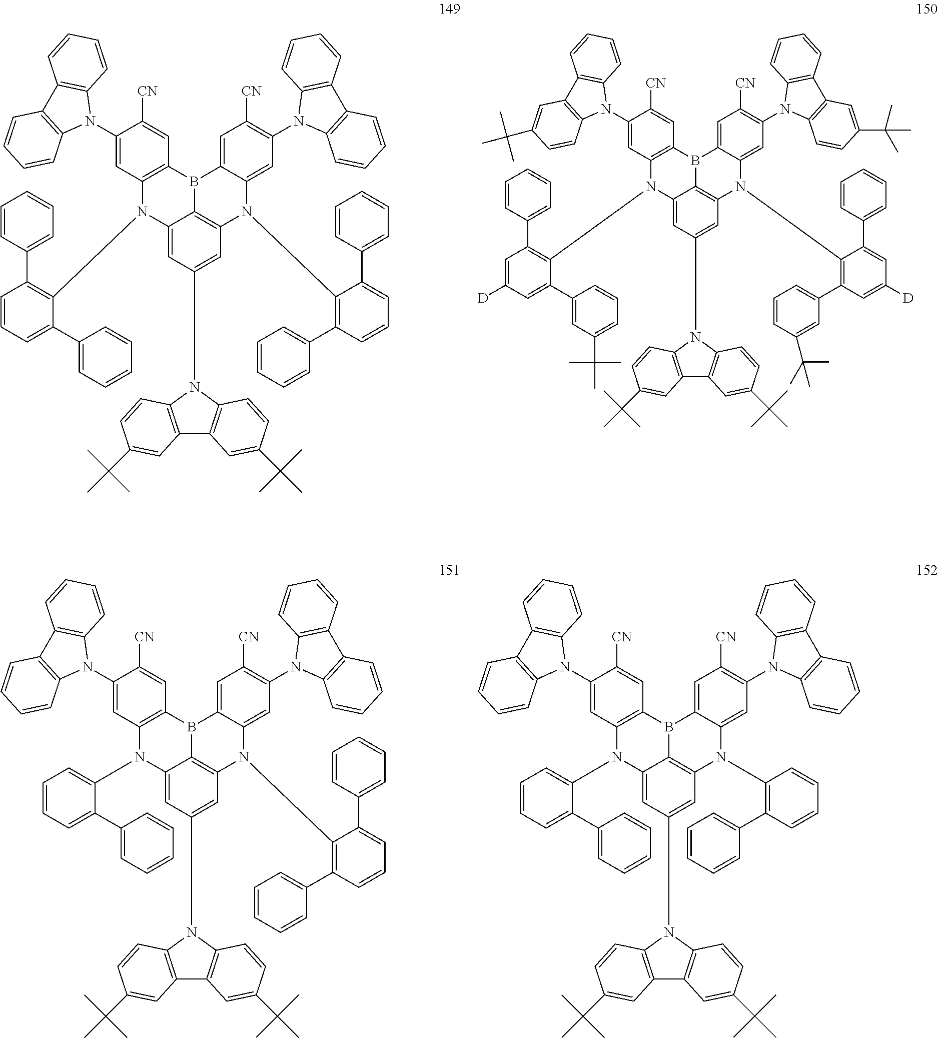 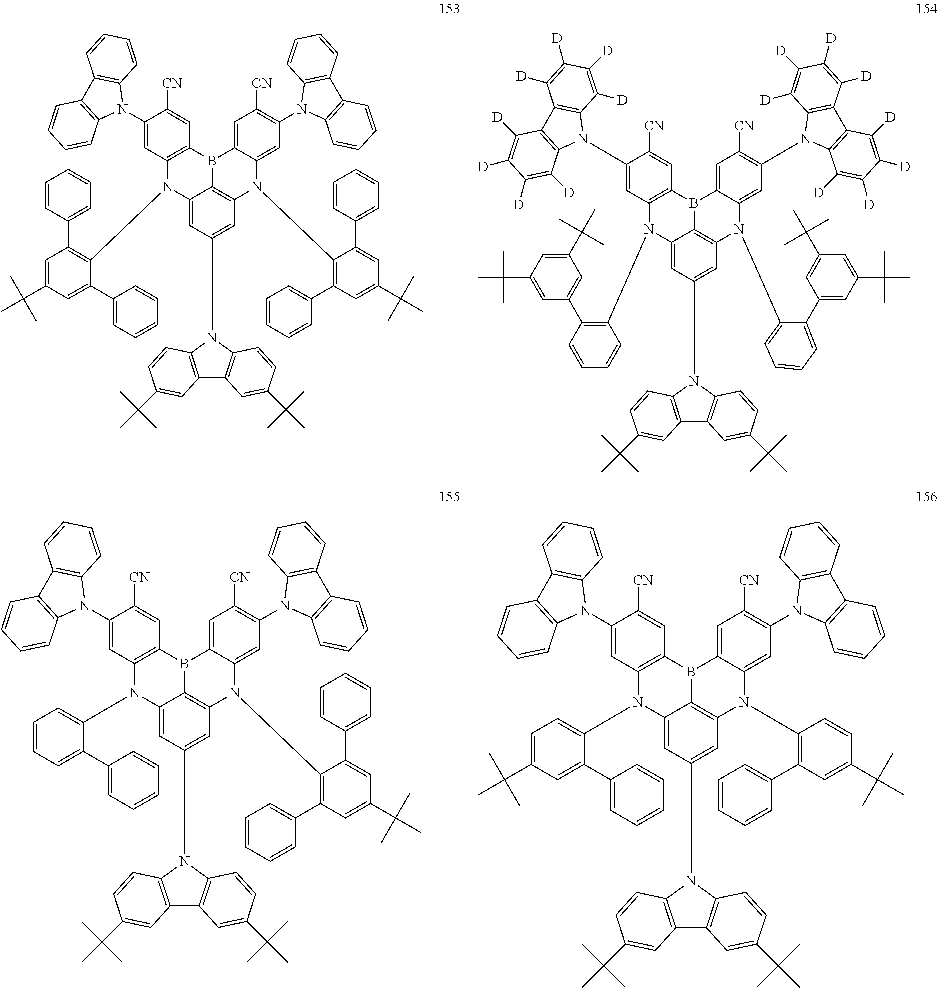 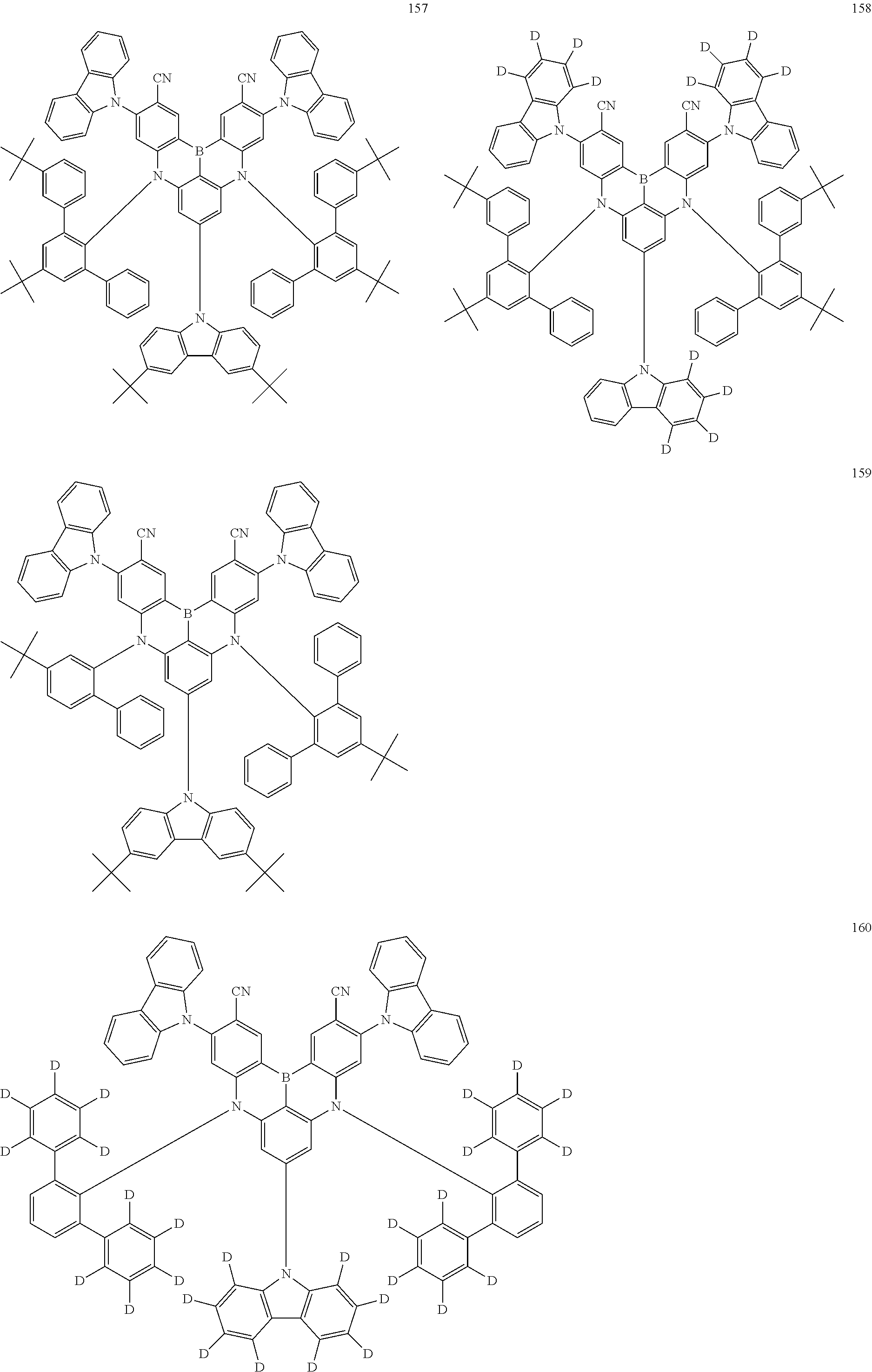 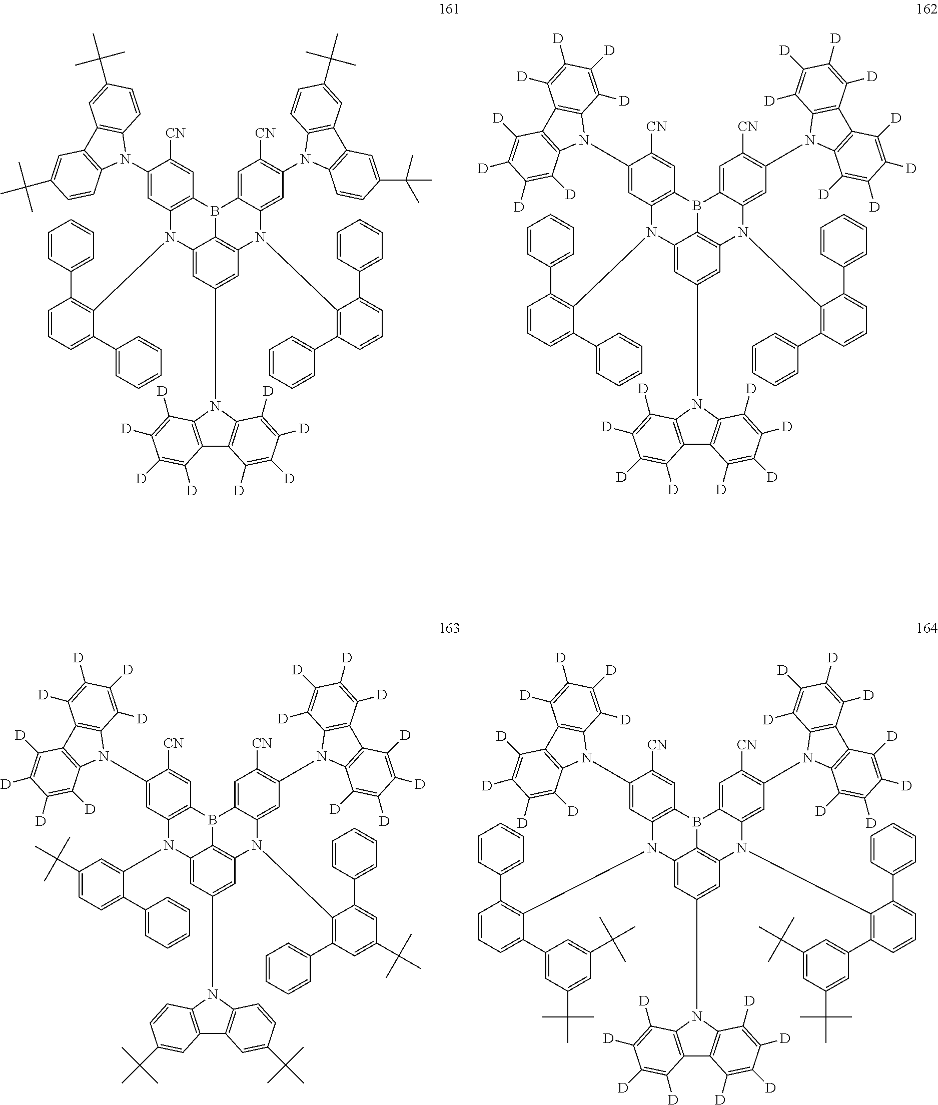 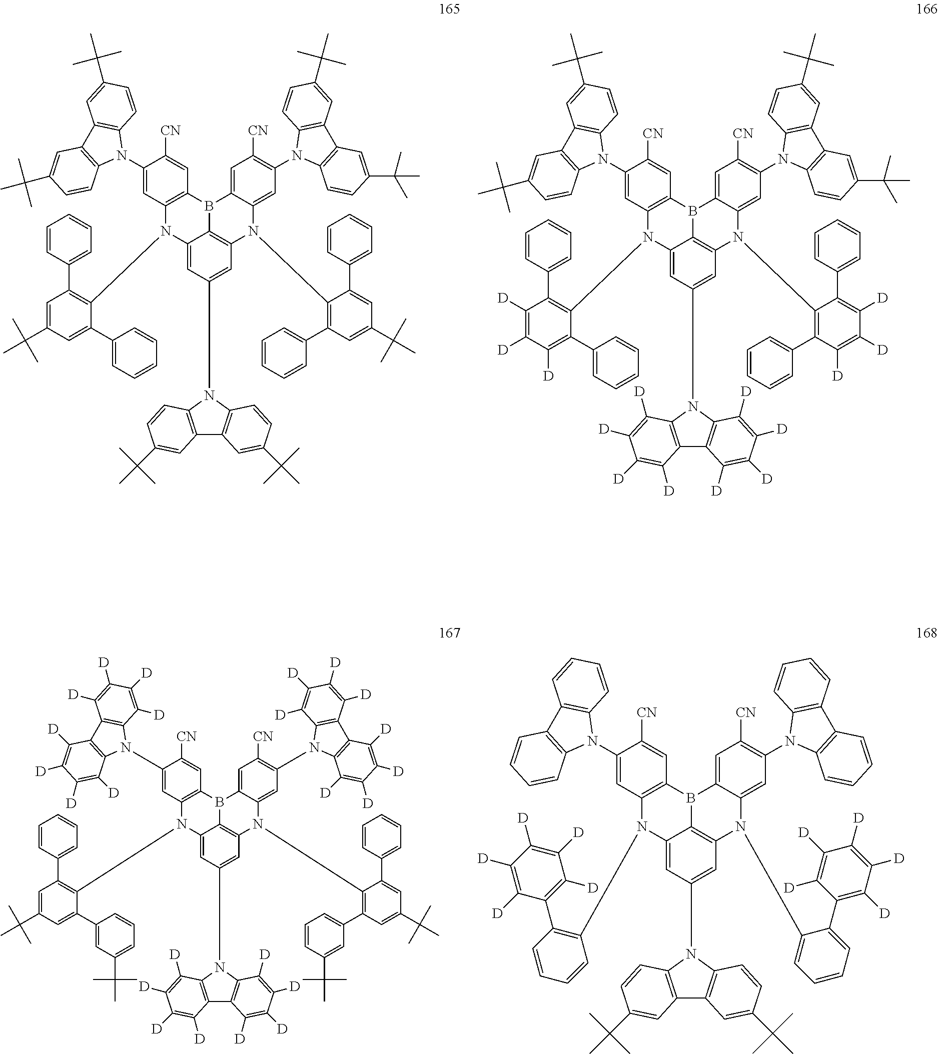 [chemical structure]
